(19) United States
(12) Patent Application Publication
(10) Pub. No.: US 2024/0143441 A1
(43) Pub. Date: May 2, 2024

(54) OPERATION METHOD OF SEMICONDUCTOR DEVICE

(71) Applicant: Semiconductor Energy Laboratory Co., Ltd., Atsugi-shi (JP)

(72) Inventors: Hidefumi RIKIMARU, Tama (JP); Seiko INOUE, Atsugi (JP); Hiromichi GODO, Isehara (JP); Yoshiyuki KUROKAWA, Sagamihara (JP)

(21) Appl. No.: 18/382,077

(22) Filed: Oct. 20, 2023

(30) Foreign Application Priority Data
Oct. 28, 2022 (JP) 2022-173321

(51) Int. Cl. G06F 11/10; G06F 7/544; G06F 11/07

(52) U.S. Cl. CPC G06F 11/1068; G06F 7/5443; G06F 11/076

(57) ABSTRACT

To provide an operation method of a semiconductor device in which a variation in arithmetic operation results is reduced. The semiconductor device includes first and second cell arrays and first to fifth circuits. First, third standard data is written from the fourth circuit to the second cell array, and first standard data is written from the first circuit to the first cell array. Then, second standard data is transmitted from the second circuit to the first cell array, a result of a product-sum operation of the first standard data and the second standard data is input from the first cell array to the third circuit, and fourth standard data corresponding to the result of the product-sum operation is transmitted from the third circuit to the second cell array. A result of a product-sum operation of the third standard data and the fourth standard data is input from the second cell array to the fifth circuit, and an output value corresponding to the result of the product-sum operation is output from the fifth circuit. Correction data corresponding to the difference between the output value and an expected value is retained in an empty cell of the first cell array and correction coefficients of the first and second cell arrays are calculated.

### BACKGROUND OF THE INVENTION

### 1. Field of the Invention

One embodiment of the present invention relates to an operation method of a semiconductor device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an image capturing device, a memory device, a signal processing device, a processor, an electronic device, a system, a driving method thereof, a manufacturing method thereof, and a testing method thereof.

### 2. Description of the Related Art

Integrated circuits that imitate the mechanism of the human brain are currently under active development. The integrated circuits incorporate electronic circuits as the brain mechanism and include circuits corresponding to neurons and synapses of the human brain. Such integrated circuits may therefore be referred to as “neuromorphic”, “brain-morphic”, or “brain-inspired” circuits, for example. The integrated circuits have a non-von Neumann architecture and are expected to be able to perform parallel processing with extremely low power consumption as compared with a von Neumann architecture, which consumes higher power with increasing processing speed.

An information processing model that imitates a biological neural network including neurons and synapses is referred to as an artificial neural network (ANN). For example, Non-Patent Documents 1 and 2 each disclose an arithmetic device including an artificial neural network constructed using a static random access memory (SRAM).

An attempt has been made to use an arithmetic device in which an artificial neural network is constructed, for example, for correction of images to be displayed by a display apparatus. For example, in a display apparatus disclosed in Patent Document 1, an arithmetic circuit in which an artificial neural network is constructed is used to adjust the luminance and tone of displayed images in accordance with the preference of the user.

### REFERENCE

### Patent Document

[Patent Document 1] Japanese Published Patent Application No. 2018-036639

### Non-Patent Documents

[Non-Patent Document 1] M. Kang et al., “IEEE Journal Of Solid-State Circuits”, 2018, Volume 53, No. 2, pp. 642-655.
[Non-Patent Document 2] J. Zhang et al., “IEEE Journal Of Solid-State Circuits”, 2017, Volume 52, No. 4, pp. 915-924.

### SUMMARY OF THE INVENTION

Examples of an arithmetic device in which an artificial neural network is constructed include an arithmetic circuit that performs a product-sum operation to yield the sum of analog currents each corresponding to the product of a weight coefficient and input data. Since the arithmetic circuit uses analog currents for an arithmetic operation, its circuit scale and circuit area can be smaller than those of an arithmetic circuit formed of a digital circuit. Furthermore, the arithmetic circuit can have lower power consumption when designed such that the analog current used in the arithmetic operation becomes lower.

In an example configuration of the above arithmetic circuit, a cell array is provided which includes a matrix of arithmetic cells performing multiplication of a weight coefficient and input data and outputting the multiplication result as an analog current. When the analog currents output from the arithmetic cells in one column are added up, for example, the sum of the analog current amounts can be dealt with as the value obtained by a product-sum operation of the weight coefficient and the input data, in which case a product-sum operation can be performed at a higher speed than in the case where a digital circuit is used.

In the case of using an arithmetic circuit that includes a cell array where arithmetic cells outputting analog currents are arranged in a matrix, on the other hand, there might be variations in the weight coefficient or input data input to the arithmetic cell, an output current from the arithmetic cell corresponding to the product of the weight coefficient and input data, and operation results of an activation function circuit, for example. Specifically, a hierarchical neural network as an artificial neural network, which performs a product-sum operation and an arithmetic operation of an activation function repetitively, sometimes produces arithmetic operation results having a greater variation when the number of layers and the number of neurons in a layer are larger. In that case, the accuracy rate of inference performed using the hierarchical neural network might be low.

An object of one embodiment of the present invention is to provide an operation method of a semiconductor device in which a variation in arithmetic operation results is reduced. Another object of one embodiment of the present invention is to provide an operation method of a semiconductor device in which the accuracy rate of inference performed using a hierarchical neural network is high.

Another object of one embodiment of the present invention is to provide a semiconductor device having a reduced circuit area. Another object of one embodiment of the present invention is to provide a semiconductor device in which arithmetic efficiency per area is not low even when small-scale calculation is performed. Another object of one embodiment of the present invention is to provide a display apparatus that includes any of the above semiconductor devices. Another object of one embodiment of the present invention is to provide an electronic device that includes the above display apparatus. Another object of one embodiment of the present invention is to provide a novel semiconductor device or a novel electronic device.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all the objects listed above and the other objects.

(1)

One embodiment of the present invention is an operation method of a semiconductor device that includes an error obtaining step, a first correction step, a second correction step, a third correction step, and an inference step. The semiconductor device includes a first cell array, a second cell array, a first circuit, a second circuit, a third circuit, a fourth circuit, and a fifth circuit. The first cell array includes a first arithmetic cell and a first driving cell, and the second cell array includes a second arithmetic cell and a second driving cell.

The error obtaining step includes a first step and a second step. The first step includes first to sixth substeps. The first substep includes a step in which second reference data is written from the second circuit to the first driving cell; a step in which a potential corresponding to the second reference data is input to the first arithmetic cell; and a step in which first reference data is written from the first circuit to the first arithmetic cell included in a first region of the first cell array. The second sub step includes a step in which a result of a product-sum operation of the first reference data and the second reference data is input from the first cell array to the third circuit; a step in which third reference data corresponding to the result of the product-sum operation of the first reference data and the second reference data is written from the third circuit to the second driving cell; a step in which a potential corresponding to the third reference data is input to the second arithmetic cell; and a step in which third standard data is written from the fourth circuit to the second arithmetic cell. The third substep includes a step in which second standard data is written from the second circuit to the first driving cell; and a step in which first standard data is written from the first circuit to the first arithmetic cell included in the first region of the first cell array. The fourth sub step includes a step in which a result of a product-sum operation of the first standard data and the second standard data is input from the first cell array to the third circuit; a step in which fourth standard data corresponding to the result of the product-sum operation of the first standard data and the second standard data is written from the third circuit to the second driving cell; a step in which a potential corresponding to the fourth standard data is input to the second arithmetic cell; a step in which a result of a product-sum operation of the third standard data and the fourth standard data is input from the second cell array to the fifth circuit; a step in which the fifth circuit outputs a first output value corresponding to the result of the product-sum operation of the third standard data and the fourth standard data; and a step of obtaining a theoretical value that is the result of the product-sum operation of the first standard data and the second standard data. The fifth substep includes a step of updating the first standard data and the second standard data and a step of repetitively performing the third sub step and the fourth sub step. The sixth sub step includes a step of creating a first graph using a plurality of the theoretical values and a plurality of the first output values obtained in updates of the first standard data and the second standard data by the fourth substep repetitively performed.

The second step includes a step of calculating, as a first error, the theoretical value such that the first output value is smallest and larger than 0 from the first graph; and a step of calculating a second error that is a difference between a gradient in a range in which the first output value is larger than 0 in the first graph and a gradient in a range in which the first output value is larger than 0 in a standard graph.

The first correction step includes a step of obtaining correction data from the first error. The second correction step includes a step of obtaining a first correction coefficient from the second error. The third correction step includes a step of obtaining a second correction coefficient from the second error. The inference step includes a step in which data retained in the first cell array reflects the correction data and the first correction coefficient and data retained in the second cell array reflects the second correction coefficient.

(2)

In another embodiment of the present invention, the operation method according to (1) above may further include third to sixth steps. In particular, the third step preferably includes a step of proceeding to the fourth step when the first error is outside a first allowable range, and the fourth step preferably includes a step of generating the correction data corresponding to the first error.

The fifth step preferably includes seventh to tenth substeps. The seventh substep preferably includes a step in which the second standard data is written from the second circuit to the first driving cell; a step in which the first standard data is written from the first circuit to the first arithmetic cell included in the first region of the first cell array; and a step in which the correction data is written from the first circuit to the first arithmetic cell included in a second region of the first cell array. The eighth substep preferably includes a step in which a result of a product-sum operation of the second standard data and a sum of the first standard data and the correction data is input from the first cell array to the third circuit; a step in which fifth standard data corresponding to the result of the product-sum operation of the second standard data and the sum of the first standard data and the correction data is written from the third circuit to the second driving cell; a step in which a potential corresponding to the fifth standard data is input to the second arithmetic cell; a step in which a result of a product-sum operation of the third standard data and the fifth standard data is input from the second cell array to the fifth circuit; and a step in which the fifth circuit outputs a second output value corresponding to the result of the product-sum operation of the third standard data and the fifth standard data. The ninth sub step preferably includes a step of updating the first standard data and the second standard data and a step of repetitively performing the seventh substep and the eighth sub step. The tenth sub step preferably includes a step of creating a second graph using a plurality of the second output values obtained in updates of the first standard data and the second standard data by the ninth sub step repetitively performed and the plurality of theoretical values.

The sixth step preferably includes a step in which the theoretical value such that the second output value is smallest and larger than 0 is calculated from the second graph and the theoretical value is updated to the first error. It is preferable that the third step be performed immediately after the sixth step.

(3)

In another embodiment of the present invention, the operation method according to (2) above may further include seventh to tenth steps. The third step in (2) preferably includes a step of proceeding to the seventh step when the first error is within the first allowable range or when the third step is repeated a first predetermined number of times. The seventh step preferably includes a step of proceeding to the eighth step when the second error is outside a second allowable range.

The eighth step preferably includes eleventh to thirteenth sub steps. The eleventh substep preferably includes a step in which the second reference data is written from the second circuit to the first driving cell; a step in which a potential corresponding to the second reference data is input to the first arithmetic cell; a step in which the first reference data is written from the first circuit to the first arithmetic cell included in the first region of the first cell array; and a step in which the correction data is written from the first circuit to the first arithmetic cell included in the second region of the first cell array. The twelfth substep preferably includes a step in which a result of a product-sum operation of the second reference data and a sum of the first reference data and the correction data is input from the first cell array to the third circuit; a step in which fourth reference data corresponding to the result of the product-sum operation of the second reference data and the sum of the first reference data and the correction data is written from the third circuit to the second driving cell; a step in which a potential corresponding to the fourth reference data is input to the second arithmetic cell; a step of generating the first correction coefficient corresponding to the second error; and a step in which sixth standard data that is a product of the third standard data and the first correction coefficient is written from the fourth circuit to the second arithmetic cell. The thirteenth substep preferably includes a step in which the second standard data is written from the second circuit to the first driving cell; a step in which the first standard data is written from the first circuit to the first arithmetic cell included in the first region of the first cell array; and a step in which the correction data is written from the first circuit to the first arithmetic cell included in the second region of the first cell array. The ninth step preferably includes fourteenth to sixteenth substeps. The fourteenth substep preferably includes a step in which the result of the product-sum operation of the second standard data and the sum of the first standard data and the correction data is input from the first cell array to the third circuit; a step in which the fifth standard data corresponding to the result of the product-sum operation of the second standard data and the sum of the first standard data and the correction data is written from the third circuit to the second driving cell; a step in which a potential corresponding to the fifth standard data is input to the second arithmetic cell; a step in which a result of a product-sum operation of the sixth standard data and the fifth standard data is input from the second cell array to the fifth circuit; and a step in which the fifth circuit outputs a third output value corresponding to the result of the product-sum operation of the sixth standard data and the fifth standard data. The fifteenth sub step preferably includes a step of updating the first standard data and the second standard data and a step of repetitively performing the thirteenth sub step and the fourteenth sub step. The sixteenth sub step preferably includes a step of creating a third graph using a plurality of the third output values obtained in updates of the first standard data and the second standard data by the fourteenth sub step repetitively performed and the plurality of theoretical values.

The tenth step preferably includes a step of updating, to the second error, a difference between a gradient in a range in which the first output value is larger than 0 in the third graph and a gradient in the standard graph. It is preferable that the seventh step be performed immediately after the tenth step.

(4)

In another embodiment of the present invention, the operation method according to (3) above may further include eleventh to fourteenth steps. The seventh step in (3) preferably includes a step of proceeding to the eleventh step when the second error is within the second allowable range or when the seventh step is repeated a second predetermined number of times. The eleventh step preferably includes a step of proceeding to the twelfth step when the second error is outside the second allowable range.

The twelfth step preferably includes seventeenth to nineteenth substeps. The seventeenth substep preferably includes a step in which the second reference data is written from the second circuit to the first driving cell; a step in which a potential corresponding to the second reference data is input to the first arithmetic cell; a step of generating the second correction coefficient corresponding to the second error; and a step in which fifth reference data that is a product of the first reference data and the second correction coefficient is written from the first circuit to the first arithmetic cell. The eighteenth sub step preferably includes a step in which a result of a product-sum operation of the second reference data and a sum of the fifth reference data and the correction data is input from the first cell array to the third circuit; a step in which sixth reference data corresponding to the result of the product-sum operation of the second reference data and the sum of the fifth reference data and the correction data is written from the third circuit to the second driving cell; a step in which a potential corresponding to the sixth reference data is input to the second arithmetic cell; and a step in which the sixth standard data is written from the fourth circuit to the second arithmetic cell. The nineteenth substep preferably includes a step in which the second standard data is written from the second circuit to the first driving cell; a step in which the first standard data is written from the first circuit to the first arithmetic cell included in the first region of the first cell array; and a step in which the correction data is written from the first circuit to the first arithmetic cell included in the second region of the first cell array. The thirteenth step preferably includes twentieth to twenty-second substeps. The twentieth substep preferably includes a step in which the result of the product-sum operation of the second standard data and the sum of the first standard data and the correction data is input from the first cell array to the third circuit; a step in which the fifth standard data corresponding to the result of the product-sum operation of the second standard data and the sum of the first standard data and the correction data is written from the third circuit to the second driving cell; a step in which a potential corresponding to the fifth standard data is input to the second arithmetic cell and the second driving cell; a step in which the result of the product-sum operation of the sixth standard data and the fifth standard data is input from the second cell array to the fifth circuit; and a step in which the fifth circuit outputs a fourth output value corresponding to the result of the product-sum operation of the sixth standard data and the fifth standard data. The twenty-first sub step preferably includes a step of updating the first standard data and the second standard data and a step of repetitively performing the nineteenth substep and the twentieth substep. The twenty-second sub step preferably includes a step of creating a fourth graph using a plurality of the fourth output values obtained in updates of the first standard data and the second standard data by the twentieth substep repetitively performed and the plurality of theoretical values.

The fourteenth step preferably includes a step of updating, to the second error, a difference between a gradient in a range in which the fourth output value is larger than 0 in the fourth graph and a gradient in the standard graph. It is preferable that the eleventh step be performed immediately after the fourteenth step.

(5)

In another embodiment of the present invention, the operation method according to (4) above may further include a fifteenth step. The eleventh step preferably includes a step of proceeding to the fifteenth step when the second error is within the second allowable range or when the eleventh step is repeated a third predetermined number of times. The fifteenth step preferably includes a step of proceeding to the third step when the first error is outside the first allowable range and the second error is outside the second allowable range.

(6)

Another embodiment of the present invention may be the operation method of the semiconductor device according to (5) above in which the third circuit is electrically connected to the first arithmetic cell through a first wiring, the third circuit is electrically connected to the second driving cell and the second arithmetic cell through a second wiring, the fifth circuit is electrically connected to the second arithmetic cell through a third wiring, and the fifth circuit is electrically connected to a fourth wiring. In particular, the third circuit preferably has a function of performing an arithmetic operation of a first activation function using, as an input value, an amount of a first current flowing in the first wiring and supplying a result of the arithmetic operation of the first activation function as a current to the second wiring. The fifth circuit preferably has a function of performing an arithmetic operation of a second activation function using, as an input value, an amount of a third current flowing in the third wiring and outputting a result of the arithmetic operation of the second activation function as digital data to the fourth wiring.

(7)

Another embodiment of the present invention may be the operation method of the semiconductor device according to (6) above in which the first arithmetic cell includes a first transistor, a second transistor, and a first capacitor, the second arithmetic cell includes a third transistor, a fourth transistor, and a second capacitor, the first driving cell includes a fifth transistor, a sixth transistor, and a third capacitor, and the second driving cell includes a seventh transistor, an eighth transistor, and a fourth capacitor.

In particular, it is preferable that one of a source and a drain of the first transistor be electrically connected to a gate of the second transistor and a first terminal of the first capacitor and the other of the source and the drain of the first transistor be electrically connected to one of a source and a drain of the second transistor and the first wiring. It is preferable that one of a source and a drain of the third transistor be electrically connected to a gate of the fourth transistor and a first terminal of the second capacitor and the other of the source and the drain of the third transistor be electrically connected to one of a source and a drain of the fourth transistor and the third wiring. It is preferable that one of a source and a drain of the fifth transistor be electrically connected to a gate of the sixth transistor and a first terminal of the third capacitor and the other of the source and the drain of the fifth transistor be electrically connected to one of a source and a drain of the sixth transistor and a fifth wiring. It is preferable that one of a source and a drain of the seventh transistor be electrically connected to a gate of the eighth transistor and a first terminal of the fourth capacitor and the other of the source and the drain of the seventh transistor be electrically connected to one of a source and a drain of the eighth transistor and the second wiring. It is preferable that a second terminal of the first capacitor and a second terminal of the third capacitor be electrically connected to the fifth wiring and a second terminal of the second capacitor and a second terminal of the fourth capacitor be electrically connected to the second wiring. It is preferable that the first circuit be electrically connected to the first wiring, the second circuit be electrically connected to the fifth wiring, and the fourth circuit be electrically connected to the third wiring.

(8)

Another embodiment of the present invention may be the operation method of the semiconductor device according to (7) above in which the first arithmetic cell includes a ninth transistor, the second arithmetic cell includes a tenth transistor, the first driving cell includes an eleventh transistor, and the second driving cell includes a twelfth transistor.

In particular, it is preferable that one of a source and a drain of the ninth transistor be directly and electrically connected to the other of the source and the drain of the first transistor and the first wiring and the other of the source and the drain of the ninth transistor be directly and electrically connected to the one of the source and the drain of the second transistor. It is preferable that one of a source and a drain of the tenth transistor be directly and electrically connected to the other of the source and the drain of the third transistor and the third wiring and the other of the source and the drain of the tenth transistor be directly and electrically connected to the one of the source and the drain of the fourth transistor. It is preferable that one of a source and a drain of the eleventh transistor be directly and electrically connected to the other of the source and the drain of the fifth transistor and the fifth wiring and the other of the source and the drain of the eleventh transistor be directly and electrically connected to the one of the source and the drain of the sixth transistor. It is preferable that one of a source and a drain of the twelfth transistor be directly and electrically connected to the other of the source and the drain of the seventh transistor and the second wiring and the other of the source and the drain of the twelfth transistor be directly and electrically connected to the one of the source and the drain of the eighth transistor.

(9)

Another embodiment of the present invention may be the operation method of the semiconductor device according to (8) above in which a channel formation region of each of the first to twelfth transistors contains one or more of indium, zinc, and an element M.

The element M is one or more of aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

According to one embodiment of the present invention, an operation method of a semiconductor device in which a variation in arithmetic operation results is reduced can be provided. According to another embodiment of the present invention, an operation method of a semiconductor device in which the accuracy rate of inference performed using a hierarchical neural network is high can be provided.

According to another embodiment of the present invention, a semiconductor device having a reduced circuit area can be provided. According to another embodiment of the present invention, a semiconductor device in which arithmetic efficiency per area is not low even when small-scale calculation is performed can be provided. According to another embodiment of the present invention, a display apparatus that includes any of the above semiconductor devices can be provided. According to another embodiment of the present invention, an electronic device that includes the above display apparatus can be provided. According to another embodiment of the present invention, a novel semiconductor device or a novel electronic device can be provided.

Note that the effects of one embodiment of the present invention are not limited to the effects mentioned above. The effects described above do not preclude the existence of other effects. The other effects are the ones that are not described above and will be described below. Effects that are not described above will be apparent from and can be appropriately derived from the description of the specification, the drawings, and the like by those skilled in the art. One embodiment of the present invention has at least one of the above effects and the other effects. Accordingly, one embodiment of the present invention does not have the above effects in some cases.

### BRIEF DESCRIPTION OF THE DRAWINGS

FIG. 1 is a block diagram illustrating a configuration example of a semiconductor device.

FIG. 2 is a block diagram illustrating a configuration example of a semiconductor device.

FIG. 3 is a circuit diagram illustrating a configuration example of a semiconductor device.

FIG. 4A is a block diagram illustrating a configuration example of a circuit included in a semiconductor device, FIG. 4B is a circuit diagram illustrating a configuration example of a circuit included in the semiconductor device, and FIG. 4C is a block diagram illustrating a configuration example of a circuit included in the semiconductor device.

FIGS. 5A to 5D are circuit diagrams each illustrating a configuration example of a circuit included in a semiconductor device.

FIG. 6 is a circuit diagram illustrating a configuration example of a circuit included in a semiconductor device.

FIG. 7 is a timing chart illustrating an operation example of a semiconductor device.

FIG. 8 is a circuit diagram illustrating a configuration example of a circuit included in a semiconductor device.

FIG. 9 is a block diagram illustrating a configuration example of a semiconductor device.

FIG. 10 is a block diagram illustrating a configuration example of a circuit included in a semiconductor device.

FIG. 11 is a circuit diagram illustrating a configuration example of a semiconductor device.

FIGS. 12A to 12C are circuit diagrams each illustrating a configuration example of a circuit included in a semiconductor device.

FIG. 13 is a block diagram illustrating a configuration example of a semiconductor device.

FIG. 14 is a flowchart illustrating an example of an operation method of a semiconductor device.

FIG. 15 is a block diagram illustrating an example of an operation method of a semiconductor device.

FIG. 16 is a block diagram illustrating an example of an operation method of a semiconductor device.

FIG. 17 is a block diagram illustrating an example of an operation method of a semiconductor device.

FIG. 18 is a block diagram illustrating an example of an operation method of a semiconductor device.

FIG. 19 is a block diagram illustrating an example of an operation method of a semiconductor device.

FIG. 20 is a block diagram illustrating an example of an operation method of a semiconductor device.

FIG. 21 is a block diagram illustrating an example of an operation method of a semiconductor device.

FIG. 22 is a block diagram illustrating an example of an operation method of a semiconductor device.

FIG. 23 is a block diagram illustrating an example of an operation method of a semiconductor device.

FIG. 24 is a block diagram illustrating an example of an operation method of a semiconductor device.

FIG. 25 is a block diagram illustrating an example of an operation method of a semiconductor device.

FIG. 26 is a block diagram illustrating a configuration example of part of a semiconductor device.

FIG. 27 is a flowchart illustrating an example of an operation method of a semiconductor device.

FIG. 28 is a flowchart illustrating an example of an operation method of a semiconductor device.

FIG. 29 is a flowchart illustrating an example of an operation method of a semiconductor device.

FIGS. 30A and 30B are graphs each illustrating an example of an output result in an operation method of a semiconductor device.

FIGS. 31A and 31B are graphs each illustrating an example of an output result in an operation method of a semiconductor device.

FIGS. 32A and 32B illustrate a hierarchical neural network.

FIG. 33 is a block diagram illustrating a configuration example of a semiconductor device.

FIGS. 34A and 34B are schematic perspective views each illustrating a structure example of a semiconductor device.

FIG. 35 is a block diagram illustrating a configuration example of a semiconductor device.

FIG. 36 is a block diagram illustrating a configuration example of a semiconductor device.

FIG. 37 is a block diagram illustrating a configuration example of a semiconductor device.

FIG. 38 is a schematic cross-sectional view illustrating a structure example of a semiconductor device.

FIG. 39 is a schematic cross-sectional view illustrating a structure example of a semiconductor device.

FIG. 40 is a schematic cross-sectional view illustrating a structure example of a semiconductor device.

FIG. 41 is a circuit diagram illustrating an example of a memory cell included in a semiconductor device.

FIG. 42 is a schematic perspective view illustrating a structure example of a semiconductor device.

FIGS. 43A to 43C are plan views illustrating a structure example of a transistor included in a semiconductor device, and FIG. 43D is a cross-sectional view illustrating the structure example of the transistor included in the semiconductor device.

FIGS. 44A and 44B are a plan view and a cross-sectional view, respectively, illustrating a structure example of a transistor included in a semiconductor device.

FIGS. 45A and 45B illustrate examples of electronic components.

FIGS. 46A and 46B illustrate examples of electronic devices, and FIGS. 46C to 46E illustrate an example of a large computer.

FIG. 47 illustrates an example of space equipment.

FIG. 48 illustrates an example of a storage system that can be used for a data center.

### DETAILED DESCRIPTION OF THE INVENTION

In this specification and the like, a semiconductor device means a device that utilizes semiconductor characteristics, and refers to a circuit including a semiconductor element (e.g., a transistor, a diode, or a photodiode), and a device including the circuit. The semiconductor device also means devices that can function by utilizing semiconductor characteristics. As an example of a semiconductor device, an integrated circuit can be given. As another example of a semiconductor device, a chip that includes an integrated circuit can be given. As another example of a semiconductor device, an electronic component in which a chip is stored in a package can be given. Furthermore, a memory device, a display apparatus, a light-emitting apparatus, a lighting device, and an electronic device themselves are semiconductor devices in some cases and include a semiconductor device in other cases.

In this specification and the like, the connection strength between synapses in an artificial neural network (hereinafter sometimes referred to as a neural network) can be changed when existing information is given to the neural network. Such processing for determining weight coefficients (sometimes rephrased as connection strengths) by providing a neural network with existing information is sometimes called learning.

When a neural network in which “learning” has been performed (weight coefficients have been determined) is provided with some information, new information can be output on the basis of the connection strengths. Such processing for outputting new information on the basis of provided information and connection strengths in a neural network is sometimes called inference or recognition.

Examples of neural network models include a Hopfield neural network and a hierarchical neural network. Specifically, a multilayer neural network may be called a deep neural network (DNN), and machine learning using a deep neural network may be called deep learning.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow(s) electrical connection between X and Y (e.g., a switch, a transistor, a capacitor element, an inductor, a resistor element, a diode, a display device, a light-emitting device, or a load) can be connected between X and Y. Note that a switch has a function of being controlled to be turned on or off. That is, the switch has a function of being in a conduction state (on state) or a non-conduction state (off state) to control whether a current flows or not.

For example, in the case where X and Y are functionally connected, one or more circuits that allow(s) functional connection between X and Y (e.g., a logic circuit (an inverter, a NAND circuit, a NOR circuit, or the like); a signal converter circuit (a digital-to-analog converter circuit, an analog-to-digital converter circuit, a gamma correction circuit, or the like); a potential level converter circuit (a power supply circuit such as a step-up circuit or a step-down circuit, a level shifter circuit for changing the potential level of a signal, or the like); a voltage source; a current source; a switching circuit; an amplifier circuit (a circuit that can increase signal amplitude, current amount, or the like, an operational amplifier, a differential amplifier circuit, a source follower circuit, a buffer circuit, or the like); a signal generation circuit; a memory circuit; or a control circuit) can be connected between X and Y. For example, even when another circuit is interposed between X and Y, X and Y are functionally connected when a signal output from X is transmitted to Y.

Note that an explicit description, X and Y are electrically connected, includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

This specification describes a circuit configuration in which a plurality of elements are electrically connected to a wiring (a wiring for supplying a constant potential or a wiring for transmitting a signal). For example, in the case in which X is directly connected to a wiring and Y is directly connected to the wiring, this specification may describe that X and Y are directly and electrically connected to each other.

The expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used, for example. Alternatively, the expression “a source of a transistor is electrically connected to X; a drain of the transistor is electrically connected to Y; and X, the source of the transistor, the drain of the transistor, and Y are electrically connected to each other in this order” can be used. Alternatively, the expression “X is electrically connected to Y through a source and a drain of a transistor, and X, the source of the transistor, the drain of the transistor, and Y are provided in this connection order” can be used. When the connection order in a circuit configuration is defined by an expression similar to the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “resistor element” can be, for example, a circuit element or a wiring having a resistance higher than 0Ω. Therefore, in this specification and the like, a “resistor element” includes a wiring having a resistance, a transistor in which a current flows between its source and drain, a diode, and a coil. Thus, the term “resistor element” can be sometimes replaced with a term such as “resistor”, “load”, or “region having a resistance”; conversely, a term such as “resistor”, “load”, or “region having a resistance” can be sometimes replaced with the term “resistor element”. The resistance can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance may be higher than or equal to 1Ω and lower than or equal to 1×10⁹Ω.

In this specification and the like, a “capacitor element” can be, for example, a circuit element having an electrostatic capacitance higher than 0 F, a region of a wiring having an electrostatic capacitance higher than 0 F, parasitic capacitance, or gate capacitance of a transistor. Terms such as “capacitor”, “parasitic capacitance”, and “gate capacitance” can be replaced with the term “capacitance” in some cases. Conversely, the term “capacitance” can be replaced with a term such as “capacitor”, “parasitic capacitance”, or “gate capacitance” in some cases. In addition, the “capacitor” (including a capacitor with three or more terminals) includes an insulator and a pair of conductors between which the insulator is interposed. The term “a pair of conductors” of a capacitor can be replaced with the term “a pair of electrodes”, “a pair of conductive regions”, “a pair of regions”, or “a pair of terminals”. In addition, the terms “one of a pair of terminals” and “the other of the pair of terminals” are referred to as a first terminal and a second terminal, respectively, in some cases. Note that the electrostatic capacitance can be higher than or equal to 0.05 fF and lower than or equal to 10 pF, for example. For example, the electrostatic capacitance may be higher than or equal to 1 pF and lower than or equal to 10 μF.

In this specification and the like, a transistor includes three terminals called a gate, a source, and a drain. The gate is a control terminal for controlling the on/off state of the transistor. The two terminals functioning as the source and the drain are input/output terminals of the transistor. Functions of the two input/output terminals of the transistor depend on the conductivity type (n-channel type or p-channel type) of the transistor and the levels of potentials applied to the three terminals of the transistor, and one of the two terminals serves as a source and the other serves as a drain. Therefore, the terms “source” and “drain” can be sometimes used interchangeably in this specification and the like. In this specification and the like, the terms “one of a source and a drain” (or a first electrode or a first terminal) and “the other of the source and the drain” (or a second electrode or a second terminal) are used to describe the connection relation of a transistor. Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of an off-state current can be reduced, and the breakdown voltage of the transistor can be increased (the reliability can be improved). Alternatively, with the multi-gate structure, a drain-source current does not change very much even if a drain-source voltage changes when the transistor operates in a saturation region, so that a flat slope of voltage-current characteristics can be obtained. By utilizing the flat slope of the voltage-current characteristics, an ideal current source circuit or an active load having an extremely high resistance can be obtained. Accordingly, a differential circuit, a current mirror circuit, or the like having excellent properties can be obtained.

A single circuit element shown in a circuit diagram may include a plurality of circuit elements. For example, a single resistor shown in a circuit diagram may be two or more resistors electrically connected to each other in series. For another example, a single capacitor shown in a circuit diagram may be two or more capacitors electrically connected to each other in parallel. For another example, a single transistor shown in a circuit diagram may be two or more transistors which are electrically connected to each other in series and whose gates are electrically connected to each other. For another example, a single switch shown in a circuit diagram may be a switch including two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit configuration and the device structure. Furthermore, a terminal, a wiring, and the like can be referred to as a node.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values, and a potential supplied to a wiring, a potential applied to a circuit and the like, and a potential output from a circuit and the like are changed with a change of the reference potential.

In this specification and the like, the term “high-level potential” or “low-level potential” does not mean a particular potential. For example, in the case where two wirings are both described as “functioning as a wiring for supplying a high-level potential”, the levels of the high-level potentials that these wirings supply are not necessarily equal to each other. Similarly, in the case where two wirings are both described as “functioning as a wiring for supplying a low-level potential”, the levels of the low-level potentials that these wirings supply are not necessarily equal to each other.

A current means an electric charge transfer (electrical conduction); for example, the expression “electrical conduction of positively charged particles is caused” can be replaced with “electrical conduction of negatively charged particles is caused in the opposite direction”. Therefore, unless otherwise specified, a current in this specification and the like refers to an electric charge transfer (electrical conduction) caused by carrier movement. Examples of a carrier here include an electron, a hole, an anion, a cation, and a complex ion, and the type of carrier differs between current flow systems (e.g., a semiconductor, a metal, an electrolyte solution, and a vacuum). The direction of a current in a wiring or the like refers to the direction in which a carrier with a positive electric charge moves, and the current amount is expressed as a positive value. In other words, the direction in which a carrier with a negative electric charge moves is opposite to the direction of a current, and the current amount is expressed as a negative value. Thus, in the case where the polarity of a current (or the direction of a current) is not specified in this specification and the like, the expression “a current flows from an element A to an element B” can be replaced with “a current flows from an element B to an element A”. The expression “a current is input to an element A” can be replaced with “a current is output from an element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or claims. For another example, a “first” component in one embodiment in this specification and the like can be omitted in other embodiments or claims.

In this specification and the like, terms for describing arrangement, such as “over”, “above”, “under”, and “below”, are sometimes used for convenience to describe the positional relation between components with reference to drawings. The positional relation between components is changed as appropriate in accordance with the direction from which each component is described. Thus, the positional relation is not limited to that described with a term used in this specification and the like and can be explained with another term as appropriate depending on the situation. For example, the expression “an insulator over (on) a top surface of a conductor” can be replaced with the expression “an insulator on a bottom surface of a conductor” when the direction of a diagram showing these components is rotated by 180°.

Terms such as “over”, “above”, “under”, and “below” do not necessarily mean that a component is placed directly on or under and directly in contact with another component. For example, the expression “an electrode B over an insulating layer A” does not necessarily mean that the electrode B is on and in direct contact with the insulating layer A, and can mean the case where another component is provided between the insulating layer A and the electrode B. In a similar manner, for example, the expression “an electrode B above an insulating layer A” does not necessarily mean that the electrode B is over and in direct contact with the insulating layer A, and can mean the case where another component is provided between the insulating layer A and the electrode B. In a similar manner, for example, the expression “an electrode B below an insulating layer A” does not necessarily mean that the electrode B is under and in direct contact with the insulating layer A, and can mean the case where another component is provided between the insulating layer A and the electrode B.

In this specification and the like, components arranged in a matrix and their positional relation are sometimes described using terms such as “row” and “column”. The positional relation between components is changed as appropriate in accordance with the direction from which each component is described. Thus, the positional relation is not limited to that described with a term used in this specification and the like and can be explained with another term as appropriate depending on the situation. For example, the term “row direction” can be replaced with the term “column direction” when the direction of the diagram is rotated by 90°.

In this specification and the like, terms such as “film” and “layer” can be interchanged with each other depending on circumstances. For example, the term “conductive layer” can be changed to the term “conductive film” in some cases. Moreover, the term “insulating film” can be changed into the term “insulating layer” in some cases. Moreover, such terms can be replaced with a word not including a term such as “film” or “layer” depending on the case or circumstances. For example, the term “conductive layer” or “conductive film” can be changed into the term “conductor” in some cases. For example, in some cases, the term “insulating layer” or “insulating film” can be changed into the term “insulator” in some cases.

In this specification and the like, terms such as “electrode”, “wiring”, and “terminal” do not have functional limitations. For example, an “electrode” is used as part of a wiring in some cases, and vice versa. Furthermore, a term such as “electrode” or “wiring” can also mean a combination of a plurality of electrodes or wirings provided in an integrated manner, for example. For another example, a “terminal” can be used as part of a wiring or an electrode, and a “wiring” and an “electrode” can be used as part of a terminal. Furthermore, the term “terminal” includes the case where at least two of electrodes, wirings, terminals, and the like are formed in an integrated manner. Therefore, for example, an “electrode” can be part of a wiring or a terminal, and a “terminal” can be part of a wiring or an electrode. Moreover, the terms “electrode”, “wiring”, and “terminal” are sometimes replaced with the term “region”, for example.

In this specification and the like, terms such as “wiring”, “signal line”, and “power supply line” can be interchanged with each other depending on the case or in accordance with circumstances. For example, the term “wiring” can be changed into the term “signal line” in some cases. For another example, the term “wiring” can be changed into a term such as “power supply line” in some cases. Inversely, a term such as “signal line” or “power supply line” can be changed into the term “wiring” in some cases. A term such as “power supply line” can be changed into the term “signal line” in some cases. Inversely, a term such as “signal line” can be changed into the term “power source line” in some cases. The term “potential” that is applied to a wiring can be changed into the term “signal” depending on the case or in accordance with circumstances. Inversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed as appropriate depending on the circumstances. For example, even when two periods are shown to have an equal length, the two periods have different lengths in some cases. Furthermore, for example, even when one of two periods is shown longer than the other, the two periods can have the equal length in some cases, or the one of the two periods has a shorter length than the other in other cases.

In this specification and the like, a flowchart is used in some cases to describe an operation method of a semiconductor device. A flowchart used in this specification and the like shows an ideal operation example, and the steps in the flowchart are classified on the function basis and are independent of one another. However, in actual processing or the like, it is difficult to separate processing shown in the flowcharts on the function basis, and there are such a case where a plurality of steps are associated with one step and a case where one step is associated with a plurality of steps. Thus, the processing shown in the flowcharts is not limited to each step described in the specification, and the steps can be exchanged as appropriate according to circumstances. Specifically, depending on circumstances, the order of steps can be changed or a step can be added or omitted, for example.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide contained in a channel formation region of a transistor is called an oxide semiconductor in some cases. That is, a metal oxide included in a channel formation region of a transistor that has at least one of an amplifying function, a rectifying function, and a switching function can be referred to as a metal oxide semiconductor. In addition, an OS transistor is a transistor including a metal oxide or an oxide semiconductor.

In this specification and the like, a metal oxide containing nitrogen is also referred to as a metal oxide in some cases. In addition, a metal oxide containing nitrogen may be referred to as a metal oxynitride.

In this specification and the like, an impurity in a semiconductor refers to, for example, elements other than the main components of a semiconductor layer. For instance, an element with a concentration lower than 0.1 atomic % is an impurity. When an impurity is contained, at least one of the following may occur: an increase in the density of defect states in the semiconductor; a decrease in carrier mobility; and a decrease in crystallinity. When a semiconductor layer contains an oxide semiconductor, examples of impurities that change the characteristics of the semiconductor include Group 1 elements, Group 2 elements, Group 13 elements, Group 14 elements, Group 15 elements, and transition metals other than the main components of the oxide semiconductor. Specific examples are hydrogen (included also in water), lithium, sodium, silicon, boron, phosphorus, carbon, and nitrogen.

In this specification and the like, a switch is in a conduction state (on state) or in a non-conduction state (off state) to control whether a current flows therethrough or not. Alternatively, a switch has a function of selecting and changing a current path. Thus, a switch may have two or more terminals through which a current flows, in addition to a control terminal. For example, an electrical switch or a mechanical switch can be used. That is, a switch is not limited to a certain element and can be any element capable of controlling a current.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. In the case of using a transistor as a switch, the conduction state of the transistor refers to a state in which a source electrode and a drain electrode of the transistor are regarded as being electrically short-circuited or a state in which a current can flow between the source electrode and the drain electrode, for example. The non-conduction state of the transistor refers to a state in which the source electrode and the drain electrode of the transistor are regarded as being electrically disconnected. In the case where a transistor operates just as a switch, there is no particular limitation on the polarity (conductivity type) of the transistor.

An example of a mechanical switch is a switch using a microelectromechanical systems (MEMS) technology. Such a switch includes an electrode that can be moved mechanically, and its conduction and non-conduction are controlled with movement of the electrode.

In this specification, “parallel” indicates a state where the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The terms “approximately perpendicular” and “substantially perpendicular” indicate that the angle formed between two straight lines is greater than or equal to 60° and less than or equal to 120°.

In this specification and the like, the structure described in each embodiment can be combined with the structures described in the other embodiments as appropriate to constitute one embodiment of the present invention. In the case where a plurality of structure examples are described in one embodiment, some of the structure examples can be combined as appropriate.

Note that a content (or part thereof) described in one embodiment can be applied to, combined with, or replaced with another content (or part thereof) described in the same embodiment and/or a content (or part thereof) described in another embodiment or other embodiments.

Note that in each embodiment, a content described in the embodiment is a content described with reference to a variety of diagrams or a content described with text in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

The embodiments in this specification are described with reference to drawings. Note that the embodiments can be implemented in many different modes, and it will be readily appreciated by those skilled in the art that modes and details can be changed in various ways without departing from the spirit and scope of the present invention. Therefore, the present invention should not be construed as being limited to the description of the embodiments. Note that in the structures of the invention described in the embodiments, the same portions or portions having similar functions are denoted by the same reference numerals in different drawings and the description of such portions is not repeated in some cases. In perspective views and the like, illustration of some components might be omitted for clarity of the drawings.

In this specification and the like, when a plurality of components denoted by the same reference numerals need to be distinguished from each other, identification signs such as “_1”, “[n]”, and “[m,n]” are sometimes added to the reference numerals. Components denoted with identification signs such as “_1”, “[n]”, and “[m,n]” in drawings and the like are sometimes denoted without such identification signs in this specification and the like when the components do not need to be distinguished from each other.

In the drawings of this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, the following can be included: a variation in a signal, a voltage, or a current due to noise or difference in timing.

### Embodiment 1

In this embodiment, a semiconductor device of one embodiment of the present invention is described.

### Configuration Example 1

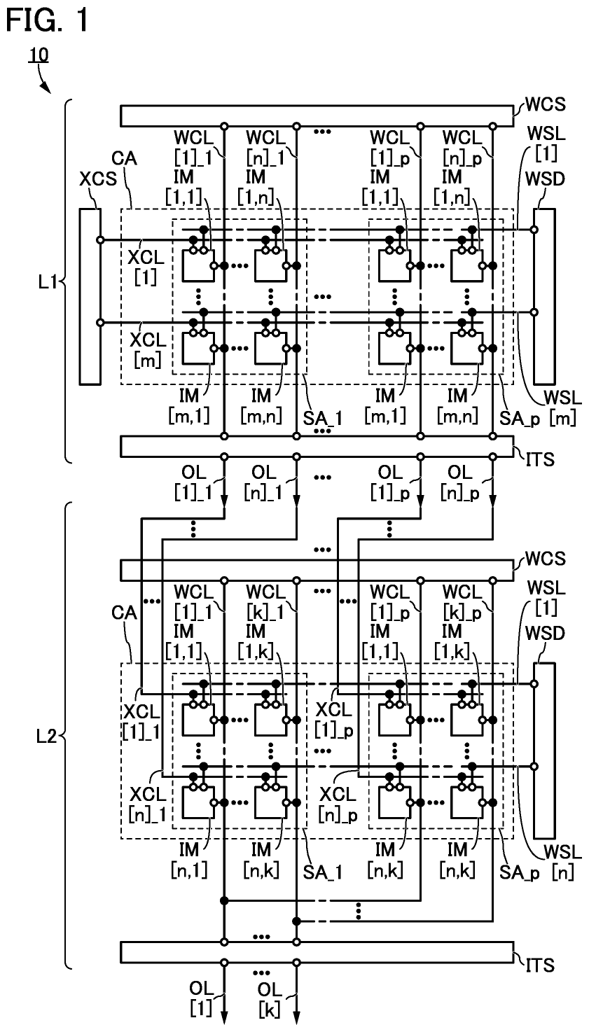

FIG. 1 is a block diagram illustrating a configuration example of an arithmetic circuit which is the semiconductor device of one embodiment of the present invention. The arithmetic circuit has a function of performing a product-sum operation of a plurality of pieces of first data and a plurality of pieces of second data and a function of performing a function operation using the result of the product-sum operation as an input value, for example. The product-sum arithmetic circuit has a function of performing an arithmetic operation of a hierarchical neural network, for example. In this case, the plurality of pieces of the first data are used as weight data (sometimes referred to as weight coefficient) and the plurality of pieces of the second data are used as data to be input to a neuron (sometimes referred to as input data), for example.

An arithmetic circuit 10 illustrated in FIG. 1 includes a region L1 and a region L2, for example. The regions L1 and L2 each include a cell array CA, a circuit WCS, a circuit WSD, and a circuit ITS, for example. The region L1 is different from the region L2 in that a circuit XCS is included.

In each of the regions L1 and L2, a plurality of arithmetic cells are arranged in a matrix in the cell array CA, for example. The cell array CA is divided into a plurality of subarrays, for example. Specifically, the plurality of arithmetic cells arranged in the cell array CA are divided into regions of subarrays SA_1 to SA_p (p is an integer greater than or equal to 2) in each of the regions L1 and L2, for example.

In the region L1, the subarrays SA_1 to SA_p each include a plurality of cells IM that function as arithmetic cells, for example. Specifically, in each of the subarrays SA_1 to SA_p included in the region L1, the cells IM are arranged in a matrix of m rows and n columns (m is an integer greater than or equal to 1 and n is an integer greater than or equal to 1). Thus, in FIG. 1, m×n×p cells IM are provided in the cell array CA.

In the region L2, the subarrays SA_1 to SA_p each include a plurality of the cells IM that function as arithmetic cells, for example. Specifically, in each of the subarrays SA_1 to SA_p included in the region L2, the cells IM are arranged in a matrix of n rows and k columns (k is an integer greater than or equal to 1). Thus, in FIG. 1, n×k×p cells IM are provided in the cell array CA.

Here, when k=n is satisfied, the number of columns in the cell array CA in the region L1 is equal to the number of columns in the cell array CA in the region L2. When the number of columns in the cell array CA in the region L1 is equal to the number of columns in the cell array CA in the region L2, the cells IM can be efficiently arranged in the arithmetic circuit 10 viewed as a whole, which can reduce the area needed for forming the arithmetic circuit 10.

Note that “[,]” added to the reference sign IM of the cell in FIG. 1 shows the address of the cell IM in the subarray; for example, “IM[x,y]” shows that the cell IM[x,y] is positioned in the x-th row and the y-th column in the subarray.

In the region L1, the circuit WCS is electrically connected to wirings WCL[1]_1 to WCL[n]_1 and wirings WCL[1]_p to WCL[n]_p, for example. Although not illustrated in FIG. 1, when p is 3 or more, the circuit WCS is electrically connected to the wirings WCL[1] to WCL[n] in the subarray SA other than the subarrays SA_1 and SA_p. The circuit ITS is electrically connected to the wirings WCL[1]_1 to WCL[n]_1 and the wirings WCL[1]_p to WCL[n]_p, for example. Although not illustrated in FIG. 1, when p is 3 or more, the circuit ITS is electrically connected to the wirings WCL[1] to WCL[n] in the subarray SA other than the subarrays SA_1 and SA_p.

The wirings WCL[1]_1 to WCL[n]_1 are electrically connected to the cells IM included in the subarray SA_1. Specifically, the wiring WCL[1]_1 is electrically connected to cells IM[1,1] to IM[m,1] arranged in the first column in the subarray SA_1, and the wiring WCL[n]_1 is electrically connected to cells IM[1,n] to IM[m,n] arranged in the n-th column in the subarray SA_1. The wirings WCL[1]_p to WCL[n]_p are electrically connected to the cells IM included in the subarray SA_p. Specifically, the wiring WCL[1]_p is electrically connected to the cells IM[1,1] to IM[m,1] arranged in the first column in the subarray SA_p, and the wiring WCL[n]_p is electrically connected to the cells IM[1,n] to IM[m,n] arranged in the n-th column in the subarray SA_p.

In the region L1, the circuit XCS is electrically connected to wirings XCL[1] to XCL[m], for example.

The wirings XCL[1] to XCL[m] are electrically connected to the cells IM included in the subarrays SA_1 to SA_p. Specifically, the wiring XCL[1] is electrically connected to the cells IM[1,1] to IM[1,n] arranged in the first row in each of the subarrays SA_1 to SA_p. The wiring XCL[m] is electrically connected to the cells IM[m,1] to IM[m,n] arranged in the m-th row in each of the subarrays SA_1 to SA_p.

In the region L1, the circuit WSD is electrically connected to wirings WSL[1] to WSL[m], for example.

The wirings WSL[1] to WSL[m] are electrically connected to the cells IM included in the subarrays SA_1 to SA_p. Specifically, the wiring WSL[1] is electrically connected to the cells IM[1,1] to IM[1,n] arranged in the first row in each of the subarrays SA_1 to SA_p. The wiring WSL[m] is electrically connected to the cells IM[m,1] to IM[m,n] arranged in the m-th row in each of the subarrays SA_1 to SA_p.

The circuit ITS included in the region L1 is electrically connected to wirings OL[1]_1 to OL[n]_1 and wirings OL[1]p to OL[n]_p. Although not illustrated in FIG. 1, when p is 3 or more, the circuit ITS is electrically connected to wirings OL[1]_s to OL[n]_s (here, s is an integer greater than or equal to 2 and less than or equal to p−1).

The wirings OL[1]_1 to OL[n]_1 included in the region L1 are electrically connected to wirings XCL[1]_1 to XCL[n]_1 included in the region L2 in a one-to-one correspondence, and the wirings OL[1]p to OL[n]p included in the region L1 are electrically connected to wirings XCL[1]p to XCL[n]p included in the region L2 in a one-to-one correspondence.

In the region L2, the circuit WCS is electrically connected to the wirings WCL[1]_1 to WCL[k]_1 and the wirings WCL[1]p to WCL[k]p, for example. Although not illustrated in FIG. 1, when p is 3 or more, the circuit WCS is electrically connected to the wirings WCL[1] to WCL[n] in the subarray SA other than the subarrays SA_1 and SA_p.

The wiring WCL[1]_1 is electrically connected to the wiring WCL[1]_p. Although not illustrated in FIG. 1, in the case where p is 3 or more, wirings WCL[1]_2 to WCL[1]_p−1 which extend in the first columns in different subarrays SA are electrically connected to the wiring WCL[1]_1. The wiring WCL[k]_1 is electrically connected to the wiring WCL[k]_p. Although not illustrated, in the case where p is 3 or more, wirings WCL[k]_2 to WCL[k]_p−1 which extend in the k-th columns in different subarrays SA are electrically connected to the wiring WCL[k]_1.

The wirings WCL[1]_1 to WCL[k]_1 are electrically connected to the cells IM included in the subarray SA_1. Specifically, the wiring WCL[1]_1 is electrically connected to the cells IM[1,1] to IM[n,1] arranged in the first column in the subarray SA_1, and the wiring WCL[k]_1 is electrically connected to cells IM[1,k] to IM[n,k] arranged in the k-th column in the subarray SA_1. The wirings WCL[1]_p to WCL [k]p are electrically connected to the cells IM included in the subarray SA_p. Specifically, the wiring WCL[1]p is electrically connected to the cells IM[1,1] to IM[n,1] arranged in the first column in the subarray SA_p, and the wiring WCL[k]p is electrically connected to the cells IM[1,k] to IM[n,k] arranged in the k-th column in the subarray SA_p.

In the region L2, the wirings XCL[1]_1 to XCL[n]_1 are electrically connected to the cells IM included in the subarray SA_1. Specifically, the wiring XCL[1]_1 is electrically connected to the cells IM[1,1] to IM[1,k] arranged in the first row in the subarray SA_1. The wiring XCL[n]_1 is electrically connected to the cells IM[n,1] to IM[n,k] arranged in the n-th row in the subarray SA_1. The wirings XCL[1]p to XCL[n]p are electrically connected to the cells IM included in the subarray SA_p. Specifically, the wiring XCL[1]_p is electrically connected to the cells IM[1,1] to IM[1,k] arranged in the first row in the subarray SA_p. The wiring XCL[n]p is electrically connected to the cells IM[n,1] to IM[n,k] arranged in the n-th row in the subarray SA_p.

In the region L2, the circuit WSD is electrically connected to the wirings WSL[1] to WSL[n], for example.

The wirings WSL[1] to WSL[n] are electrically connected to the cells IM included in the subarrays SA_1 to SA_p. Specifically, the wiring WSL[1] is electrically connected to the cells IM[1,1] to IM[1,k] arranged in the first row in each of the subarrays SA_1 to SA_p. Furthermore, the wiring WSL[n] is electrically connected to the cells IM[n,1] to IM[n,k] arranged in the n-th row in each of the subarrays SA_1 to SA_p.

In the region L2, the wirings WCL[1]_1 to WCL[k]_1 are electrically connected to the circuit ITS. The circuit ITS is electrically connected to wirings OL[1] to OL[k].

Next, the cell IM, the circuit WCS, the circuit XCS, the circuit WSD, and the circuit ITS included in the arithmetic circuit 10 in FIG. 1 are described.

The cells IM included in the regions L1 and L2 have a function of retaining the first data, for example. The cells IM have a function of outputting a current with the amount corresponding to the product of the first data and the second data to the wiring WCL, in response to an input of a signal that serves as the second data.

The circuit WCS in the region L1 has a function of supplying a signal (e.g., one or both of a current and a voltage) corresponding to the first data to the wirings WCL[1]_1 to WCL[n]_1 and the wirings WCL[1]p to WCL[n]_p, for example. Note that when p is 3 or more, the circuit WCS has a function of supplying a signal corresponding to the first data also to the wirings WCL[1] to WCL[n] in the subarray SA other than the subarrays SA_1 and SA_p. The circuit WCS in the region L2 has a function of supplying a signal (e.g., one or both of a current and a voltage) corresponding to the first data to the wirings WCL[1]_1 to WCL[k]_1 and the wirings WCL[1]p to WCL[k]p, for example. That is, the circuit WCS has a function of supplying the first data to be stored in the cell IM when a writing transistor included in the cell IM is in an on state.

In the region L1, the circuit XCS has a function of supplying a signal (e.g., one or both of a current and a voltage) corresponding to the second data or reference data, which will be described later, to the wirings XCL[1] to XCL[m], for example. That is, in the arithmetic circuit 10 in FIG. 1, the circuit XCS has a function of supplying a signal (e.g., one or both of a current and a voltage) corresponding to the second data or the reference data to each of the cells IM included in the cell array CA in the region L1.

In the region L1, the circuit WSD has a function of selecting a row in the cell array CA to which the first data is to be written, by supplying a predetermined signal to the wirings WSL[1] to WSL[m] at the time of writing the first data to each of the cells included in the cell array CA, for example. For example, when the circuit WSD supplies the wiring WSL[1] with a high-level potential and supplies the wirings WSL[1] (not illustrated) to WSL[m] with a low-level potential, writing transistors whose gates are electrically connected to the wiring WSL[1] can be turned on and writing transistors whose gates are electrically connected to the wirings WSL[1] to WSL[m] can be turned off. In the region L2, the circuit WSD, like the circuit WSD included in the region L1, has a function of selecting a row in the cell array CA to which the first data is to be written, by supplying a predetermined signal to the wirings WSL[1] to WSL[n] at the time of writing the first data to each of the cells included in the cell array CA, for example.

In the region L1, the circuit ITS has a function of converting, to voltages, the amounts of currents input from the wirings WCL[1]_1 to WCL[n]_1 and the wirings WCL[1]_p to WCL[n]p, for example. Note that the amount of a current flowing from the wiring WCL [1]_1 to the circuit ITS is the sum of the amounts of currents output from the cells IM[1,1] to IM[m,1] in the first column in the subarray SA_1, for example. That is, the sum of the amounts of currents corresponds to the result of the product-sum operation of a plurality of pieces of the first data retained in the cells IM[1,1] to IM[m,1] and a plurality of pieces of the second data input to the cells IM[1,1] to IM[m,1]; thus, in the circuit ITS, a voltage corresponding to the product-sum of the plurality of pieces of the first data and the plurality of pieces of the second data is generated from the sum of the amounts of currents. The circuit ITS may have a function of converting the voltage into a current amount.

The circuit ITS in the region L1 has a function of transmitting the voltage, a current that is converted from the voltage, or the like as a signal to the wirings OL[1]_1 to OL[n]_1 and the wirings OL[1]_p to OL[n]_p. Specifically, the circuit ITS has a function of outputting, to the wiring OL[1]_1, a signal corresponding to the current amount input from the wiring WCL[1]_1. Similarly, the circuit ITS has a function of outputting, to the wiring OL[n]_1, the wiring OL[1]_p, and the wiring OL[n]p, respectively, a signal corresponding to the current amount input from the wiring WCL[n]_1, a signal corresponding to the current amount input from the wiring WCL[1]_p, and a signal corresponding to the current amount input from the wiring WCL[n]_p.

In the region L2, the circuit ITS has a function of converting, to voltages, the amounts of currents that are input from the wirings WCL[1]_1 to WCL[k]_1 and the wirings WCL[1]_p to WCL[k]p, for example. Note that the amount of a current flowing from the wirings WCL[1]_1 and WCL[1]_p to the circuit ITS is the sum of the amounts of currents output from the cells IM[1,1] to IM[n,1] in the first column in each of the subarrays SA_1 to SA_p, for example. That is, the sum of the amounts of currents corresponds to the result of the product-sum operation of a plurality of pieces of the first data retained in the cells IM[1,1] to IM[n,1] in the subarrays SA_1 to SA_p and a plurality of pieces of the second data input to the cells IM[1,1] to IM[n,1] in the subarrays SA_1 to SA_p; thus, in the circuit ITS, a voltage corresponding to the product-sum of the plurality of pieces of the first data and the plurality of pieces of the second data is generated from the sum of the amounts of currents. The circuit ITS may have a function of converting the voltage into a current amount.

The circuit ITS in the region L2 has a function of transmitting the voltage, a current that is converted from the voltage, or the like as a signal to the wirings OL[1] to OL[k]. Specifically, the circuit ITS has a function of outputting a signal corresponding to the current amount input from the wirings WCL[1]_1 to WCL[1]p, to the wiring OL[1]. Similarly, the circuit ITS has a function of outputting signals corresponding to the current amounts input from the wirings WCL[k]_1 to WCL[k]p, to the wirings OL[k]_1 to OL[k]_p.

Specifically, in the regions L1 and L2, the circuit ITS may have a function of performing a function operation using the result of the product-sum operation of the plurality of pieces of the first data and the plurality of pieces of the second data as an input value. The circuit ITS may output the result of the function operation as a signal (e.g., one or both of a current and a voltage) to the wirings OL[1]_1 to OL[n]_1 and the wirings OL[1]_p to OL[n]_p (the wirings OL[1] to OL[k]). Note that as the above-described function, for example, a sigmoid function, a tanh function, a softmax function, a ReLU function, or a threshold function can be used.

The above-described configuration of the arithmetic circuit 10 enables a circuit area smaller than that of a conventional arithmetic circuit.

As described above, the cell array CA included in the region L2 is divided into the subarrays SA_1 to SA_p and a plurality of results calculated by the cell array CA and the circuit ITS included in the region L1 is input as a signal in the row direction of the subarrays SA_1 to SA_p, whereby the cells IM can be efficiently arranged in the arithmetic circuit 10. In addition, when k=n is satisfied, the cells IM can be arranged more efficiently. Thus, when an arithmetic operation is performed in the arithmetic circuit 10, the number of cells IM that are not used for the arithmetic operation can be reduced, so that arithmetic efficiency per area of the arithmetic circuit 10 can be increased.

### Configuration Example 2

Although the cells IM are illustrated as the arithmetic cells in the cell array CA in the arithmetic circuit 10 in FIG. 1, a cell other than the cell IM, such as a dummy arithmetic cell, a reference arithmetic cell, or the like may be necessary depending on the arithmetic method. Thus, in the arithmetic circuit 10 in FIG. 1, a dummy arithmetic cell or a reference arithmetic cell may be provided separately in accordance with the arithmetic method.

Note that a reference arithmetic cell refers to an arithmetic cell to which data as the standard for the first data is written when the first data is written to the cell IM. Specifically, for example, the ratio between the data written to the reference arithmetic cell and data that flows from the circuit XCS corresponds to the second data by which the first data is multiplied in the cell IM. Note that a specific operation example will be described later in detail. In this specification and the like, data as the standard is sometimes referred to as reference data. In this specification and the like, a reference arithmetic cell is sometimes referred to as a driving cell.

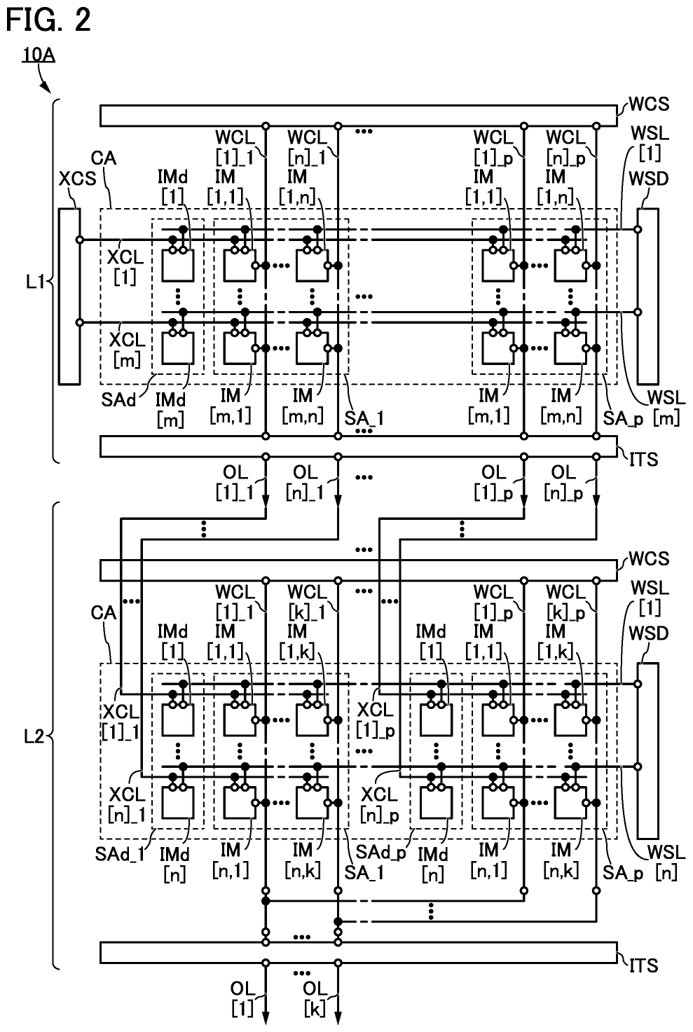

An arithmetic circuit 10A in FIG. 2 is a variation example of the arithmetic circuit 10 in FIG. 1 and has a circuit configuration of a case where a reference arithmetic cell is necessary for a product-sum operation.

In the region L1, the cell array CA includes a subarray SAd, in addition to the subarrays SA_1 to SA_p, for example. The subarray SAd includes cells IMd[1] to IMd[m], for example.

The cells IMd[1] to IMd[m] are electrically connected to the wirings WSL[1] to WSL[m] in a one-to-one correspondence, for example. The cells IMd[1] to IMd[m] are electrically connected to the wirings XCL[1] to XCL[m] in a one-to-one correspondence, for example.

In the region L2, the cell array CA includes subarrays SAd_1 to SAd_p, in addition to the subarrays SA_1 to SA_p, for example. The subarrays SAd_1 to SAd_p each include the cells IMd[1] to IMd[n], for example.

The cells IMd[1] to IMd[n] included in the subarray SAd_1 are electrically connected to the wirings WSL[1] to WSL[n] in a one-to-one correspondence, for example. The cells IMd[1] to IMd[n] included in the subarray SAd_1 are electrically connected to the wirings XCL[1]_1 to XCL[n]_1 in a one-to-one correspondence, for example. The cells IMd[1] to IMd[n] included in the subarray SAd_p are electrically connected to the wirings WSL[1] to WSL[n] in a one-to-one correspondence, for example. The cells IMd[1] to IMd[n] included in the subarray SAd_p are electrically connected to the wirings XCL[1]_p to XCL[m]_p in a one-to-one correspondence, for example.

### <<Cells IM and IMd>>

Next, specific configuration examples of the cells IM and IMd are described.

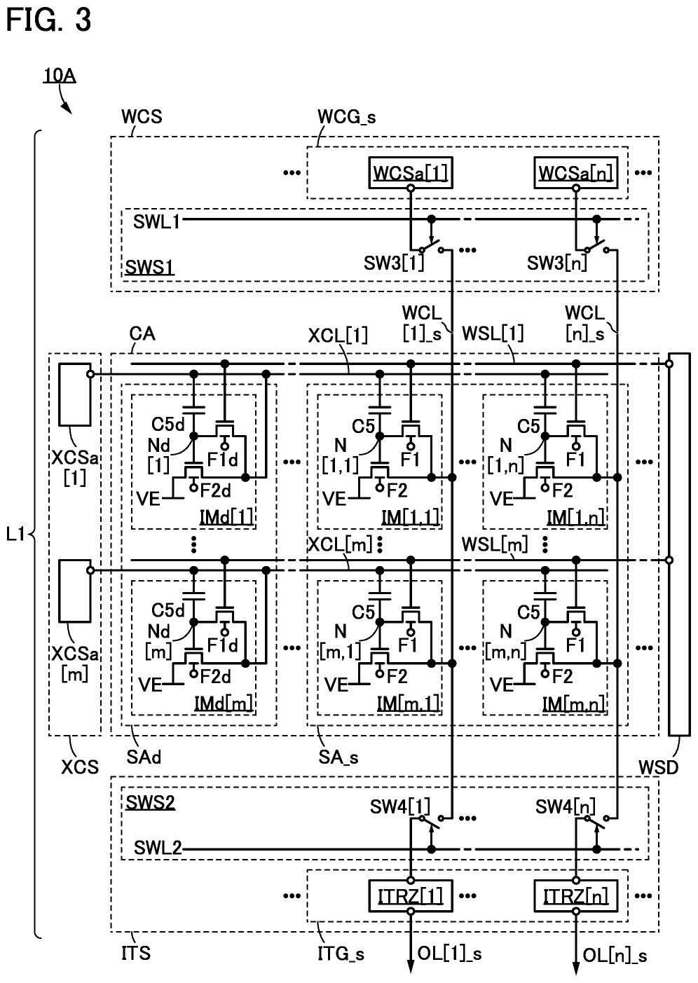

FIG. 3 is a circuit diagram illustrating specific configuration examples of the cells IM and IMd in the arithmetic circuit 10A in FIG. 2. Note that FIG. 3 selectively illustrates the subarrays SAd and SA_s (s is an integer greater than or equal to 1 and less than or equal top). FIG. 3 selectively illustrates the circuit WCS, the circuit XCS, the circuit WSD, and the circuit ITS to show electrical connection to the cell array CA.

The cells IM[1,1] to IM[m,n] each include a transistor F1, a transistor F2, and a capacitor C5, and the cells IMd[1] to IMd[m] each include a transistor F1d, a transistor F2d, and a capacitor CSd, for example.

Specifically, it is preferable that the transistors F1 included in the cells IM[1,1] to IM[m,n] have the same structure and size (e.g., the same channel length and the same channel width), and the transistors F2 included in the cells IM[1,1] to IM[m,n] have the same structure and size. It is preferable that the transistors F1d included in the cells IMd[1] to IMd[m] have the same structure and size, and the transistors F2d included in the cells IMd[1] to IMd[m] have the same structure and size. It is also preferable that the transistor F1 and the transistor F1d have the same structure and size, and the transistor F2 and the transistor F2d have the same structure and size.

By making the transistors have the same structure and size, the transistors can have substantially the same electrical characteristics. Thus, by making the transistors F1 included in the cells IM[1,1] to IM[m,n] have the same structure and size and the transistors F2 included in the cells IM[1,1] to IM[m,n] have the same structure and size, the cells IM[1,1] to IM[m,n] can perform substantially the same operation when being in the same conditions as one another. The same conditions here mean, for example, potentials input to a source, a drain, and a gate of the transistor F1, potentials input to a source, a drain, and a gate of the transistor F2, and potentials input to the cells IM[1,1] to IM[m,n]. By making the transistors F1d included in the cells IMd[1] to IMd[m] have the same size and the transistors F2d included in the cells IMd[1] to IMd[m] have the same size, the cells IMd[1] to IMd[m] can perform substantially the same operation and can have substantially the same result of the operation, for example. In the case of the same conditions, the cells IMd[1] to IMd[m] can perform substantially the same operation. The same conditions here mean, for example, potentials input to a source, a drain, and a gate of the transistor F1d, potentials input to a source, a drain, and a gate of the transistor F2d, and potentials input to the cells IMd[1] to IMd[m].

Unless otherwise specified, the transistor F1 and the transistor F1d in an on state may operate in a linear region in the end. In other words, the gate voltage, the source voltage, and the drain voltage of each of the above transistors may be appropriately biased to voltages in the range where the transistor operates in the linear region. However, one embodiment of the present invention is not limited thereto. For example, one or both of the transistor F1 and the transistor F1d in an on state may operate in a saturation region or may operate both in a linear region and in a saturation region.

Unless otherwise specified, the transistor F2 and the transistor F2d may operate in a subthreshold region (i.e., the gate-source voltage may be lower than the threshold voltage in the transistor F2 or the transistor F2d, further preferably, the drain current increases exponentially with respect to the gate-source voltage). In other words, the gate voltage, the source voltage, and the drain voltage of each of the above transistors may be appropriately biased to voltages in the range where the transistor operates in the subthreshold region. Thus, the transistor F2 and the transistor F2d may operate such that an off-state current (referred to as leakage current in some cases) flows between the source and the drain.

One or both of the transistor F1 and the transistor F1d are preferably an OS transistor, for example. In addition, it is further preferable that a channel formation region in one or both of the transistor F1 and the transistor F1d be an oxide containing at least one of indium, gallium, and zinc. Instead of the oxide, an oxide containing one or more selected from indium, an element M (as the element M, for example, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony can be used), and zinc may be used. It is further preferable that one or both of the transistor F1 and the transistor F1d have the structure of the transistor described in Embodiment 5, in particular.

With the use of an OS transistor as one or both of the transistor F1 and the transistor F1d, the leakage current of one or both of the transistor F1 and the transistor F1d can be inhibited, so that the power consumption of the arithmetic circuit can be reduced. Specifically, in the case where one or both of the transistor F1 and the transistor F1d are in the non-conducting state, the amount of a leakage current from a retention node to a write word line can be extremely small and thus the frequency of a refresh operation for the potential of the retention node can be reduced. By reducing the frequency of a refresh operation, the power consumption of the arithmetic circuit can be reduced. An extremely low leakage current from the retention node to the wiring WCL or the wiring XCL allows cells to retain the potential of the retention node for a long time, increasing the arithmetic operation accuracy of the arithmetic circuit.

The use of an OS transistor also as one or both of the transistor F2 and the transistor F2d enables an operation with a wide range of current in the subthreshold region, leading to a reduction in the current consumption. With the use of OS transistors also as the transistor F2 and the transistor F2d, the transistor F2 and the transistor F2d can be manufactured concurrently with the transistor F1 and the transistor F1d; thus, the manufacturing process of the arithmetic circuit can sometimes be shortened. One or both of the transistor F2 and the transistor F2d can be, other than an OS transistor, a transistor containing silicon in its channel formation region (hereinafter, referred to as a Si transistor). As the silicon, amorphous silicon (referred to as hydrogenated amorphous silicon in some cases), microcrystalline silicon, polycrystalline silicon, single crystal silicon, or the like can be used, for example.

When a semiconductor device and the like are highly integrated into a chip or the like, heat may be generated in the chip by driving of the circuit. This heat increases the temperature of a transistor to change the characteristics of the transistor; thus, the field-effect mobility thereof might change or the operation frequency thereof might decrease, for example. Since an OS transistor has higher heat resistance than a Si transistor, a change in field-effect mobility and a decrease in operation frequency due to a temperature change do not easily occur. Even when having a high temperature, an OS transistor is likely to keep a property of the drain current increasing exponentially with respect to the gate-source voltage. With the use of an OS transistor, an arithmetic operation can thus be easily performed even in a high temperature environment. To form a semiconductor device highly resistant to heat due to driving, an OS transistor is preferably used as its transistor.

In each of the cells IM[1,1] to IM[m,n], a first terminal of the transistor F1 is electrically connected to a gate of the transistor F2. A first terminal of the transistor F2 is electrically connected to a wiring VE. A first terminal of the capacitor C5 is electrically connected to the gate of the transistor F2.

In each of the cells IMd[1] to IMd[m], a first terminal of the transistor F1d is electrically connected to a gate of the transistor F2d. A first terminal of the transistor F2d is electrically connected to the wiring VE. A first terminal of the capacitor C5d is electrically connected to the gate of the transistor F2d.

In each of the transistor F1, the transistor F2, the transistor F1d, and the transistor F2d in FIG. 3, a back gate is illustrated but the connection configuration of the back gate is not illustrated; however, a point to which the back gate is electrically connected can be determined at the design stage. For example, in a transistor including a back gate, a gate and the back gate may be electrically connected to each other to increase the on-state current of the transistor. In other words, the gate and the back gate of the transistor F1 may be electrically connected to each other, and the gate and the back gate of the transistor F1d may be electrically connected to each other, for example. Furthermore, for example, in a transistor including a back gate, a wiring electrically connecting the back gate of the transistor to an external circuit or the like may be provided and a potential may be supplied to the back gate of the transistor with the external circuit or the like to change the threshold voltage of the transistor or to reduce the off-state current of the transistor.

The transistor F1 and the transistor F2 illustrated in FIG. 3 have back gates; however, the semiconductor device of one embodiment of the present invention is not limited thereto. For example, the transistor F1 and the transistor F2 illustrated in FIG. 3 may each be a transistor having a structure not including a back gate, i.e., a single-gate structure. It is also possible that some transistors have a structure including a back gate and the other transistors have a structure not including a back gate.

The transistors F1 and the transistors F2 illustrated in FIG. 3 are n-channel transistors; however, the semiconductor device of one embodiment of the present invention is not limited thereto. For example, some or all of the transistors F1 and the transistors F2 may be replaced with p-channel transistors.

The above-described examples of changes in the structure and polarity of the transistor are not limited to the transistor F1 and the transistor F2. For example, the same applies to the transistors F1d and F2d, transistors described in other parts of this specification, and transistors illustrated in other drawings.

The wiring VE functions as a wiring for making a current flow between the first terminal and a second terminal of the transistor F2 of each of the cells IM[1,1], IM[m,1], IM[1,n], and IM[m,n] and a wiring for making a current flow between the first terminal and a second terminal of the transistor F2d of each of the cells IMd[1] and IMd[m]. The wiring VE functions as a wiring for supplying a constant voltage, for example. The constant voltage can be, for example, a low-level potential, a ground potential, or the like.

In the cell IM[1,1], a second terminal of the transistor F1 is electrically connected to a wiring WCL[1]_s, and the gate of the transistor F1 is electrically connected to the wiring WSL[1]. The second terminal of the transistor F2 is electrically connected to the wiring WCL[1]_s, and a second terminal of the capacitor C5 is electrically connected to the wiring XCL[1]. In the cell IM[1,1] in FIG. 3, a connection portion of the first terminal of the transistor F1, the gate of the transistor F2, and the first terminal of the capacitor C5 is a node N[1,1].

In the cell IM[m,1], the second terminal of the transistor F1 is electrically connected to the wiring WCL[1]_s, and the gate of the transistor F1 is electrically connected to the wiring WSL[m]. The second terminal of the transistor F2 is electrically connected to the wiring WCL[1]_s, and the second terminal of the capacitor C5 is electrically connected to the wiring XCL[m]. In the cell IM[m,1] in FIG. 3, a connection portion of the first terminal of the transistor F1, the gate of the transistor F2, and the first terminal of the capacitor C5 is a node N[m,1].

In the cell IM[1,n], the second terminal of the transistor F1 is electrically connected to a wiring WCL[n]_s, and the gate of the transistor F1 is electrically connected to the wiring WSL[1]. The second terminal of the transistor F2 is electrically connected to the wiring WCL[n]_s, and the second terminal of the capacitor C5 is electrically connected to the wiring XCL[1]. In the cell IM[1,n] in FIG. 3, a connection portion of the first terminal of the transistor F1, the gate of the transistor F2, and the first terminal of the capacitor C5 is a node N[1,n].

In the cell IM[m,n], the second terminal of the transistor F1 is electrically connected to the wiring WCL[n]_s, and the gate of the transistor F1 is electrically connected to the wiring WSL[m]. The second terminal of the transistor F2 is electrically connected to the wiring WCL[n]_s, and the second terminal of the capacitor C5 is electrically connected to the wiring XCL[m]. In the cell IM[m,n] in FIG. 3, a connection portion of the first terminal of the transistor F1, the gate of the transistor F2, and the first terminal of the capacitor C5 is a node N[m,n].

In the cell IMd[1], a second terminal of the transistor F1d is electrically connected to the wiring XCL[1], and the gate of the transistor F1d is electrically connected to the wiring WSL[1]. The second terminal of the transistor F2d is electrically connected to the wiring XCL[1], and a second terminal of the capacitor C5d is electrically connected to the wiring XCL[1]. In the cell EVId[1] in FIG. 3, a connection portion of the first terminal of the transistor F1d, the gate of the transistor F2d, and the first terminal of the capacitor C5d is a node Nd[1].

In the cell IMd[m], the second terminal of the transistor F1d is electrically connected to the wiring XCL[m], and the gate of the transistor F1d is electrically connected to the wiring WSL[m]. The second terminal of the transistor F2d is electrically connected to the wiring XCL[m], and the second terminal of the capacitor C5d is electrically connected to the wiring XCL[m]. In the cell IMd[m] in FIG. 3, a connection portion of the first terminal of the transistor F1d, the gate of the transistor F2d, and the first terminal of the capacitor C5d is a node Nd[m].

The nodes N[1,1] to N[m,n] and the nodes Nd[1] to Nd[m] function as retention nodes of the cells.

In the case where the transistor F1 is in an on state in each of the cells IM[1,1] to IM[m,n], for example, the transistor F2 is a diode-connected transistor. When a constant voltage supplied from the wiring VE is a ground potential (GND), the transistor F1 is in an on state, and a current with a current amount I flows from the wiring WCL to the second terminal of the transistor F2, the potential of the gate of the transistor F2 (the node N) is determined in accordance with the current amount I. Since the transistor F1 is in an on state, the potential of the second terminal of the transistor F2 is ideally equal to that of the gate of the transistor F2 (the node N). Here, by turning off the transistor F1, the potential of the gate of the transistor F2 (the node N) is retained. Accordingly, the transistor F2 can make the current with the current amount I corresponding to the ground potential of the first terminal of the transistor F2 and the potential of the gate of the transistor F2 (the node N) flow between the source and the drain of the transistor F2. In this specification and the like, such an operation is called “setting (programing) the amount of a current flowing between the source and the drain of the transistor F2 in the cell IM to I”, for example.

Next, specific configuration examples of the circuit WCS, the circuit XCS, the circuit WSD, and the circuit ITS are described.

### <<Circuit WC S>>

The circuit WCS includes a circuit SWS1 and a circuit WCG_s, for example. The circuit WCG_s includes circuits WCSa[1] to WCSa[n], for example.

The circuit SW includes switches SW3[1] to SW3[n], for example. A first terminal of the switch SW3[1] is electrically connected to the wiring WCL[1]_s, a second terminal of the switch SW3[1] is electrically connected to the circuit WCSa[1], and a control terminal of the switch SW3[1] is electrically connected to a wiring SWL1. A first terminal of the switch SW3[n] is electrically connected to the wiring WCL[n]_s, a second terminal of the switch SW3[n] is electrically connected the circuit WCSa[n], and a control terminal of the switch SW3[n] is electrically connected to the wiring SWL1.

The wiring SWL1 functions as a wiring for switching an on state and an off state of each of the switches SW3[1] to SW3[n], for example. Accordingly, the wiring SWL1 is supplied with a high-level potential or a low-level potential.

As each of the switches SW3[1] to SW3[n], an electrical switch such as an analog switch or a mechanical switch may be used, for example. As one of the electrical switches, a transistor that can be used as the transistor F1 or the transistor F2 may be used. In particular, an OS transistor is preferably used as the transistor, for example.

As described above, the circuit SWS1 functions as a circuit that establishes or breaks electrical continuity between the circuit WCG_s and each of the wirings WCL[1]_s to WCL[n]_s. In other words, the circuit SWS1 switches electrical continuity and discontinuity between the circuit WCG_s and each of the wirings WCL[1]_s to WCL[n]_s by using the switches SW3[1] to SW3[n] as switching elements.

The circuit WCG_s has a function of supplying the wirings WCL[1]_s to WCL[n]_s with a signal with an amount corresponding to the first data. In other words, the circuit WCG_s supplies, when the switches SW3[1] to SW3[n] are in an on state, the first data that is to be stored in the cells IM of the cell array CA. Note that in the case of the arithmetic circuit 10A in FIG. 3, the signal is preferably a current.

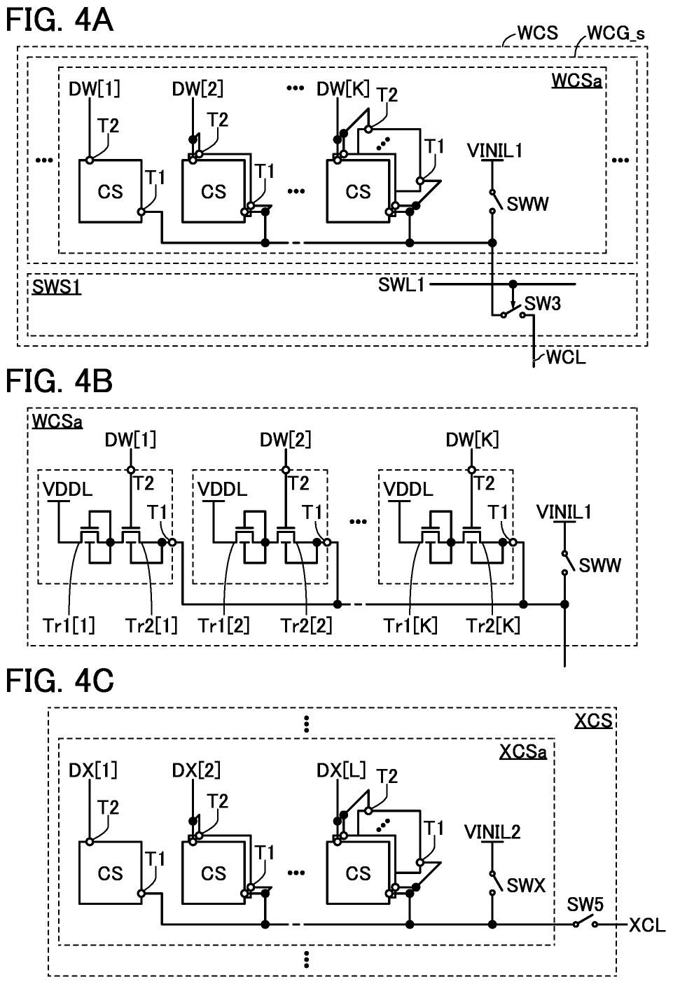

The circuit WCG_s can have a configuration illustrated in FIG. 4A, for example. In FIG. 4A, to illustrate electrical connection between the circuit WCG_s and its peripheral circuits, the circuit SWS1, the switch SW3, the wiring SWL1, and the wiring WCL are also shown.

The circuit WCG_s includes the circuits WCSa the number of which is the same as that of the columns in the subarray SA, for example. In other words, in the case of the arithmetic circuit 10A in FIG. 2 and FIG. 3, the circuit WCG_s includes n circuits WCSa.

The circuit SWS1 includes the switches SW3 the number of which is the same as that of the wirings WCL. In other words, the circuit SWS1 also includes n switches SW3.

Thus, the switch SW3 illustrated in FIG. 4A can be any one of the switches SW3[1] to SW3[n] included in the arithmetic circuit 10A in FIG. 3. Similarly, the wiring WCL can be any one of the wirings WCL[1] to WCL[n] included in the arithmetic circuit 10A in FIG. 3.

Thus, the wirings WCL[1] to WCL[n] are electrically connected to the respective circuits WCSa through the respective switches SW3.

The circuit WCSa illustrated in FIG. 4A includes a switch SWW, for example. A first terminal of the switch SWW is electrically connected to the second terminal of the switch SW3, and a second terminal of the switch SWW is electrically connected to a wiring VINIL1. The wiring VINIL1 functions as a wiring for supplying an initialization potential to the wiring WCL, and the initialization potential can be set to a ground potential (GND), a low-level potential, or a high-level potential. Note that the switch SWW is in an on state only when the initialization potential is supplied to the wiring WCL; otherwise, the switch is in an off state.

As the switch SWW, an electrical switch such as an analog switch or a transistor can be used, for example. When a transistor is used as the switch SWW, for example, the transistor can be a transistor having a structure similar to that of the transistor F1 or the transistor F2. Other than the electrical switch, a mechanical switch may be used.

The circuit WCSa in FIG. 4A includes a plurality of current sources CS, for example. Specifically, the circuit WCSa has a function of outputting K-bit first data (2^{K} values) (K is an integer greater than or equal to 1) as a current amount; in this case, the circuit WCSa includes 2 K−1 current sources CS. The circuit WCSa includes one current source CS that outputs information corresponding to the first bit value as a current, two current sources CS that output information corresponding to the second bit value as a current, and 2^{K-1} current sources CS that output information corresponding to the K-th bit value as a current, for example.

Each of the current sources CS in FIG. 4A includes a terminal T1 and a terminal T2. The terminal T1 of each of the current sources CS is electrically connected to the second terminal of the switch SW3 included in the circuit SWS1. The terminal T2 of one current source CS is electrically connected to a wiring DW[1], the terminals T2 of two current sources CS are electrically connected to a wiring DW[2], and the terminals T2 of 2^{K -1} current sources CS are electrically connected to a wiring DW[K].

The plurality of current sources CS included in the circuit WCSa have a function of outputting the same constant current I_{Wut} from the terminals T1. In practice, at the manufacturing stage of the arithmetic circuit 10A, the transistors included in the current sources CS may have different electrical characteristics; this may yield an error. The error in the constant currents I_{Wut} output from the terminals T1 of the plurality of current sources CS is thus preferably within 10%, further preferably within 5%, still further preferably within 1%. In this embodiment, the description is made on the assumption that there is no error in the constant currents I_{Wut} output from the terminals T1 of the plurality of current sources CS included in the circuit WCSa. In the case where there is an error, use of the correction method described in Embodiment 3 can sometimes reduce the error.

The wirings DW[1] to DW[K] function as wirings for transmitting control signals to make the current sources CS, which are electrically connected to the wirings DW[1] to DW[K], output the constant currents I_{Wut}. Specifically, for example, when a high-level potential is supplied to the wiring DW[1], the current source CS electrically connected to the wiring DW[1]_supplies I_{Wut} as a constant current to the second terminal of the switch SW3, and when a low-level potential is supplied to the wiring DW[1], the current source CS electrically connected to the wiring DW[1] does not output I_{Wut}. For example, when a high-level potential is supplied to the wiring DW[2], the two current sources CS electrically connected to the wiring DW[2]_supply 2I_{Wut}, a constant current, in total to the second terminal of the switch SW3, and when a low-level potential is supplied to the wiring DW[2], 2I_{Wut}, a constant current, in total is not output by the current sources CS electrically connected to the wiring DW[2]. For example, when a high-level potential is supplied to the wiring DW[K], the 2^{K-1} current sources CS electrically connected to the wiring DW[K]_supply 2^{K-1} I_{Wut}, a constant current, in total to the second terminal of the switch SW3, and when a low-level potential is supplied to the wiring DW[K], 2^{K-1} I_{Wut}, a constant current, in total is not output by the current sources CS electrically connected to the wiring DW[K].

The current flowing from the one current source CS electrically connected to the wiring DW[1] corresponds to the value of the first bit, the current flowing from the two current sources CS electrically connected to the wiring DW[2] corresponds to the value of the second bit, and the amount of the current flowing from the K current sources CS electrically connected to the wiring DW[K] corresponds to the value of the K-th bit. The circuit WCSa with K of 2 is considered. For example, when the value of the first bit is “1” and the value of the second bit is “0”, a high-level potential is supplied to the wiring DW[1], and a low-level potential is supplied to the wiring DW[2]. In this case, I_{Wut} flows as a constant current to the second terminal of the switch SW3 of the circuit SWS1 from the circuit WCSa. For example, when the value of the first bit is “0” and the value of the second bit is “1”, a low-level potential is supplied to the wiring DW[1], and a high-level potential is supplied to the wiring DW[2]. In this case, 2I_{Wut} flows as a constant current to the second terminal of the switch SW3 of the circuit SWS1 from the circuit WCSa. For example, when the value of the first bit is “1” and the value of the second bit is “1”, a high-level potential is supplied to the wirings DW[1] and DW[2]. In this case, 3I_{Wut} flows as a constant current to the second terminal of the switch SW3 of the circuit SWS1 from the circuit WCSa. For example, when the value of the first bit is “0” and the value of the second bit is “0”, a low-level potential is supplied to the wirings DW[1] and DW[2]. In this case, the constant current does not flow from the circuit WCSa to the second terminal of the switch SW3 of the circuit SWS1.

FIG. 4A illustrates the circuit WCSa where K is an integer greater than or equal to 3; when K is 1, the current sources CS electrically connected to the wirings DW[2] to DW[K] are not provided in the circuit WCSa in FIG. 4A. When K is 2, the current sources CS electrically connected to the wirings DW[3] to DW[K] are not provided in the circuit WCSa in FIG. 4A.

Next, a specific configuration example of the current source CS is described.

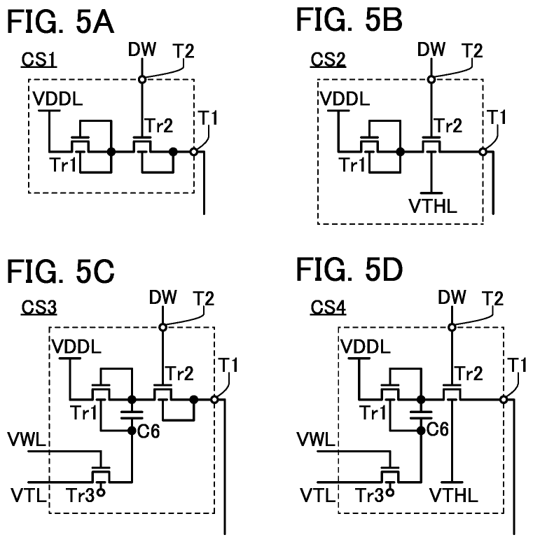

A current source CS1 illustrated in FIG. 5A is a circuit that can be used as the current source CS included in the circuit WCSa in FIG. 4A, and the current source CS1 includes a transistor Tr1 and a transistor Tr2.

A first terminal of the transistor Tr1 is electrically connected to a wiring VDDL, and a second terminal of the transistor Tr1 is electrically connected to a gate of the transistor Tr1, a back gate of the transistor Tr1, and a first terminal of the transistor Tr2. A second terminal of the transistor Tr2 is electrically connected to the terminal T1, and a gate of the transistor Tr2 is electrically connected to the terminal T2. The terminal T2 is electrically connected to the wiring DW.

The wiring DW is any one of the wirings DW[1] to DW[K] in FIG. 4A.

The wiring VDDL functions as a wiring for supplying a constant voltage. The constant voltage can be a high-level potential, for example.

When the constant voltage supplied from the wiring VDDL is set at a high-level potential, a high-level potential is input to the first terminal of the transistor Tr1. The potential of the second terminal of the transistor Tr1 is lower than the high-level potential. At this time, the first terminal of the transistor Tr1 functions as a drain, and the second terminal of the transistor Tr1 functions as a source. Since the gate of the transistor Tr1 is electrically connected to the second terminal of the transistor Tr1, the gate-source voltage of the transistor Tr1 is 0 V. When the threshold voltage of the transistor Tr1 is within an appropriate range, a current in the current range of the subthreshold region (drain current) flows between the first terminal and the second terminal of the transistor Tr1. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, when the transistor Tr1 is an OS transistor. For example, the current is further preferably within a range where the current exponentially increases with respect to the gate-source voltage. That is, the transistor Tr1 functions as a current source for supplying a current within a current range of the transistor Tr1 operating in the subthreshold region. The current corresponds to I_{Wut} described above or I_{Xut} described later.

The transistor Tr2 functions as a switching element. When the potential of the first terminal of the transistor Tr2 is higher than the potential of the second terminal of the transistor Tr2, the first terminal of the transistor Tr2 functions as a drain and the second terminal of the transistor Tr2 functions as a source. Since a back gate of the transistor Tr2 and the second terminal of the transistor Tr2 are electrically connected to each other, a back gate-source voltage becomes 0 V. Thus, when the threshold voltage of the transistor Tr2 is within an appropriate range and a high-level potential is input to the gate of the transistor Tr2, the transistor Tr2 is turned on; when a low-level potential is input to the gate of the transistor Tr2, the transistor Tr2 is turned off. Specifically, when the transistor Tr2 is in an on state, the current within the current range of the subthreshold region flows from the second terminal of the transistor Tr1 to the terminal T1, and when the transistor Tr2 is in an off state, the current does not flow from the second terminal of the transistor Tr1 to the terminal T1.

The circuit that can be used as the current source CS included in the circuit WCSa in FIG. 4A is not limited to the current source CS1 in FIG. 5A. For example, the current source CS1 has a configuration in which the back gate of the transistor Tr2 and the second terminal of the transistor Tr2 are electrically connected to each other; however, the back gate of the transistor Tr2 may be electrically connected to another wiring. Such a configuration example is illustrated in FIG. 5B. In a current source CS2 illustrated in FIG. 5B, the back gate of the transistor Tr2 is electrically connected to a wiring VTHL. When the wiring VTHL of the current source CS2 is electrically connected to an external circuit or the like, the external circuit or the like supplies a predetermined potential to the wiring VTHL and the back gate of the transistor Tr2 can be supplied with the predetermined potential. This can change the threshold voltage of the transistor Tr2. In particular, the off-state current of the transistor Tr2 can be reduced by an increase in the threshold voltage of the transistor Tr2.

For example, the current source CS1 has a configuration in which the back gate of the transistor Tr1 and the second terminal of the transistor Tr1 are electrically connected to each other; however, the voltage between the back gate and the second terminal of the transistor Tr2 may be retained with a capacitor. Such a configuration example is illustrated in FIG. 5C. A current source CS3 illustrated in FIG. 5C includes a transistor Tr3 and a capacitor C6 in addition to the transistor Tr1 and the transistor Tr2. The current source CS3 is different from the current source CS1 in that the second terminal of the transistor Tr1 and the back gate of the transistor Tr1 are electrically connected to each other through the capacitor C6, and the back gate of the transistor Tr1 and a first terminal of the transistor Tr3 are electrically connected to each other. In the current source CS3, a second terminal of the transistor Tr3 is electrically connected to a wiring VTL, and a gate of the transistor Tr3 is electrically connected to a wiring VWL. In the current source CS3, the wiring VWL is supplied with a high-level potential to turn on the transistor Tr3, so that the wiring VTL and the back gate of the transistor Tr1 can be in a conduction state. In this case, a predetermined potential can be input to the back gate of the transistor Tr1 from the wiring VTL. The wiring VWL is supplied with a low-level potential to turn off the transistor Tr3, so that the voltage between the second terminal of the transistor Tr1 and the back gate of the transistor Tr1 can be retained with the capacitor C6. The threshold voltage of the transistor Tr1 can be changed when the voltage supplied to the back gate of the transistor Tr1 is determined by the wiring VTL, and the threshold voltage of the transistor Tr1 can be fixed with the transistor Tr3 and the capacitor C6.

For example, as the circuit that can be used as the current source CS included in the circuit WC Sa in FIG. 4A, a current source CS4 illustrated in FIG. 5D may be used. The current source CS4 is different from the current source CS3 in FIG. 5C in that the back gate of the transistor Tr2 is electrically connected not to the second terminal of the transistor Tr2 but to the wiring VTHL. That is, in the current source CS4, the threshold voltage of the transistor Tr2 can be changed with the potential supplied from the wiring VTHL, as in the current source CS2 in FIG. 5B.

When a high current flows between the first terminal and the second terminal of the transistor Tr1 in the current source CS4, to supply the current from the terminal T1 to the outside of the current source CS4, the on-state current of the transistor Tr2 needs to be increased. In this case, in the current source CS4, the wiring VTHL is supplied with a high-level potential to reduce the threshold voltage of the transistor Tr2 and increase the on-state current of the transistor Tr2, whereby a high current flowing between the first terminal and the second terminal of the transistor Tr1 can be supplied from the terminal T1 to the outside of the current source CS4.

The use of the current sources CS1 to CS4 illustrated in FIGS. 5A to 5D as the current sources CS included in the circuit WCSa in FIG. 4A enables the circuit WCSa to output a current corresponding to the K-bit first data. The amount of the current can be the amount of a current flowing between the first terminal and the second terminal of the transistor F1 in the range where the transistor F1 operates in the subthreshold region, for example.

As the circuit WCSa in FIG. 4A, the circuit WCSa illustrated in FIG. 4B may be used. In the circuit WCSa in FIG. 4B, one current source CS in FIG. 5A is connected to each of the wirings DW[1] to DW[K]. When the channel width of a transistor Tr1[1] is w[1], the channel width of a transistor Tr1[2] is w[2], and the channel width of a transistor Tr1 [K] is w[K], the ratio between the channel widths is w[1]:w[2]:w[K]=1:2:2^{K-1}. Since a current flowing between a source and a drain of a transistor that operates in the subthreshold region is proportional to the channel width, the circuit WCSa illustrated in FIG. 4B can output a current corresponding to the K-bit first data like the circuit WCSa in FIG. 4A.

As each of the transistor Tr1 (including the transistors Tr1 [1] to Tr1 [K]), the transistor Tr2 (including the transistors Tr2[1] to Tr2[K]), and the transistor Tr3, a transistor that can be used as the transistor F1 or F2 can be used, for example. In particular, as each of the transistor Tr1 (including the transistors Tr1 [1] to Tr1 [K]), the transistor Tr2 (including the transistors Tr2[1] to Tr2[K]), and the transistor Tr3, an OS transistor is preferably used.

### <<Circuit XCS>>

The circuit XCS includes circuits XCSa[1] to XCSa[m], for example.

In FIG. 3, the circuit XCSa[1] is electrically connected to the wiring XCL[1], for example, and the circuit XCSa[m] is electrically connected to the wiring XCL[m], for example.

The circuit XCSa has a function of supplying, to the wirings XCL[1]_s to XCL[n]_s, a signal with an amount corresponding to the second data. Note that in the case of the arithmetic circuit 10A in FIG. 3, the signal is preferably a current.

FIG. 4C is a block diagram illustrating an example of the circuit XCS that can be used as the arithmetic circuit 10A in FIG. 2 and FIG. 3. FIG. 4C also shows the wiring XCL to illustrate electrical connection between the circuit XCS and its peripheral circuits.

The circuit XCS includes as many circuits XCSa as the wirings XCL and as many switches SW5 as the wirings XCL, for example. That is, the circuit XCS includes m circuits XCSa and m switches SW5.

Thus, the wiring XCL illustrated in FIG. 4C can be any one of the wirings XCL[1] to XCL[m] included in the arithmetic circuit 10A in FIG. 3. Thus, the first terminals of different switches SW5 are electrically connected to the wirings XCL[1] to XCL[m], and different circuits XCSa are electrically connected to the second terminals of the m switches SW5.

Depending on the circuit configuration of the arithmetic circuit, the circuit XCS in FIG. 4C may have a configuration not provided with the switch SW5.

The circuit XCSa illustrated in FIG. 4C includes a switch SWX, for example. A first terminal of the switch SWX is electrically connected to the wiring XCL, and a second terminal of the switch SWX is electrically connected to a wiring VINIL2. The wiring VINIL2 functions as a wiring for supplying an initialization potential to the wiring XCL, and the initialization potential can be set to a ground potential (GND), a low-level potential, or a high-level potential. The initialization potential supplied from the wiring VINIL2 can be the same as the potential supplied from the wiring VINIL1. The switch SWX is turned on only when the initialization potential is supplied to the wiring XCL; otherwise, the switch is in an off state.

As the switch SWX, a switch that can be used as the switch SWW can be used, for example.

The circuit XCSa in FIG. 4C can have substantially the same configuration as the circuit WCSa in FIG. 4A. Specifically, the circuit XCSa has a function of outputting reference data as a current amount, and a function of outputting L-bit second data (2^{L} values) (L is an integer greater than or equal to 1) as a current amount; in this case, the circuit XCSa includes 2 L−1 current sources CS. The circuit XCSa includes one current source CS that outputs information corresponding to the first bit value as a current, two current sources CS that output information corresponding to the second bit value as a current, and 2^{L-1} current sources CS that output information corresponding to the L-th bit value as a current.

The reference data output from the circuit XCSa as a current can be information in which the first bit value is “1” and the second and subsequent bit values are “0”, for example.

In FIG. 4C, the terminal T2 of one current source CS is electrically connected to a wiring DX[1], the terminals T2 of two current sources CS are electrically connected to a wiring DX[2], and the terminals T2 of 2^{L-1} current sources CS are electrically connected to a wiring DX[L].

The plurality of current sources CS included in the circuit XCSa have a function of outputting the same constant current I_{Xut} from the terminals T1. The wirings DX[1] to DX[L] function as wirings for transmitting control signals to make the current sources CS, which are electrically connected to the wirings DX[1] to DX[L], output I_{Xut}. In other words, the circuit XCSa has a function of making a current with the amount corresponding to the L-bit information transmitted from the wirings DX[1] to DX[L] flow to the wiring XCL.

Specifically, the circuit XCSa with L of 2 is considered here. For example, when the value of the first bit is “1” and the value of the second bit is “0”, a high-level potential is supplied to the wiring DX[1], and a low-level potential is supplied to the wiring DX[2]. In this case, I_{Xut} flows as a constant current from the circuit XCSa to the circuit XCL. For example, when the value of the first bit is “0” and the value of the second bit is “1”, a low-level potential is supplied to the wiring DX[1], and a high-level potential is supplied to the wiring DX[2]. In this case, 2I_{Xut} flows as a constant current from the circuit XCSa to the wiring XCL. For example, when the value of the first bit is “1” and the value of the second bit is “1”, a high-level potential is supplied to the wirings DX[1] and DX[2]. In this case, 3I_{Xut} flows as a constant current from the circuit XCSa to the wiring XCL. For example, when the value of the first bit is “0” and the value of the second bit is “0”, a low-level potential is supplied to the wirings DX[1] and DX[2]. In this case, the constant current does not flow from the circuit XCSa to the wiring XCL. In this specification and the like, this case is sometimes rephrased as “a current with an amount of zero flows from the circuit XCSa to the wiring XCL”. A current amount of zero, I_{Xut}, 2I_{Xut}, 3I_{Xut}, or the like output from the circuit XCSa can be the second data output from the circuit XCSa; specifically, a current amount of I_{Xut} output from the circuit XCSa can be the reference data output from the circuit XCSa.

When the transistors in the current sources CS included in the circuit XCSa have different electrical characteristics and this yields errors, the errors in the constant currents I_{Xut} output from the terminals T1 of the plurality of current sources CS are preferably within 10%, further preferably within 5%, still further preferably within 1%. In this embodiment, the description is made on the assumption that there is no error in the constant currents I_{Xut} output from the terminals T1 of the plurality of current sources CS included in the circuit XCSa. In this embodiment, the description is made on the assumption that there is no error in the constant currents I_{Wut} output from the terminals T1 of the plurality of current sources CS included in the circuit WCSa. In the case where there is an error, use of the correction method described in Embodiment 3 can sometimes reduce the error.

As the current source CS of the circuit XCSa, any of the current sources CS1 to CS4 in FIGS. 5A to 5D can be used in a manner similar to that of the current source CS of the circuit WCSa. In that case, the wiring DW illustrated in FIGS. 5A to 5D is replaced with the wiring DX. This allows the circuit XCSa to make a current within the current range of the subthreshold region flow through the wiring XCL as the reference data or the L-bit second data.

The circuit XCSa in FIG. 4C can have a circuit configuration similar to that of the circuit WCSa illustrated in FIG. 4B. In that case, the circuit WCSa illustrated in FIG. 4B is replaced with the circuit XCSa, the wiring DW[1] is replaced with the wiring DX[1], the wiring DW[2] is replaced with the wiring DX[2], the wiring DW[K] is replaced with the wiring DX[L], the switch SWW is replaced with the switch SWX, and the wiring VINIL1 is replaced with the wiring VINIL2.

### <<Circuit WSD>>

As described above, the circuit WSD has a function of selecting a row in the cell array CA to which the first data is to be written, by supplying a predetermined signal to the wirings WSL[1] to WSL[m] at the time of writing the first data to the cells EVI[1,1] to IM[m,n]. For example, when the circuit WSD supplies the wiring WSL[1] with a high-level potential and supplies the wirings WSL[1] (not illustrated) to WSL[m] with a low-level potential, the transistor F1 whose gate is electrically connected to the wiring WSL[1] can be turned on and the transistor F1 whose gate is electrically connected to the wirings WSL[1] to WSL[m] can be turned off; thus, the cell IM that is electrically connected to the wiring WSL[1] can be selected as the cell IM to which data is to be written.

### <<Circuit ITS>>

In FIG. 3, the circuit ITS includes a circuit SWS2 and a circuit ITG_s, for example. The circuit ITG_s includes converter circuits ITRZ[1] to ITRZ[n], for example.

The circuit SWS2 includes switches SW4[1] to SW4[n], for example. A first terminal of the switch SW4[1] is electrically connected to the wiring WCL[1]_s, a second terminal of the switch SW4[1] is electrically connected to an input terminal of the converter circuit ITRZ[1], and a control terminal of the switch SW4[1] is electrically connected to a wiring SWL2. A first terminal of the switch SW4[n] is electrically connected to the wiring WCL[n]_s, a second terminal of the switch SW4[n] is electrically connected to an input terminal of the converter circuit ITRZ[n], and a control terminal of the switch SW4[n] is electrically connected to the wiring SWL2.

An output terminal of the converter circuit ITRZ[1] is electrically connected to the wiring OL[1]_s, and an output terminal of the converter circuit ITRZ [n] is electrically connected to the wiring OL[n]_s, for example.

The wiring SWL2 functions as a wiring for switching an on state and an off state of the switches SW4[1] to SW4[n], for example. Accordingly, the wiring SWL2 is supplied with a high-level potential or a low-level potential.

As each of the switches SW4[1] to SW4[n], a switch that can be used as the switches SW3[1] to SW3[n] or the like can be used, for example.

As described above, the circuit SWS2 has a function of establishing or breaking electrical continuity between the circuit ITG_s and each of the wirings WCL[1]_s to WCL[n]_s. In other words, the circuit SWS2 switches electrical continuity and discontinuity between the circuit ITS and each of the wirings WCL[1]_s to WCL[n]_s by using the switches SW4[1] to SW4[n] as switching elements.

The converter circuits ITRZ [1] to ITRZ [n] are current-voltage converter circuits each having a function of generating a voltage corresponding to the amount of a current input to the input terminal and outputting the voltage from the output terminal. The voltage can be, for example, an analog voltage, a digital voltage, or the like. The converter circuits ITRZ[1] to ITRZ [n] may each include an arithmetic circuit of a function system. In that case, for example, the arithmetic circuit may perform an arithmetic operation of a function with the use of the voltage obtained by the conversion and may output the arithmetic operation results to the wirings OL[1]_s to OL[n]_s.

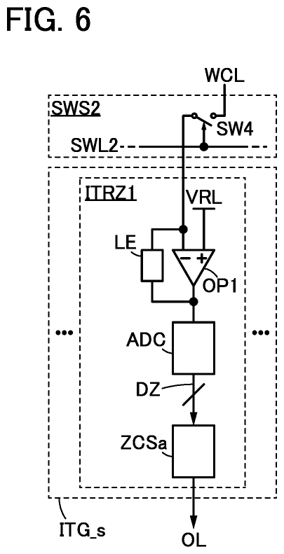

A converter circuit ITRZ1 illustrated in FIG. 6 is an example of a circuit that can be used as the converter circuits ITRZ[1] to ITRZ[n] in FIG. 3. FIG. 6 also shows the circuit SWS2, the wiring WCL, the wiring SWL2, the switch SW4, and the wiring OL to illustrate electrical connection between the converter circuit ITRZ1 and its peripheral circuits. The wiring WCL is any one of the wirings WCL[1] to WCL[n] included in the arithmetic circuit 10A in FIG. 3, the switch SW4 is any one of the switches SW4[1] to SW4[n] included in the arithmetic circuit 10A in FIG. 3, and the wiring OL is any one of the wirings OL[1]_s to OL[n]_s included in the arithmetic circuit 10A in FIG. 3.

The converter circuit ITRZ1 in FIG. 6 is electrically connected to the wiring WCL through the switch SW4. The converter circuit ITRZ1 is electrically connected to the wiring OL. The converter circuit ITRZ1 has a function of converting the amount of a current flowing from the converter circuit ITRZ1 to the wiring WCL or the amount of a current flowing from the wiring WCL to the converter circuit ITRZ1 into an analog voltage, converting the analog voltage into a digital voltage and an analog current in this order, and outputting the analog current to the wiring OL.

The converter circuit ITRZ1 in FIG. 6 includes a load LE, an operational amplifier OP1, an analog-digital converter circuit ADC, and a circuit ZCSa, for example.

An inverting input terminal of the operational amplifier OP1 is electrically connected to a first terminal of the load LE and a second terminal of the switch SW4. A non-inverting input terminal of the operational amplifier OP1 is electrically connected to a wiring VRL. An output terminal of the operational amplifier OP1 is electrically connected to a second terminal of the load LE and an input terminal of the analog-digital converter circuit ADC. An output terminal of the analog-digital converter circuit ADC is electrically connected to the circuit ZCSa through a wiring DZ. The circuit ZCSa is electrically connected to the wiring OL.

The wiring VRL functions as a wiring for supplying a constant voltage. The constant voltage can be a ground potential (GND), a low-level potential, or the like, for example.

As the load LE, for example, a resistor, a diode, or a transistor can be used.

In the converter circuit ITRZ1, the amount of a current flowing from the wiring WCL to the inverting input terminal of the operational amplifier OP1 and the first terminal of the load LE through the switch SW4 or the amount of a current flowing from the inverting input terminal of the operational amplifier OP1 and the first terminal of the load LE to the wiring WCL through the switch SW4 can be converted into an analog voltage owing to the configuration of the operational amplifier OP1 and the load LE. The analog voltage is input to the input terminal of the analog-digital converter circuit ADC.

In particular, by setting the constant potential supplied from the wiring VRL to a ground potential (GND), the inverting input terminal of the operational amplifier OP1 is virtually grounded, and the analog voltage output to the wiring OL can be a voltage with reference to the ground potential (GND).

The analog-digital converter circuit ADC has a function of, in response to input of an analog voltage to its input terminal, outputting a digital voltage corresponding to the analog voltage to the wiring DZ, for example.

Note that here, the wiring DZ is one or more wirings. The number of wirings DZ, for example, can be determined by the resolution of the analog-digital converter circuit ADC. For example, when the resolution of the analog-digital converter circuit ADC is one bit, the number of wirings DZ can be one, and for another example, when the resolution of the analog-digital converter circuit ADC is eight bits, the number of wirings DZ can be eight.

The circuit ZCSa has a function of generating an analog current on the basis of a digital voltage that is input to the wiring DZ and outputting the analog current to the wiring OL, for example. Specifically, the circuit ZCSa can have a configuration similar to that of the circuit WCSa in FIG. 4A, the circuit WCSa in FIG. 4B, or the circuit XCSa in FIG. 4C, for example. In the case where the circuit XCSa in FIG. 4C is used as the circuit ZCSa, the wirings DX[1] to DX[K] illustrated in FIG. 4C are replaced with the wirings DZ.

Furthermore, in the case where the circuit XCSa in FIG. 4C is used as the circuit ZCSa, an additional logic circuit (not illustrated) may be provided for the circuit ZCSa. In particular, it is preferable that the wirings DZ be electrically connected to an input terminal of the logic circuit and a control terminal of the switch SWX be electrically connected to an output terminal of the logic circuit. In addition, the logic circuit preferably outputs a signal for turning on the switch SWX to the output terminal of the logic circuit when a digital value input to the wiring DZ is “0” and preferably outputs a signal for turning off the switch SWX to the output terminal of the logic circuit when a digital value input to the wiring DZ is other than “0”. Thus, when a digital value input to the wiring DZ is “0”, the circuit ZCSa can output a potential corresponding to “0” (a potential supplied from the wiring VINIL2) to the wiring OL.

The analog-digital converter circuit ADC can be regarded as one of the above-described arithmetic circuits of a function system. Thus, to use an arithmetic circuit of a different function system in the converter circuit ITRZ1, the analog-digital converter circuit ADC may be replaced with a circuit that performs a desired function operation. Note that the circuit performing the function operation preferably has a configuration in which the input is an analog voltage and the output is a digital voltage.

Although FIG. 3 illustrates a circuit configuration in the region L1 of the arithmetic circuit 10A, each circuit configuration in the arithmetic circuit 10A described with reference to FIG. 3 can be referred to for the circuit configuration in the region L2 of the arithmetic circuit 10A in FIG. 2. That is, the circuit WCS in the region L2 can have a configuration similar to that of the circuit WCS in the region L1, the circuit WSD in the region L2 can have a configuration similar to that of the circuit WSD in the region L1, and the circuit ITS in the region L2 can have a configuration similar to that of the circuit ITS in the region L1, for example. Furthermore, the subarrays SA_1 to SA_p in the region L2 can have a configuration similar to that of the subarray SA in the region L1.

A current output from the circuit ITS in the region L1 is input to each of the wirings XCL[1]_1 to XCL[n]_1 and the wirings XCL[1]_p to XCL[n]p that extend in the cell array CA in the region L2. With use of an operation result that is transmitted from the circuit ITS in the region L1 as the second data, a product-sum operation of the first data transmitted from the circuit WCS in the region L2 and the second data can be performed in the region L2. Furthermore, the circuit ITS in the region L2 can perform a function operation using the result of the product-sum operation as an input value and output the result of the function operation to the wirings OL[1] to OL[k].

### Example of Arithmetic Operation

Here, an operation example of the arithmetic circuit 10A shown in FIG. 3 is described.

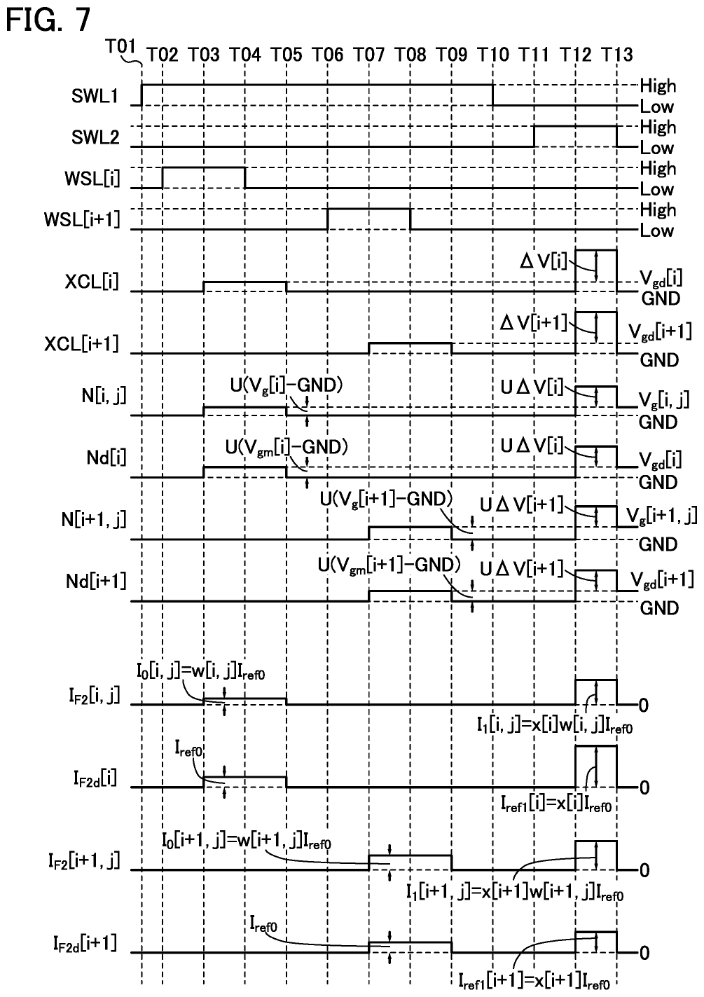

FIG. 7 is a timing chart showing an operation example of the arithmetic circuit 10A shown in FIG. 3. The timing chart in FIG. 7 shows changes in the potentials of the wiring SWL1, the wiring SWL2, the wiring WSL[i] (i is an integer greater than or equal to 1 and less than or equal to m−1), the wiring WSL[i+1], the wiring XCL[i], the wiring XCL[i+1], the node N[i,j] is an integer greater than or equal to 1 and less than or equal to n−1), the node N[i+1,j], the node Nd[i], and the node Nd[i+1] in the period from Time T01 to Time T13 and the vicinity thereof. The timing chart in FIG. 7 also shows changes in an amount of I_{F2}[i,j] of a current flowing between the first terminal and the second terminal of the transistor F2 included in the cell IM[i,j]; an amount of I_{F2d}[i] of a current flowing between the first terminal and the second terminal of the transistor F2d included in the cell IMd[i]; an amount of I_{F2}[i+1,j] of a current flowing between the first terminal and the second terminal of the transistor F2 included in the cell IM[i+1,j]; and an amount of I_{F2d}[i+1] of a current flowing between the first terminal and the second terminal of the transistor F2d included in the cell IMd[i+1].

The circuit WCS in FIG. 4A is used as the circuit WCS of the arithmetic circuit 10A, and the circuit XCS in FIG. 4C is used as the circuit XCS of the arithmetic circuit 10A. The circuit XCS may have a configuration where the switch SW5 is not provided; that is, the wiring XCL and the circuit XCSa may be directly and electrically connected. Alternatively, in this operation example, the switch SW5 of the circuit XCS may always be in an on state during an operation.

Note that in this operation example, the potential of the wiring VE is a ground potential GND. Before Time T01, the potential of each of the nodes N[i,j], N[i+1,j], Nd[i], and Nd[i+1] is the ground potential GND. Specifically, for example, the potentials of the nodes N[i,j] and N[i+1,j] can be set to the ground potential GND when the initialization potential of the wiring VINIL1 in FIG. 4A is set to the ground potential GND and the switch SWW, the switch SW3, and the transistor F1 included in each of the cells IM[i,j] and EVI[i+1,j] are turned on. For example, the potentials of the nodes Nd[i,j] and Nd[i+1,j] can be set to the ground potential GND when the initialization potential of the wiring VINIL2 in FIG. 4C is set to the ground potential GND and the switch SWX and the transistor F1d included in each of the cells IMd[i] and IMd[i+1] are turned on.

### [From Time T01 to Time T02]

In the period from Time T01 to Time T02, a high-level potential (shown as High in FIG. 7) is applied to the wiring SWL1, and a low-level potential (shown as Low in FIG. 7) is applied to the wiring SWL2. Accordingly, a high-level potential is applied to each of the control terminals of the switches SW3[1] to SW3[n], so that the switches SW3[1] to SW3[n] are turned on, and a low-level potential is applied to each of the gates of the switches SW4[1] to SW4[n], so that the switches SW4[1] to SW4[n] are turned off

In the period from Time T01 to Time T02, a low-level potential is applied to the wirings WSL[i] and WSL[i+1]. Accordingly, in the i-th row in the cell array CA, a low-level potential is applied to the gates of the transistors F1 included in the cells IM[i,1] to IM[i,n] and the gate of the transistor F1d included in the cell IMd[i], so that the transistors F1 and the transistor F1d are turned off. In addition, in the i+1-th row in the cell array CA, a low-level potential is applied to the gates of the transistors F1 included in the cells IM[i+1,1] to IM[i+1,n] and the gate of the transistor F1d included in the cell IMd[i+1], so that the transistors F1 and the transistor F1d are turned off.

In the period from Time T01 to Time T02, the ground potential GND is applied to the wirings XCL[i] and XCL[i+1]. Specifically, for example, when the wiring XCL illustrated in FIG. 4C is the wirings XCL[i] and XCL[i+1], the potentials of the wirings XCL[i] and XCL[i+1] can be set to the ground potential GND by setting the initialization potential of the wiring VINIL2 to the ground potential GND and turning on the switch SWX.

In the period from Time T01 to Time T02, the first data is not input to the wirings DW[1] to DW[K] in the circuits WCSa in FIG. 4A, which are electrically connected to the wirings WCL[1]_s to WCL[n]_s through the respective switches SW3. In that case, the low-level potential is input to the wirings DW[1] to DW[K] in the circuits WCSa in FIG. 4A. In the period from Time T01 to Time T02, the second data is not input to the wirings DX[1] to DX[L] in the circuits XCSa in FIG. 4C, which are electrically connected to the wirings XCL[1] to XCL[m]. In that case, the low-level potential is input to the wirings DX[1] to DX[L] in the circuits XCSa in FIG. 4C.

In the period from Time T01 to Time T02, no current flows in a wiring WCL[j]_s, the wiring XCL[i], and the wiring XCL[i+1]. Therefore, I_{F2}[i,j], I_{F2d}[i], I_{F2}[i+1,j], and I_{F2d}[i+1] are each 0.

### [From Time T02 to Time T03]

In the period from Time T02 to Time T03, a high-level potential is applied to the wiring WSL[i]. Accordingly, in the i-th row in the cell array CA, a high-level potential is applied to the gates of the transistors F1 included in the cells IM[i,1] to IM[i,n] and the gate of the transistor F1d included in the cell IMd[i], so that the transistors F1 and the transistor F1d are turned on. Furthermore, in the period from Time T02 to Time T03, a low-level potential is applied to the wirings WSL[1] to WSL[m] other than the wiring WSL[i], so that in the rows other than the i-th row of the cell array CA, the transistors F1 included in the cells IM[1,1] to IM[m,n] and the transistors F1d included in the cells IMd[1] to IMd[m] are in an off state.

The ground potential GND has been applied to the wirings XCL[1] to XCL[m] since before Time T02.

### [From Time T03 to Time T04]

In the period from Time T03 to Time T04, a current with a current amount of I₀[i,j] flows as the first data from the circuit WCSa[j] to the wiring WCL[j]_s through the switch SW3[j]. Specifically, when the wiring WCL illustrated in FIG. 4A is the wiring WCL[j]_s, signals corresponding to the first data are input to the wirings DW[1] to DW[K], whereby a current I₀[i,j] flows from the circuit WCSa to the second terminal of the switch SW3[j]. That is, when the value of the K-bit signal input as the first data is α[i,j] (α[i,j] is an integer greater than or equal to 0 and less than or equal to 2_{K}−1), I₀[i,j]=α[i,j]×I_{Wut}.

Since I₀[i,j]=0 when α[i,j] is 0, a current does not flow from the circuit WCSa to the cell array CA through the switch SW3[j] in a strict sense, but in this specification and the like, an expression such as “a current such that I₀[i,j]=0 flows” is sometimes used.

In the period from Time T03 to Time T04, a conduction state is established between the wiring WCL[j]_s and the first terminal of the transistor F1 included in the cell IM[i,j] in the i-th row in the cell array CA, and a non-conduction state is established between the wiring WCL[j]_s and the first terminals of the transistors F1 included in the cells IM[i,j] to IM[m,j] in the rows other than the i-th row in the cell array CA; accordingly, a current with a current amount of I₀[i,j] flows from the wiring WCL[j] to the cell IM[i,j].

When the transistor F1 included in the cell IM[i,j] is turned on, the transistor F2 included in the cell IM[i,j] has a diode-connected structure. Therefore, when a current flows from the wiring WCL[j]_s to the cell IM[i,j], the potentials of the gate of the transistor F2 and the second terminal of the transistor F2 are substantially equal to each other. The potentials are determined by the amount of a current flowing from the wiring WCL[j] to the cell IM[i,j], the potential of the first terminal of the transistor F2 (here, GND), and the like. In this operation example, a current with a current amount of flows from the wiring WCL[j] to the cell IM[i,j], whereby the potential of the gate of the transistor F2 (the node NM) becomes V_{g}[i,j]. That is, the gate-source voltage of the transistor F2 is V_{g}[i,j]-GND, and a current amount of I₀[i,j] is set as the amount of a current flowing between the first terminal and the second terminal of the transistor F2.

Here, a current amount of I₀[i,j] of the case where the threshold voltage of the transistor F2 in the cell IM[i,j] is Vₜₕ[i,j] and the transistor F2 operates in a subthreshold region can be expressed by the following formula.

I₀[i,j]=Iₐ exp{J(V_{g}[i,j]−Vₜₕ[i,j])} [Formula 1]

Note that Iₐ is a drain current for the case where V_{g}[i,j] is Vₜₕ[i,j], and J is a correction coefficient determined with the temperature, the device structure, and the like.

In the period from Time T03 to Time T04, a current with a current amount of I_{ref0} flows as the reference data from the circuit XCS to the wiring XCL[i]. Specifically, when the wiring XCL illustrated in FIG. 4C is the wiring XCL[i], a high-level potential is input to the wiring DX[1], a low-level potential is input to the wirings DX[2] to DX[K], and a current I_{ref0} flows from the circuit XCSa to the wiring XCL[i]. In other words, I_{ref0}=I_{Xut}.

In the period from Time T03 to Time T04, since a conduction state is established between the first terminal of the transistor F1d included in the cell IMd[i] and the wiring XCL[i], a current with a current amount of I_{ref0} flows from the wiring XCL[i] to the cell IMd[i].

As in the cell IM[i,j], when the transistor F1d included in the cell IMd[i] is turned on, the transistor F2d included in the cell IMd[i] has a diode-connected structure. Therefore, when a current flows from the wiring XCL[i] to the cell IMd[i], the potentials of the gate of the transistor F2d and the second terminal of the transistor F2d are substantially equal to each other. The potentials are determined by the amount of a current flowing from the wiring XCL[i] to the cell IMd[i], the potential of the first terminal of the transistor F2d (here, GND), and the like. In this operation example, the current with a current amount of I_{ref0} flows from the wiring XCL[i] to the cell IMd[i], whereby the potential of the gate of the transistor F2 (the node Nd[i]) becomes V_{gd}[i]; at this time, the potential of the wiring XCL[i] is also V_{gd}[i]. That is, the gate-source voltage of the transistor F2d is V_{gd}[i]— GND, and a current amount of I_{ref0} is set as the amount of a current flowing between the first terminal and the second terminal of the transistor F2d.

Here, a current amount of I_{ref0} of the case where the threshold voltage of the transistor F2d is V_{thd}[i] and the transistor F2d operates in the subthreshold region can be expressed by the following formula.

[Formula 2]

I_{ref0}=Iₐ exp{J(V_{gd}[i]−V_{thd}[i])} (1.2)

Note that the correction coefficient J is the same as that of the transistor F2 included in the cell IM[i,j]. For example, the same device structure and the same size (channel length and channel width) are used for the transistors. Furthermore, although variations in manufacturing cause variations in the correction coefficient J among the transistors, the variations are suppressed to the extent that the argument described later can be made with sufficient precision for practical purposes.

Here, a weight coefficient w[i,j] that is the first data is defined as follows.

[Formula 3]

w[i,j]=exp{J(V_{g}[i,j]−Vₜₕ[i,j]−V_{gd}[i]+V_{thd}[i])} (1.3)

Therefore, Formula (1.1) can be rewritten into the following formula with use of Formula (1.2), Formula (1.3), I₀[i,j]=α[i,j]×I_{Wut}, and I_{ref0}=I_{Xut}.

[Formula 4]

I₀[i,j]=w[i,j]I_{ref0}↔α[i,j]I_{Wut}=w[i,j]I_{Xut} (1.4)

When the current I_{Wut} output from the current source CS of the circuit WCSa in FIG. 4A is equal to the current I_{Xut} output from the current source CS of the circuit XCSa in FIG. 4C, w[i,j]=α[i,j]. That is, when I_{Wut} is equal to I_{Xut}, α[i,j] corresponds to the value of the first data; thus, I_{Wut} and I_{Xut} are preferably equal to each other.

### [From Time T04 to Time T05]

In the period from Time T04 to Time T05, a low-level potential is applied to the wiring WSL[i]. Accordingly, in the i-th row of the cell array CA, a low-level potential is applied to each of the gates of the transistors F1 included in the cells IM[i,1] to IM[i,n] and the gate of the transistor F1d included in the cell IMd[i], so that the transistors F1 and the transistor F1d are turned off.

When the transistor F1 included in the cell IM[i,j] is turned off, V_{g}[i,j]−V_{gd}[i], which is the difference between the potential of the gate of the transistor F2 (the node N[i,j]) and the potential of the wiring XCL[i], is retained in the capacitor C5. When the transistor F1d included in the cell IMd[i] is turned off, 0, which is the difference between the potential of the gate of the transistor F2d (the node Nd[i]) and the potential of the wiring XCL[i], is retained in the capacitor CSd. In the operation from Time T03 to Time T04, the voltage retained in the capacitor C5d might be a voltage that is not 0 (e.g., Vas) depending on the transistor characteristics of the transistor F1d and/or the transistor F2d. In this case, the node Nd[i] can be regarded as having a potential obtained by adding Vas to the potential of the wiring XCL[i].

### [From Time T05 to Time T06]

In the period from Time T05 to Time T06, the ground potential GND is applied to the wiring XCL[i]. Specifically, for example, when the wiring XCL illustrated in FIG. 4C is the wiring XCL[i], the potential of the wiring XCL[i] can be set to the ground potential GND by setting the initialization potential of the wiring VINIL2 to the ground potential GND and turning on the switch SWX.

Thus, the potentials of the nodes N[i,1] to N[i,n] change because of capacitive coupling of the capacitors C5 included in the cells IM[i,1] to IM[i,n] in the i-th row, and the potential of the node Nd[i] changes because of capacitive coupling of the capacitor C5d included in the cell IMd[i].

The amount of change in the potentials of the nodes N[i,1] to N[i,n] i s a potential obtained by multiplying the amount of change in the potential of the wiring XCL[i] by the capacitive coupling coefficient that is determined by the configurations of the cells IM[i,1] to IM[i,n] included in the cell array CA. The capacitive coupling coefficient is calculated on the basis of the values of the static capacitance of the capacitor C5, the gate capacitance of the transistor F2, and the parasitic capacitance, for example. When the capacitive coupling coefficient due to the capacitor C5 is U in each of the cells IM[i,1] to the potential of the node N[i,j] in the cell IM[i,j] decreases from the potential in the period from Time T04 to Time T05 by U(V_{gd}[i]-GND).

Similarly, when the potential of the wiring XCL[i] changes, the potential of the node Nd[i] also changes because of capacitive coupling of the capacitor C5d included in the cell IMd[i]. In the case where the capacitive coupling coefficient due to the capacitor C5d is U like that due to the capacitor C5, the potential of the node Nd[i] in the cell IMd[i] decreases from the potential in the period from Time T04 to Time T05 by U(V_{gd}[i]-GND).

In the timing chart in FIG. 7, U=1, for example. Thus, the potential of the node Nd[i] is GND in the period from Time T05 to Time T06.

Accordingly, the potential of the node N[i,j] of the cell IM[i,j] decreases, so that the transistor F2 is turned off; similarly, the potential of the node Nd[i] of the cell IMd[i] decreases, so that the transistor F2d is also turned off. Therefore, I_{F2}[i,j] and I_{F2d}[i] are each 0 in the period from Time T05 to Time T06.

### [From Time T06 to Time T07]

In the period from Time T06 to Time T07, a high-level potential is applied to the wiring WSL[i+1]_s. Accordingly, in the i+1-th row of the cell array CA, a high-level potential is applied to each of the gates of the transistors F1 included in the cells IM[i+1,1] to IM[i+1,n] and the gate of the transistor F1d included in the cell IMd[i+1], so that the transistors F1 and the transistor F1d are turned on. Furthermore, in the period from Time T06 to Time T07, a low-level potential is applied to each of the wirings WSL[1]_s to WSL[m]_s other than the wiring WSL[i+1]_s, so that in the rows other than the i+1-th row of the cell array CA, the transistors F1 included in the cells IM[1,1] to IM[m,n] and the transistors F1d included in the cells IMd[1] to IMd[m] are in an off state.

The ground potential GND has been applied to the wirings XCL[1] to XCL[m] since before Time T06.

### [From Time T07 to Time T08]

In the period from Time T07 to Time T08, a current with a current amount of I₀[i+1,j] flows as the first data from the circuit WCS to the cell array CA through the switch SW3[i]. For a current amount of I₀[i+1,j], the description of an amount of I₀[i,j] of the current flowing from the circuit WCS to the cell array CA in the period from Time T03 to Time T04 can be referred to. Accordingly, in the case where the value of the first data is α[i+1,j], a current amount of I₀[i+1,j] can be expressed by I₀[i+1,j]=α[i+1,j]×I_{Wut}.

At this time, a conduction state is established between the wiring WCL[i]_s and the first terminal of the transistor F1 included in the cell IM[i+1,j] in the i+1-th row of the cell array CA, and a non-conduction state is established between the wiring WCL[i]_s and the first terminals of the transistors F1 included in the cells IM[1,j] to IM[m,j] in the rows other than the i+1-th row of the cell array CA. Accordingly, a current with a current amount of I₀[i+1,j] flows from the wiring WCL[i]_s to the cell IM[i+1,j].

When the transistor F1 included in the cell IM[i+1,j] is turned on, the transistor F2 included in the cell IM[i+1,j] has a diode-connected structure. In this operation example, a current with a current amount of I₀[i+1,j] flows from the wiring WCL[j]_s to the cell IM[i+1,j], whereby the potential of the gate of the transistor F2 (the node N[i+1,j]) becomes V_{g}[i+1,j]. Accordingly, as in the operation in the period from Time T03 to Time T04, the gate-source voltage of the transistor F2 is V_{g}[i+1,j]−GND, and a current amount of I₀[i+1,j] is set as the amount of a current flowing between the first terminal and the second terminal of the transistor F2.

Here, a current amount of I₀[i+1,j] of the case where the threshold voltage of the transistor F2 in the cell IM[i+1,j] is Vₜₕ[i+1,j] and the transistor F2 operates in a subthreshold region can be expressed by the following formula.

[Formula 5]

I₀[i+1,j]=Iₐ exp{J(V_{g}[i+1,j]−Vₜₕ[i+1,j])} (1.5)

Note that the correction coefficient is J, which is the same as those of the transistor F2 included in the cell IM[i,j] and the transistor F2d included in the cell IMd[i].

In the period from Time T07 to Time T08, a current with a current amount of I_{ref0} flows as the reference data from the circuit XCS to the wiring XCL[i+1]. Specifically, as in the period from Time T03 to Time T04, when the wiring XCL illustrated in FIG. 4C is the wiring XCL[i+1], a high-level potential is input to the wiring DX[1], a low-level potential is input to the wirings DX[2] to DX[K], and a current I_{ref0}=I_{Xut} flows from the circuit XCSa to the wiring XCL[i+1].

In the period from Time T07 to Time T08, since a conduction state is established between the first terminal of the transistor F1d included in the cell IMd[i+1] and the wiring XCL[i+1], a current with a current amount of I_{ref0} flows from the wiring XCL[i+1] to the cell IMd[i+1].

As in the cell IM[i+1,j], when the transistor F1d included in the cell IMd[i+1] is turned on, the transistor F2d included in the cell IMd[i+1,j] has a diode-connected structure. In this operation example, a current flows from the wiring XCL[i+1] to the cell IMd[i+1], whereby the potential of the gate of the transistor F2d (the node Nd[i+1]) becomes V_{gd}[i+1]. Accordingly, as in the operation in the period from Time T03 to Time T04, the gate-source voltage of the transistor F2d is V_{gd}[i+1]−GND, and a current amount of I_{ref0} is set as the amount of a current flowing between the first terminal and the second terminal of the transistor F2d.

Here, a current amount of I_{ref0} of the case where the threshold voltage of the transistor F2d is V_{thd}[i+1,j] and the transistor F2d operates in a subthreshold region can be expressed by the following formula.

[Formula 6]

I_{ref0}=Iₐ exp{J(V_{gd}[i+1]−V_{thd}[i+1])} (1.6)

Note that the correction coefficient J is the same as that of the transistor F2 included in the cell IM[i+1,j].

Here, a weight coefficient w[i+1,j] that is the first data is defined as follows.

[Formula 7]

w[i+1,j]=exp{J(V_{g}[i+1,j]−Vₜₕ[i+1,j]−V_{gd}[i+1]+V_{thd}[i+1])} (1.7)

Therefore, Formula (1.5) can be rewritten into the following formula with use of Formula (1.6), Formula (1.7), I₀ᵣ[i+1,j]=α[i+1,j]×I_{Wut}, and I_{ref0}[i]=I_{Xut}.

[Formula 8]

I₀[i+1,j]=w[i+1,j]I_{ref0}↔α[i+1,j]I_{Wut}=w[i+1,j]I_{Xut} (1.8)

As in Formula (1.4), I_{Wut} is preferably equal to I_{Xut}.

### [From Time T08 to Time T09]

In the period from Time T08 to Time T09, a low-level potential is applied to the wiring WSL[i+1]. Accordingly, in the i+1-th row of the cell array CA, a low-level potential is applied to each of the gates of the transistors F1 included in the cells IM[i+1,1] to IM[i+1,n] and the gate of the transistor F1d included in the cell IMd[i+1], so that the transistors F1 and the transistor F1d are turned off.

When the transistor F1 included in the cell IMr[i+1,j] is turned off, V_{g}[i+1,j]−V_{gd}[i+1], which is the difference between the potential of the gate of the transistor F2 (the node N[i+1,j]) and the potential of the wiring XCL[i+1], is retained in the capacitor C5. When the transistor F1 included in the cell IMd[i+1] is turned off, 0, which is the difference between the potential of the gate of the transistor F2d (the node Nd[i+1]) and the potential of the wiring XCL[i+1], is retained in the capacitor C5d. In the operation in the period from Time T08 to Time T09, the voltage retained in the capacitor C5d might be a voltage that is not 0 (e.g., Vas) depending on the transistor characteristics of the transistor F1d and/or the transistor F2d and the like. In this case, the node Nd[i+1] can be regarded as having a potential obtained by adding Vas to the potential of the wiring XCL[i+1].

### [From Time T09 to Time T10]

In the period from Time T09 to Time T10, the ground potential GND is applied to the wiring XCL[i+1]. Specifically, for example, when the wiring XCL illustrated in FIG. 4A is the wiring XCL[i+1], the potential of the wiring XCL[i+1] can be set to the ground potential GND by setting the initialization potential of the wiring VINIL2 to the ground potential GND and turning on the switch SWX.

Thus, as in the operation in the period from Time T05 to Time T06, the potentials of the nodes N[i+1,1] to N[i+1,n] change because of capacitive coupling of the capacitors C5 included in the cells IM[i+1,1] to IM[i+1,n] in the i+1-th row, and the potential of the node Nd[i+1] changes because of capacitive coupling of the capacitor C5d included in the cell IMd[i+1]. For the change in the potentials of the nodes N[i+1,1] to N[i+1,n], the description of the change in the potentials of the nodes N[i,1] to N[i,n] in the period from Time T05 to Time T06 can be referred to.

Here, the amount of change in the potentials of the nodes N[i+1,1] to N[i+1,n] is a potential obtained by multiplying the amount of change in the potential of the wiring XCL[i+1] by the capacitive coupling coefficient U that is determined by the configurations of the cells IM[i+1,1] to IM[i+1,n] included in the cell array CA, as in the operation in the period from Time T05 to Time T06. At this time, the potential of the node N[i+1,j] in the cell decreases from the potential in the period from Time T08 to Time T09 by U(V_{gd}[i+1]−GND).

Similarly, when the potential of the wiring XCL[i+1] changes, the potential of the node Nd[i+1] also changes because of capacitive coupling of the capacitor C5d included in the cell IMd[i+1]. In the case where the capacitive coupling coefficient due to the capacitor C5d is U like that due to the capacitor C5, the potential of the node Nd[i+1] in the cell IMd[i+1] decreases from the potential in the period from Time T08 to Time T09 by U(V_{gd}[i+1]-GND).

Accordingly, the potential of the node N[i+1,j] of the cell IM[i+1,j] decreases, so that the transistor F2 is turned off; similarly, the potential of the node Nd[i+1] of the cell IMd[i+1] decreases, so that the transistor F2d is also turned off. Therefore, I_{F2}[i+1,j] and I_{F2d}[i+1] are each 0 in the period from Time T09 to Time T10.

### [From Time T10 to Time T11]

In the period from Time T10 to Time T11, a low-level potential is applied to the wiring SWL1. Accordingly, a low-level potential is applied to each of the control terminals of the switches SW3[1] to SW3[n], whereby the switches SW3[1] to SW3[n] are turned off.

### [From Time T11 to Time T12]

In the period from Time T11 to Time T12, a high-level potential is applied to the wiring SWL2. Accordingly, a high-level potential is applied to each of the control terminals of the switches SW4[1] to SW4 [n], whereby the switches SW4[1] to SW4 [n] are turned on.

### [From Time T12 to Time T13]

In the period from Time T12 to Time T13, a current with an amount of x[i]I_{ref0}, i.e., x[i] times a current amount of I_{ref0}, flows from the circuit XCS to the wiring XCL[i] as the second data. Specifically, for example, when the wiring XCL illustrated in FIG. 4C is the wiring XCL[i], a high-level potential or a low-level potential is input to the wirings DX[1] to DX[K] in accordance with the value of x[i], and x[i]I_{ref0}=x[i]I_{Xut} flows as a current amount from the circuit XCSa to the wiring XCL[i]. In this operation example, x[i] corresponds to the value of the second data. At this time, the potential of the wiring XCL[i] changes from 0 to V_{gd}[i]+ΔV[i].

When the potential of the wiring XCL[i] changes, the potentials of the nodes N[i,1] to N[1,n] also change because of the capacitive coupling of the capacitors C5 included in the cells IM[i,1] to IM[i,n] in the i-th row of the cell array CA. Thus, the potential of the node N[i,j] in the cell IM[i,j] becomes V_{g}[i,j]+UΔV[i].

Similarly, when the potential of the wiring XCL[i] changes, the potential of the node Nd[i] also changes because of capacitive coupling of the capacitor C5d included in the cell IMd[i]. Thus, the potential of the node Nd[i] in the cell IMd[i] becomes V_{gd}[i]+UΔV[i].

Accordingly, an amount of h[i,j] of a current flowing between the first terminal and the second terminal of the transistor F2 and an amount of I_{ref1}[i,j] of a current flowing between the first terminal and the second terminal of the transistor F2d in the period from Time T12 to Time T13 can be expressed as follows.

$$\begin{matrix}[ Formula 9 ] & \\ \begin{matrix}{I}_{1} [ i , j ] = {I}_{a} exp \{ J ( {V}_{g} [ i , j ] + U Δ V [ i ] - {V}_{th} [ i , j ] ) \} \\ = {I}_{0} [ i , j ] exp ( JU Δ V [ i ] )\end{matrix} & ( 1.9 )\end{matrix}$$

$$\begin{matrix}[ Formula 10 ] & \\ \begin{matrix}{I}_{ref 1} [ i ] = {I}_{a} exp \{ J ( {V}_{gd} [ i ] + U Δ V [ i ] - {V}_{thd} [ i ] ) \} \\ = x [ i ] {I}_{ref 0}\end{matrix} & ( 1.1 )\end{matrix}$$

Note that x[i] is as expressed by the following formula.

[Formula 11]

x[i]=exp(JUΔV[i]) (1.11)

Therefore, Formula (1.9) can be rewritten into the following formula with the use of Formula (1.4) and Formula (1.11).

[Formula 12]

I₁[i,j]=x[i]w[j]I_{ref0} (1.12)

That is, the amount of a current flowing between the first terminal and the second terminal of the transistor F2 included in the cell is proportional to the product of w[i,j] that is the first data and x[i] that is the second data.

In the period from Time T12 to Time T13, a current with an amount of x[i+1]I_{ref0}, i.e., x[i+1] times a current amount of I_{ref0}, flows from the circuit XCS to the wiring XCL[i+1] as the second data. Specifically, for example, when the wiring XCL illustrated in FIG. 4C is the wiring XCL[i+1], a high-level potential or a low-level potential is input to the wirings DX[1] to DX[K] in accordance with the value of x[i+1], and x[i+1]I_{ref0}=x[i+1]I_{Xut} flows as a current amount from the circuit XCSa to the wiring XCL[i+1]. In this operation example, x[i+1] corresponds to the value of the second data. At this time, the potential of the wiring XCL[i+1] changes from 0 to V_{gd}[i+1]+ΔV[i+1].

When the potential of the wiring XCL[i+1] changes, the potentials of the nodes N[i+1,1] to N[i+1,n] also change because of the capacitive coupling of the capacitors C5 included in the cells IM[i+1,1] to IM[i+1,n] in the i+1-th row of the cell array CA. Thus, the potential of the node N[i+1,j] in the cell IM[i+1,j] becomes V_{g}[i+1,j]+UΔV[i+1].

Similarly, when the potential of the wiring XCL[i+1] changes, the potential of the node Nd[i+1] also changes because of capacitive coupling of the capacitor C5d included in the cell IMd[i+1]. Thus, the potential of the node Nd[i+1] of the cell IMd[i+1] becomes V_{gd}[i+1]+UΔV[1+1].

Accordingly, an amount of h[i+1,j] of a current flowing between the first terminal and the second terminal of the transistor F2 and an amount of Len[i+1 j] of a current flowing between the first terminal and the second terminal of the transistor F2d in the period from Time T12 to Time T13 can be expressed as follows.

$$\begin{matrix}[ Formula 13 ] & \\ \begin{matrix}{I}_{1} [ i + 1 , j ] = {I}_{a} exp \{ J ( {V}_{g} [ i + 1 , j ] + U Δ V [ i + 1 ] - {V}_{th} [ i + 1 , j ] ) \} \\ = {I}_{0} [ i + 1 , j ] exp ( JU Δ V [ i + 1 ] )\end{matrix} & ( 1.13 )\end{matrix}$$

$$\begin{matrix}[ Formula 14 ] & \\ \begin{matrix}{I}_{ref 1} [ i + 1 ] = {I}_{a} exp \{ J ( {V}_{gd} [ i + 1 ] + U Δ V [ i + 1 ] - {V}_{thd} [ i + 1 ] ) \} \\ = x [ i + 1 ] {I}_{ref 0}\end{matrix} & ( 1.14 )\end{matrix}$$

Note that x[i+1] is as expressed by the following formula.

[Formula 15]

x[i+1]=exp(JUΔV[i+1]) (1.15)

Therefore, Formula (1.13) can be rewritten into the following formula with the use of Formula (1.8) and Formula (1.15).

[Formula 16]

I₁[i+1,j]=x[i+1]w[i+1,j]I_{ref0} (1.16)

That is, the amount of a current flowing between the first terminal and the second terminal of the transistor F2 included in the cell IM[i+1,j] is proportional to the product of w[i+1,j] that is the first data and x[i+1] that is the second data.

Here, the sum of the amounts of currents flowing from the converter circuit ITRZ[j] to the cells IM[i,j] and IM[i+1,j] through the switch SW4[i] and the wiring WCL[j]_s is considered. According to Formula (1.12) and Formula (1.16), when the sum of the amounts of the currents is I_{S}[j], I_{S}[j] can be expressed by the following formula.

$$\begin{matrix}[ Formula 17 ] & \\ \begin{matrix}{I}_{S} [ j ] = {I}_{1} [ i , j ] + {I}_{1} [ i + 1 , j ] \\ = {I}_{ref 0} ( x [ i ] w [ i , j ] + x [ i + 1 ] w [ i + 1 , j ] )\end{matrix} & ( 1.17 )\end{matrix}$$

Thus, the current amount output from the converter circuit ITRZ[i] is proportional to the result of a product-sum operation of the weight coefficients w[i,j] and w[i+1,j] that are the first data and the values x[i] and x[i+1] of the signals of the neurons that are the second data.

Although in the above-described operation example, the sum of the amounts of currents flowing in the cells IM[i,j] and IM[i+1,j] is described, the sum of the amounts of currents flowing in a plurality of cells, i.e., the cells IM[1,j] to IM[m,j], may be described. In that case, Formula (1.17) can be rewritten into the following formula.

$$\begin{matrix}[ Formula 18 ] & \\ {I}_{S} [ j ] = {I}_{ref 0} {\sum }_{i = 1}^{m} x [ i ] w [ i , j ] & ( 1.18 )\end{matrix}$$

Thus, even in the case of the arithmetic circuit 10A including the cell array CA having three or more rows and a plurality of columns, a product-sum operation can be performed in the above-described manner. In the arithmetic circuit 10A of such a case, cells in one of a plurality of columns retain current amounts of I_{ref0} and xI_{ref0}, whereby product-sum operations, the number of which corresponds to the number of the rest of the columns among the plurality of columns, can be executed concurrently. That is, when the number of columns in a memory cell array is increased, a semiconductor device that achieves a high-speed product-sum operation can be provided.

Note that the operation method of the semiconductor device of the present invention is not limited to the above-described operation method. For example, although a current with a current amount of I_{ref0} as the reference data flows from the circuit XCSa to the wiring XCL in the period from Time T03 to Time T04 and the period from Time T07 to Time T08 in the timing chart shown in FIG. 7 according to the above operation method, the amount of the current flowing as the reference data is not limited thereto. In other words, although a current with an amount such that I_{ref0}=xᵤₜ, i.e., the value of the second data is 1, flows from the circuit XCSa to the wiring XCL in the period from Time T03 to Time T04 and the period from Time T07 to Time T08 in the timing chart shown in FIG. 7, the amount of the current flowing as the reference data may be x_{bs}I_{ref0} (x_{bs} is an integer greater than or equal to 1). Note that x_{bs} is a number that can be expressed with L bits in the circuit XCSa in FIG. 4C, for example. For example, when L=8, x_{bs} may be any of the values ranging from 0 to 255.

In a specific example, when a current with an amount of 255I_{ref0} (=255xᵤₜ) flows as reference data from the circuit XCSa[i] to the wiring XCL[i] in the period from Time T03 to Time T04 in the timing chart shown in FIG. 7 to write w[i,j] as the first data to the cell IM[i,j], and I_{ref0} (=xᵤₜ) as the second data then flows from the circuit XCSa[i] to the wiring XCL[i] in the period from Time T12 to Time T13, a current with an amount corresponding to w[i,j]/255 flows between the cell IM[i,j] and the wiring WCL[j]. In another specific example, when a current with an amount of 128I_{ref0} (=128xᵤₜ) flows as reference data from the circuit XCSa[i] to the wiring XCL[i] in the period from Time T03 to Time T04 in the timing chart shown in FIG. 7 to write w[i,j] as the first data to the cell IM[i,j], and 192I_{ref0} (=192xᵤₜ) as the second data then flows from the circuit XCSa[i] to the wiring XCL[i] in the period from Time T12 to Time T13, a current with an amount corresponding to w[i,j]×192/128=1.5w[i,j] flows between the cell IM[i,j] and the wiring WCL [j].

In short, when a current with an amount of x_{bs}I_{ref0} (=x_{bs}xᵤₜ) flows as reference data to write w[i,j] as the first data to the cell IM[i,j] and then, x[i]I_{ref0} (=x[i]xᵤₜ) flows as the second data from the circuit XCSa[i] to the wiring XCL[i], a current with an amount corresponding to w[i,j]x[i]/x_{bs} flows between the cell IM[i,j] and the wiring WCL[j].

### Configuration Example 3

The configurations of the cells IM and IMd that can be used in the arithmetic circuit 10A in FIG. 2 described in Configuration example 2 are not limited to those of the cells IM and IMd in the arithmetic circuit 10A in FIG. 3. The configuration of the semiconductor device of one embodiment of the present invention may be changed depending on circumstances.

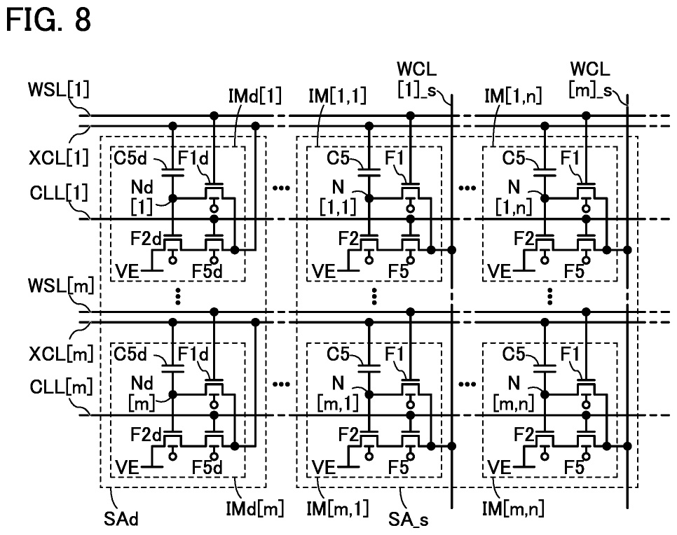

For example, the configurations of the cells IM and IMd illustrated in FIG. 8 can be used for the cells IM and IMd in the arithmetic circuit 10A in FIG. 2. FIG. 8 illustrates the subarrays SAd and SA_s included in the cell array CA in the region L1, for example. As in the arithmetic circuit 10A in FIG. 3, the subarray SAd includes the cells IMd[1] to IMd[m] and the subarray SA_s includes the cells IM[1,1] to IM[m,n].

In FIG. 8, the cells IM[1,1] to IM[m,n] each include a transistor F5 in addition to the circuit elements included in the cells IM[1,1] to IM[m,n] in FIG. 3. In FIG. 8, the cells IMd[1] to IMd[m] each include a transistor F5d in addition to the circuit elements included in the cells IMd[1] to IMd[m] in FIG. 3.

Note that as each of the transistors F5 and F5d, a transistor that can be used as the transistor F1, F2, F1d, or F2d can be used, for example. Thus, for the structures of the transistors F5 and F5d, the above description of the transistors F1, F2, F1d, and F2d is to be referred to.

In each of the cells IM[1,1] to IM[m,n] in FIG. 8, the first terminal of the transistor F1 is electrically connected to the gate of the transistor F2. The first terminal of the transistor F2 is electrically connected to the wiring VE. The first terminal of the capacitor C5 is electrically connected to the gate of the transistor F2. The second terminal of the transistor F2 is electrically connected to a first terminal of the transistor F5. A second terminal of the transistor F5 is electrically connected to the second terminal of the transistor F1.

In each of the cells IMd[1] to IMd[m] in FIG. 8, a first terminal of the transistor F1d is electrically connected to a gate of the transistor F2d. A first terminal of the transistor F2d is electrically connected to the wiring VE. A first terminal of the capacitor C5d is electrically connected to the gate of the transistor F2d. The second terminal of the transistor F2d is electrically connected to a first terminal of the transistor F5d. A second terminal of the transistor F5d is electrically connected to the second terminal of the transistor F1d.

In the cell IMd[1] and the cells IM[1,1] to IM[1,n] that are arranged in the first row in the cell array CA, each of the gates of the transistors F5 and F5d is electrically connected to a wiring CLL[1]. In the cell EVId[m] and the cells IM[m,1] to IM[m,n] that are arranged in the m-th row in the cell array CA, each of the gates of the transistors F5 and F5d is electrically connected to a wiring CLL[m].

Each of the wirings CLL[1] to CLL[m]_serves as a wiring for supplying a fixed potential, for example. The constant potential can be, for example, a potential that is higher than 0 V or a potential that is higher than a ground potential.

In the configuration of the cell IM illustrated in FIG. 3, the transistor F2 is directly and electrically connected to the wiring WCL; thus, when the amount of a current flowing through the wiring WCL is changed, the potential of the second terminal of the transistor F2 is sometimes changed. In the configuration of the cell IMd illustrated in FIG. 3, the transistor F2d is directly and electrically connected to the wiring XCL; thus, when the amount of a current flowing through the wiring XCL is changed, the potential of the second terminal of the transistor F2d is sometimes changed. Accordingly, the source-drain voltage of the transistor F2 or the transistor F2d may be changed, in which case the amount of a current flowing through the transistor F2 or the transistor F2d is sometimes changed.

By providing the transistor F5 in the cell IM as illustrated in FIG. 8, the second terminal of the transistor F2 is less likely to be directly affected by a change in the potential of the wiring WCL. Thus, a sudden change in the potential of the second terminal of the transistor F2 in response to the change in the potential of the wiring WCL can be prevented. In a similar manner, by providing the transistor F5d in the cell IMd, the second terminal of the transistor F2d is less likely to be directly affected by a change in the potential of the wiring XCL. Thus, a sudden change in the potential of the second terminal of the transistor F2d in response to the change in the potential of the wiring XCL can be prevented.

That is, the transistor F5 has a function of fixing the potential of the second terminal of the transistor F2 or a function of preventing a sudden change in the potential of the second terminal of the transistor F2. In a similar manner, the transistor F5d has a function of fixing the potential of the second terminal of the transistor F2d or a function of preventing a sudden change in the potential of the second terminal of the transistor F2d.

Thus, when the cells IM and IMd illustrated in FIG. 8 are used in the arithmetic circuit 10A in FIG. 2, an operation of the arithmetic circuit 10A can be stable.

Although FIG. 8 illustrates a configuration example of the cell array CA in the region L1, the configurations of the cells IM and IMd in FIG. 8 may be used for the cells IM and IMd included in the cell array CA in the region L2.

### Configuration Example 4

The configuration of the arithmetic circuit 10A in FIG. 2 described in Configuration example 2 may be changed in accordance with circumstances.

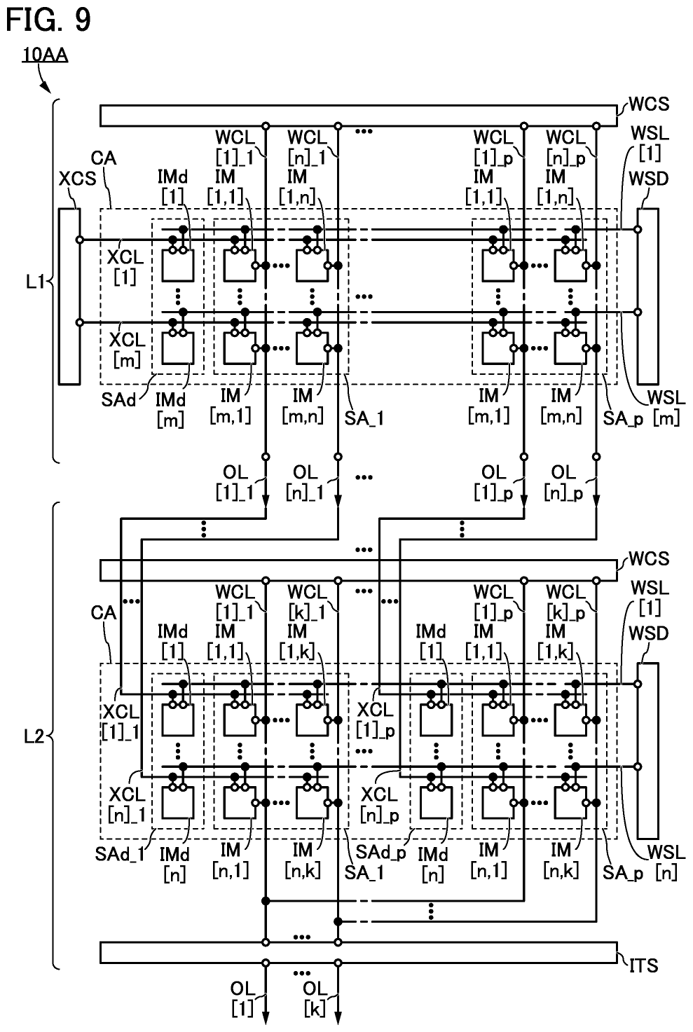

The configuration of the arithmetic circuit 10A illustrated in FIG. 2 may be changed as illustrated in an arithmetic circuit 10AA in FIG. 9, for example. The circuit ITS of the arithmetic circuit 10A is not provided in the arithmetic circuit 10AA. That is, in the arithmetic circuit 10AA in FIG. 9, the wirings WCL[1]_1 to WCL[n]_1 are directly and electrically connected to the wirings OL[1]_1 to OL[n]_1 in a one-to-one correspondence, and the wirings WCL[1]_p to WCL[n]_p are directly and electrically connected to the wirings OL[1]p to OL[n]p in a one-to-one correspondence. Although not illustrated in FIG. 9, when p is 3 or more, the wirings WCL[1] to WCL[n] in the subarray SA other than the subarrays SA_1 and SA_p are electrically connected to the corresponding wirings OL.

With the arithmetic circuit 10AA illustrated in FIG. 9, a current flowing from the wiring WCL[1]_1 to the wiring OL[1]_1, that is, the sum of the currents output from the cells IM[1,1] to IM[m,1], can flow directly to the wiring XCL[1]_1 in the region L2, for example. In addition, the wirings WCL other than the wiring WCL[1]_1 in the region L1 can be considered in a similar manner.

Since the circuit ITS is not provided in the arithmetic circuit 10AA in FIG. 9, the arithmetic circuit 10AA can have a smaller circuit area than the arithmetic circuit 10A in FIG. 2. Furthermore, the arithmetic circuit 10AA in FIG. 9 can save the power required for driving the circuit ITS, unlike the arithmetic circuit 10A in FIG. 2.

### Configuration Example 5

Although Configuration example 2 describes the configuration example of the arithmetic circuit 10A that performs a product-sum operation of positive or “0” first data and positive or “0” second data, the circuit configuration of the arithmetic circuit 10A can be changed so that the arithmetic circuit can perform a product-sum operation of positive, negative, or “0” first data and positive or “0” second data.

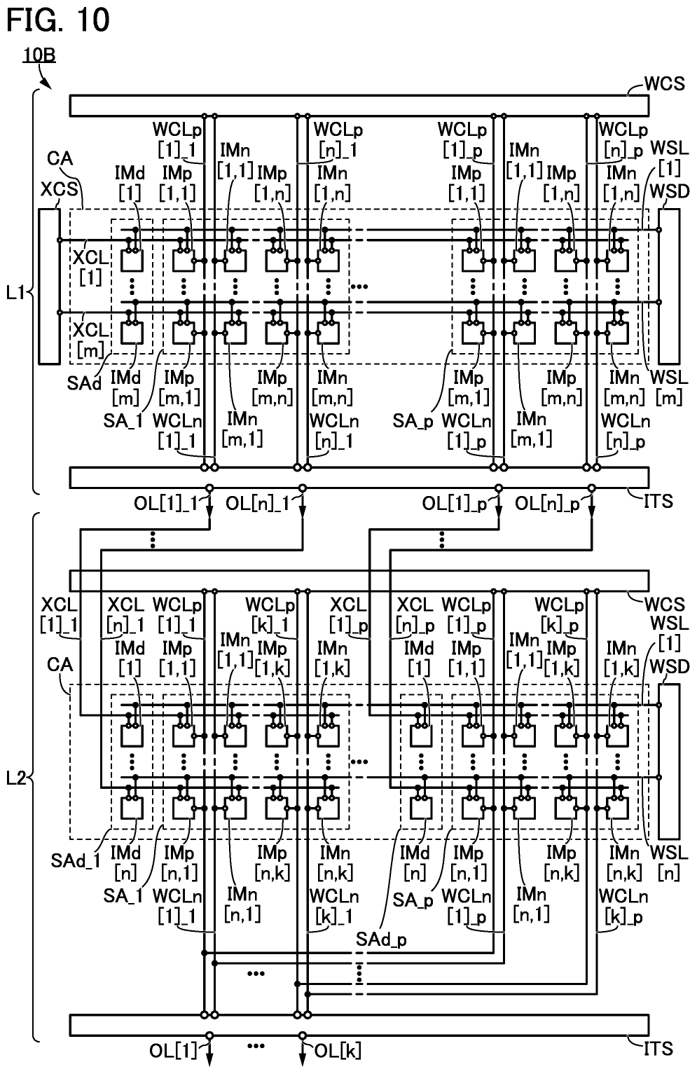

An arithmetic circuit 10B illustrated in FIG. 10 is a variation example of the arithmetic circuit 10A in FIG. 2, and the arithmetic circuit 10B is different from the arithmetic circuit 10A in that, for example, a plurality of cells IMp and a plurality of cells IMn are provided instead of the plurality of cells IM and a plurality of wirings WCLp and a plurality of wirings WCLn are provided instead of a plurality of the wirings WCL in each of the subarrays SA_1 to SA_p in the regions L1 and L2.

In each of the subarrays SA_1 to SA_p in the regions L1 and L2, a cell IMp[i,j] (not illustrated) and a cell IMr[i,j] (not illustrated) in the i-th row and the j-th column are provided so as to be in a pair, for example. Thus, in each of the subarrays SA_1 to SA_p, arithmetic cells of the cells IMp and IMn are provided in a matrix of m rows and 2n columns. Note that in the arithmetic circuit 10B, one pair of the cell IMp[i,j] and the cell IMn[i,j] retains one piece of the first data.

In each of the subarrays SA_1 to SA_p in the regions L1 and L2, a wiring WCLp[j] (not illustrated) and a wiring WCLn[j] (not illustrated) in the j-th column are provided so as to be in a pair, for example. That is, wirings WCLp[1]_1 to WCLp[n]_1 and wirings WCLn[1]_1 to WCLn[n]_1 extend in the column direction in the subarray SA_1, and wirings WCLp[1]_p to WCLp[n]p and wirings WCLn[1]_p to WCLn[n]_p extend in the column direction in the subarray SA_p, for example.

In the subarray SA_s (not illustrated) in the region L1, the cell IMp[i,j] is electrically connected to the wiring XCL[i] (not illustrated) and the wiring WSL[i] (not illustrated). The cell IMp[i,j] is electrically connected to a wiring WCLp[j]_s (not illustrated). In the subarray SA_s (not illustrated) in the region L2, a cell IMp[j,h] (h is an integer greater than or equal to 1 and less than or equal to k) is electrically connected to a wiring XCL[j]_s (not illustrated) and the wiring WSL[j] (not illustrated). The cell IMp[j,h] is electrically connected to a wiring WCLp[h]_s.

In the subarray SA_s in the region L1, the cell IMn[i,j] is electrically connected to the wiring XCL[i] and the wiring WSL[i]. The cell IMn[i,j] is electrically connected to a wiring WCLn[j]_s. In the subarray SA_s in the region L2, a cell IMn[j,h] is electrically connected to the wiring XCL[j]_s and the wiring WSL[j]. The cell IMn[j,h] is electrically connected to a wiring WCLn[h]_s.

In the region L2, the wiring WCLp[1]_1 is electrically connected to the wiring WCLp[1]p, as in the arithmetic circuit 10A in FIG. 2. Although not illustrated, in the case wherep is 3 or more, wirings WCLp[1]_2 to WCLp[1]_p−1 which extend in the first columns in different subarrays SA are electrically connected to the wiring WCLp[1]_1. A wiring WCLp[k]_1 is electrically connected to a wiring WCLp[k]_p. Although not illustrated, in the case where p is 3 or more, wirings WCLp[k]_2 to WCLp[k]_p−1 which extend in the k-th columns in different subarrays SA are electrically connected to the wiring WCLp[k]_1.

Furthermore, in the region L2, the wiring WCLn[1]_1 is electrically connected to the wiring WCLn[1]_p. Although not illustrated, in the case where p is 3 or more, wirings WCLn[1]_2 to WCLn[1]_p−1 which extend in the first columns in different subarrays SA are electrically connected to the wiring WCLn[1]_1. A wiring WCLn[k]_1 is electrically connected to a wiring WCLn[k]_p. Although not illustrated, in the case where p is 3 or more, wirings WCLn[k]_2 to WCLn[k]_p−1 which extend in the k-th columns in different subarrays SA are electrically connected to the wiring WCLn[k]_1.

In the subarray SA_s in the region L1, the circuit ITS has a function of obtaining the difference between the amount of a current flowing through the wiring WCLp[j]_s and the amount of a current flowing through the wiring WCLn[j]_s and outputting information corresponding to the difference (e.g., one or both of a current and a voltage) to the wiring OL[j]_s. Furthermore, in the region L2, the circuit ITS has a function of obtaining the sum of the amounts of currents flowing through the wirings WCLp[j]_1 to WCLp[j]p positioned in the j-th column in each of the subarrays SA and the sum of the amounts of currents flowing through the wirings WCLn[j]_1 to WCLn[j]p positioned in the j-th column in each of the subarrays SA and outputting information corresponding to the difference between the sums (e.g., one or both of a current and a voltage) to the wiring OL[j].

The cells IMp and IMn can each have a configuration similar to that of the cells IM[1,1] to IM[m,n] included in the cell array CA in the arithmetic circuit 10A in FIG. 2, for example.

Next, configuration examples of the cell IMp, the cell IMn, the cell IMd, and the like that can be used for the arithmetic circuit 10B in FIG. 10 are described.

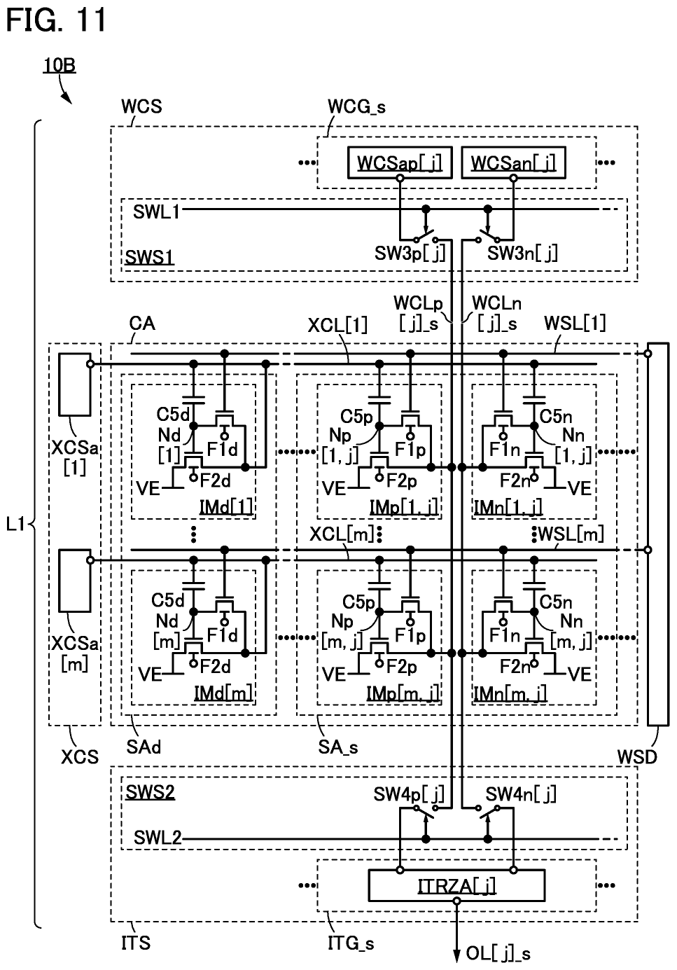

FIG. 11 is a circuit diagram illustrating specific configuration examples of the cell IMp, the cell IMn, the cell IMd, the circuit WCS, and the circuit ITS of the arithmetic circuit 10B in FIG. 10. Note that FIG. 11 selectively illustrates the subarray SAd and the subarray SA s. FIG. 11 also shows the circuit WCS and the circuit WSD to illustrate electrical connection to the cell array CA.

The cell IMd can have a configuration similar to that of the cell IMp or IMn. FIG. 11 shows the cell IMp having a configuration similar to that of the cell IMn, for example. To distinguish the transistors, the capacitors, and the like included in the cell IMp and the cell IMn, “p” is added to the reference numerals representing the transistors and the capacitor included in the cell IMp, and “n” is added to the reference numerals representing the transistors and the capacitor included in the cell IMn.

Specifically, the cell IMp includes a transistor F1p, a transistor F2p, and a capacitor C5p. The transistor F1p corresponds to the transistor F1 in the cell IM, the transistor F2p corresponds to the transistor F2 in the cell IM, and the capacitor C5p corresponds to the capacitor C5 in the cell IM. Thus, for the electrical connection structure between the transistor F1p, the transistor F2p, and the capacitor C5p, refer to the above description of the cells IM[1,1] to IM[m,n].

Specifically, the cell IMn includes a transistor F1n, a transistor F2n, and a capacitor C5n. The transistor F1n corresponds to the transistor F1 in the cell IM, the transistor F2n corresponds to the transistor F2 in the cell IM, and the capacitor C5n corresponds to the capacitor C5 in the cell IM. Thus, for the electrical connection structure between the transistor F1n, the transistor F2n, and the capacitor C5n, refer to the above description of the cells IM[1,1] to IM[m,n].

In the cell IMp, a connection portion of a first terminal of the transistor F1p, the gate of the transistor F2p, and a first terminal of the capacitor C5p is a node Np. In the cell IMn, a connection portion of a first terminal of the transistor F1n, the gate of the transistor F2n, and a first terminal of the capacitor C5n is a node Nn.

In the cell IMp[1,j], a second terminal of the capacitor C5p is electrically connected to the wiring XCL[1], the gate of the transistor F1p is electrically connected to the wiring WSL[1], and a second terminal of the transistor F1p and a second terminal of the transistor F2p are electrically connected to the wiring WCLp[j]_s. In the cell IMn[li], a second terminal of the capacitor C5n is electrically connected to the wiring XCL[1], the gate of the transistor F1n is electrically connected to the wiring WSL[1], and a second terminal of the transistor F1n and a second terminal of the transistor F2n are electrically connected to the wiring WCLn[j]_s.

Similarly, in the cell IMp[m,j], the second terminal of the capacitor C5p is electrically connected to the wiring XCL[m], the gate of the transistor F1p is electrically connected to the wiring WSL[m], and the second terminal of the transistor F1p and the second terminal of the transistor F2p are electrically connected to the wiring WCLp[j]_s. Similarly, in the cell IMn[m,j], the second terminal of the capacitor C5n is electrically connected to the wiring XCL[m], the gate of the transistor F1n is electrically connected to the wiring WSL[m], and the second terminal of the transistor F1n and the second terminal of the transistor F2n are electrically connected to the wiring WCLn[j]_s.

The wiring WCLp[j]_s functions as, for example, a wiring that supplies a current from the circuit WCS to the cell IMp, like the wirings WCL[1] to WCL[n] in FIG. 2. For another example, the wiring WCLp[j]_s functions as a wiring that supplies a current from the circuit ITS to the cell IMp. In a similar manner, the wiring WCLn[j]_s functions as, for example, a wiring that supplies a current from the circuit WCS to the cell IMn, like the wirings WCL[1] to WCL[n] in FIG. 2. For another example, the wiring WCLn[j]_s functions as a wiring that supplies a current from the circuit ITS to the cell IMn.

In the arithmetic circuit 10B in FIG. 11, the circuit SWS1 includes a switch SW3p[j] and a switch SW3n[j]. A first terminal of the switch SW3p[j] is electrically connected to the wiring WCLp[j]_s, a second terminal of the switch SW3p[j] is electrically connected to a circuit WCSap[j] included in the circuit WCG_s to be described later, and a control terminal of the switch SW3p[j] is electrically connected to the wiring SWL1. A first terminal of the switch SW3n[j] is electrically connected to the wiring WCLn[j], a second terminal of the switch SW3n[j] is electrically connected to a circuit WCSan[j] included in the circuit WCG_s to be described later, and a control terminal of the switch SW3n[j] is electrically connected to the wiring SWL1.

The circuit WCG_s of the circuit WCS in FIG. 11 includes the circuits WC Sap[j] and WC San[j], for example. For the circuits WC Sap[j] and WC San[j] in FIG. 11, the configuration of the circuit WCSa illustrated in FIG. 4A, FIG. 4B, or the like can be used, for example.

In the arithmetic circuit 10B in FIG. 11, the circuit SWS2 includes a switch SW4p[j] and a switch SW4n[j]. A first terminal of the switch SW4p[j] is electrically connected to the wiring WCLp[j]_s, a second terminal of the switch SW4p[j] is electrically connected to a converter circuit ITRZA[j] described later, and a control terminal of the switch SW4p[j] is electrically connected to the wiring SWL2. A first terminal of the switch SW4n[j] is electrically connected to the wiring WCLn[j], a second terminal of the switch SW4n[j] is electrically connected to the converter circuit ITRZA[j] described later, and a control terminal of the switch SW4n[j] is electrically connected to the wiring SWL2.

The circuit ITG s of the circuit ITS in FIG. 11 includes the converter circuit ITRZA[j], for example. The converter circuit ITRZA[j] is a circuit corresponding to the converter circuit ITRZ[j] in the arithmetic circuit 10A in FIG. 2; for example, the converter circuit ITRZA[j] has a function of generating a voltage corresponding to the difference between the amount of a current flowing from the converter circuit ITRZA[j] to the wiring WCLp[j]_s and the amount of a current flowing from the converter circuit ITRZA[j] to the wiring WCLn[j]_s and outputting the voltage to the wiring OL[j]_s.

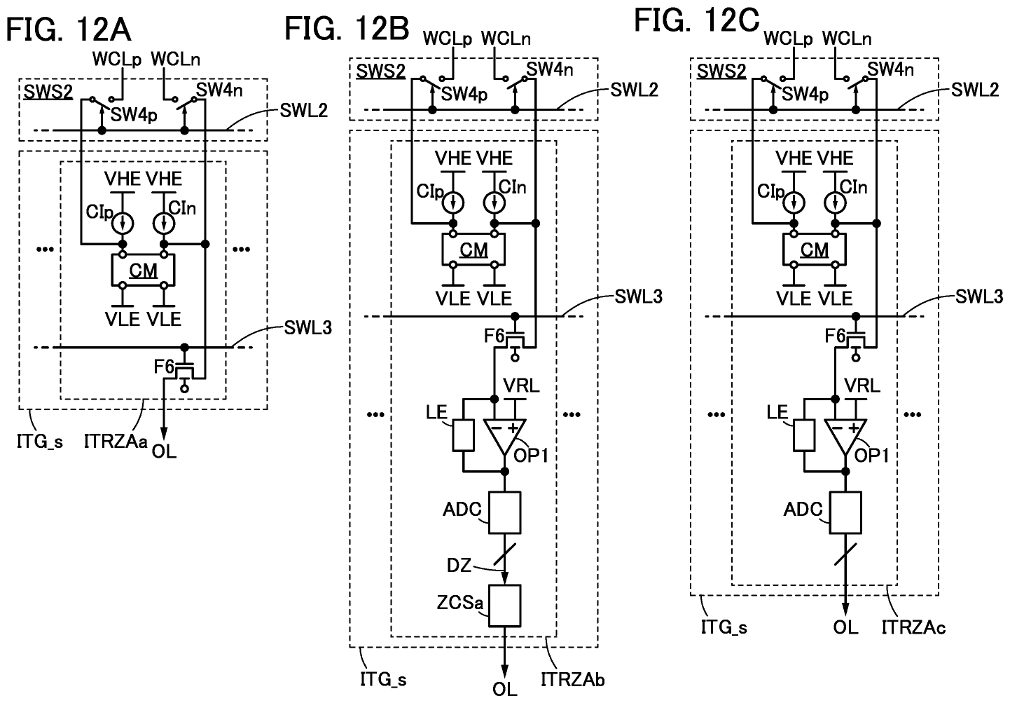

FIG. 12A illustrates a specific configuration example of the converter circuit ITRZA[j]. A converter circuit ITRZAa illustrated in FIG. 12A is an example of a circuit that can be used as the converter circuit ITRZA[j] in FIG. 11. FIG. 12A also shows the circuit SWS2, the wiring WCLp, the wiring WCLn, the wiring SWL2, the switch SW4p, and the switch SW4n to illustrate electrical connection between the converter circuit ITRZAa and its peripheral circuits. The wiring WCLp and the wiring WCLn can be the wiring WCLp[j]_s and the wiring WCLn[j]_s included in the arithmetic circuit 10B in FIG. 11, respectively, for example, and the switch SW4p and the switch SW4n can be the switch SW4p[j] and the switch SW4n[j] included in the arithmetic circuit 10B in FIG. 11, respectively, for example.

The converter circuit ITRZAa in FIG. 12A is electrically connected to the wiring WCLp through the switch SW4p. The converter circuit ITRZAa is electrically connected to the wiring WCLn through the switch SW4n. The converter circuit ITRZAa is electrically connected to the wiring OL. The converter circuit ITRZAa has a function of obtaining the difference current between one of the amount of a current flowing from the converter circuit ITRZAa to the wiring WCLp through the switch SW4p and the amount of a current flowing from the wiring WCLp to the converter circuit ITRZAa through the switch SW4p, and one of the amount of a current flowing from the converter circuit ITRZAa to the wiring WCLn through the switch SW4n and the amount of a current flowing from the wiring WCLn to the converter circuit ITRZAa through the switch SW4n. The converter circuit ITRZAa has a function of making the difference current flow between the converter circuit ITRZAa and the wiring OL.

The converter circuit ITRZAa in FIG. 12A includes, for example, a transistor F6, a current source CIp, a current source CIn, and a current mirror circuit CM.

The second terminal of the switch SW4p is electrically connected to a first terminal of the current mirror circuit CM and an output terminal of the current source CIp, and the second terminal of the switch SW4n is electrically connected to a second terminal of the current mirror circuit CM, an output terminal of the current source CIn, and a first terminal of the transistor F6. An input terminal of the current source CIp is electrically connected to a wiring VHE, and an input terminal of the current source CIn is electrically connected to the wiring VHE. A third terminal of the current mirror circuit CM is electrically connected to a wiring VLE, and a fourth terminal of the current mirror circuit CM is electrically connected to the wiring VLE.

A second terminal of the transistor F6 is electrically connected to the wiring OL and a gate of the transistor F6 is electrically connected to a wiring SWL3.

The current mirror circuit CM has, for example, a function of making a current with an amount corresponding to the potential of the first terminal of the current mirror circuit CM flow between the first terminal and the third terminal of the current mirror circuit CM and between the second terminal and the fourth terminal of the current mirror circuit CM.

The wiring VHE functions as a wiring for supplying a constant potential, for example. Specifically, the constant potential can be a high-level potential or the like.

The wiring VLE functions as a wiring for supplying a constant potential, for example. Specifically, the constant potential can be a low-level potential, a ground potential, or the like.

The wiring SWL3 functions as, for example, a wiring for transmitting a signal to switch the on state and the off state of the transistor F6. Specifically, for example, a high-level potential or a low-level potential is input to the wiring SWL3.

The current source CIp has a function of making a constant current flow between the input terminal and the output terminal of the current source CIp. The current source CIn has a function of making a constant current flow between the input terminal and the output terminal of the current source CM. The amount of a current flowing from the current source CIp and the amount of a current flowing from the current source CIn are preferably equal to each other in the converter circuit ITRZAa in FIG. 12A.

An operation example of the converter circuit ITRZAa in FIG. 12A is described here.

First, the amount of a current flowing from the converter circuit ITRZAa to the wiring WCLp through the switch SW4p is set to I_{Sp}, and the amount of a current flowing from the converter circuit ITRZAa to the wiring WCLn through the switch SW4n is set to I_{Sn}. The amount of a current flowing from each of the current sources CIp and CIn is set to Lm.

In the arithmetic circuit 10B in FIG. 11, I_{Sp} is the sum of the amounts of currents flowing through the cells IMp[1,j] to IMp[m,j]_positioned in the j-th column, for example. In the arithmetic circuit 10B in FIG. 11, I_{Sn} is the sum of the amounts of currents flowing through the cells IMn[1,j] to IMn[m,j]_positioned in the j-th column, for example.

When a high-level potential is input to the wiring SWL2, the switch SW4p and the switch SW4n are turned on. Accordingly, the amount of a current flowing from the first terminal to the third terminal of the current mirror circuit CM becomes Iᵢₙᵢ−I_{Sp}. Due to the current mirror circuit CM, a current with an amount of Iᵢₙᵢ−I_{Sp} flows from the second terminal to the fourth terminal of the current mirror circuit CM.

Next, a high-level potential is input to the wiring SWL3 to turn on the transistor F6. When the amount of a current flowing through the wiring OL is Iₒᵤₜ, Iₒᵤₜ=Iᵢₙᵢ−(Iᵢₙᵢ−I_{Sp})I_{Sn}=I_{Sp}−I_{Sn}.

Here, in the arithmetic circuit 10B in FIG. 11, description is made on the case where a product-sum operation of positive, negative, or “0” first data and positive or “0” second data is performed. Note that for retention of the first data in the cell IM, the above example of retaining the first data is referred to.

To retain the positive first data in the pair of the cells IMp[i,j] and IMn[i,j], the current amount corresponding to the absolute value of the positive first data is set in the cell IMp[i,j] as the amount of the current flowing between the first terminal and the second terminal of the transistor F2p of the cell IMp[i,j], and a current amount of 0 is set in the cell IMn[i,j] as the amount of the current flowing between the first terminal and the second terminal of the transistor F2n of the cell IMn[i,j]. To retain the negative first data in the pair of the cells IMp[i,j] and IMn[i,j], a current amount of 0 is set in the cell IMp[i,j] as the amount of the current flowing between the first terminal and the second terminal of the transistor F2p of the cell IMp[i,j], and the current amount corresponding to the absolute value of the negative first data is set in the cell IMn[i,j] as the amount of the current flowing between the first terminal and the second terminal of the transistor F2n of the cell IMn[i,j]. To retain the “0” first data in the pair of the cells IMp[i,j] and IMn[i,j], a current amount of 0 is set in the cell IMp[i,j] as the amount of the current flowing between the first terminal and the second terminal of the transistor F2p of the cell IMp[i,j], and a current amount of 0 is set in the cell IMn[i,j] as the amount of the current flowing between the first terminal and the second terminal of the transistor F2n of the cell

Specifically, for example, the case where the first data with a value of w[i,j] is written to the cells IMp[i,j] and IMn[i,j] is considered. A value of wₚ[i,j] is written to the cell IMp[i,j], and a value of wₙ[i,j] is written to the cell IMn[i,j]. When w[i,j] is positive, wₚ[i,j]=w[i,j] and wₙ[i,j]=0. When w[i,j] is negative, wₚ[i,j]=0 and wₙ[i,j]=|w[i,j]|. When w[i,j] is 0, wₚ[i,j]=0 and wₙ[i,j]=0.

Here, in the case where the second data is input to each of the wirings XCL[1] to XCL[m] of the arithmetic circuit 10B in FIG. 11, the amount of a current flowing between the first terminal and the second terminal of the transistor F2p in the cell IMp[i,j] and the amount of a current flowing between the first terminal and the second terminal of the transistor F2n in the cell IMn[i,j] are each proportional to the second data.

I_{Sp} is the sum of the amounts of currents flowing through the cells IMp[1,j] to IMp[m,j]_positioned in the j-th column. Thus, I_{Sp} can be expressed by Formula (1.19) shown below, for example. That is, I_{Sp} corresponds to the result of a product-sum operation of the absolute value of the positive first data and the second data. I_{Sn} is the sum of the amounts of currents flowing through the cells IMn[1,j] to IMn[m,j]_positioned in the j-th column. Thus, is, is the sum of the amounts of currents flowing through the cells IMn and can be expressed similarly by Formula (1.20) shown below, for example. That is, I_{Sn} corresponds to the result of a product-sum operation of the absolute value of the negative first data and the second data.

$$\begin{matrix}[ Formula 19 ] & \\ {I}_{Sp} [ j ] = {I}_{ref 0} {\sum }_{i = 1}^{m} x [ i ] {w}_{P} [ i , j ] & ( 1.19 )\end{matrix}$$

$${I}_{Sn} [ j ] = {I}_{ref 0} {\sum }_{i = 1}^{m} x [ i ] {w}_{n} [ i , j ] \qquad ( 1.2 )$$

Thus, an amount of Iₒᵤₜ=I_{Sp}−I_{Sp} of a current flowing to the wiring OL corresponds to the difference between the result of the product-sum operation of the absolute value of the positive first data and the second data and the result of the product-sum operation of the absolute value of the negative first data and the second data. That is, Iₒᵤₜ=I_{Sp}−I_{Sp} corresponds to the result of the product-sum operation of the negative, “0”, or positive first data retained in the cells IMp[1,j] to IMp[m,j] and the cells IMn[1,j] to IMn[m,j] and the second data input to each of the wirings XCL[1] to XCL[m].

When the sum of the amounts of currents flowing through the cells IMp[1,j] to IMp[m,j] is larger than the sum of the amounts of currents flowing through the cells IMn[1,j] to IMn[m,j], i.e., I_{Sp} is larger than I_{Sn}, Iₒᵤₜ is a current amount larger than 0 and flows from the converter circuit ITRZAa to the wiring OL. By contrast, when the sum of the amounts of currents flowing through the cells IMp[1,j] to IMp[m,j] is smaller than the sum of the amounts of currents flowing through the cells IMn[1,j] to IMn[m,j], i.e., I_{Sp} is smaller than I_{Sn}, a current does not flow from the wiring OL to the converter circuit ITRZAa in some cases. That is, when I_{Sp} is smaller than I_{Sn}, Iₒᵤₜ can be approximately 0. Therefore, the converter circuit ITRZAa can be regarded as operating as a ReLU function, for example.

The hierarchical neural network will be described in Embodiment 4.

As the converter circuit ITRZA of the arithmetic circuit 10B in FIG. 11, a converter circuit ITRZAb illustrated in FIG. 12B may be used. The converter circuit ITRZAb has a circuit configuration in which the converter circuit ITRZAa in FIG. 12A and the converter circuit ITRZ1 in FIG. 6 are combined. Thus, a current with an amount corresponding to the result of the product-sum operation of the first data and the second data, which flows between the first terminal and the second terminal of the transistor F6, is converted into an analog voltage by a current-voltage converter circuit formed of the load LE and the operational amplifier OP1. The analog voltage is converted into a digital voltage by an analog-digital converter circuit, and the digital voltage is converted into an analog current by the circuit ZCSa. Thus, unlike the converter circuit ITRZAa, the converter circuit ITRZAb can perform current-voltage conversion, analog-digital conversion, and analog current conversion; as a result, a difference in the amount of a current output to the wiring OL can be made smaller than that in the converter circuit ITRZAa.

As the converter circuit ITRZA included in the circuit ITS in the region L2 of the arithmetic circuit 10B in FIG. 10, for example, a converter circuit ITRZAc shown in FIG. 12C may be used. The converter circuit ITRZAc has the circuit configuration of the converter circuit ITRZAb in FIG. 12B from which the circuit ZCSa is omitted. In other words, an arithmetic operation result output from the region L2 of the arithmetic circuit 10B in FIG. 10 can be used as digital data.

### Configuration Example 6

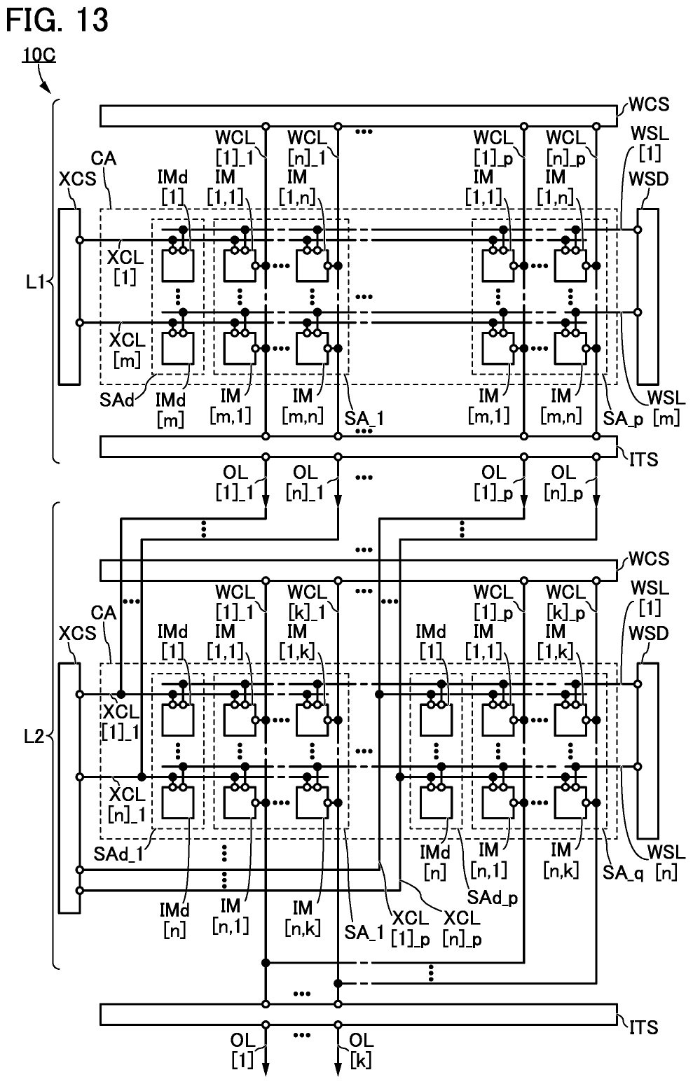

The arithmetic circuit 10A in FIG. 2 described in Configuration example 2 may be changed to an arithmetic circuit 10C in FIG. 13. The arithmetic circuit 10C in FIG. 13 is different from the arithmetic circuit 10A in that the circuit XCS is provided in the region L2.

In the region L2, the circuit XCS is electrically connected to the wirings XCL[1]_1 to XCL[n]_1 and the wirings XCL[1]_p to XCL[n]_p.

The circuit XCS in the region L2 of the arithmetic circuit 10C outputs a current amount of I_{ref0} to the wiring XCL at the time of writing the first data to the cell IM in the cell array CA, for example. That is, in the period from Time T03 to Time T05, the period from Time T07 to Time T09, or the like in the timing chart in FIG. 7, the circuit XCS outputs a current amount of I_{ref0} to the wiring XCL, whereby the potential of the wiring XCL is V_{gm}.

In addition, the circuit XCS in the region L2 of the arithmetic circuit 10C stops the output of a current to the wiring XCL when an arithmetic operation is performed by the cell array CA. Specifically, in the circuit XCS in FIG. 4C, the switch SW5 is turned off. Instead, a current corresponding to the result of the arithmetic operation performed by the cell array CA in the region L1 is input to the wiring XCL. That is, in the period from Time T12 to Time T13 or the like in FIG. 7, a current is supplied from the circuit ITS in the region L1 to the wiring XCL in the region L2.

In the arithmetic circuit 10C, the circuit XCS in the region L2 can make a current for reference flow to the wiring XCL at the time of writing the first data to the cell array CA in the region L2, as described above. By making the current for reference flow to the wiring XCL at the time of writing the first data, an arithmetic operation of the first data and the second data can be performed with high accuracy when a current corresponding to the result of the arithmetic operation performed by the cell array CA in the region L1 is input to the wiring XCL.

Although the circuit WCS for writing the first data is provided in each of the regions L1 and L2 in the above-described arithmetic circuits 10, 10A, 10B, and 10C, a configuration may be employed in which the first data is written to the cell IM or the like included in the cell array CA in the region L2 with use of the circuit WCS in the region L1, for example. That is, the above-described arithmetic circuits 10, 10A, 10B, and 10C may each have a configuration in which the circuit WCS in the region L2 is not provided and the circuit WCS in the region L1 is electrically connected to the plurality of wirings WCL extending in the cell array CA in the region L2.

At least part of any of the structure examples, the drawings corresponding thereto, and the like described in this embodiment can be combined with any of the other structure examples, the other drawings corresponding thereto, and the like as appropriate.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 2

In this embodiment, an operation example of the arithmetic circuit described in the above embodiment will be described. Specifically, an operation example of the arithmetic circuit 10B shown in FIG. 10 is described.

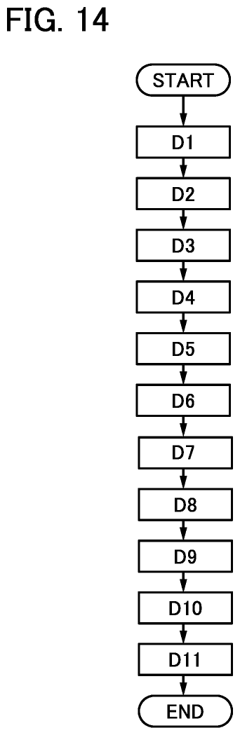

The flowchart in FIG. 14 shows an operation example of the arithmetic circuit 10B. As shown in FIG. 14, the operation example of the arithmetic circuit 10B includes Steps D1 to D11.

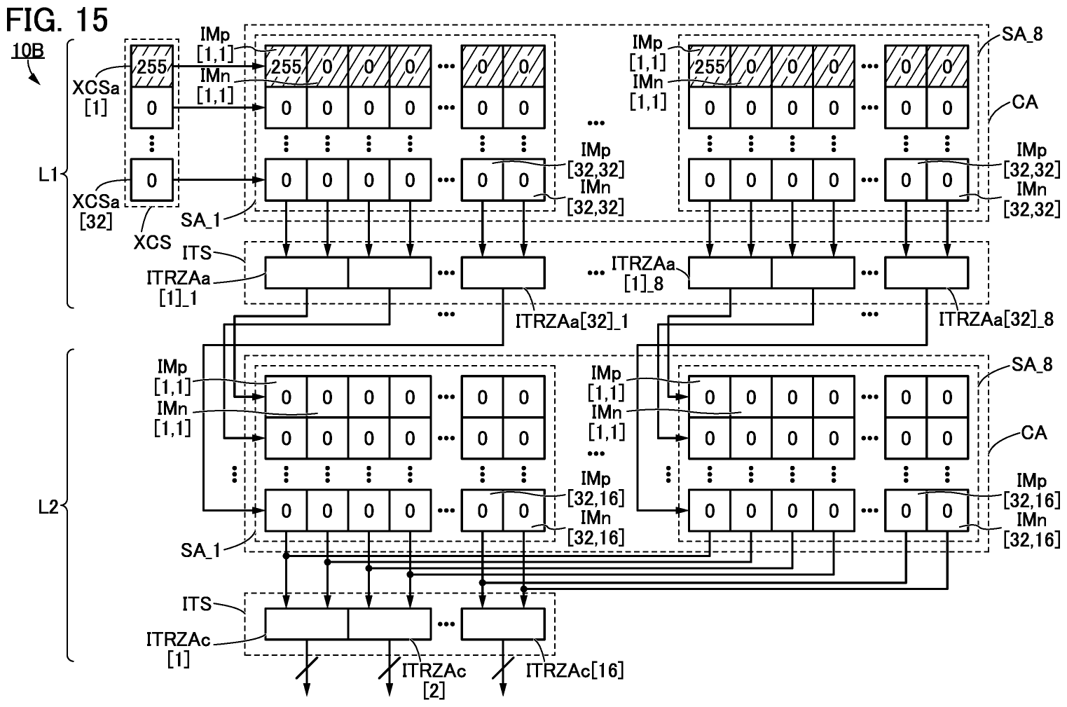

FIGS. 15 to 25 are block diagrams illustrating the operation example of the arithmetic circuit 10B shown in FIG. 10. In each of the block diagrams of FIGS. 15 to 25, the arithmetic circuit 10B shown in FIG. 10 has a configuration where m=32, n=32, k=16, and p=8, for example.

Each of the block diagrams in FIGS. 15 to 25 shows the circuit XCS, the cell array CA in the region L1, the circuit ITS in the region L1, the cell array CA in the region L2, and the circuit ITS in the region L2. Each of the block diagrams of FIGS. 15 to 25 shows some of the circuits XCSa[1] to XCSa[32] in the circuit XCS, some of the subarrays SA_1 to SA_8 in the cell array CA in the region L1, some of a plurality of the converter circuits ITRZAa (see FIG. 12A) in the circuit ITS in the region L1, some of the subarrays SA_1 to SA_8 in the cell array CA in the region L2, and some of a plurality of the converter circuits ITRZAc in the circuit ITS in the region L2.

Specifically, in the circuit ITS in the region L1, the converter circuits ITRZAa that are electrically connected to the subarray SA_1 are shown as the converter circuits ITRZAa[1]_1 to ITRZAa[32]_1, and the converter circuits ITRZA that are electrically connected to the subarray SA_8 are shown as the converter circuits ITRZAa[1]_8 to ITRZAa[32]_8. In a similar manner, in the circuit ITS in the region L2, the converter circuit ITRZAc that is electrically connected to the first columns of the subarrays SA_1 to SA_8 is shown as the converter circuit ITRZAc[1], the converter circuit ITRZAc that is electrically connected to the second columns of the subarrays SA_1 to SA_8 is shown as the converter circuit ITRZAc[2], and the converter circuit ITRZAc that is electrically connected to the sixteenth columns of the subarrays SA_1 to SA_8 is shown as the converter circuit ITRZAc[16]. In this embodiment, the plurality of converter circuits ITRZAa included in the circuit ITS in the region L1 each have the configuration of the converter circuit ITRZAa shown in FIG. 12A, and the plurality of converter circuits ITRZAc included in the circuit ITS in the region L2 each have the configuration of the converter circuit ITRZAc shown in FIG. 12C.

Furthermore, in each of the subarrays SA_1 and SA_8 included in the cell array CA in the region L1, some of the cells IMp[1,1] to IMp[32,32] and some of the cells IMn[1,1] to IMn[32,32] are shown; in each of the subarrays SA_1 and SA_8 included in the cell array CA in the region L2, some of the cells IMp[1,1] to IMp[32,16] and some of the cells IMn[1,1] to IMn[32,16] are shown.

In each of FIG. 15 to FIG. 25 showing the arithmetic circuit 10B, the cell IMp, the cell IMn, the circuit XCSa, the converter circuit ITRZAa, and the converter circuit ITRZAc whose operation changes when entering the corresponding step are denoted with hatching for easy understanding.

### <<Steps D1 to D3>>

In each of Steps D1 to D3, to write the first data (weight coefficient) to the plurality of cells IMp and the plurality of cells IMn included in the subarrays SA_1 to SA_8 of the cell array CA in the region L2 of the arithmetic circuit 10B, preparation is made for supplying a plurality of the wirings XCL extending to the cell array CA in the region L2 with a current with the amount corresponding to reference data (which corresponds to later-described third reference data).

Here, description is made on the process of an operation in which a current that corresponds to the third reference data corresponding to a result of a product-sum operation of first reference data and second reference data and a result of an arithmetic operation of an activation function flows to each row of the subarrays SA_1 to SA_8 in the region L2 when the first reference data is written to the plurality of cells IMp and the plurality of cells IMn included in the subarrays SA_1 to SA_8 in the region L1 and the second reference data is transmitted from the circuit XCS to each row of the subarrays SA_1 to SA_8 in the region L1.

### [Step D1]

The block diagram in FIG. 15 shows an operation example of Step D1. In Step D1, the cell IMp[1,1] in each of the subarrays SA_1 to SA_8 in the region L1 retains “255”, for example. The cell IMn[1,1] in each of the subarrays SA_1 to SA_8 in the region L1 retains “0”. That is, as the first data, “255” is written to the cells IMp[1,1] and IMn[1,1]. The plurality of cells IMp and the plurality of cells IMn provided in the first row and the second and following columns of each of the subarrays SA_1 to SA_8 in the region L1 retain “0”. In other words, as the first data, “0” is written to pairs of the cell IMp and the cell IMn provided in the first row and the second and following columns of each of the subarrays SA_1 to SA_8 in the region L1.

At this time, the circuit XCSa[1] inputs a potential corresponding to a current amount of 255I_{ref0} (which is denoted as “255” in FIG. 15) as the second reference data to the plurality of cells IMp and the plurality of cells IMn provided in the first row of the cell array CA in the region L1.

For an operation relating to setting of current amounts (data writing) in the cells IMp and IMn, the operation in the period from Time T02 to Time T04 or the operation in the period from Time T06 to Time T08 in the timing chart of FIG. 7 can be referred to. Specifically, for example, a current amount such that I₀ₚ[1,1]=255I_{ref0} is set in the cell IMp[1,1] in each of the subarrays SA_1 to SA_8 in the region L1, and a current amount such that I₀ₙ[1,1]=0 is set in the cell IMn[1,1] in each of the subarrays SA_1 to SA_8 in the region L1. Note that I₀ₚ[i,j] (where i is an integer greater than or equal to 1 and less than or equal to 32, and j is an integer greater than or equal to 1 and less than or equal to 32) is a current amount set in the cell IMp[i,j], and I₀ₙ[i,j] is a current amount set in the cell IMn[i,j]. A current amount of 0 is set in the plurality of cells IMp and the plurality of cells IMn other than the cell IMp[1,1] and the cell IMn[1,1] in the first row of each of the subarrays SA_1 to SA_8 in the region L1. At this time, a potential corresponding to a current with an amount such that x_{bs}I_{ref0}=255I_{ref0} is input from the circuit XCSa[1] to the plurality of cells IMp and the plurality of cells IMn provided in the first row of the cell array CA in the region L1.

### [Step D2]

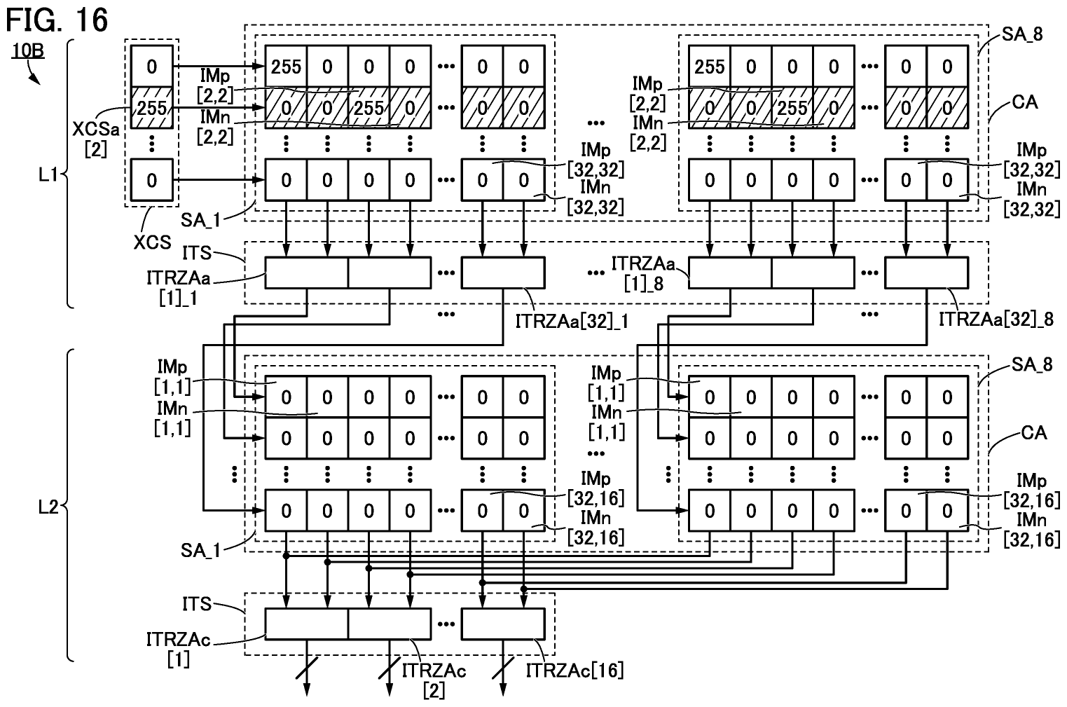

The block diagram in FIG. 16 shows an operation example of Step D2. In Step D2, the cell IMp[2,2] in each of the subarrays SA_1 to SA_8 in the region L1 retains “255”, for example. The cell IMn[2,2] in each of the subarrays SA_1 to SA_8 in the region L1 retains “0”. That is, as the first data, “255” is written to the cells IMp[2,2] and IMn[2,2]. The plurality of cells IMp and the plurality of cells IMn provided in the second row and the first column and the second row and the third and following columns of each of the subarrays SA_1 to SA_8 in the region L1 retain “0”. In other words, as the first data, “0” is written to pairs of the cell IMp and the cell IMn provided in the second row and the first column and the second row and the third and following columns of each of the subarrays SA_1 to SA_8 in the region L1.

At this time, the circuit XCSa[2] inputs a potential corresponding to a current amount of 255I_{ref0} (which is denoted as “255” in FIG. 16) as the second reference data to the plurality of cells IMp and the plurality of cells IMn provided in the second row of the cell array CA in the region L1.

Specifically, for example, a current amount such that I₀ₚ[2,2]=255I_{ref0} is set in the cell IMp[2,2] in each of the subarrays SA_1 to SA_8 in the region L1, and a current amount such that I₀ₙ[2,2]=0 is set in the cell IMn[2,2] in each of the subarrays SA_1 to SA_8 in the region L1 as in Step D1. A current amount of 0 is set in the plurality of cells IMp and the plurality of cells IMn other than the cell IMp[2,2] and the cell IMn[2,2] in the second row of each of the subarrays SA_1 to SA_8 in the region L1. At this time, a potential corresponding to a current with an amount such that x_{bs}I_{ref0}=255I_{ref0} is input from the circuit XCSa[2] to the plurality of cells IMp and the plurality of cells IMn provided in the second row of the cell array CA in the region L1.

### [Step D3]

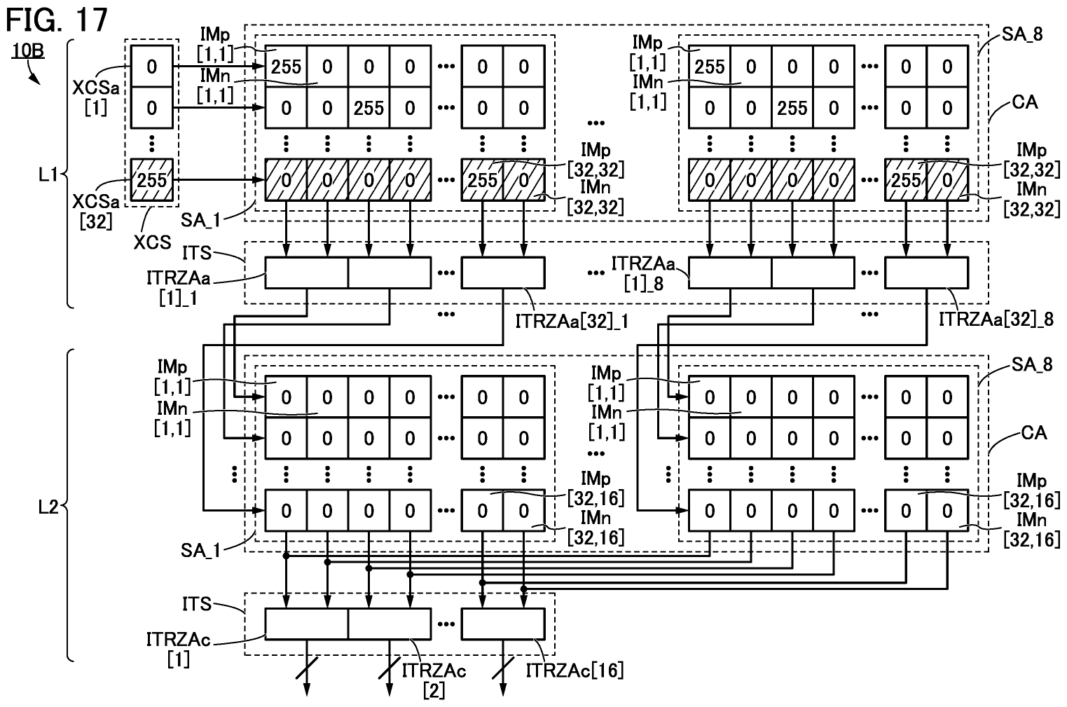

The block diagram in FIG. 17 shows an operation example of Step D3. In Step D3, “255” is set in the cell IMp[i,i] (where i is an integer greater than or equal to 3 and less than or equal to 31) in each of the subarrays SA_1 to SA_8 in the region L1, for example, as in the operations in Steps D1 and D2. “0” is set in the cell IMn[i,i] in each of the subarrays SA_1 to SA_8 in the region L1. That is, as the first data, “255” is written to the cells IMp[i,i] and IMn[i,i]. A current amount of “0” is set in the plurality of cells IMp and the plurality of cells IMn other than the cells IMp[i,i] and IMn[i,i] in the third to thirty-first rows of each of the subarrays SA_1 to SA_8 in the region L1. In other words, as the first data, “0” is written to pairs of the cell IMp and the cell IMn other than the cells IMp[i,i] and IMn[i,i] in the third to thirty-first rows of each of the subarrays SA_1 to SA_8 in the region L1.

Here, when a current amount is sequentially set in the plurality of cells IMp and the plurality of cells IMn provided in the third to thirty-first rows of the subarrays SA_1 to SA_8 in the region L1, the circuit XCSa corresponding to the row where current amount setting is performed inputs, as the second reference data, a potential corresponding to a current amount of 255I_{ref0} to the plurality of cells IMp and the plurality of cells IMn provided in the row.

Specifically, for example, a current amount such that I₀ₚ[i,i]=255I_{ref0} is set in the cell IMp[i,i] in each of the subarrays SA_1 to SA_8 in the region L1, and a current amount such that/on[i,i]=0 is set in the cell IMn[i,i] in each of the subarrays SA_1 to SA_8 in the region L1 as in Steps D1 and D2. A current amount of 0 is set in each of the plurality of cells IMp and the plurality of cells IMn other than the cells IMp[i,i] and IMn[i,i] in the third to thirty-first rows of each of the subarrays SA_1 to SA_8 in the region L1. At the time of current amount setting performed in each of the third to thirty-first rows, a potential corresponding to a current with an amount such that x[i]I_{ref0}=255I_{ref0} is input from the circuit XCSa[i] to the plurality of cells IMp and the plurality of cells IMn provided in the corresponding row of the cell array CA in the region L1.

In Step D3, the cell IMp[32,32] in each of the subarrays SA_1 to SA_8 in the region L1 retains “255”, for example. The cell IMn[32,32] in each of the subarrays SA_1 to SA_8 in the region L1 retains “0”. That is, as the first data, “255” is written to the cells IMp[32,32] and IMn[32,32]. The plurality of cells IMp and the plurality of cells IMn provided in the thirty-second row and the thirty-first and preceding columns of each of the subarrays SA_1 to SA_8 in the region L1 retain “0”. In other words, as the first data, “0” is written to pairs of the cell IMp and the cell IMn provided in the thirty-second row and the thirty-first and preceding columns of each of the subarrays SA_1 to SA_8 in the region L1.

At this time, the circuit XCSa[32] inputs a potential corresponding to a current amount of 255I_{ref0} (which is denoted as “255” in FIG. 17) as the second reference data to the plurality of cells IMp and the plurality of cells IMn provided in the thirty-second row of the cell array CA in the region L1.

Specifically, for example, a current amount such that I₀ₚ[32,32]=255I_{ref0} is set in the cell IMp[32,32] in each of the subarrays SA_1 to SA_8 in the region L1, and a current amount such that I₀ₙ[32,32]=0 is set in the cell IMn[32,32] in each of the subarrays SA_1 to SA_8 in the region L1 as in Steps D1 and D2. A current amount of 0 is set in the plurality of cells IMp and the plurality of cells IMn other than the cell IMp[32,32] and the cell IMn[32,32] in the thirty-second row of each of the subarrays SA_1 to SA_8 in the region L1. At this time, a potential corresponding to a current with an amount such that x_{bs}I_{ref0}=255I_{ref0} is supplied from the circuit XCSa[32] to the plurality of cells IMp and the plurality of cells IMn provided in the thirty-second row of the cell array CA in the region L1.

Through Steps D1 to D3, the first data for generating a current with the amount corresponding to the reference data necessary for writing of the first data to the cell array CA in the region L2 can be written to each pair of the cell IMp and the cell IMn of the cell array CA in the region L1. Note that the first data written to the cell array CA in the region L1 can be expressed as a matrix R of 32 rows and 256 columns by Formula (2.1). Hereinafter, the matrix R is sometimes referred to as the first reference data.

$$\begin{matrix}[ Formula 20 ] & \\ R = ( {\underbrace{\begin{matrix}255 & 0 & … & 0 \\ 0 & 255 & … & 0 \\ ⋮ & ⋮ & & ⋮ \\ 0 & 0 & … & 255\end{matrix}}}_{SA \_ 1} \begin{matrix}… \\ … \\ … \\ …\end{matrix} {\underbrace{\begin{matrix}255 & 0 & … & 0 \\ 0 & 255 & … & 0 \\ ⋮ & ⋮ & & ⋮ \\ 0 & 0 & … & 255\end{matrix}}}_{SA \_ 8} ) & ( 2.1 )\end{matrix}$$

### <<Steps D4 to D6>>

In each of Steps D4 to D6, the corresponding first data (weight coefficient) is written to the plurality of cells IMp and the plurality of cells IMn included in the subarrays SA_1 to SA_8 of the cell array CA in the region L2 in the arithmetic circuit 10B.

### [Step D4]

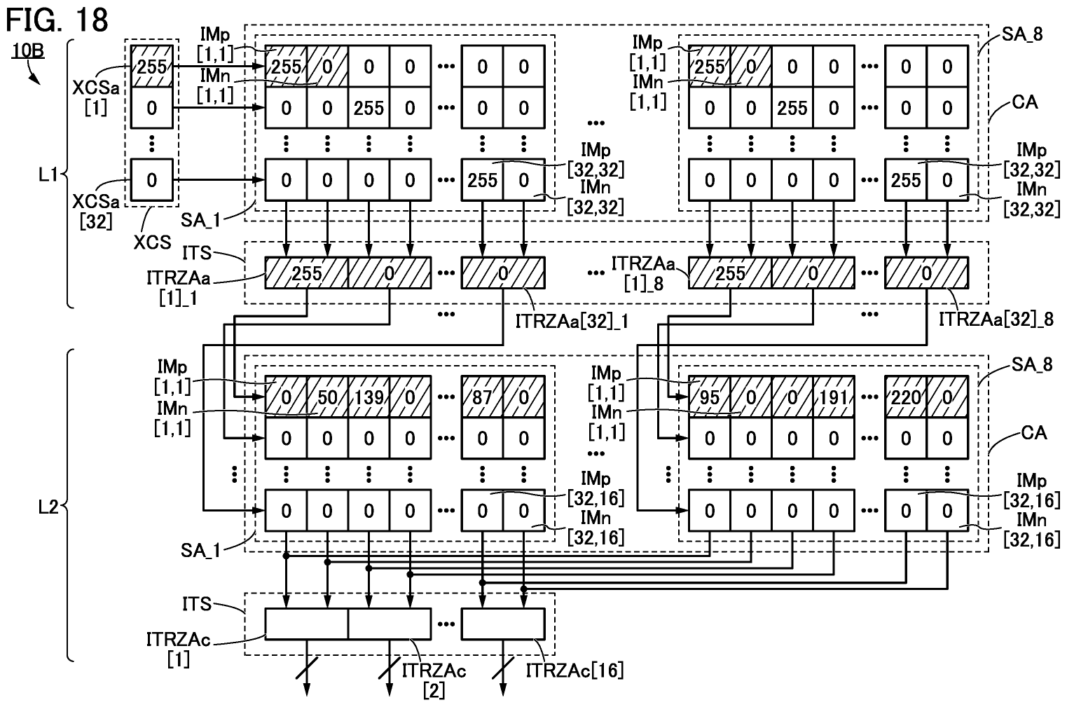

The block diagram in FIG. 18 shows an operation example of Step D4. In Step D4, first, preparation is made for supplying the plurality of converter circuits ITRZAa included in the circuit ITS with the corresponding current in the region L1, for example. Specifically, in the case where the arithmetic circuit 10B has the circuit configuration shown in FIG. 11, a high-level potential is input to the wiring SWL2 so that the switches SW4p[1] to SW4p[32] and the switches SW4n[1] to SW4n[32] included in the circuit SWS2 are turned on, for example. Note that for this operation, description of the operation in the period from Time T11 to Time T12 in the timing chart of FIG. 7 can be referred to.

Then, the circuit XCSa[1]_supplies, as the second reference data, a current with an amount of 255I_{ref0} (which is denoted as “255” in FIG. 18) to the first row of each of the subarrays SA_1 to SA_8 in the region L1. The circuits XCSa in the rows other than the first row supply a current with an amount of 0 to the corresponding rows of the subarrays SA_1 to SA_8 in the region L1.

Here, description is made with focus on the first column of each of the subarrays SA_1 to SA_8 in the region L1. Since 255I_{ref0} is supplied from the circuit XCSa[1] to the first row of each of the subarrays SA_1 to SA_8 in the region L1, a current with an amount such that I₀ₚ[1,1]=255I_{ref0} is generated in the cell IMp[1,1]. Since a current with an amount of 0 is supplied to the second to thirty-second rows of each of the subarrays SA_1 to SA_8 in the region L1 from the circuits XCSa in the corresponding rows, the amount of a current generated in each of the cells IMp[2,1] to IMp[32,1] is 0. Accordingly, the sum of the amounts of currents generated in the cells IMp[1,1] to IMp[32,1] is I_{Sp}=255I_{ref0}. Since 0 is set as the current amount in each of the cells IMn[1,1] to IMn[32,1], the sum of the amounts of currents generated in the cells IMn[1,1] to IMn[32,1] is I_{Sp}=0.

From the above, a difference current I_{Sp}−I_{Sn}, is 255I_{ref0} in each of the converter circuits ITRZAa[1]_1 to ITRZAa[1]_8. Since each of the converter circuits ITRZAa[1]_1 to ITRZAa[1]_8 has the configuration shown in FIG. 12A, the difference current I_{Sp}−I_{Sp} (=255I_{ref0}) is supplied to the first row of each of the subarrays SA_1 to SA_8 in the region L2.

In each of the second to thirty-second columns of each of the subarrays SA_1 to SA_8 in the region L1, the sum of the amounts of currents generated in the cells IMp[1,i] (where i is an integer greater than or equal to 2 and less than or equal to 32) to IMp[32,i] is 0 and the sum of the amounts of currents generated in the cells IMn[1,i] to IMn[32,i] is also 0. Thus, the difference current I_{Sp}−I_{Sp} in each of the plurality of converter circuits ITRZAa other than the converter circuits ITRZAa[1]_1 to ITRZAa[1]_8 included in the circuit ITS in the region L1 is 0. A current amount of 0 output from the plurality of converter circuits ITRZAa is supplied to the second to thirty-second rows of each of the subarrays SA_1 to SA_8 in the region L2. That is, no current flows from the plurality of converter circuits ITRZAa other than the converter circuits ITRZAa[1]_1 to ITRZAa[1]_8 to the second to thirty-second rows of the subarrays SA_1 to SA_8 in the region L2.

The difference current I_{Sp}−I_{Sn} (=255I_{ref0}) supplied from the converter circuits ITRZAa[1]_1 to ITRZAa[1]_8 to the first rows of the subarrays SA_1 to SA_8 in the region L2 is a current whose amount corresponds to the third reference data and which is for writing the first data (weight coefficient) to the plurality of cells IMp and the plurality of cells IMn included in the subarrays SA_1 to SA_8 of the cell array CA in the region L2.

Accordingly, while the converter circuits ITRZAa[1]_1 to ITRZAa[1]_8 input a potential that corresponds a current with an amount of 255I_{ref0} corresponding to the third reference data to the first rows of the subarrays SA_1 to SA_8 in the region L2, the corresponding first data (weight coefficient) is written to the plurality of cells IMp and the plurality of cells IMn provided in the first row of each of the subarrays SA_1 to SA_8 of the cell array CA in the region L2.

For example, in the subarray SA_1 in the region L2 shown in FIG. 18, the cell IMp[1,1] retains “0” and the cell IMn[1,1] retains “50”. That is, “−50” is written to the cells IMp[1,1] and IMn[1,1] as the first data. In a similar manner, “139” is written to the cells IMp[1,2] and IMn[1,2] as the first data, and “87” is written to the cells IMp[1,16] and IMn[1,16] as the first data.

For another example, in the subarray SA_8 in the region L2 shown in FIG. 18, “95” is written to the cells IMp[1,1] and IMn[1,1] as the first data, “−191” is written to the cells IMp[1,2] and IMn[1,2] as the first data, and “220” is written to the cells IMp[1,16] and IMn[1,16] as the first data.

### [Step D5]

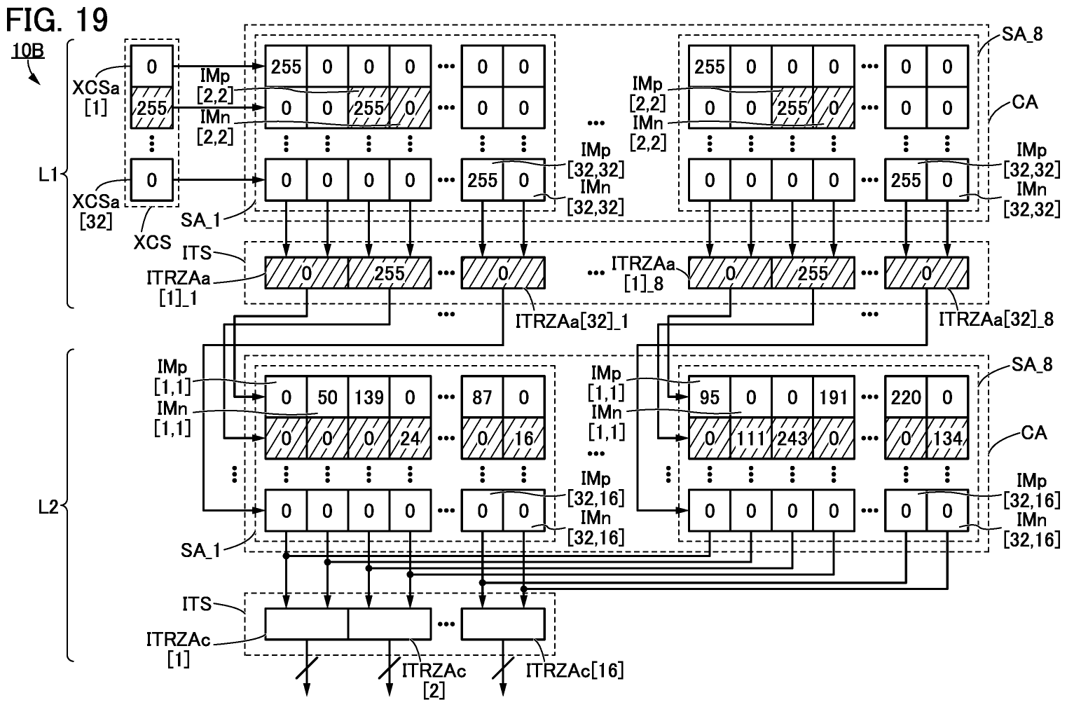

The block diagram in FIG. 19 shows an operation example of Step D5. In Step D5, the circuit XCSa[2]_supplies, as the second reference data, a current with an amount of 255I_{ref0} (which is denoted as “255” in FIG. 19) to the second row of each of the subarrays SA_1 to SA_8 in the region L1, for example, as in Step D4. The circuits XCSa in the rows other than the second row supply a current with an amount of 0 to the corresponding rows of the subarrays SA_1 to SA_8 in the region L1.

Here, description is made with focus on the second column of each of the subarrays SA_1 to SA_8 in the region L1. Since 255I_{ref0} is supplied from the circuit XCSa[2] to the second row of each of the subarrays SA_1 to SA_8 in the region L1, a current with an amount such that I₀ₚ[2,1]=255I_{ref0} is generated in the cell IMp[2,1]. Since a current with an amount of 0 is supplied to the first and third to thirty-second rows of each of the subarrays SA_1 to SA_8 in the region L1 from the circuits XCSa in the corresponding rows, the amount of a current generated in each of the cells IMp[1,2] and IMp[3,2] to IMp[32,2] is 0. Accordingly, the sum of the amounts of currents generated in the cells IMp[1,2] to IMp[32,2] is I_{Sp}=255I_{ref0}. Since 0 is set as the current amount in each of the cells IMn[1,2] to IMn[32,2], the sum of the amounts of currents generated in the cells IMn[1,2] to IMn[32,2] is I_{Sp}=0.

From the above, the difference current I_{Sp}−I_{Sp} is 255I_{ref0} in each of the converter circuits ITRZAa[2]_1 to ITRZAa[2]_8. Since each of the converter circuits ITRZAa[2]_1 to ITRZAa[2]_8 has the configuration shown in FIG. 12A, the difference current I_{Sp}−I_{Sp} (=255I_{ref0}) is supplied to the second row of each of the subarrays SA_1 to SA_8 in the region L2.

In each of the first and third to thirty-second columns of each of the subarrays SA_1 to SA_8 in the region L1, the sum of the amounts of currents generated in the cells IMp[1,i] (where i is 1 or an integer greater than or equal to 3 and less than or equal to 32) to IMp[32,i] is 0 and the sum of the amounts of currents generated in the cells IMn[1,i] to IMn[32,i] is also 0. Thus, the difference current I_{Sp}−I_{Sp} in each of the plurality of converter circuits ITRZAa other than the converter circuits ITRZAa[2]_1 to ITRZAa[2]_8 included in the circuit ITS is 0. A current amount of 0 output from the plurality of converter circuits ITRZAa is supplied to the first and third to thirty-second rows of each of the subarrays SA_1 to SA_8 in the region L2. That is, no current flows from the plurality of converter circuits ITRZAa other than the converter circuits ITRZAa[2]_1 to ITRZAa[2]_8 to the first and third to thirty-second rows of the subarrays SA_1 to SA_8 in the region L2.

The difference current I_{Sp}−I_{Sp} (=255I_{ref0}) supplied from the converter circuits ITRZAa[2]_1 to ITRZAa[2]_8 to the second rows of the subarrays SA_1 to SA_8 in the region L2 corresponds to a current whose amount corresponds to the third reference data and which is for writing the first data (weight coefficient) to the plurality of cells IMp and the plurality of cells IMn included in the subarrays SA_1 to SA_8 of the cell array CA in the region L2.

Accordingly, while the converter circuits ITRZAa[2]_1 to ITRZAa[2]_8 input a potential that corresponds to a current with an amount of 255I_{ref0} corresponding to the third reference data for the region L2 to the second rows of the subarrays SA_1 to SA_8 in the region L2, the corresponding first data (weight coefficient) is written to the plurality of cells IMp and the plurality of cells IMn provided in the first row of each of the subarrays SA_1 to SA_8 of the cell array CA in the region L2.

For example, in the subarray SA_1 in the region L2 shown in FIG. 19, the cell IMp[2,1] retains “139” and the cell IMn[2,1] retains “0”. That is, “139” is written to the cells IMp[2,1] and IMn[2,1] as the first data. In a similar manner, “−24” is written to the cells IMp[2,2] and IMn[2,2] as the first data, and “−16” is written to the cells IMp[2,16] and IMn[2,16] as the first data.

For another example, in the subarray SA_8 in the region L2 shown in FIG. 19, “−111” is written to the cells IMp[2,1] and IMn[2,1] as the first data, “243” is written to the cells IMp[2,2] and IMn[2,2] as the first data, and “−134” is written to the cells IMp[2,16] and IMn[2,16] as the first data.

### [Step D6]

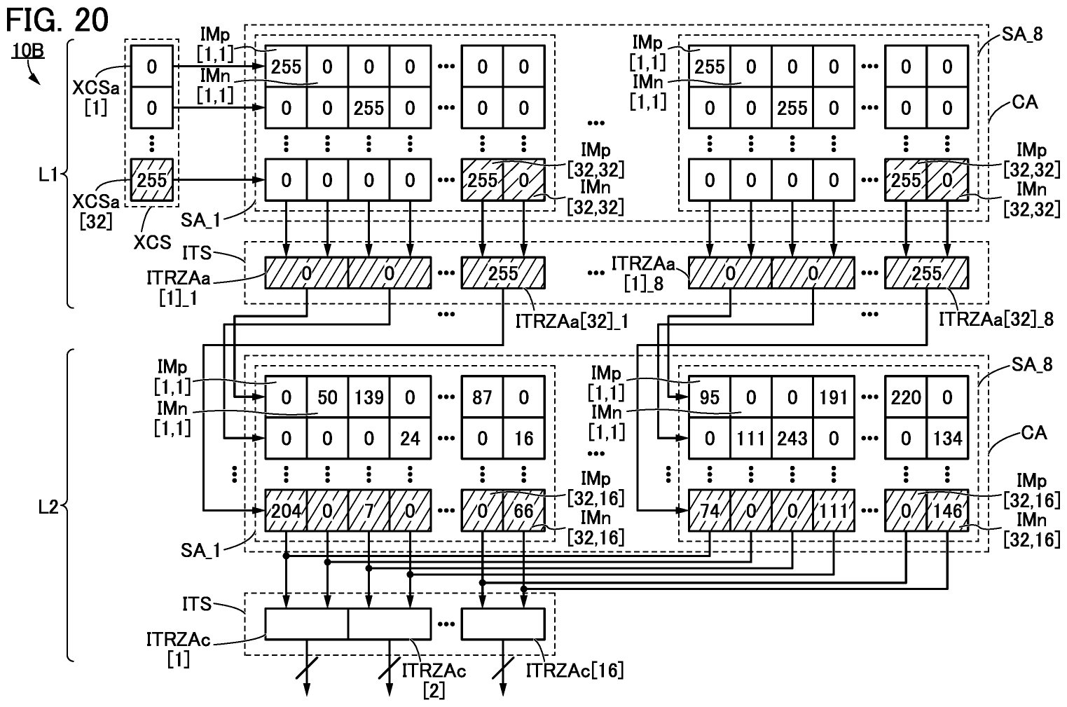

The block diagram in FIG. 20 shows an operation example of Step D6. In Step D6, the circuit XCSa[i] (where i is an integer greater than or equal to 3 and less than or equal to 31) supplies a current with an amount of 255I_{ref0} corresponding to the second reference data to the i-th row of each of the subarrays SA_1 to SA_8 in the region L1, for example, as in Steps D4 and D5. The circuits XCSa in the rows other than the i-th row supply a current with an amount of 0 to the corresponding rows of the subarrays SA_1 to SA_8 in the region L1.

Here, description is made with focus on the i-th column of each of the subarrays SA_1 to SA_8 in the region L1. Since 255I_{ref0} is supplied from the circuit XCSa[i] to the i-th row of each of the subarrays SA_1 to SA_8 in the region L1, a current with an amount such that I₀ₚΔw_{1[i,j]_p} [i,1]=255I_{ref0} is generated in the cell IMp[1,1]. Since a current with an amount of 0 is supplied to the first to thirty-second rows other than the i-th row of each of the subarrays SA_1 to SA_8 in the region L1 from the circuits XCSa in the corresponding rows, the amount of a current generated in each of the cells IMp[1,i] to IMp[32,i] other than the cell IMp[i,i] is 0. Accordingly, the sum of the amounts of currents generated in the cells IMp[1,i] to IMp[32,i] is I_{Sp}=255I_{ref0}. Since 0 is set as the current amount in each of the cells IMn[1,i] to IMn[32,i], the sum of the amounts of currents generated in the cells IMn[1,i] to IMn[32,i] is I_{Sn}=0.

From the above, the difference current I_{Sp}−I_{Sn} is 255I_{ref0} in each of the converter circuits ITRZAa[i]_1 to ITRZAa[i]_8. Since each of the converter circuits ITRZAa[i]_1 to ITRZAa[i]_8 has the configuration shown in FIG. 12A, the difference current I_{Sp}−I_{Sn} (=255I_{ref0}) is supplied to the i-th row of each of the subarrays SA_1 to SA_8 in the region L2.

In each of the first to thirty-second columns other than the i-th column of each of the subarrays SA_1 to SA_8 in the region L1, the sum of the amounts of currents generated in the cells IMp[1,j] (where j is an integer greater than or equal to 1 and less than or equal to 32 other than i) to IMp[32j] is 0 and the sum of the amounts of currents generated in the cells IMn[1,j] to IMn[32j] is also 0. Thus, the difference current I_{Sp}−I_{Sn} in each of the plurality of converter circuits ITRZAa other than the converter circuits ITRZAa[j]_1 to ITRZAa[j]_8 included in the circuit ITS is 0. A current amount of 0 output from the plurality of converter circuits ITRZAa is supplied to the first to thirty-second columns other than the i-th column of each of the subarrays SA_1 to SA_8 in the region L2. That is, no current flows from the plurality of converter circuits ITRZAa other than the converter circuits ITRZAa[j]_1 to ITRZAa[j]_8 to the first to thirty-second rows other than the i-th row of the subarrays SA_1 to SA_8 in the region L2.

The difference current I_{Sp}−I_{Sp} (=255I_{ref0}) supplied from the converter circuits ITRZAa[i]_1 to ITRZAa[i]_8 to the i-th rows of the subarrays SA_1 to SA_8 in the region L2 corresponds to a current whose amount corresponds to the third reference data and which is for writing the first data (weight coefficient) to the plurality of cells IMp and the plurality of cells IMn included in the subarrays SA_1 to SA_8 of the cell array CA in the region L2.

Accordingly, while the converter circuits ITRZAa[i]_1 to ITRZAa[i]_8 input a potential that corresponds to a current with an amount of 255I_{ref0} corresponding to the third reference data for the region L2 to the i-th rows of the subarrays SA_1 to SA_8 in the region L2, the corresponding first data (weight coefficient) is written to the plurality of cells IMp and the plurality of cells IMn provided in the first row of each of the subarrays SA_1 to SA_8 of the cell array CA in the region L2 (this operation is not shown in FIG. 20).

In Step D6, the circuit XCSa[32]_supplies, as the third reference data, a current with an amount of 255I_{ref0} (which is denoted as “255” in FIG. 20) to the thirty-second row of each of the subarrays SA_1 to SA_8 in the region L1, for example, as in Steps D4 and D5. The circuits XCSa in the rows other than the thirty-second row supply a current with an amount of 0 to the corresponding rows of the subarrays SA_1 to SA_8 in the region L1.

Here, description is made with focus on the thirty-second column of each of the subarrays SA_1 to SA_8 in the region L1. Since 255I_{ref0} is supplied from the circuit XCSa[32] to the thirty-second row of each of the subarrays SA_1 to SA_8 in the region L1, a current with an amount such that I₀ₚ[32,1]=255I_{ref0} is generated in the cell IMp[32,1]. Since a current with an amount of 0 is supplied to the first to thirty-first rows of each of the subarrays SA_1 to SA_8 in the region L1 from the circuits XCSa in the corresponding rows, the amount of a current generated in each of the cells IMp[1,32] to IMp[31,32] is 0. Accordingly, the sum of the amounts of currents generated in the cells IMp[1,32] to IMp[32,32] is I_{Sp}=255I_{ref0}. Since 0 is set as the current amount in each of the cells IMn[1,32] to IMn[32,32], the sum of the amounts of currents generated in the cells IMn[1,32] to IMn[32,32] is I_{Sp}=0.

From the above, the difference current I_{Sp}−I_{Sp} is 255I_{ref0} in each of the converter circuits ITRZAa[32]_1 to ITRZAa[32]_8. Since each of the converter circuits ITRZAa[32]_1 to ITRZAa[32]_8 has the configuration shown in FIG. 12A, the difference current I_{Sp}−I_{Sp} (=255I_{ref0}) is supplied to the i-th row of each of the subarrays SA_1 to SA_8 in the region L2.

In each of the first to thirty-first columns of each of the subarrays SA_1 to SA_8 in the region L1, the sum of the amounts of currents generated in the cells IMp[1,j] (where j is an integer greater than or equal to 1 and less than or equal to 31) to IMp[32j] is 0 and the sum of the amounts of currents generated in the cells IMn[1,j] to IMn[32j] is also 0. Thus, the difference current I_{Sp}−I_{Sp} in each of the plurality of converter circuits ITRZAa other than the converter circuits ITRZAa[j]_1 to ITRZAa[j]_8 included in the circuit ITS is 0. A current amount of 0 output from the plurality of converter circuits ITRZAa is supplied to the first to thirty-first columns of each of the subarrays SA_1 to SA_8 in the region L2. That is, no current flows from the plurality of converter circuits ITRZAa other than the converter circuits ITRZAa[32]_1 to ITRZAa[32]_8 to the first to thirty-first rows of the subarrays SA_1 to SA_8 in the region L2.

The difference current I_{Sp}−I_{Sn} (=255I_{ref0}) supplied from the converter circuits ITRZAa[32]_1 to ITRZAa[32]_8 to the thirty-second rows of the subarrays SA_1 to SA_8 in the region L2 corresponds to a current whose amount corresponds to the third reference data and which is for writing the first data (weight coefficient) to the plurality of cells IMp and the plurality of cells IMn included in the subarrays SA_1 to SA_8 of the cell array CA in the region L2.

Accordingly, while the converter circuits ITRZAa[32]_1 to ITRZAa[32]_8 supply a current with an amount of 255I_{ref0} corresponding to the third reference data for the region L2 to the thirty-second rows of the subarrays SA_1 to SA_8 in the region L2, the corresponding first data (weight coefficient) is written to the plurality of cells IMp and the plurality of cells IMn provided in the first row of each of the subarrays SA_1 to SA_8 of the cell array CA in the region L2.

For example, in the subarray SA_1 in the region L2 shown in FIG. 20, the cell IMp[32,1] retains “204” and the cell IMn[32,1] retains “0”. That is, “204” is written to the cells IMp[32,1] and IMn[32,1] as the first data. In a similar manner, “7” is written to the cells IMp[32,2] and IMn[32,2] as the first data, and “−66” is written to the cells IMp[32,16] and IMn[32,16] as the first data.

For another example, in the subarray SA_8 in the region L2 shown in FIG. 20, “74” is written to the cells IMp[32,1] and IMn[32,1] as the first data, “−111” is written to the cells IMp[32,2] and IMn[32,2] as the first data, and “−146” is written to the cells IMp[32,16] and IMn[32,16] as the first data.

### [Step D7]

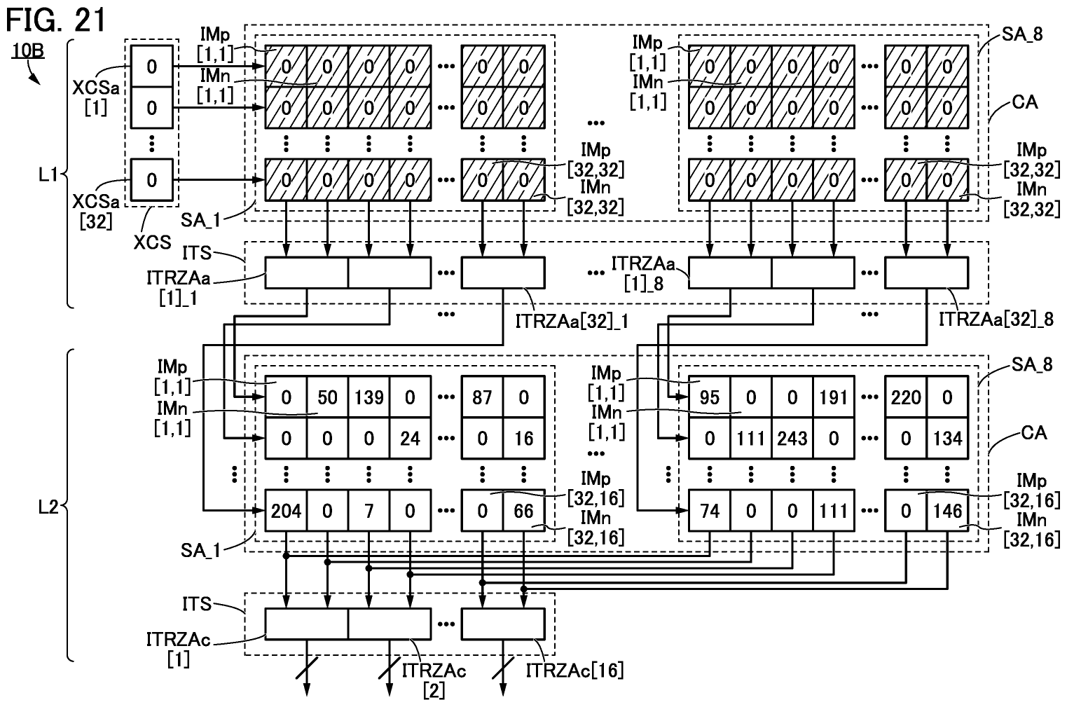

The block diagram in FIG. 21 shows an operation example of Step D7. In Step D7, all the current amounts set in the plurality of cells IMp and the plurality of cells IMn included in the subarrays SA_1 to SA_8 in the region L1 are set to 0. Note that Step D7 is sometimes referred to as initialization operation.

In this operation example, the operation process may proceed from Step D6 to Step D8, with Step D7 skipped.

### <<Steps D8 to D10>>

In each of Steps D8 to D10, the corresponding first data (weight coefficient) is written to the plurality of cells IMp and the plurality of cells IMn included in the subarrays SA_1 to SA_8 of the cell array CA in the region L1 in the arithmetic circuit 10B. [Step D8]

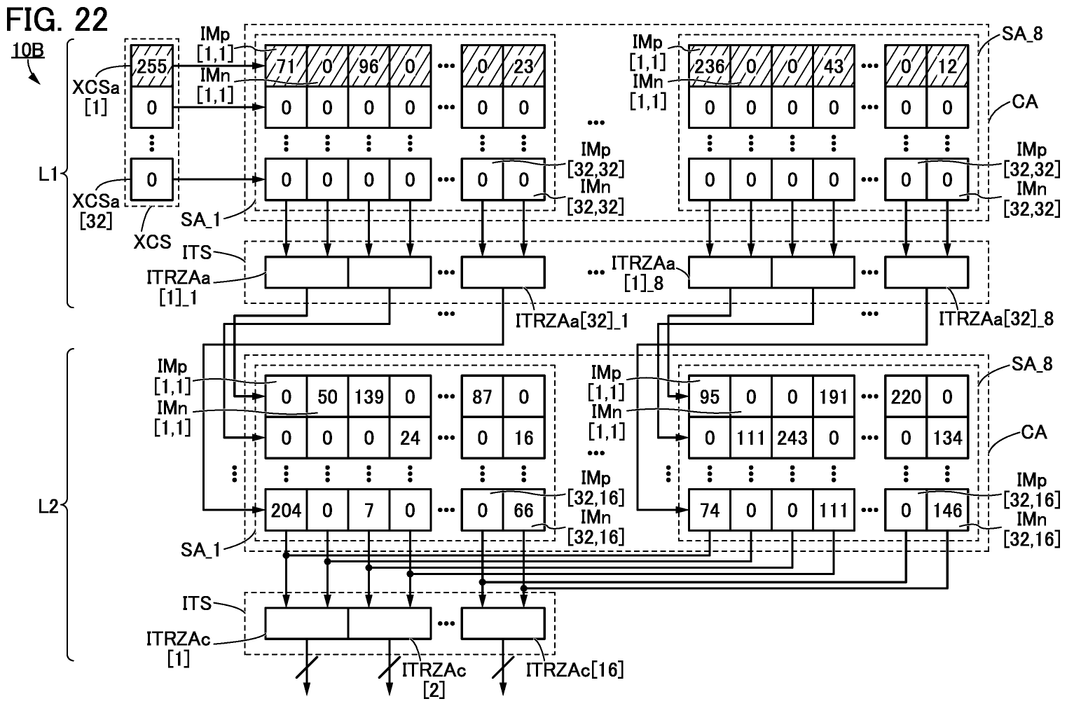

The block diagram in FIG. 22 shows an operation example of Step D8. In Step D8, the circuit XCSa[1]_supplies a current with an amount of 255I_{ref0} (which is denoted as “255” in FIG. 22) corresponding to the reference data to the first row of each of the subarrays SA_1 to SA_8 in the region L1, for example. The circuits XCSa in the rows other than the first row supply a current with an amount of 0 to the corresponding rows of the subarrays SA_1 to SA_8 in the region L1.

While the circuit XCSa[1]_supplies a current with an amount of 255I_{ref0} corresponding to the reference data to the first row of each of the subarrays SA_1 to SA_8 in the region L1, the corresponding first data (weight coefficient) is written to the plurality of cells IMp and the plurality of cells IMn provided in the first row of each of the subarrays SA_1 to SA_8 of the cell array CA in the region L1.

For example, in the subarray SA_1 in the region L1 shown in FIG. 22, the cell IMp[1,1] retains “71” and the cell IMn[1,1] retains “0”. That is, “71” is written to the cells IMp[1,1] and IMn[1,1] as the first data. In a similar manner, “96” is written to the cells IMp[1,2] and IMn[1,2] as the first data, and “−23” is written to the cells IMp[1,16] and IMn[1,16] as the first data.

For another example, in the subarray SA_8 in the region L1 shown in FIG. 22, “236” is written to the cells IMp[1,1] and IMn[1,1] as the first data, “−43” is written to the cells IMp[1,2] and IMn[1,2] as the first data, and “−12” is written to the cells IMp[1,16] and IMn[1,16] as the first data.

### [Step D9]

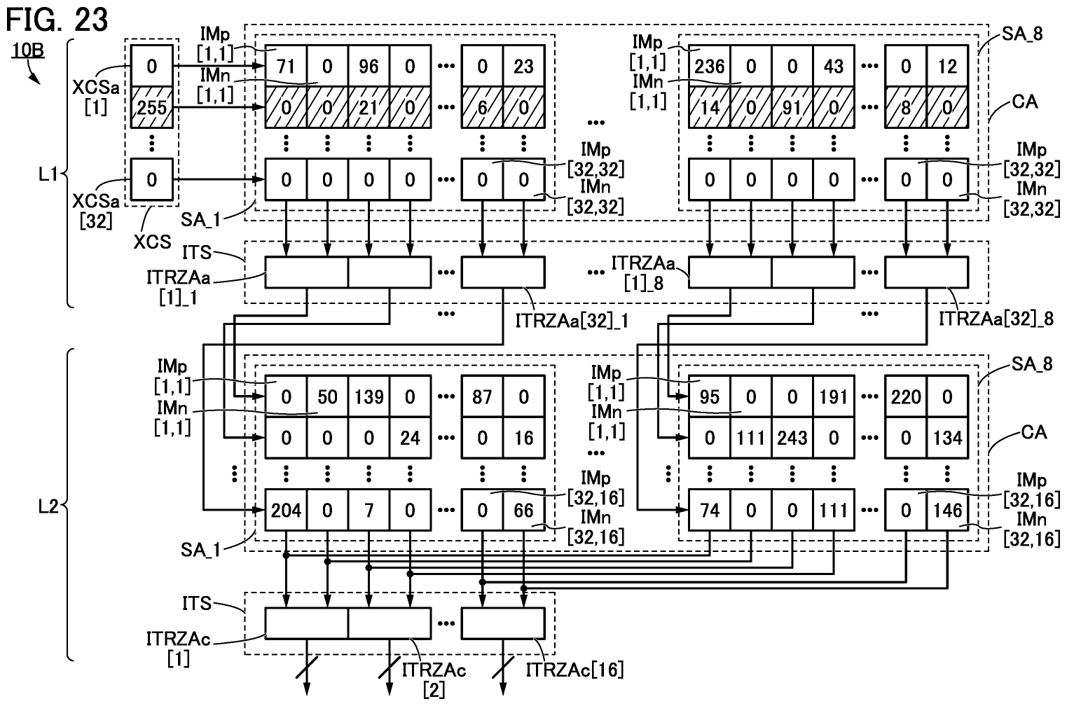

The block diagram in FIG. 23 shows an operation example of Step D9. In Step D9, the circuit XCSa[2]_supplies a current with an amount of 255I_{ref0} (which is denoted as “255” in FIG. 23) corresponding to the reference data to the second row of each of the subarrays SA_1 to SA_8 in the region L1, for example, as in Step D8. The circuits XCSa in the rows other than the second row supply a current with an amount of 0 to the corresponding rows of the subarrays SA_1 to SA_8 in the region L1.

While the circuit XCSa[2]_supplies a current with an amount of 255I_{ref0} corresponding to the reference data to the second row of each of the subarrays SA_1 to SA_8 in the region L1, the corresponding first data (weight coefficient) is written to the plurality of cells IMp and the plurality of cells IMn provided in the second row of each of the subarrays SA_1 to SA_8 of the cell array CA in the region L1.

For example, in the subarray SA_1 in the region L1 shown in FIG. 23, the cell IMp[2,1] retains “0” and the cell IMn[2,1] retains “0”. That is, “0” is written to the cells IMp[2,1] and IMn[2,1] as the first data. In a similar manner, “21” is written to the cells IMp[2,2] and IMn[2,2] as the first data, and “6” is written to the cells IMp[2,16] and IMn[2,16] as the first data.

For another example, in the subarray SA_8 in the region L1 shown in FIG. 23, “14” is written to the cells IMp[2,1] and IMn[2,1] as the first data, “91” is written to the cells IMp[2,2] and IMn[2,2] as the first data, and “8” is written to the cells IMp[2,16] and IMn[2,16] as the first data.

### [Step D10]

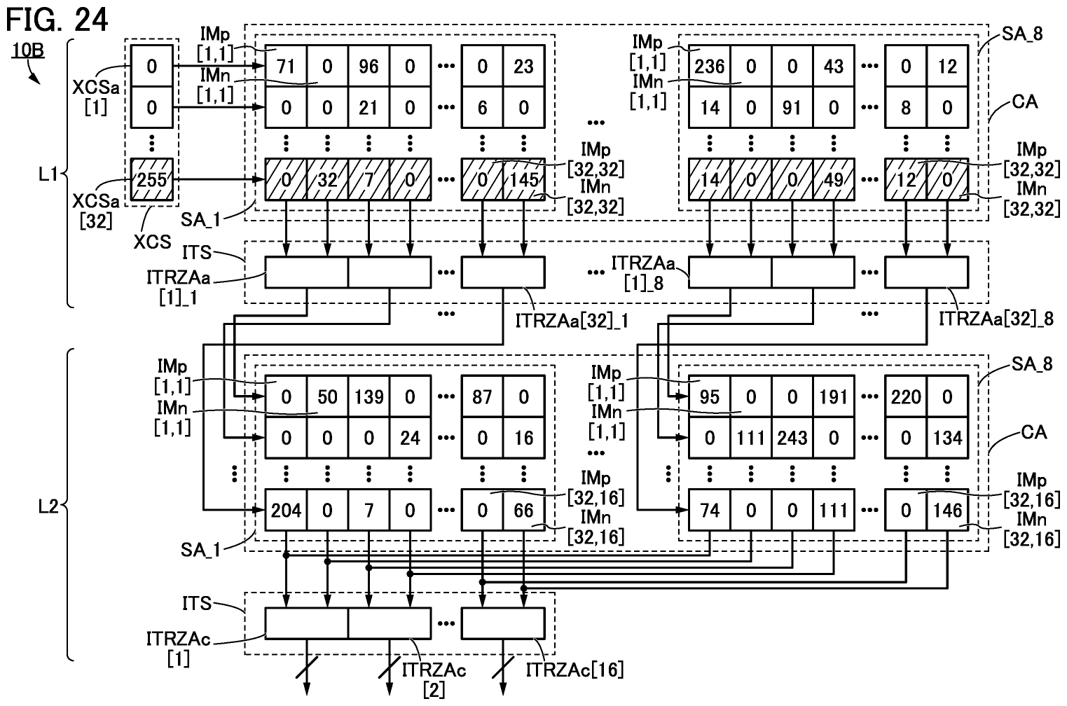

The block diagram in FIG. 24 shows an operation example of Step D9. In Step D9, the circuit XCSa[i] (where i is an integer greater than or equal to 3 and less than or equal to 31) supplies a current with an amount of 255I_{ref0} corresponding to the reference data to the i-th row of each of the subarrays SA_1 to SA_8 in the region L1, for example, as in Steps D7 and D8. The circuits XCSa in the rows other than the i-th row supply a current with an amount of 0 to the corresponding rows of the subarrays SA_1 to SA_8 in the region L1.

While the circuit XCSa[i]_supplies a current with an amount of 255I_{ref0} corresponding to the reference data to the i-th row of each of the subarrays SA_1 to SA_8 in the region L1, the corresponding first data (weight coefficient) is written to the plurality of cells IMp and the plurality of cells IMn provided in the i-th row of each of the subarrays SA_1 to SA_8 of the cell array CA in the region L1 (this operation is not shown).

In Step D9, the circuit XCSa[32]_supplies a current with an amount of 255I_{ref0} corresponding to the reference data to the thirty-second row of each of the subarrays SA_1 to SA_8 in the region L1, for example, as in Steps D7 and D8. The circuits XCSa in the rows other than the thirty-second row supply a current with an amount of 0 to the corresponding rows of the subarrays SA_1 to SA_8 in the region L1.

While the circuit XCSa[32]_supplies a current with an amount of 255I_{ref0} corresponding to the reference data to the thirty-second row of each of the subarrays SA_1 to SA_8 in the region L1, the corresponding first data (weight coefficient) is written to the plurality of cells IMp and the plurality of cells IMn provided in the thirty-second row of each of the subarrays SA_1 to SA_8 of the cell array CA in the region L1 (this operation is not shown).

For example, in the subarray SA_1 in the region L1 shown in FIG. 24, the cell IMp[32,1] retains “0” and the cell IMn[32,1] retains “32”. That is, “−32” is written to the cells IMp[32,1] and IMn[32,1] as the first data. In a similar manner, “7” is written to the cells IMp[32,2] and IMn[32,2] as the first data, and “−145” is written to the cells IMp[32,16] and IMn[32,16] as the first data.

For another example, in the subarray SA_8 in the region L1 shown in FIG. 24, “14” is written to the cells IMp[32,1] and IMn[32,1] as the first data, “−49” is written to the cells IMp[32,2] and IMn[32,2] as the first data, and “12” is written to the cells IMp[32,16] and IMn[32,16] as the first data.

### [Step D11]

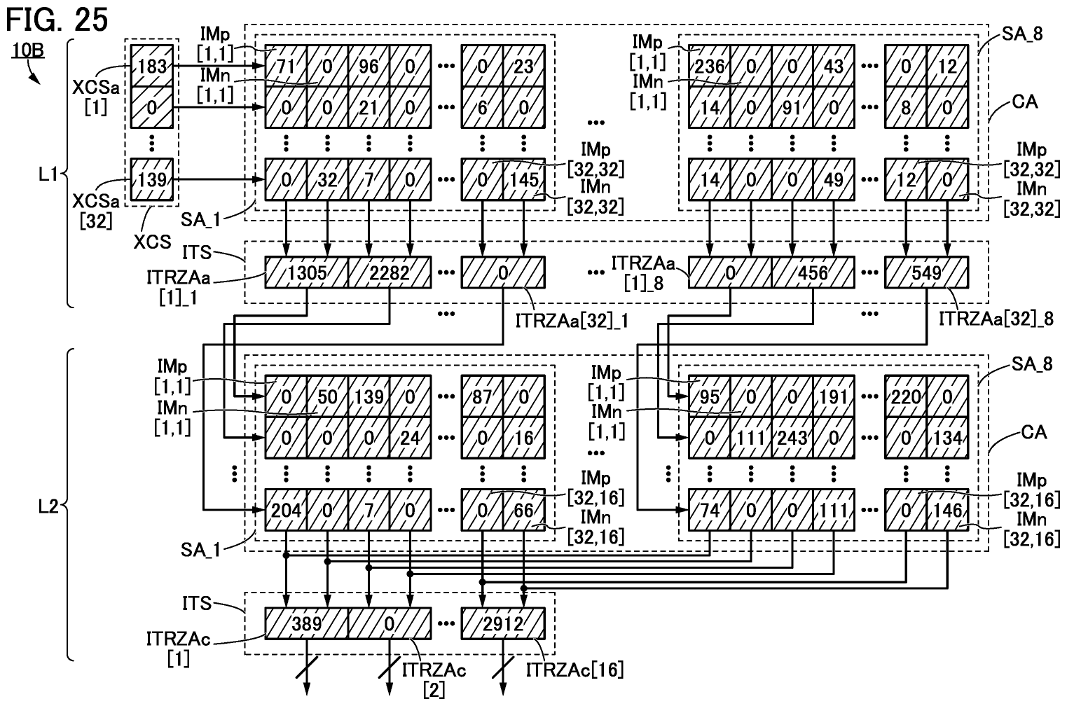

The block diagram in FIG. 25 shows an operation example of Step D11. In Step D11, a product-sum operation of a plurality of pieces of the first data written to the cell array CA and a plurality of pieces of the second data input from the circuits XCS and an arithmetic operation of an activation function (which is a ReLU function here, for example) using the product-sum operation result as an input value are performed in the region L1. Furthermore, in the region L2, a product-sum operation of the plurality of pieces of the first data written to the cell array CA and a result of the above-described arithmetic operation of the activation function is performed and the product-sum operation result is converted into a digital value.

Specifically, from the circuits XCSa[1] to XCSa[32] to the rows of the subarrays SA_1 to SA_8 in the region L1, currents with an amount of x[i]I_{ref0} corresponding to the second data in the corresponding rows are supplied, for example. In FIG. 25, “183” is supplied as the second data from the circuit XCSa[1] to the first row of each of the subarrays SA_1 to SA_8 in the region L1, “0” is supplied as the second data from the circuit XCSa[2] to the second row of each of the subarrays SA_1 to SA_8 in the region L1, and “139” is supplied as the second data from the circuit XCSa[32] to the thirty-second row of each of the subarrays SA_1 to SA_8 in the region L1.

In Steps D8 to D10, the current amount corresponding to the reference data is 255I_{ref0} when the first data is written to the cell array CA in the region L1; thus, in the subarray SA_1, the cell IMp[1,1]_performs an arithmetic operation of 71×183/255 and the cell IMn[1,1]_performs an arithmetic operation of 0×183/255, for example. For example, the cell IMp[2,1]_performs an arithmetic operation of 0×0/255, and the cell IMn[2,1]_performs an arithmetic operation of 0×0/255. For example, the cell IMp[32,1]_performs an arithmetic operation of 0×139/255, and the cell IMn[32,1] performs an arithmetic operation of 32×139/255.

Accordingly, in the cell array CA and the circuit ITS in the region L1, a product-sum operation of the plurality of pieces of the first data written to the cell array CA and the plurality of pieces of the second data input from the circuits XCS is performed. At this time, product-sum operations for 32 columns are performed in each subarray in the region L1; thus, product-sum operations for 256 columns (32×8) in total are performed in the entire region L1.

The results of the product-sum operations for the 256 columns are used as input values of a ReLU function in the circuit ITS in the region L1. Accordingly, with the use of the product-sum operation results for the 256 columns as input values, the plurality of converter circuits ITRZAa included in the circuit ITS supply currents as output values of a ReLU function to the rows of the subarrays SA_1 to SA_8 of the cell array CA in the region L2.

Specifically, for example, the current amount output from the cell IMp provided in the first column of the subarray SA_1 in the region L1 and the current amount output from the cell IMn provided in the first column of the subarray SA_1 in the region L1 are input to the converter circuit ITRZAa[1]_1, and the converter circuit ITRZAa[1]_1 performs an arithmetic operation of a ReLU function with the use of the difference current between the two current amounts as an input value. In FIG. 25, accordingly, a current with an amount of 1305I_{ref0} (which is denoted as “1305” in FIG. 25) is supplied to the first row of the subarray SA_1 in the region L2. Furthermore, the current amount output from the cell IMp provided in the second column of the subarray SA_1 in the region L1 and the current amount output from the cell IMn provided in the second column of the subarray SA_1 in the region L1 are input to the converter circuit ITRZAa[2]_1, and the converter circuit ITRZAa[2]_1 performs an arithmetic operation of a ReLU function with the use of the difference current between the two current amounts as an input value. In FIG. 25, accordingly, a current with an amount of 2282I_{ref0} (which is denoted as “2282” in FIG. 25) is supplied to the second row of the subarray SA_1 in the region L2. Furthermore, the current amount output from the cell IMp provided in the thirty-second column of the subarray SA_1 in the region L1 and the current amount output from the cell IMn provided in the thirty-second column of the subarray SA_1 in the region L1 are input to the converter circuit ITRZAa[32]_1, and the converter circuit ITRZAa[32]_1 performs an arithmetic operation of a ReLU function with the use of the difference current between the two current amounts as an input value. In FIG. 25, accordingly, a current with an amount of 0 (which is denoted as “0” in FIG. 25) is supplied to the thirty-second row of the subarray SA_1 in the region L2.

The current amount output from the cell IMp provided in the first column of the subarray SA_8 in the region L1 and the current amount output from the cell IMn provided in the first column of the subarray SA_8 in the region L1 are input to the converter circuit ITRZAa[1]_8, and the converter circuit ITRZAa[1]_8 performs an arithmetic operation of a ReLU function with the use of the difference current between the two current amounts as an input value. In FIG. 25, accordingly, a current with an amount of 0 (which is denoted as “0” in FIG. 25) is supplied to the first row of the subarray SA_8 in the region L2. Furthermore, the current amount output from the cell IMp provided in the second column of the subarray SA_8 in the region L1 and the current amount output from the cell IMn provided in the second column of the subarray SA_8 in the region L1 are input to the converter circuit ITRZAa[2]_8, and the converter circuit ITRZAa[2]_8 performs an arithmetic operation of a ReLU function with the use of the difference current between the two current amounts as an input value. In FIG. 25, accordingly, a current with an amount of 456I_{ref0} (which is denoted as “456” in FIG. 25) is supplied to the second row of the subarray SA_8 in the region L2. Furthermore, the current amount output from the cell IMp provided in the thirty-second column of the subarray SA_8 in the region L1 and the current amount output from the cell IMn provided in the thirty-second column of the subarray SA_8 in the region L1 are input to the converter circuit ITRZAa[32]_8, and the converter circuit ITRZAa[32]_8 performs an arithmetic operation of a ReLU function with the use of the difference current between the two current amounts as an input value. In FIG. 25, accordingly, a current with an amount of 549I_{ref0} (which is denoted as “549” in FIG. 25) is supplied to the thirty-second row of the subarray SA_8 in the region L2.

Accordingly, in the cell array CA and the circuit ITS in the region L2, a product-sum operation of the plurality of pieces of the first data written to the cell array CA and the plurality of pieces of the second data corresponding to the currents input from the circuit ITS in the region L1 is performed. At this time, the same columns of the subarrays SA_1 to SA_8 in the region L2 are electrically connected to one another and thus, product-sum operations for 16 columns are performed in the region L2.

The results of the product-sum operations for the 16 columns are used as input values of a ReLU function in the circuit ITS in the region L2. Accordingly, with the use of the product-sum operation results for the 16 columns as input values, the plurality of converter circuits ITRZAc included in the circuit ITS outputs digital data corresponding to output values of a ReLU function.

Specifically, for example, in the converter circuit ITRZAc[1] is generated the difference current between the current amount output from the cell IMp provided in the first column of each of the subarrays SA_1 to SA_8 in the region L2 and the current amount output from the cell IMn provided in the first column of each of the subarrays SA_1 to SA_8 in the region L2, and the converter circuit ITRZAc[1] outputs “389” that is digital data as a result of an arithmetic operation of a ReLU function using the difference current as an input value. Furthermore, in the converter circuit ITRZAc[2] is generated the difference current between the current amount output from the cell IMp provided in the second column of each of the subarrays SA_1 to SA_8 in the region L2 and the current amount output from the cell IMn provided in the second column of the subarray SA_1 in the region L2, and the converter circuit ITRZAc[2] outputs a current amount of “0” as a result of an arithmetic operation of a ReLU function using the difference current as an input value. Furthermore, in the converter circuit ITRZAc[16] is generated the difference current between the current amount output from the cell IMp provided in the sixteenth column of each of the subarrays SA_1 to SA_8 in the region L2 and the current amount output from the cell IMn provided in the sixteenth column of the subarray SA_1 in the region L2, and the converter circuit ITRZAc[16] outputs a current amount of “2912” as a result of an arithmetic operation of a ReLU function using the difference current as an input value.

By using the above operation method, a product-sum operation in the region L1, an arithmetic operation of an activation function in the region L1, and a product-sum operation in the region L2 can be performed in the arithmetic circuit 10B shown in FIG. 10.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 3

This embodiment describes a correction method for a normal operation of the arithmetic circuit described in the above embodiment. Specifically, a correction method of the arithmetic circuit 10B shown in FIG. 10 is described here.

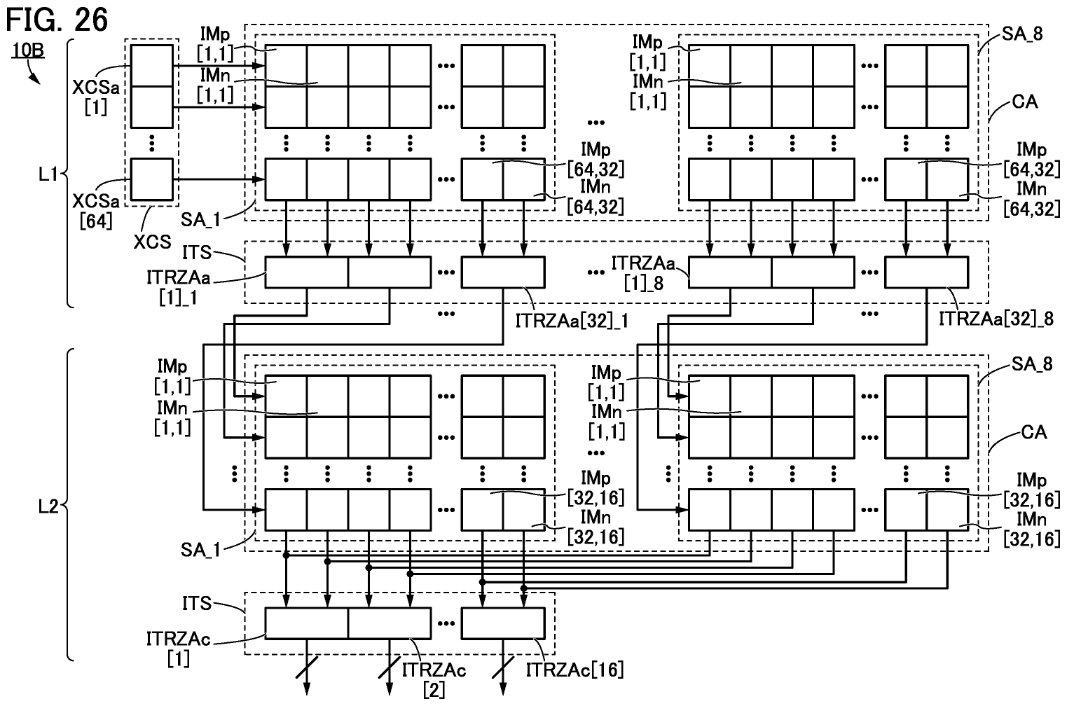

The arithmetic circuit 10B that performs the operation by the correction method described in this embodiment has the configuration shown in FIG. 26. In FIG. 26, the arithmetic circuit 10B shown in FIG. 10 has a configuration where m=64, n=32, k=16, and p=8, for example. Note that the block diagram in FIG. 26 is different from that of the arithmetic circuit 10B described in Embodiment 2 with reference to FIG. 15 to FIG. in m.

### Operation Method Example 1

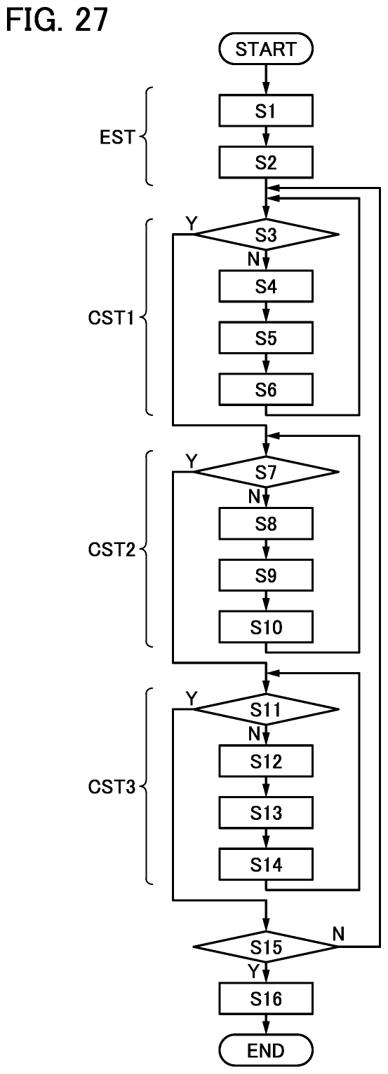

FIG. 27 is a flowchart showing an operation method including the correction method of the arithmetic circuit 10B, which is one embodiment of the present invention. The operation method of the arithmetic circuit 10B includes Steps S1 to S16 as shown in FIG. 27, for example. In FIG. 27, the start of the operation method is denoted as “START” and the end of the operation method is denoted as “END”.

In Steps S1 and S2 of the flowchart in FIG. 27, an error necessary for the correction method is obtained. Thus, Steps S1 and S2 are collectively referred to as an error obtaining step EST in this specification and the like.

An operation by a first correction method is performed in Steps S3 to S6, an operation by a second correction method is performed in Steps S7 to S10, and an operation by a third correction method is performed in Steps S11 to S14 in the flowchart of FIG. 27. Thus, in this specification and the like, Steps S3 to S6 are collectively referred to as a correction step CST1, Steps S7 to S10 are collectively referred to as a correction step CST2, and Steps S11 to S14 are collectively referred to as a correction step CST3.

### <<Step S1>>

In Step S1, for example, the arithmetic circuit 10B performs an operation for obtaining a data set using first standard data, second standard data, and third standard data.

The first standard data is, for example, the first data written to the plurality of cells IMp and the plurality of cells IMn included in the subarrays SA_1 to SA_8 in the region L1 of the arithmetic circuit 10B.

The second standard data is, for example, the second data corresponding to a current supplied from the circuit XCS to each row of the subarrays SA_1 to SA_8 of the cell array CA in the region L1 of the arithmetic circuit 10B.

The third standard data is, for example, the first data written to the plurality of cells IMp and the plurality of cells IMn included in the subarrays SA_1 to SA_8 in the region L2 of the arithmetic circuit 10B.

Specifically, the first standard data and the second standard data are used as data for generating a constant current to be supplied to each of the plurality of converter circuits ITRZAa included in the circuit ITS in the region L1. It is particularly preferable that the first standard data and the second standard data be defined such that the difference current between a current generated by the plurality of cells IMp and a current generated by the plurality of cells IMn in the same column of the cell array CA in the region L1 is one of I(1) to I(tₘₐₓ) (tₘₐₓ is an integer greater than or equal to 1). It is preferable that I(1) to I(tₘₐₓ) be set such that the differences between every two consecutive values thereof are the same; for example, I(1)=−124, I(2)=−120, and I(3)=−116 (where the difference between the consecutive values is 4). Some of I(1) to I(tₘₐₓ) preferably include a negative current amount. In this specification and the like, I(1) to I(tₘₐₓ) obtained by a theoretical product-sum operation of the first standard data and the second standard data are sometimes referred to as theoretical values.

Note that tₘₐₓ=64 in this operation example. That is, 64 sets of the first standard data and the second standard data are needed to obtain 64 difference currents. Here, the sum of current amounts (difference current amounts) input to the plurality of converter circuits ITRZAa of the circuit ITS in the region L1 with the use of the t-th set (where t is an integer greater than or equal to 1 and less than or equal to tₘₐₓ (=64)) of the first standard data and the second standard data is defined as I(t). For example, I(32)=0 and I(64)=128 in the case where the difference between every two consecutive values is 4 and/(1)=−124.

Note that in this operation example, the first standard data is a matrix W₁(t) of 64 rows and 256 columns and the second standard data is a matrix X₁(t) of one row and 64 columns. Specifically, the matrix W₁(t) of the first standard data includes a current amount of “0” as the first data in the range of the thirty-third row and the first column to the sixty-fourth row and the two hundred and fifty-sixth column, and the second standard data includes a current amount of “0” as the second data in the range of the thirty-third column to the sixty-fourth column, for example. Accordingly, the matrix W₁(t) is expressed by Formula (3.1), and the matrix X₁(t) is expressed by Formula (3.2).

$$\begin{matrix}[ Formula 21 ] & \\ {W}_{1} ( t ) = ( {\underbrace{\begin{matrix}{w}_{1 [ 1 , 1 ] \_ 1} & … & {w}_{1 [ 1 , 32 ] \_ 1} \\ ⋮ & & ⋮ \\ {w}_{1 [ 32 , 1 ] \_ 1} & … & {w}_{1 [ 32 , 32 ] \_ 1} \\ 0 & … & 0 \\ ⋮ & & ⋮ \\ 0 & … & 0\end{matrix}}}_{SA \_ 1} \begin{matrix}… \\ … \\ … \\ … \\ …\end{matrix} {\underbrace{\begin{matrix}{w}_{1 [ 1 , 1 ] \_ 8} & … & {w}_{1 [ 1 , 32 ] \_ 8} \\ ⋮ & & ⋮ \\ {w}_{1 [ 32 , 1 ] \_ 8} & … & {w}_{1 [ 32 , 32 ] \_ 8} \\ 0 & … & 0 \\ ⋮ & & ⋮ \\ 0 & … & 0\end{matrix}}}_{SA \_ 8} ) \begin{matrix}\} & First to \\ & thirty - second rows \\ \} & Thirty - third to \\ & sixty - fourth rows\end{matrix} & ( 3.1 )\end{matrix}$$

$${X}_{1} ( t ) = ( {\underbrace{\begin{matrix}{x}_{1} [ 1 ] & … & {x}_{1} [ 32 ]\end{matrix}}}_{\begin{matrix}First to \\ thirty - second rows\end{matrix}} {\underbrace{\begin{matrix}0 & … & 0\end{matrix}}}_{\begin{matrix}Thirty - third to \\ sixty - fourth rows\end{matrix}} ) \qquad ( 3.2 )$$

Note that W₁(t) includes, in the first to thirty-second rows, a value of corresponding to the address in the i-th row and the j-th column of the subarray SA_p (where p is an integer greater than or equal to 1 and less than or equal to 8, i is an integer greater than or equal to 1 and less than or equal to 32, and j is an integer greater than or equal to 1 and less than or equal to 32), and X₁(t) includes a value of x₁[j] in the j-th column.

It is thus assumed that the following formula is satisfied by the arithmetic operation in the cell array CA in the region L1.

[Formula 22]

X₁(t)W₁(t)=(I(t) . . . I(t)) (3.3)

The right side is a matrix of one row and 256 columns and indicates the sum of current amounts (difference current amounts) input to the plurality of converter circuits ITRZAa included in the circuit ITS in the region L1. The plurality of converter circuits ITRZAa included in the circuit ITS perform an arithmetic operation of an activation function (or a ReLU function when the converter circuit ITRZAa has the configuration shown in FIG. 12A) with the use of the input difference current amounts as input values. Accordingly, the converter circuits ITRZAa supply a current with an amount of I(t) to the rows of the subarrays SA_1 to SA_8 of the cell array CA in the region L2 when I(t)>0; the converter circuits ITRZAa supply a current with an amount of “0” to the rows of the subarrays SA_1 to SA_8 of the cell array CA in the region L2 when I(t) 0. Note that the current amounts supplied by the converter circuits ITRZAa to the rows of the subarrays SA_1 to SA_8 of the cell array CA in the region L2 are referred to as fourth standard data, which is expressed by a matrix X₃(t) of one row and 256 columns. The following formula is satisfied when the activation function is F.

[Formula 23]

F(X₁(t)W₁(t))=X₃(t) (3.4)

The third standard data is used as data for selecting one row of the subarrays SA_1 to SA_8 in the region L2 and supplying the converter circuits ITRZAc included in the circuit ITS in the region L2 with the currents output from pairs of the cell IMp and the cell IMn provided in the selected row. For example, since the subarrays SA_1 to SA_8 each include 32 rows, any one of 256 (32×8) rows of the subarrays SA_1 to SA_8 is selected. Accordingly, 256 patterns of the third standard data are needed. Here, the s-th set (where s is an integer greater than or equal to 1 and less than or equal to 256) of the third standard data is a matrix W₃(s) of 256 rows and 16 columns. The third standard data W₃(s) includes the first data greater than or equal to 1 (which is referred to as W₃ here) at all the addresses in the s-th row and includes the first data of 0 at the other addresses.

For example, when s=1, the third standard data W₃(1) includes W₃ at all the addresses in the first row and includes “0” at all the addresses in the rows other than the first row, as expressed by Formula (3.5). This corresponds to the case where a current amount of w₃ is set to all the addresses in the first row of the subarray SA_1 in the region L2 and a current amount of “0” is set to all the addresses in the second to thirty-second rows of the subarray SA_1 and all the addresses of the subarrays SA_2 to SA_8. For another example, when s=34, the third standard data W₃(34) includes W₃ at all the addresses in the thirty-fourth row and includes “0” at all the addresses in the rows other than the thirty-fourth row as expressed by Formula (3.6). This corresponds to the case where a current amount of w₃ is set to all the addresses in the second row of the subarray SA_2 in the region L2 and a current amount of “0” is set to all the addresses in the first and third to thirty-second rows of the subarray SA_2 and all the addresses of the subarrays SA_1 and SA_3 to SA_8. For another example, when s=256, the third standard data W₃(256) includes W₃ at all the addresses in the two hundred and fifty-sixth row and includes “0” at all the addresses in the rows other than the two hundred and fifty-sixth row as expressed by Formula (3.7). This corresponds to the case where a current amount of w₃ is set to all the addresses in the thirty-second row of the subarray SA_8 in the region L2 and a current amount of “0” is set to all the addresses of the subarrays SA_1 to SA_8 and all the addresses in the first to thirty-first rows of the subarray SA_8.

$$\begin{matrix}[ Formula 24 ] & \\ {W}_{3} ( 1 ) = ( \begin{matrix}{w}_{3} & … & {w}_{3} \\ 0 & … & 0 \\ ⋮ & & ⋮ \\ 0 & … & 0 \\ 0 & … & 0 \\ ⋮ & & ⋮ \\ 0 & … & 0 \\ ⋮ & & ⋮ \\ 0 & … & 0 \\ ⋮ & & ⋮ \\ 0 & … & 0\end{matrix} ) \begin{matrix}\} & SA\_ 1 \\ \} & SA\_ 2 \\ ⋮ & \\ \} & SA\_ 8\end{matrix} & ( 3.5 )\end{matrix}$$

$${W}_{3} ( 34 ) = ( \begin{matrix}0 & … & 0 \\ ⋮ & … & ⋮ \\ 0 & & 0 \\ 0 & … & 0 \\ {w}_{3} & … & {w}_{3} \\ ⋮ & & ⋮ \\ 0 & … & 0 \\ ⋮ & & ⋮ \\ 0 & … & 0 \\ ⋮ & & ⋮ \\ 0 & … & 0\end{matrix} ) \begin{matrix}\} & SA\_ 1 \\ \} & SA\_ 2 \\ ⋮ & \\ \} & SA\_ 8\end{matrix} \qquad ( 3.6 )$$

$${W}_{3} ( 256 ) = ( \begin{matrix}0 & … & 0 \\ ⋮ & & ⋮ \\ 0 & … & 0 \\ ⋮ & & ⋮ \\ 0 & … & 0 \\ ⋮ & & ⋮ \\ 0 & … & 0 \\ 0 & … & 0 \\ ⋮ & & ⋮ \\ 0 & … & 0 \\ {w}_{3} & … & {w}_{3}\end{matrix} ) \begin{matrix}\} & SA\_ 1 \\ ⋮ & \\ \} & SA\_ 7 \\ \} & SA\_ 8\end{matrix} \qquad ( 3.7 )$$

In the region L2, the product of the fourth standard data X₃(t) and the third standard data W₃(s) is calculated. At this time, the arithmetic operation result for X₃(t)W₃(s) is a matrix of one row and 16 columns. In this matrix, the column in which w₃ is written in the third standard data W₃(s) is a value of w₃×I[t] and the other columns are a value of 0. As examples, Formulae (3.8) to (3.10) respectively show X₃(t)W₃(1), X₃(t)W₃(34), and X₃(t)W₃(256).

$$\begin{matrix}[ Formula 25 ] & \\ {X}_{3} ( t ) {W}_{3} ( 1 ) = ( {\underbrace{\begin{matrix}{w}_{3} I ( t ) & … & {w}_{3} I ( t )\end{matrix}}}_{SA \_ 1} ) & ( 3.8 )\end{matrix}$$

$${X}_{3} ( t ) {W}_{3} ( 34 ) = ( {\underbrace{\begin{matrix}{w}_{3} I ( t ) & … & {w}_{3} I ( t )\end{matrix}}}_{SA \_ 2} ) \qquad ( 3.9 )$$

$${X}_{3} ( t ) {W}_{3} ( 256 ) = ( {\underbrace{\begin{matrix}{w}_{3} I ( t ) & … & {w}_{3} I ( t )\end{matrix}}}_{SA \_ 8} ) \qquad ( 3.1 )$$

According to the components of the matrices X₃(t), W₃(1), W₃(34), and W₃(256), X₃(t)W₃(1) corresponds to a current amount output from the subarray SA_1, X₃(t)W₃(34) corresponds to a current amount output from the subarray SA_2, and X₃(t)W₃(256) corresponds to a current amount output from the subarray SA_8.

The converter circuit ITRZAc included in the circuit ITS in the region L2 performs an arithmetic operation of an activation function (or a ReLU function when the converter circuit ITRZAc has the configuration shown in FIG. 12C) with the use of an input current amount of X₃(t)W₃(s) as an input value. Thus, in the case where w₃I(t)>0, the converter circuit ITRZAc outputs a current with an amount of w₃I(t) to the outside of the arithmetic circuit 10B; in the case where w₃I(t) 0, the converter circuit ITRZAc outputs a current with an amount of “0” to the outside of the arithmetic circuit 10B.

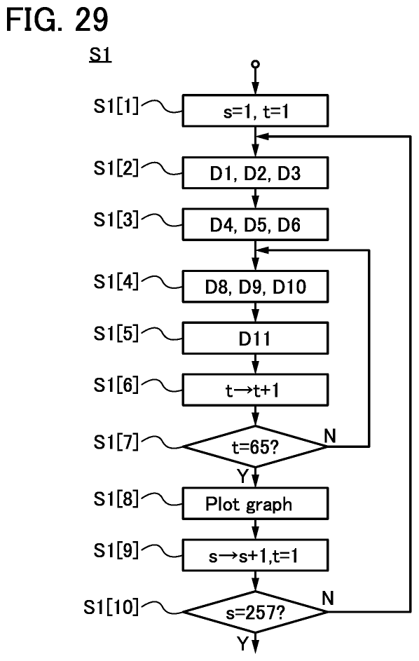

FIG. 29 is a flowchart showing a specific operation in Step S1, and Step S1 includes Steps S1[1] to S1[10]. In this specification and the like, Steps S1[1] to S1[10] are sometimes referred to as substeps.

Note that the flowchart of Step S1 shown in FIG. 29 can be applied to Steps S5, S9, and S13, which will be described later.

First, Step S1[1] is performed. In Step S1[1], the first standard data W₁(t) and the second standard data X₁(t) in each of which t=1 and the third standard data W₃(s) in which s=1 are prepared.

Step S1[2] includes, for example, operations for performing Steps D1 to D3 in the flowchart of FIG. 14, which illustrates the operation method of the arithmetic circuit 10B described in Embodiment 2. Specifically, in Step S1[2], Steps D1 to D3 are performed where a preparation operation for supplying a current corresponding to the third reference data from the circuit ITS in the region L1 to the region L2 is performed to write the third standard data W₃(s) to the plurality of cells IMp and the plurality of cells IMn included in the subarrays SA_1 to SA_8 of the cell array CA in the region L2. Note that the first reference data R for generating a current corresponding to the third reference data here is a matrix expressed by Formula (3.11).

$$\begin{matrix}[ Formula 26 ] & \\ R = ( {\underbrace{\begin{matrix}255 & 0 & … & 0 \\ 0 & 255 & … & 0 \\ ⋮ & ⋮ & & ⋮ \\ 0 & 0 & … & 255 \\ 0 & 0 & … & 0 \\ ⋮ & ⋮ & & ⋮ \\ 0 & 0 & … & 0\end{matrix}}}_{SA \_ 1} \begin{matrix}… \\ … \\ … \\ … \\ …\end{matrix} {\underbrace{\begin{matrix}255 & 0 & … & 0 \\ 0 & 255 & … & 0 \\ ⋮ & ⋮ & & ⋮ \\ 0 & 0 & … & 255 \\ 0 & 0 & … & 0 \\ ⋮ & ⋮ & & ⋮ \\ 0 & 0 & … & 0\end{matrix}}}_{SA \_ 8} ) \begin{matrix}\} & First to \\ & thirty - second rows \\ \} & Thirty - third to \\ & sixty - fourth rows\end{matrix} & ( 3.11 )\end{matrix}$$

That is, here, the first to thirty-second rows of each of the subarrays SA_1 to SA_8 are used to generate a current that corresponds to the third reference data and that is to flow to the region L2.

Step S1[3] includes, for example, operations for performing Steps D4 to D6 in the flowchart of FIG. 14, which illustrates the operation method of the arithmetic circuit 10B described in Embodiment 2. Specifically, in Step S1[3], Steps D4 to D6 are performed to write the third standard data W₃(s) to the plurality of cells IMp and the plurality of cells IMn included in the subarrays SA_1 to SA_8 in the region L2 of the arithmetic circuit 10B with the use of the current that corresponds to the third reference data and that is prepared in Step S1[2].

In Step S1[3], Step D7 may be performed after Steps D4 to D6 are performed.

Step S1[4] includes, for example, operations for performing Steps D8 to D10 in the flowchart of FIG. 14, which illustrates the operation method of the arithmetic circuit 10B described in Embodiment 2. Specifically, in Step S1[4], Steps D8 to D10 are performed to write the first standard data W₁(t) to the plurality of cells IMp and the plurality of cells IMn included in the subarrays SA_1 to SA_8 in the region L1 of the arithmetic circuit 10B.

Step S1[5] includes, for example, operations for performing Step D11 in the flowchart of FIG. 14, which illustrates the operation method of the arithmetic circuit 10B described in Embodiment 2. Specifically, in Step S1[5], Step D11 is performed to supply the second standard data X₁(t) from the circuit XCS to the rows of the subarrays SA_1 to SA_8 in the region L1 of the arithmetic circuit 10B.

In this manner, an arithmetic operation of X₃(t)=F(X₁(t)W₁(t)) as the fourth standard data is performed in the region L1 and then, a product-sum operation of X₃(t)W₃(s) is performed in the region L2.

An arithmetic operation result of X₃(t)W₃(s) is converted into digital data by the converter circuit ITRZAc included in the circuit ITS in the region L2, and the converter circuit ITRZAc outputs the digital data. Note that the arithmetic operation result of X₃(t)W₃(s) output from the converter circuit ITRZAc is written to a memory device or the like provided outside the arithmetic circuit 10B.

Step S1[6] is performed after Step S1[5] is performed. In Step S1[6], 1 is added to the value of t.

In Step S1[7], the first standard data W₁(t) and the second standard data X₁(t) are updated to data obtained by adding 1 to the value of t in the Step S1[6]. In the case where the first standard data W₁(t) and the second standard data X₁(t) relating to t are updated, the process proceeds to Step S1[4] (as indicated by an arrow with N in the flowchart of FIG. 29); in the case where the first standard data W₁(t) and the second standard data X₁(t) relating to t cannot be updated (the case where t is greater than or equal to 65), the process proceeds to Step S1[8] (as indicated by an arrow with Y in the flowchart of FIG. 29).

In the case where the process proceeds to Step S1[4], Steps S1[4] and S1[5] are performed again, so that the arithmetic operation result of X₃(t)W₃(s) output from the converter circuit ITRZAc is written to a memory device or the like provided outside the arithmetic circuit 10B. After Step S1[5], Steps S1[6] and S1[7] are performed to further update the first standard data W₁(t) and the second standard data X₁(t). In the case where the first standard data W₁(t) and the second standard data X₁(t) cannot be updated (the case where t is greater than or equal to 65), the process proceeds to Step S1[8] as described above.

Step S1[8] includes a step of creating a graph in which a theoretical value I(t) as one component of X₁(t)W₁(t) that is a result of a theoretical product-sum operation of the first standard data W₁(t) and the second standard data X₁(t) is plotted on the horizontal axis and an output value (e.g., digital data) output from the converter circuit ITRZAc is plotted on the vertical axis.

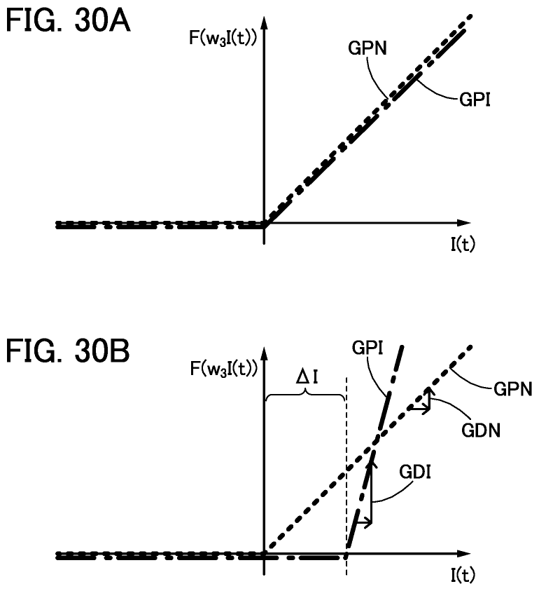

By the operations in Steps S1[4] to S1[7], a data set in which s is any one of 1 to 256 is obtained. With the use of the data set, for example, graphs in each of which I(t) is plotted on the horizontal axis and an output value F(w₃I(t)) is plotted on the vertical axis (e.g., a graph GPI shown in FIG. 30A or 30B) are obtained. Since the circuit ITS in the region L2 includes 16 of the converter circuits ITRZAc in the arithmetic circuit 10B shown in FIG. 26, one data set enables creating 16 graphs; however, in this operation example, description is made on one graph for simplicity.

In Step S1[9], 1 is added to the value of s. In addition, the value of t is reset to 1.

In Step S1[10], the third standard data W₃(s) is updated to data obtained by adding 1 to the value of s in the Step S1[9]. In the case where the third standard data W₃(s) relating to s is updated, the process proceeds to Step S1[2] (as indicated by an arrow with N in the flowchart of FIG. 29); in the case where the third standard data W₃(s) relating to s cannot be updated (the case where s is greater than or equal to 257), the process proceeds to Step S2 (as indicated by an arrow with Y in the flowchart of FIG. 29).

In the case where the process proceeds to Step S1[2], Steps S1[2] to S1[3] are performed again to write the third standard data W₃(s) to the plurality of cells IMp and the plurality of cells IMn included in the subarrays SA_1 to SA_8 in the region L2 of the arithmetic circuit 10B. Then, in Steps S1[4] to S1[7], an arithmetic operation of F(X₃(t)W₃(s)) is performed for the respective cases where t is 1 to 64.

By the operations in Step S1 (Steps S1[1] to S1[10]), the data sets of the respective cases where s is 1 to 256, which are used for the operation by the correction method of the arithmetic circuit 10B, are obtained. Accordingly, 256 graphs can be created in Step S1[8].

### <<Step S2>>

In Step S2, the difference between the data set calculated in Step S1 and a graph as an expected value (which is sometimes referred to as standard graph) is calculated.

Each of FIGS. 30A and 30B shows the graph GPI indicating the data set calculated in Step S1 as an example and a graph GPN as an expected value. Note that in each of FIGS. 30A and 30B, the horizontal axis represents any of the difference currents I(1) to I(64) calculated by the cell array CA in the region L1 and the vertical axis represents F(w₃I(t)) that is a result of an arithmetic operation by the cell array CA and the circuit ITS in the region L2.

In a normal operation of the arithmetic circuit 10B, for example, the graph GPI of an output value (data set) of the case where t is changed from 1 to 64 in one of the plurality of converter circuits ITRZAc included in the circuit ITS in the region L2 largely overlaps with the graph GPN as an expected value, as shown in FIG. 30A. By contrast, in an abnormal operation of the arithmetic circuit 10B, for example, the graph GPI of an output value (data set) of the case where t is changed from 1 to 64 in one of the plurality of converter circuits ITRZAc included in the circuit ITS in the region L2 deviates from the graph GPN as an expected value, as shown in FIG. 30B.

In an abnormal operation of the arithmetic circuit 10B, for example, data at the time of writing and data at the time of reading in the cells IMp and IMn of the cell array CA in the region L1 or the region L2 are different from each other; the current amount output from the circuit XCSa is different from a desired amount; an arithmetic operation result of an activation function in the circuits ITS in each of the region L1 and the region L2 is different from a desired value; or an output value of the analog-digital converter circuit of the converter circuit ITRZAc in the circuit ITS in the region L2 is different from a desired value.

In Step S2, for example, ΔI that is an intercept of I(t) of the graph GPI is calculated in FIG. 30B. In Step S2, a difference ΔGD between a gradient GDI of the graph GPI and a gradient GDN of the graph GPN in the range in which the output value exceeds 0 in FIG. 30B is calculated.

Note that ΔGD can be defined as ΔGD=|GDI−GDN|/GDN, for example. In that case, for example, the allowable range of ΔGD is preferably from −0.3 to 0.3 inclusive, further preferably from −0.2 to 0.2 inclusive, still further preferably from −0.1 to 0.1 inclusive.

For example, ΔI is I(t) that is one component of the theoretical value (a theoretical product-sum operation of the first standard data W₁(t) and the second standard data X₁(t)) such that the output value is smallest and larger than 0, in a data set in which s is any one of 1 to 256. For example, ΔGD is calculated as the difference between the gradient in the range in which the output value is larger than 0 and the gradient in the range in which the output value of the graph GPN as an expected value is larger than 0 (which is sometimes referred to as standard gradient) in a data set in which s is any one of 1 to 256.

### <<Steps S3 to S6>>

In Steps S3 to S6, the first standard data W₁(t) is corrected so that the intercept ΔI of I(t) in the graph GPI of FIG. 30B becomes close to 0.

In Step S3, it is determined whether ΔI calculated in Step S2 is within the allowable range. The process proceeds to Step S7 when ΔI is within the allowable range (as indicated by an arrow with Y in the flowchart of FIG. 27), and the process proceeds to Step S4 when ΔI is outside the allowable range (as indicated by an arrow with N in the flowchart of FIG. 27).

The allowable range of ΔI can be, for example, from −ma to ma inclusive. Note that a is the difference between the consecutive values of I(1) to I(64), for example, and m is a real number exceeding 0. Note also that m is preferably less than or equal to 5, further preferably less than or equal to 3, still further preferably less than or equal to 1.

In Step S4, some components of the first standard data W₁(t) are rewritten. The cell array in the region L1 of the arithmetic circuit 10B in this embodiment has 64 rows and 256 columns as already described above, and all the addresses in the thirty-third to sixty-fourth rows of the first standard data W₁(t) are 0 as described in Step S1. In Step S4, one or more rows selected from the thirty-third to sixty-fourth rows of the first standard data W₁(t) are selected, and Δw_{1[i,j]_p} (where p is an integer greater than or equal to 1 and less than or equal to 8, i is an integer greater than or equal to 33 and less than or equal to 64, and j is an integer greater than or equal to 1 and less than or equal to 32) as data for correction is added to each component of the selected one row. The data for correction added to one component of the first standard data W₁(t) may be the same as or different from the data for correction added to another component of the first standard data W₁(t).

Step S4 includes an operation for generating Δw_{1[i,j]_p} as data for correction. Δw_{1[i,j]_p} can be defined in accordance with ΔI, for example.

In this operation example, Δw_{1[64,1]_p} to Δw_{1[64,32]_p} are added to the sixty-fourth row of the first standard data W₁(t), for example. Formula (3.12) shows the first standard data W₁(t) to which the data for correction is added.

$$\begin{matrix}[ Formula 27 ] & \\ {W}_{1} ( t ) = ( {\underbrace{\begin{matrix}{w}_{1 [ 1 , 1 ] \_ 1} & … & {w}_{1 [ 1 , 32 ] \_ 1} \\ ⋮ & & ⋮ \\ {w}_{1 [ 32 , 1 ] \_ 1} & … & {w}_{1 [ 32 , 32 ] \_ 1} \\ 0 & … & 0 \\ ⋮ & & ⋮ \\ 0 & … & 0 \\ Δ {w}_{1 [ 64 , 1 ] \_ 1} & … & Δ {w}_{1 [ 64 , 32 ] \_ 1}\end{matrix}}}_{SA \_ 1} \begin{matrix}… \\ … \\ … \\ … \\ …\end{matrix} {\underbrace{\begin{matrix}{w}_{1 [ 1 , 1 ] \_ 8} & … & {w}_{1 [ 1 , 32 ] \_ 8} \\ ⋮ & & ⋮ \\ {w}_{1 [ 32 , 1 ] \_ 8} & … & {w}_{1 [ 32 , 32 ] \_ 8} \\ 0 & … & 0 \\ ⋮ & & ⋮ \\ 0 & … & 0 \\ Δ {w}_{1 [ 64 , 1 ] \_ 1} & … & Δ {w}_{1 [ 64 , 32 ] \_ 1}\end{matrix}}}_{SA \_ 8} ) \begin{matrix}\} & First to \\ & thirty - second rows \\ \} & Thirty - third to \\ & sixty - third rows \\ \} & Sixty - fourth rows\end{matrix} & ( 3.12 )\end{matrix}$$

This corresponds to the case where the corresponding Δw_{1[i,j]_p} is set in the sixty-fourth row of each of the subarrays SA_1 to SA_8 in the region L1.

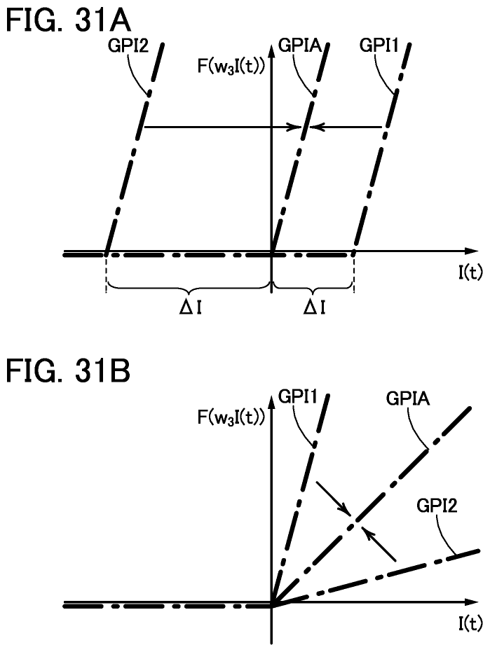

Here, in the case where the data set calculated in Step S1 is a graph GPI1 shown in FIG. 31A, for example, the data Δw_{1[i,j]_p} for correction added to the corresponding first standard data W₁(t) preferably has a positive value. When the data Δw_{1[i,j]_p} for correction has a positive value, the amount of the difference current for X₁(t)W₁(t) calculated in Step S1 increases, which can make the graph GPI1 close to a graph GPIA in which ΔI is close to 0 as shown in FIG. 31A. By contrast, in the case where the data set calculated in Step S1 is a graph GPI2 shown in FIG. 31A, for example, the data Δw_{1[i,j]_p} for correction added to the corresponding first standard data W₁(t) preferably has a negative value. When the data Δw_{1[i,j]_p} for correction has a negative value, the amount of the difference current for X₁(t)W₁(t) calculated in Step S1 decreases, which can make the graph GPI2 close to the graph GPIA in which ΔI is close to 0 as shown in FIG. 31A.

In Step S5, by the operation method similar to that in Step S1, a data set is obtained using the first standard data W₁(t) corrected in Step S4, the second standard data X₁(t), and the third standard data W₃(s). Thus, the description of the operation method in Step S1 is to be referred to for Step S5.

In Step S6, by the operation method similar to that in Step S2, the difference between the data set calculated in Step S5 and the graph as an expected value is calculated. Thus, the description of the operation method in Step S2 is to be referred to for Step S6. Since Steps S3 to S5 are performed to make ΔI close to 0, only an operation for obtaining ΔI may be performed in Step S6.

After Step S6, Step S3 is performed again. In Step S3, it is determined whether ΔI obtained in Step S6 is within the allowable range. The process proceeds to Step S7 when ΔI is within the allowable range (as indicated by an arrow with Y in the flowchart of FIG. 27), and the process proceeds to Step S4 again when ΔI is outside the allowable range (as indicated by an arrow with N in the flowchart of FIG. 27). Note that in the case where the process proceeds to Step S7, an operation for storing the data Δw_{1[i,j]_p} for correction added to the first standard data W₁(t) in a memory device outside the arithmetic circuit 10B is also performed.

Even after Steps S4 to S6 are repetitively performed two or more times, ΔI is sometimes outside the allowable range. In that case, ΔI sometimes falls within the allowable range by performing later-described Steps S7 to S10 or Steps S11 to S14. Therefore, in the case where ΔI is outside the allowable range in Step S3 after the correction is performed the freely selected number of times (which may be rephrased as “predetermined number of times”), the process may proceed to Step S7 (as indicated by an arrow with Y in the flowchart of FIG. 27).

As already described above, correction for making the intercept of I(t) in the graph GPI in FIG. 30B close to 0 is performed in Steps S3 to S6. In other words, the difference current generated using the first standard data W₁(t) and the second standard data X₁(t) in the region L1 is corrected in Steps S3 to S6. Thus, in Step S5, it is not necessary to calculate the products of X₃(t) and the third standard data W₃(s) where s is 1 to 256; for example, only the arithmetic operation result of multiplication of X₃(t) and the third standard data W₃(1) may be obtained and in Steps S3 and S6, only a data set as the arithmetic operation result may be used to calculate ΔI and determine ΔI.

### <<Steps S7 to S10>>

In Steps S7 to S10, the third standard data W₃(s) is corrected so that the gradient difference ΔGD between the graph GPI and the graph GPN in FIG. 30B becomes close to 0.

In Step S7, it is determined whether ΔGD calculated in Step S2 is within the allowable range. In the case where ΔGD is within the allowable range, the process proceeds to Step S11 (as indicated by an arrow with Y in the flowchart of FIG. 27). In the case where ΔGD is outside the allowable range, the process proceeds to Step S8 (as indicated by an arrow with N in the flowchart of FIG. 27), and the third standard data W₃(s) is corrected.

In Step S8, some components of the third standard data W₃(s) are rewritten. The third standard data W₃(s) includes W₃ at all the addresses in the s-th row and includes 0 at all the addresses in the rows other than the s-th row. In Step S8, W₃ of the s rows and j columns of the third standard data W₃(s) is multiplied by a correction coefficient M_{(s,j)} (where j is an integer greater than or equal to 1 and less than or equal to 16) set in accordance with ΔGD obtained in Step S3. The correction coefficient M_{(s,j)} by which W₃ of one column is multiplied may be the same as or different from that by which W₃ of another column is multiplied.

Step S8 includes an operation for generating the correction coefficient M_{(s,j)}. It is possible to set M_{(s,j)} in accordance with ΔGD, for example.

Formulae (3.13) to (3.15) show examples of the third standard data W₃(s) corrected in Step S8. Formulae (3.13), (3.14), and (3.15) respectively show the third standard data W₃(1), the third standard data W₃(34), and the third standard data W₃(256).

$$\begin{matrix}[ Formula 28 ] & \\ {W}_{3} ( 1 ) = ( \begin{matrix}{M}_{( 1 , 1 )} {w}_{3} & … & {M}_{( 1 , 16 )} {w}_{3} \\ 0 & … & 0 \\ ⋮ & & ⋮ \\ 0 & … & 0 \\ 0 & … & 0 \\ ⋮ & & ⋮ \\ 0 & … & 0 \\ ⋮ & & ⋮ \\ 0 & … & 0 \\ ⋮ & & ⋮ \\ 0 & … & 0\end{matrix} ) \begin{matrix}\} & SA\_ 1 \\ \} & SA\_ 2 \\ ⋮ & \\ \} & SA\_ 8\end{matrix} & ( 3.13 )\end{matrix}$$

$${W}_{3} ( 34 ) = ( \begin{matrix}0 & … & 0 \\ ⋮ & … & ⋮ \\ 0 & & 0 \\ 0 & … & 0 \\ {M}_{( 34 , 1 )} {w}_{3} & … & {M}_{( 34 , 16 )} {w}_{3} \\ ⋮ & & ⋮ \\ 0 & … & 0 \\ ⋮ & & ⋮ \\ 0 & … & 0 \\ ⋮ & & ⋮ \\ 0 & … & 0\end{matrix} ) \begin{matrix}\} & SA\_ 1 \\ \} & SA\_ 2 \\ ⋮ & \\ \} & SA\_ 8\end{matrix} \qquad ( 3.14 )$$

$${W}_{3} ( 256 ) = ( \begin{matrix}0 & … & 0 \\ ⋮ & & ⋮ \\ 0 & … & 0 \\ ⋮ & & ⋮ \\ 0 & … & 0 \\ ⋮ & & ⋮ \\ 0 & … & 0 \\ 0 & … & 0 \\ ⋮ & & ⋮ \\ 0 & … & 0 \\ {M}_{( 64 , 1 )} {w}_{3} & … & {M}_{( 64 , 16 )} {w}_{3}\end{matrix} ) \begin{matrix}\} & SA\_ 1 \\ ⋮ & \\ \} & SA\_ 7 \\ \} & SA\_ 8\end{matrix} \qquad ( 3.15 )$$

Here, in the case where the data set calculated in Step S1 is the graph GPI1 shown in FIG. 31B, for example, the component W₃ of the corresponding third standard data W₃(s) is preferably multiplied by the correction coefficient M_{(s,j)} that is greater than 0 and less than 1. In that case, the value M_{(s,j)}w₃I(t) in the j-th column of X₃(t)W₃(s) calculated in Step S1 is smaller than w₃I(t), which can make the graph GPI1 close to the graph GPIA. By contrast, in the case where the data set calculated in Step S1 is the graph GPI2 shown in FIG. 31B, for example, the component W₃ of the corresponding third standard data W₃(s) is preferably multiplied by the correction coefficient M_{(s,j)} that is greater than 1. In that case, the value M_{(s,j)}w₃I(t) in the j-th column of X₃(t)W₃(s) calculated in Step S1 is larger than w₃I(t), which can make the graph GPI1 close to the graph GPIA.

In Step S9, by the operation method similar to that in Step S1, a data set is obtained using the first standard data W₁(t) corrected in Step S4, the second standard data X₁(t), and the third standard data W₃(s) corrected in Step S8. Thus, the description of the operation method in Step S1 is to be referred to for Step S9.

In Step S10, by the operation method similar to that in Step S2, the difference between the data set calculated in Step S9 and the graph as an expected value is calculated. Thus, the description of the operation method in Step S2 is to be referred to for Step S10. Since Steps S8 to S11 are performed to make ΔGD close to 0, only an operation for obtaining ΔGD may be performed in Step S10.

After Step S10, Step S7 is performed again. In Step S7, it is determined whether ΔGD obtained in Step S10 is within the allowable range. The process proceeds to Step S11 when ΔGD is within the allowable range (as indicated by an arrow with Y in the flowchart of FIG. 27), and the process proceeds to Step S7 again when ΔGD is outside the allowable range (as indicated by an arrow with N in the flowchart of FIG. 27). Note that in the case where the process proceeds to Step S11, an operation for storing a correction coefficient M(I d) by which the third standard data W₃(s) has been multiplied in a memory device outside the arithmetic circuit 10B is also performed.

Even after Steps S8 to S10 are repetitively performed two or more times, ΔGD is sometimes outside the allowable range. In that case, ΔGD sometimes falls within the allowable range by performing later-described Steps S11 to S14. Therefore, in the case where ΔGD is outside the allowable range in Step S7 after the correction is performed the freely selected number of times (which may be rephrased as “predetermined number of times”), the process may proceed to Step S11 (as indicated by an arrow with Y in the flowchart of FIG. 27).

As already described above, correction for making the gradient of the graph GPI in FIG. 30B close to that of the graph GPN is performed in Steps S7 to S10. Since the third standard data W₃(s) is stored in the cell array CA in the region L2, correction of the third standard data W₃(s) for making the gradient of the graph GPI close to that of the graph GPN can be regarded as corresponding to correction of a variation in output values of the analog-digital converter circuits ADC included in the plurality of converter circuits ITRZAc of the circuit ITS in the region L2. Thus, in Step S8, it is not necessary to calculate the products of X₃(t) and the third standard data W₃(s) where s is 1 to 256; for example, only the arithmetic operation result of multiplication of X₃(t) and the third standard data W₃(1) may be obtained and in Steps S10 and S7, only a data set as the arithmetic operation result may be used to calculate ΔGD and determine ΔGD.

### <<Steps S11 to S14>>

In Steps S11 to S14, the first reference data R used in Steps D1 to D3 is corrected to make the gradient difference ΔGD between the graph GPI and the graph GPN in FIG. 30B close to 0, as in Steps S7 to S10.

In Step S11, it is determined whether ΔGD calculated in Step S2 or S10 is within the allowable range, as in Step S7. In the case where ΔGD is within the allowable range, the process proceeds to Step S15 (as indicated by an arrow with Y in the flowchart of FIG. 27). In the case where ΔGD is outside the allowable range, the process proceeds to Step S12 (as indicated by an arrow with N in the flowchart of FIG. 27), and the first reference data R is corrected.

In Step S12, some components of the first reference data R are rewritten. As shown in Formula (3.11), the first reference data R includes the values “0” and “255” at the addresses in the first to thirty-second rows of each of the subarrays SA_1 to SA_8. In Step S12, the first reference data R is multiplied by a correction coefficient E_{i_p} (where i is an integer greater than or equal to 1 and less than or equal to 32, and p is an integer greater than or equal to 1 and less than or equal to 8) defined in accordance with ΔGD obtained in Step S3. The correction coefficient E_{i_p} by which one component of the first reference data R is multiplied may be the same as or different from that by which another component of the first reference data R is multiplied.

Step S12 includes an operation for generating the correction coefficient E_{i_p}. It is possible to set E_{i_p} in accordance with ΔGD, for example.

Formula (3.16) shows an example of the first reference data R corrected in Step S12.

$$\begin{matrix}[ Formula 29 ] & \\ R = ( {\underbrace{\begin{matrix}255 {E}_{1 \_ 1} & 0 & … & 0 \\ 0 & 255 {E}_{2 \_ 1} & … & 0 \\ ⋮ & ⋮ & & ⋮ \\ 0 & 0 & … & 255 {E}_{32 \_ 1} \\ 0 & 0 & … & 0 \\ ⋮ & ⋮ & & ⋮ \\ 0 & 0 & … & 0\end{matrix}}}_{SA \_ 1} \begin{matrix}… \\ … \\ … \\ … \\ …\end{matrix} {\underbrace{\begin{matrix}255 {E}_{1 \_ 8} & 0 & … & 0 \\ 0 & 255 {E}_{2 \_ 1} & … & 0 \\ ⋮ & ⋮ & & ⋮ \\ 0 & 0 & … & 255 {E}_{32 \_ 1} \\ 0 & 0 & … & 0 \\ ⋮ & ⋮ & & ⋮ \\ 0 & 0 & … & 0\end{matrix}}}_{SA \_ 8} ) \begin{matrix}\} & First to \\ & thirty - second rows \\ \} & Thirty - third to \\ & sixty - fourth rows\end{matrix} & ( 3.16 )\end{matrix}$$

Formula (3.16) does not reflect Δw_{1[i,j]_p} to Δw_{1[i,j]_p}, which are the data for correction obtained in Steps S3 to S6; however, it is preferable that the data for correction be reflected in an actual operation example.

Here, in the case where the data set calculated in Step S1 is the graph GPI1 shown in FIG. 31B, for example, a component (“255”) of the first reference data R is preferably multiplied by the correction coefficient E_{i_p} that is larger than 1. In that case, W₃ of W₃(s) can be smaller than a desired value in writing of W₃(s) to the cell array CA in the region L2 in Step S1, which can make the graph GPI1 close to the graph GPIA. By contrast, in the case where the data set calculated in Step S1 is the graph GPI2 shown in FIG. 31B, for example, a component (“255”) of the first reference data R is preferably multiplied by the correction coefficient E_{i_p} that is larger than 0 and smaller than 1. In that case, W₃ of W₃(s) can be larger than a desired value in writing of W₃(s) to the cell array CA in the region L2 in Step S1, which can make the graph GPI1 close to the graph GPIA. That is, the correction of the first reference data R in Step S12 leads to the correction of W₃(s) written to the cell array CA in the region L2.

In Step S13, by the operation method similar to that in Step S1, a data set is obtained using the first standard data W₁(t) corrected in Step S4, the second standard data X₁(t), and the third standard data W₃(s) corrected in Steps S8 and S12. Thus, the description of the operation method in Step S1 is to be referred to for Step S13.

In Step S14, by the operation method similar to that in Step S2, the difference between the data set calculated in Step S13 and the graph as an expected value is calculated. Thus, the description of the operation method in Step S2 is to be referred to for Step S14. Since Steps S12 to S15 are performed to make ΔGD close to 0, only an operation for obtaining ΔGD may be performed in Step S14.

After Step S14, Step S11 is performed again. In Step S11, it is determined whether ΔGD obtained in Step S14 is within the allowable range. The process proceeds to Step S15 when ΔGD is within the allowable range (as indicated by an arrow with Y in the flowchart of FIG. 27), and the process proceeds to Step S12 again when ΔGD is outside the allowable range (as indicated by an arrow with N in the flowchart of FIG. 27). Note that in the case where the process proceeds to Step S15, an operation for storing the correction coefficient E_{i_p} by which the first reference data R has been multiplied in a memory device outside the arithmetic circuit 10B is also performed.

Even after Steps S12 to S14 are repetitively performed two or more times, ΔGD is sometimes outside the allowable range. In that case, ΔGD sometimes falls within the allowable range by performing Steps S8 to S10 described above. Therefore, in the case where ΔGD is outside the allowable range in Step S11 after the correction is performed the freely selected number of times (which may be rephrased as “predetermined number of times”), the process may proceed to Step S15 (as indicated by an arrow with Y in the flowchart of FIG. 27).

### <<Step S15>>

In Step S15, the process proceeds to Step S16 when the correction of ΔI is completed in Steps S3 to S6 and the correction of ΔGD is completed in Steps S7 to S10 or Steps S11 to S14. The process proceeds to Step S3 and the correction of ΔI or ΔGD is performed again when the correction of ΔI in Steps S3 to S6 and/or the correction of ΔGD in Steps S7 to S10 or Steps S11 to S14 are/is not completed.

### <<Step S16>>

In Step S16, inference is performed using the arithmetic circuit 10B. Thus, Step S16 is referred to as an inference step in some cases in this specification and the like. At the time of the inference, the above-described correction is reflected on the learned first data written to the plurality of cells IMp and the plurality of cells IMn included in the cell array CA of the region L1 and the cell array CA of the region L2.

For example, when the learned first data is written to the plurality of cells IMp and the plurality of cells IMn included in the cell array CA of the region L1, the data Δw_{1[i,j]_p} for correction of the first standard data W₁(t) in Steps S4 to S7 is also written to the rows of the cell array CA other than the rows to which the first data is written.

For example, the learned first data multiplied by the correction coefficient M_{(s,j)} for the third standard data W₃(s) in Steps S7 to S10 is written to the plurality of cells IMp and the plurality of cells IMn included in the cell array CA of the region L2.

At the time of writing of the learned first data to the plurality of cells IMp and the plurality of cells IMn included in the cell array CA of the region L2, for example, a current that is generated with the first reference data R multiplied by the correction coefficient E_{i_p} in Steps S11 to S14 is used.

In this manner, the operation by the above-described correction method performed in the arithmetic circuit 10B can inhibit a variation in the arithmetic operation results generated in the arithmetic circuit 10B. Accordingly, the accuracy rate of the inference performed using a hierarchical neural network can be high.

### Operation Method Example 2

A method for operating a semiconductor device of one embodiment of the present invention is not limited to the flowchart in FIG. 27 and may be modified depending on circumstances.

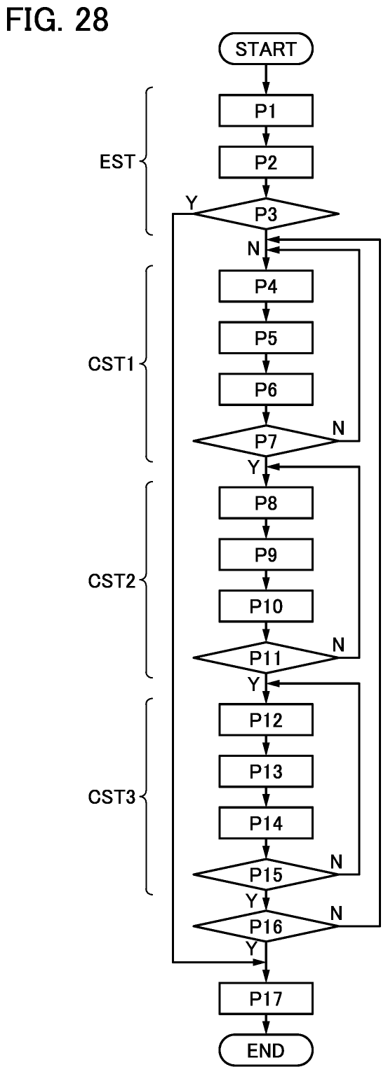

The flowchart in FIG. 28 shows a correction method of the arithmetic circuit 10B that is different from the correction method shown in the flowchart in FIG. 27. The correction method for the arithmetic circuit 10B shown in FIG. 28 is that for the arithmetic circuit 10B shown in FIG. 10 and includes Steps P1 to P17, for example. In FIG. 28, the start of the correction method is denoted as “START” and the end of the correction method is denoted as “END” as in FIG. 27.

The arithmetic circuit 10B that performs the operation by the correction method described in this embodiment has the configuration shown in FIG. 26 as in the operation example of the flowchart in FIG. 27.

The description of the operation method shown in FIG. 28 sometimes omits the contents already described for the timing chart in FIG. 27.

### <<Steps P1 and P2>>

For Steps P1 and P2, the description of Steps S1 and S2 of the flowchart in FIG. 27 can be referred to.

### <<Steps P3 to and P7>>

In Steps P3 to P6, the first standard data W₁(t) is corrected so that the intercept ΔI of I(t) in the graph GPI of FIG. 30B becomes close to 0.

In Step P3, it is determined whether ΔI calculated in Step P2 is within the allowable range and whether ΔGD calculated in Step P2 is within the allowable range. The process proceeds to Step P17 when both ΔI and ΔGD are within the allowable ranges (as indicated by an arrow with Y in the flowchart of FIG. 28), and the process proceeds to Step P4 when ΔI and/or ΔGD are/is outside the allowable range(s) (as indicated by an arrow with N in the flowchart of FIG. 28).

For Steps P4 to P6, the description of Steps S4 to S6 of the flowchart in FIG. 27 can be referred to.

In Step P7, it is determined whether ΔI calculated in Step P2 is within the allowable range as in Step P3. In the case where ΔI is within the allowable range, the process proceeds to Step P8 (as indicated by an arrow with Y in the flowchart of FIG. 28). At this time, an operation for storing Δw_{1[i,j]_p} added to the first standard data W₁(t) in a memory device outside the arithmetic circuit 10B is also performed. In the case where ΔI is outside the allowable range, the process proceeds to Step P4 (as indicated by an arrow with N in the flowchart of FIG. 28), and the first standard data W₁(t) is corrected again.

Even after Steps P4 to P7 are repetitively performed two or more times, ΔI is sometimes outside the allowable range. In that case, ΔI sometimes falls within the allowable range by performing later-described Steps P8 to P10 or Steps P11 to P15.

Therefore, in the case where ΔI is outside the allowable range in Step P7 after the correction is performed the freely selected number of times (which may be rephrased as “predetermined number of times”), the process may proceed to Step P8 (as indicated by an arrow with Y in the flowchart of FIG. 28).

As already described above, correction for making the intercept of I(t) in the graph GPI in FIG. 30B close to 0 is performed in Steps P4 to P7. In other words, the difference current generated using the first standard data W₁(t) and the second standard data X₁(t) in the region L1 is corrected in Steps P4 to P7. Thus, in Step P5, it is not necessary to calculate the products of X₃(t) and the third standard data W₃(s) where s is 1 to 256; for example, only the arithmetic operation result of multiplication of X₃(t) and the third standard data W₃(1) may be obtained and in Steps P6 and P7, only a data set as the arithmetic operation result may be used to calculate ΔI and determine ΔI.

### <<Steps P8 to P11>>

In Steps P8 to P11, the third standard data W₃(s) is corrected so that the gradient difference ΔGD between the graph GPI and the graph GPN in FIG. 30B becomes close to 0.

For Steps P8 to P11, the description of Steps S8 to S11 of the flowchart in FIG. 27 can be referred to.

In Step P11, it is determined whether ΔGD calculated in Step P10 is within the allowable range as in Step P3. In the case where ΔGD is within the allowable range, the process proceeds to Step P12 (as indicated by an arrow with Y in the flowchart of FIG. 28). At this time, an operation for storing the correction coefficient M_{(i,j)} by which the third standard data W₃(s) is multiplied in a memory device outside the arithmetic circuit 10B is also performed. In the case where ΔGD is outside the allowable range, the process proceeds to Step P8 (as indicated by an arrow with N in the flowchart of FIG. 28), and the third standard data W₃(s) is corrected again.

Even after Steps P8 to P11 are repetitively performed two or more times, ΔGD is sometimes outside the allowable range. In that case, ΔGD sometimes falls within the allowable range by performing later-described Steps P12 to P15. Therefore, in the case where ΔGD is outside the allowable range in Step P11 after the correction is performed the freely selected number of times (which may be rephrased as “predetermined number of times”), the process may proceed to Step P12 (as indicated by an arrow with Y in the flowchart of FIG. 28).

As already described above, correction for making the gradient of the graph GPI in FIG. 30B close to that of the graph GPN is performed in Steps P8 to P11. Since the third standard data W₃(s) is stored in the cell array CA in the region L2, correction of the third standard data W₃(s) for making the gradient of the graph GPI close to that of the graph GPN can be regarded as corresponding to correction of a variation in output values of the analog-digital converter circuits ADC included in the plurality of converter circuits ITRZAc of the circuit ITS in the region L2. Thus, in Step P8, it is not necessary to calculate the products of X₃(t) and the third standard data W₃(s) where s is 1 to 256; for example, only the arithmetic operation result of multiplication of X₃(t) and the third standard data W₃(1) may be obtained and in Steps P10 and P11, only a data set as the arithmetic operation result may be used to calculate ΔGD and determine ΔGD.

### <<Steps P12 to P15>>

In Steps P12 to P15, the first reference data R used in Steps D1 to D3 is corrected to make the gradient difference ΔGD between the graph GPI and the graph GPN in FIG. 30B close to 0, as in Steps P8 to P11.

For Steps P12 to P14, the description of Steps S12 to S14 of the flowchart in FIG. 27 can be referred to.

In Step P15, it is determined whether ΔGD calculated in Step P14 is within the allowable range as in Step P3. In the case where ΔGD is within the allowable range, the process proceeds to Step P16 (as indicated by an arrow with Y in the flowchart of FIG. 28). At this time, an operation for storing the correction coefficient E_{i_p} by which the first reference data R is multiplied in a memory device outside the arithmetic circuit 10B is also performed. In the case where ΔGD is outside the allowable range, the process proceeds to Step P12 and the third standard data W₃(s) is corrected again (as indicated by an arrow with N in the flowchart of FIG. 28).

Even after Steps P12 to P15 are repetitively performed two or more times, ΔGD is sometimes outside the allowable range. In that case, ΔGD sometimes falls within the allowable range by performing Steps P8 to P10 described above. Therefore, in the case where ΔGD is outside the allowable range in Step P15 after the correction is performed the freely selected number of times (which may be rephrased as “predetermined number of times”), the process may proceed to Step P16 (as indicated by an arrow with Y in the flowchart of FIG. 28).

In Step P16, the process proceeds to Step P17 when the correction of ΔI is completed in Steps P3 to P6 and the correction of ΔGD is completed in Steps P8 to P11 or Steps P12 to P15. The process proceeds to Step P4 and the correction of ΔI or ΔGD is performed again when the correction of ΔI in Steps P3 to P6 and/or the correction of ΔGD in Steps P8 to P11 or Steps P12 to P15 are/is not completed.

For Step P17, the description of Step S16 of the flowchart in FIG. 27 can be referred to.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 4

In this embodiment, a hierarchical neural network will be described. An arithmetic operation of a hierarchical neural network can be performed using the arithmetic circuit described in the above embodiments.

### <Hierarchical Neural Network>

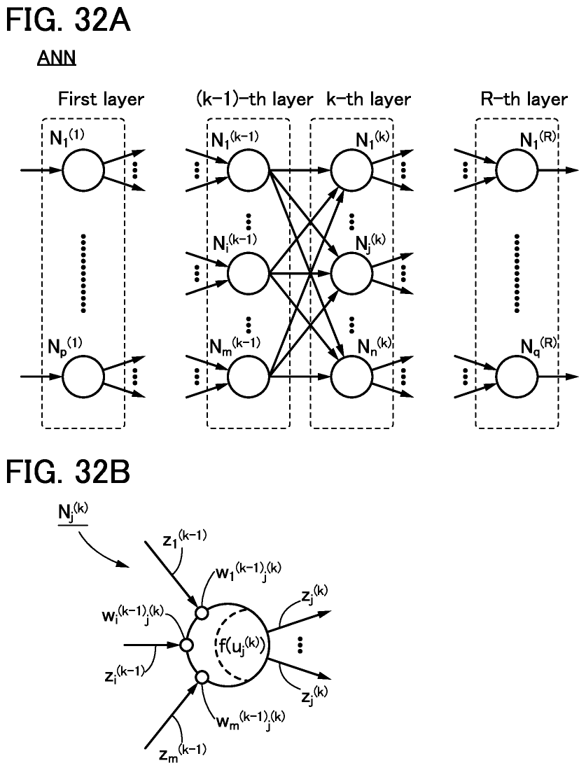

A hierarchical neural network is composed of three or more layers of one input layer, one or more intermediate layers (hidden layers), and one output layer, for example. FIG. 32A illustrates an example of the hierarchical neural network, and a neural network ANN includes first to R-th layers (here, R is an integer greater than or equal to 4). Specifically, the first layer is the input layer, the R-th layer is the output layer, and the other layers are the intermediate layers. FIG. 32A illustrates a (k−1)-th layer and a k-th layer (here, k is an integer greater than or equal to 3 and less than or equal to R−1) as the intermediate layers, and does not show the other intermediate layers.

Each of the layers of the neural network ANN includes one or more neurons. In FIG. 32A, the first layer includes neurons N₁⁽¹⁾ to Nₚ⁽¹⁾ (here, p is an integer greater than or equal to 1). The (k−1)-th layer includes neurons N₁^{(k-1)} to Nₘ^{(k-1)} (here, m is an integer greater than or equal to 1). The k-th layer includes neurons N₁^{(k)} to Nₙ^{(k)} (here, n is an integer greater than or equal to 1). The R-th layer includes neurons N₁^{(R)} to N_{q}^{(R)} (here, q is an integer greater than or equal to 1).

FIG. 32A illustrates, in addition to the neurons N₁⁽¹⁾, Nₚ⁽¹⁾, N₁^{(k-1)}, N₁^{(k)}, Nₙ^{(k)}, N₁^{(R)}, and N_{q}(R), a neuron N₁^{(k-1)} (here, i is an integer greater than or equal to 1 and less than or equal to m) in the (k−1)-th layer and a neuron Nⱼ^{(k)} (here, j is an integer greater than or equal to 1 and less than or equal to n) in the k-th layer; the other neurons are not illustrated.

Next, signal transmission from a neuron in one layer to a neuron in the next layer and signals input to and output from neurons will be described. The description here is made with a focus on the neuron Nⱼ^{(k)} in the k-th layer.

FIG. 32B illustrates the neuron Nⱼ^{(k)} in the k-th layer, signals input to the neuron Nⱼ(k), and signals output from the neuron Nⱼ(k).

Specifically, output signals z₁^{(k-1)} to zₘ^{(k-1)} from the neurons N₁^{(k-1)} to Nₘ^{(k -1)} in the (k−1)-th layer are output to the neuron Nⱼ^{(k)}. Then, the neuron Nⱼ^{(k)} generates output signals zⱼ^{(k)} in response to the signals z₁^{(k-1)} to zₘ^{(k-1)}, and outputs the output signals zⱼ^{(k)} to the neurons in the (k+1)-th layer (not illustrated).

The degree of transmitting a signal input from a neuron in one layer to a neuron in the next layer depends on the connection strength (hereinafter referred to as weight coefficient) of the synapse that connects the neurons to each other. In the neural network ANN, a signal output from a neuron in one layer is multiplied by a corresponding weight coefficient and then is input to a neuron in the next layer. When i is an integer greater than or equal to 1 and less than or equal to m and the weight coefficient of the synapse between the neuron N₁^{(k-1)} in the (k−1)-th layer and the neuron Nⱼ^{(k)} in the k-th layer is wᵢ^{(k-1)}ⱼ^{(k)}, a signal input to the neuron Nⱼ^{(k)} in the k-th layer can be expressed by Formula (4.1).

[Formula 30]

wᵢ^{(k-1)}ⱼ^{(k)}·zᵢ^{(k-1)} (4.1)

That is, when the signals z₁^{(k-1)} to zₘ^{(k -1)} are transmitted from the neurons N₁^{(k-1)} to Nₘ^{(k-1)} in the (k−1)-th layer to the neuron Nⱼ^{(k)} in the k-th layer, the signals z₁^{(k-1)} to zₘ^{(k -1)} are multiplied by respective weight coefficients w₁^{(k-1)}ⱼ^{(k)} to wₘ^{(k-1)}ⱼ^{(k)} Then, w₁^{(k-1)}ⱼ^{(k)}·z₁^{(k-1)} to wₘ^{(k-1)}ⱼ^{(k)}·zₘ^{(k-1)} are input to the neuron Nⱼ^{(k)} in the k-th layer. At this time, the total sum uⱼ^{(k)} of the signals input to the neuron Nⱼ^{(k)} in the k-th layer is expressed by Formula (4.2).

$$\begin{matrix}[ Formula 31 ] & \\ {u}_{j}^{( k )} = {\sum }_{i = 1}^{m} {w}_{i}^{( k - 1 )} \begin{matrix}( k ) \\ j\end{matrix} \cdot {z}_{i}^{( k - 1 )} & ( 4.2 )\end{matrix}$$

In addition, a bias may be added to the product-sum result of the weight coefficients w₁^{(k-1)}ⱼ^{(k)} to wₘ^{(k-1)}ⱼ^{(k)} and the signals z₁^{(k-1)} to zₘ^{(k-1)} of the neurons. When the bias is denoted by b, Formula (4.2) can be rewritten as the following formula.

$$\begin{matrix}[ Formula 32 ] & \\ {u}_{j}^{( k )} = {\sum }_{i = 1}^{m} {w}_{i}^{( k - 1 )} \begin{matrix}( k ) \\ j\end{matrix} \cdot {z}_{i}^{( k - 1 )} + b & ( 4.3 )\end{matrix}$$

The neuron Nⱼ^{(k)} generates the output signal z₁^{(k)} in accordance with uⱼ^{(k)}. Note that the output signal z₁^{(k)} from the neuron N₁^{(k)} is defined by the following formula.

[Formula 33]

zⱼ^{(k)}=ƒ(uⱼ^{(k)}) (4.4)

A function ƒ(uⱼ^{(k)}) is an activation function in a hierarchical neural network. A step function, a linear ramp function, a sigmoid function, or the like can be used as the function ƒ(uⱼ^{(k)}). Note that the activation function may be the same among all neurons or may be different among neurons. Furthermore, the neuron activation function in one layer may be the same as or different from that in another layer.

Signals output from the neurons in the layers, weight coefficients w, or bias b may have an analog value or a digital value. The digital value may be, for example, a binary value or a ternary value. A value having a larger number of bits may be used. In the case of an analog value, for example, a linear ramp function or a sigmoid function is used as the activation function. In the case of a binary digital value, for example, a step function with an output of −1 or 1 or a step function with an output of 0 or 1 is used. Alternatively, the neurons in the layers may each output a ternary or higher-level signal; in this case, a step function with an output of three values, for example, a step function with an output of −1, 0, or 1 or a step function with an output of 0, 1, or 2 is used as the activation function. Furthermore, as an activation function for outputting five values, a step function with an output of −2, −1, 0, 1, or 2 may be used, for example. Using a digital value as at least one of the signals output from the neurons in the layers, the weight coefficients w, and the bias b enables a reduction in the circuit scale, a reduction in power consumption, or an increase in operation speed, for example. Furthermore, the use of an analog value as at least one of the signals output from the neurons in the layers, the weight coefficients w, and the bias b can improve the arithmetic accuracy.

The neural network ANN performs operation in which an input signal is input to the first layer (the input layer), output signals are sequentially generated in layers from the first layer (the input layer) to the last layer (the output layer) according to Formula (4.1), Formula (4.2) or (4.3), and Formula (4.4) on the basis of the signals input from the previous layers, and the output signals are output to the subsequent layers. The signal output from the last layer (the output layer) corresponds to the calculation results of the neural network ANN.

In the case where the circuit included in the region L1 of the arithmetic circuit described in Embodiment 1 is used as the above-described hidden layer, the weight coefficient w_{s[k-1]}^{(k-1)}_{s[k]}^{(k)} (s[k−1] is an integer greater than or equal to 1 and less than or equal to m, and s[k] is an integer greater than or equal to 1 and less than or equal to n) is used as the first data, the current amount corresponding to the first data is stored in the cells IM in the same column sequentially, the output signal z_{s[k-1]}^{(k -1)} from the neuron N_{s[k-1]}^{(k-1)} in the (k−1)-th layer is used as the second data, and the current with the amount corresponding to the second data is made to flow from the circuit XCS to the wiring XCL in each row, so that the sum of products of the first data and the second data can be obtained from a current amount of Is input to the converter circuit ITRZ. In addition, the value of the activation function can be obtained from the value of the sum of products, so that the value of the activation function can be the output signal z_{s[k]}^{(k)} of the neuron N_{s[k]}^{(k)} in the k-th layer.

In the case where the circuit included in the region L2 of the arithmetic circuit described in Embodiment 1 is used as the above-described output layer, the weight coefficient w_{s[R-1]}^{(R-1)}_{s[R]}^{(R)} (s[R−1] is an integer greater than or equal to 1, and s[R] is an integer greater than or equal to 1 and less than or equal to q) is used as the first data, the current amount corresponding to the first data is stored in the cells IM in the same column sequentially, the output signal z_{s[R-1]}^{(R-1)} from the neuron N_{s[R-1]}^{(R-1)} in the (R−1)-th layer is used as the second data, and the current with the amount corresponding to the second data is made to flow from the circuit XCS to the wiring XCL in each row, so that the sum of products of the first data and the second data can be obtained from a current amount of I_{S} input to the converter circuit ITRZ. In addition, the value of the activation function can be obtained from the value of the sum of products, so that the value of the activation function can be the output signal z_{s[R]}^{(R)} of the neuron N_{s[R]}^{(R)} in the R-th layer.

Note that the input layer described in this embodiment may function as a buffer circuit that outputs an input signal to the second layer.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 5

This embodiment describes a learning method of a weight coefficient in the arithmetic circuit 10 described in the above embodiment.

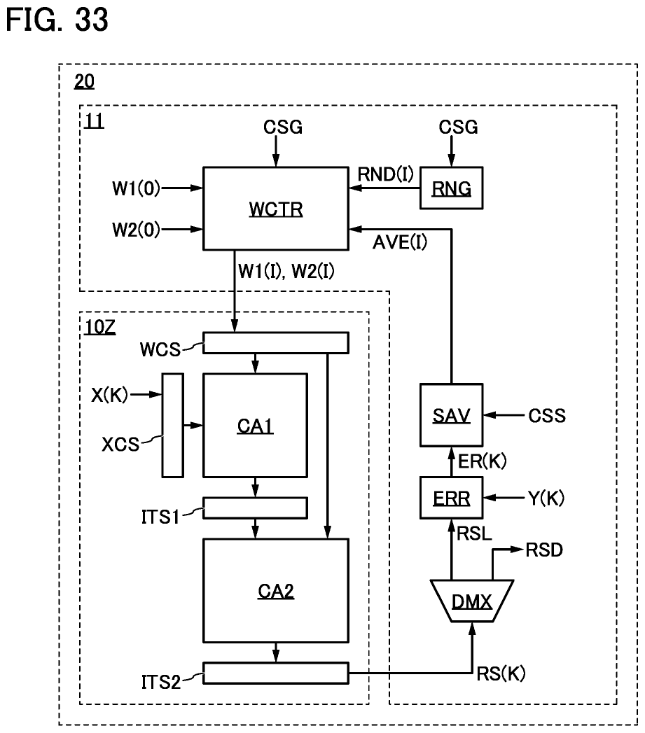

FIG. 33 shows a configuration of an arithmetic device capable of learning a weight coefficient. Specifically, FIG. 33 shows a configuration of an arithmetic device that includes an arithmetic circuit 10Z and a peripheral circuit 11, for example. The arithmetic device 20 has a circuit configuration that enables learning a weight coefficient using a random weight change (RWC) algorithm.

As the arithmetic circuit 10Z, for example, any of the arithmetic circuits 10, 10A, 10AA, 10B, and 10C described in the above embodiments can be used. In FIG. 33, the arithmetic circuit 10Z includes a cell array CA1, a cell array CA2, the circuit WCS, the circuit XCS, the circuit WSD, a circuit ITS1, and a circuit ITS2, for example. In the configuration of the arithmetic circuit 10Z shown in FIG. 33, one circuit WCS transmits the first data to the cell array CA1 and the cell array CA2. In the arithmetic circuit 10Z shown in FIG. 33, for example, the circuit ITS1 corresponds to the circuit ITS included in the region L1 shown in FIG. 1, and the circuit ITS2 corresponds to the circuit ITS included in the region L2 shown in FIG. 1. FIG. 33 shows a value RS as an arithmetic operation result output from the circuit ITS2.

The peripheral circuit 11 includes, for example, a demultiplexer DMX, a circuit ERR, a circuit SAV, a circuit RNG, and a control circuit WCTR.

The demultiplexer DMX has a function of determining whether to transmit, to the circuit ERR, the arithmetic operation result output from the arithmetic circuit 10Z or to output the arithmetic operation result to the outside of the arithmetic device 20. Specifically, the value RS output from the arithmetic circuit 10Z is transmitted as an arithmetic operation result RSL from the demultiplexer DMX to the circuit ERR in the case where learning of a weight coefficient is performed in the arithmetic device 20; the value RS output from the arithmetic circuit 10Z is output as an arithmetic operation result RSD from the demultiplexer DMX to the outside of the arithmetic device 20 in the case where inference is performed.

The circuit ERR has a function of calculating an error ER(K) (K is an integer greater than or equal to 1) between the arithmetic operation result RSL transmitted from the arithmetic circuit 10Z through the demultiplexer DMX and a correct value Y(K).

The circuit SAV has a function of sequentially adding up the errors ER(K) output from the circuit ERR to obtain an average value AVE(I) (I, which is a variable indicating the number of times of repetition of learning here, is an integer greater than or equal to 0) of the errors ER(K).

The circuit SAV may have a function of initializing (resetting) a memory circuit (e.g., a register) therein retaining the average value AVE(I), with the use of a control signal CSS.

The circuit RNG has a function of generating random numbers. That is, the circuit RNG functions as a random number generator. Specifically, for example, the circuit RNG outputs an output value RND, which is “1” or “0” with a probability of 1/2. The circuit RNG can include a linear feedback shift register (e.g., a Fibonacci linear feedback shift register or a Galois linear feedback shift register), for example. The circuit RNG may have a function of outputting “0” as the output value RND when a control signal CSG input to the circuit RNG is “0”.

The control circuit WCTR has a function of controlling a weight coefficient; specifically, the control circuit WCTR calculates an update value of a weight coefficient with the use of the average value AVE obtained by the circuit SAV and the output value RND output from the circuit RNG. Here, weight coefficients W1(I) and W2(I) (specifically, W1(1) and W2(1) are weight coefficients before update amounts are added, i.e., the initial weight coefficients) are transmitted to memory cells of the cell array CA1 and the cell array CA2 through the circuit WC S in the arithmetic circuit 10Z. The update amount for the weight coefficient W1(I) is ΔW1[i,j](I+1), and the update amount for the weight coefficient W2(I) is ΔW2[i,j](I+1). Note that the control circuit WCTR may include a register for retaining the weight coefficients W1(I) and W2(I) and the like and a counter for storing the number of trials, for example.

The control circuit WCTR may have a function of initializing the values of the register and counter that are included in the control circuit WCTR in the case where the control signal CSG input to the control circuit WCTR is “0”.

Description will be made on a method in which learning is performed using the value RS output from the circuit ITS2 of the arithmetic circuit 10Z and the weight coefficient W1 retained in the cell array CA1 and the weight coefficient W2 retained in the cell array CA2 are updated.

First, the data of the registers included in the control circuit WCTR and the circuit RNG is reset using the control signals CSG. In the case where the data of the register included in the control circuit WCTR is initialized, the update amounts for the weight coefficients are as follows: ΔW1 [i,j](0)=0 and ΔW2[i,j](0)=0. Furthermore, the average value AVE retained in the circuit SAV is reset using the control signal CSS. For example, the average value AVE(0) retained in the circuit SAV is set to 0 when the circuit SAV receives the control signal CSS.

Then, to the control circuit WCTR, the initial weight coefficients W1(1) and W2(1) to be respectively retained in the cell arrays CA1 and CA2 of the arithmetic circuit 10Z are input. Note that the weight coefficient W1(1) is a matrix of m rows and n columns to be retained in the cell array CA1 and the weight coefficient W2(1) is a matrix of n rows and k columns to be retained in the cell array CA2.

The control circuit WCTR transmits the weight coefficients W1(1) and W2(1) as W1(I) and W2(I) (that is, I=1) to the arithmetic circuit 10Z. Thus, the circuit WCS of the arithmetic circuit 10Z writes W1(I) and W2(I) respectively to the cell array CA1 and the cell array CA2.

Subsequently, X(K) as data for learning is input to the circuit XCS of the arithmetic circuit 10Z, and Y(K) as correct data is input to the circuit ERR. Note that X(K) is a matrix of one row and m columns.

When X(K) is input to the circuit XCS of the arithmetic circuit 10Z, the circuit ITS2 of the arithmetic circuit 10Z outputs RS(K) as an arithmetic operation result of the arithmetic circuit 10Z.

Furthermore, RS(K) is input to the circuit ERR through the demultiplexer DMX. The circuit ERR calculates the difference between RS(K) and Y(K) and outputs ER(K) as the calculation result.

The operation from the input of X(K) to the circuit XCS of the arithmetic circuit 10Z to the output of ER(K) from the circuit ERR is repeated from K=1 to K=K_{MAX}. Note that K_{MAX} is the number of pieces of prepared data for learning.

In this manner, ER(1) to ER(K_{MAX}) are sequentially transmitted from the circuit ERR to the circuit SAV. The circuit SAV adds up ER(1) to ER(K_{MAX}) and outputs the average value AVE(I) thereof.

The circuit RNG outputs the output value RND(I) that is a random variable to the control circuit WCTR. Here, the output value RND(I) is “+1” or “−1” with a probability of (1/2)ⁿ and is “0” with a probability of 1−(1/2)ⁿ, for example.

The control circuit WCTR obtains the average value AVE(I) from the circuit SAV and the output value RND(I) from the circuit RNG and updates the weight coefficient W1(1) and the weight coefficient W2(1) to the weight coefficient W1(I+1) and the weight coefficient W2(I+1), respectively.

Specifically, in the case where the weight coefficient W1 [i,j](I) of the i-th row and the j-th column (where i is an integer greater than or equal to 1 and less than or equal to m, and j is an integer greater than or equal to 1 and less than or equal to n) of the cell array CA1 is updated to W1[i,j](I+1), the control circuit WCTR calculates an update amount of ΔW1 [i/](I+1) such that W1 [i,j](I+1)=W1[i,j](I)+ΔW1[i,j](I+1). For example, in the case where AVE(I+1) is less than AVE(I), ΔW1 [i,j](I+1)=ΔW1[i,j](I); in the case where AVE(I+1) is greater than or equal to AVE(I), ΔW1 [i,j](I+1)=RND (I).

Likewise, in the case where the weight coefficient W2[i,j](I) of the i-th row and the j-th column (where i is an integer greater than or equal to 1 and less than or equal to n, and j is an integer greater than or equal to 1 and less than or equal to k) of the cell array CA2 is updated to W2[i,j](I+1), the control circuit WCTR calculates an update amount of ΔW2[i,j](I+1) such that W2[i,j](I+1)=W2[i,j](I)+ΔW2[i,j](I+1). For example, in the case where AVE(I+1) is less than AVE(I), ΔW2[i,j](I+1)=ΔW2[i,j](I); in the case where AVE(I+1) is greater than or equal to AVE(I), ΔW2[i,j](I+1)=RND(I).

As described above, the weight coefficients W1(I) and W2(I) are respectively updated to the weight coefficients W1(I+1) and W2(I+1). Then, the control circuit WCTR transmits the weight coefficients W1(I+1) and W2(I+1) as W1(I) and W2(I) (that is, 1 is added to I) to the arithmetic circuit 10Z. Thus, the circuit WCS of the arithmetic circuit 10Z writes W1(I) and W2(I) respectively to the cell array CA1 and the cell array CA2.

The above operation is repeated from I=0 to I=I_{MAX}. Note that I_{MAX} is the number of times of updates of a weight coefficient, and can be freely set.

As described above, learning in a neural network can be performed in the arithmetic circuit 10Z when the circuit configuration shown in FIG. 33 is employed. Accordingly, the weight coefficient in the neural network can be updated and the accuracy of inference can be increased.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 6

This embodiment describes configuration examples of any of the arithmetic circuits 10, 10A, 10AA, 10B, and 10C described in the above embodiments. In this embodiment, the arithmetic circuits 10, 10A, 10AA, 10B, and 10C are collectively referred to as the arithmetic circuit 10.

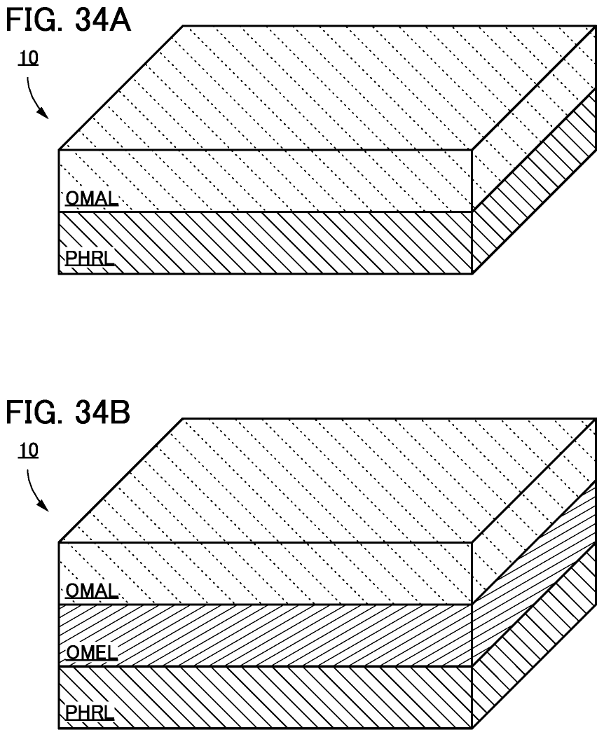

FIG. 34A is a schematic perspective view showing the arithmetic circuit 10 that is a semiconductor device of one embodiment of the present invention. The arithmetic circuit 10 shown in FIG. 34A includes a circuit layer PHRL and an arithmetic layer OMAL, for example. The arithmetic layer OMAL is above the circuit layer PHRL. That is, the circuit layer PHRL and the arithmetic layer OMAL are stacked in this order from the bottom in the arithmetic circuit 10 shown in FIG. 34A.

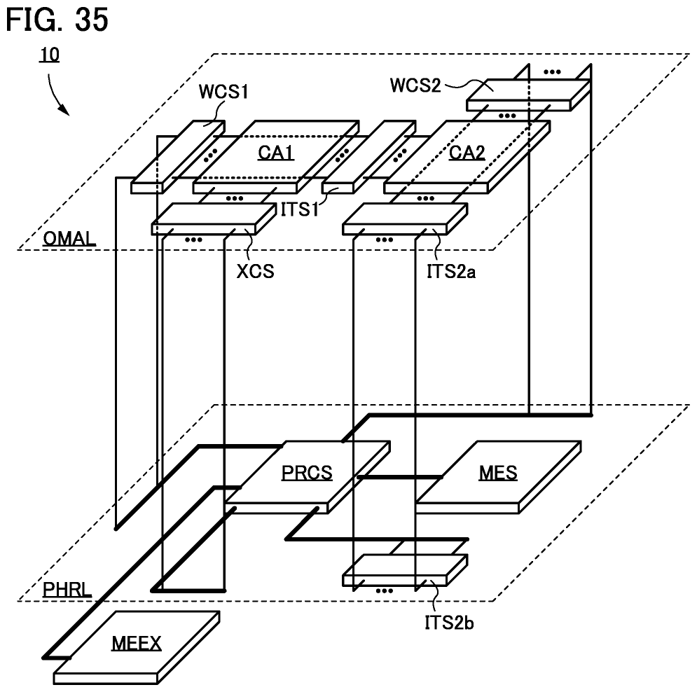

FIG. 35 is a block diagram showing configuration examples of the circuit layer PHRL and the arithmetic layer OMAL shown in FIG. 34A.

In FIG. 35, the circuit layer PHRL includes a processor PRCS, a memory device MES, and a circuit ITS2b, for example. The arithmetic layer OMAL includes the cell array CA1, the cell array CA2, a circuit WCS1, a circuit WCS2, the circuit XCS, the circuit ITS1, and a circuit ITS2a, for example.

The cell array CA1 corresponds to the cell array CA that is included in the region L1 shown in FIG. 1, and the cell array CA2 corresponds to the cell array CA that is included in the region L2 shown in FIG. 1. The circuit WCS1 corresponds to the circuit WCS that is included in the region L1 shown in FIG. 1, and the circuit WCS2 corresponds to the circuit WCS that is included in the region L2 shown in FIG. 1. The circuit XCS corresponds to the circuit XCS that is included in the region L1 shown in FIG. 1. The circuit ITS1 corresponds to the circuit ITS that is included in the region L1 shown in FIG. 1, and the circuit ITS2a and the circuit ITS2b correspond to the circuit ITS that is included in the region L2 shown in FIG. 1.

Note that one or more selected from the circuit WCS1, the circuit WCS2, the circuit XCS, the circuit ITS1, and the circuit ITS2a may be included in the circuit layer PHRL.

The circuit layer PHRL can be formed by providing a circuit element such as a transistor or a capacitor over a substrate, for example. As the substrate, a semiconductor substrate (e.g., a single crystal substrate formed of silicon or germanium) can be used. Besides such a semiconductor substrate, for example, any of the following can be used: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. Examples of the glass substrate include a barium borosilicate glass substrate, an aluminoborosilicate glass substrate, and a soda lime glass substrate. Examples of materials for the flexible substrate, the attachment film, or the base film include plastic typified by polyethylene terephthalate (PET), polyethylene naphthalate (PEN), polyethersulfone (PES), and polytetrafluoroethylene (PTFE). Another example is a synthetic resin such as an acrylic resin. Other examples are polypropylene, polyester, polyvinyl fluoride, and polyvinyl chloride. Other examples are polyamide, polyimide, aramid, an epoxy resin, an inorganic vapor-deposited film, and paper. Note that in the case where the manufacturing process of the arithmetic circuit 10 involves heat treatment, a highly heat-resistant material is preferably selected for the substrate.

Note that the substrate included in the circuit layer PHRL is described as a semiconductor substrate containing silicon in this embodiment.

When the substrate included in the circuit layer PHRL is a semiconductor substrate containing silicon as a material, for example, the transistors included in the processor PRCS, the memory device MES, and the circuit ITS2b can be formed over the semiconductor substrate. In that case, the transistors are Si transistors. The Si transistor has high field-effect mobility and thus can make a large amount of on-state current flow. Accordingly, the driving speed of each of the above-described circuits can be increased, and the range of a signal can be expanded, for example. In the case where the circuit layer PHRL of the arithmetic circuit 10 in FIG. 35 includes one or more selected from the circuit WCS1, the circuit WCS2, the circuit XCS, the circuit ITS1, and the circuit ITS2a, the transistors included in the selected circuit(s) can also be formed over the semiconductor substrate containing silicon as a material, whereby the driving speed of the circuit(s) can be increased and the range of a signal can be expanded, for example.

The stack of the circuit layer PHRL and the arithmetic layer OMAL can be fabricated by directly forming the arithmetic layer OMAL on the circuit layer PHRL. Alternatively, the stack can be fabricated in the following manner: the arithmetic layer OMAL is formed by providing a circuit element such as a transistor or a capacitor over a substrate, and the substrate is mounted over the circuit layer PHRL.

In the case where the arithmetic layer OMAL is directly formed on the circuit layer PHRL, the arithmetic layer OMAL preferably includes an OS transistor. The OS transistor can be formed not only over a semiconductor substrate but also over an insulator substrate, a conductor substrate, a conductive film, an insulating film, and a semiconductor film and thus can be easily provided over a semiconductor substrate where a Si transistor is formed (over the circuit layer PHRL). Thus, the transistors included in the cell array CA1, the cell array CA2, the circuit WCS1, the circuit WCS2, the circuit XCS, the circuit ITS1, and the circuit ITS2a in the arithmetic layer OMAL can be OS transistors.

In the case where the arithmetic layer OMAL is formed by providing a circuit element such as a transistor or a capacitor over a substrate and the substrate is mounted over the circuit layer PHRL, a flip-chip bonding method or a wire bonding method can be used. Alternatively, the arithmetic layer OMAL may be mounted over the circuit layer PHRL in the following manner: a first bonding layer is provided on the circuit layer PHRL side, a second bonding layer is provided on the substrate of the arithmetic layer OMAL, and the first bonding layer and the second bonding layer are bonded to each other by surface activated bonding and/or hydrophilic bonding. Specifically, in what is called Cu—Cu junction, the first bonding layer and the second bonding layer each include copper (Cu) as a conductor, and copper (Cu) of the first bonding layer and that of the second bonding layer are bonded to each other.

Since the circuit ITS2a in the arithmetic circuit 10 shown in FIG. 35 can include an OS transistor, the circuit ITS2a preferably includes the current source CIp, the current source CIn, the current mirror circuit CM, the switch SW4p, the switch SW4n, and the transistor F6 in the case where the converter circuit ITRZAc shown in FIG. 12C is used as the converter circuits ITRZ included in the circuits ITS2a and ITS2b of the arithmetic circuit 10 shown in FIG. 35. Meanwhile, since the circuit ITS2b can include a Si transistor, the circuit ITS2b preferably includes the operational amplifier OP1, the analog-digital converter circuit ADC, and the load LE in the case where the converter circuit ITRZAc shown in FIG. 12C is used as the converter circuits ITRZ included in the circuits ITS2a and ITS2b of the arithmetic circuit 10 shown in FIG. 35. Specifically, the operational amplifier OP1 and the analog-digital converter circuit ADC are preferably formed in the circuit ITS2b included in the circuit layer PHRL because the operational amplifier OP1 and the analog-digital converter circuit ADC can be easily formed as CMOS circuits.

The processor PRCS is electrically connected to the circuit WCS1, the circuit WCS2, the circuit XCS, the circuit ITS2b, the memory device MES, and a memory device MEEX, for example. The thick solid lines in the circuit layer PHRL shown in FIG. 35 indicate bus wirings.

The memory device MES is provided in the circuit layer PHRL, and the memory device MEEX is provided outside the arithmetic circuit 10. The memory device MES can be a volatile memory device such as a dynamic random access memory (DRAM) or an SRAM, for example. The memory device MEEX can be a nonvolatile memory device such as a hard disk drive (HDD) or a solid state drive (SSD), for example.

The memory device MES and the memory device MEEX have a function of, for example, storing the data used for an arithmetic operation performed in the arithmetic layer OMAL and the data of the arithmetic operation result. For example, when the arithmetic operation is an arithmetic operation of a hierarchical neural network, the memory device MES and the memory device MEEX can store the first data (weight coefficient), the second data (input signal), and the arithmetic operation result. In the case where the arithmetic circuit 10 performs the operation by the correction method described in Embodiment 3, the memory device MES and the memory device MEEX can store the correction coefficient, correction data, and the like that are used for the correction method.

The processor PRCS has a function of, for example, controlling the circuit WCS1, the circuit WCS2, and the circuit XCS included in the arithmetic layer OMAL. For example, the processor PRCS can transmit, to the circuit WCS1 or WCS2, a data signal including the first data and a control signal for driving the circuit WCS1 or WCS2. Furthermore, the processor PRCS can transmit, to the circuit XCS, a data signal including reference data or the second data and a control signal for driving the circuit XCS, for example.

The processor PRCS has a function of obtaining an arithmetic operation result from the circuit ITS2b and transmitting, to the memory device MES or the memory device MEEX, a control signal for writing the arithmetic operation result to the memory device MES or the memory device MEEX, for example. The processor PRCS has a function of transmitting an instruction signal for reading data from the memory device MES or the memory device MEEX, for example.

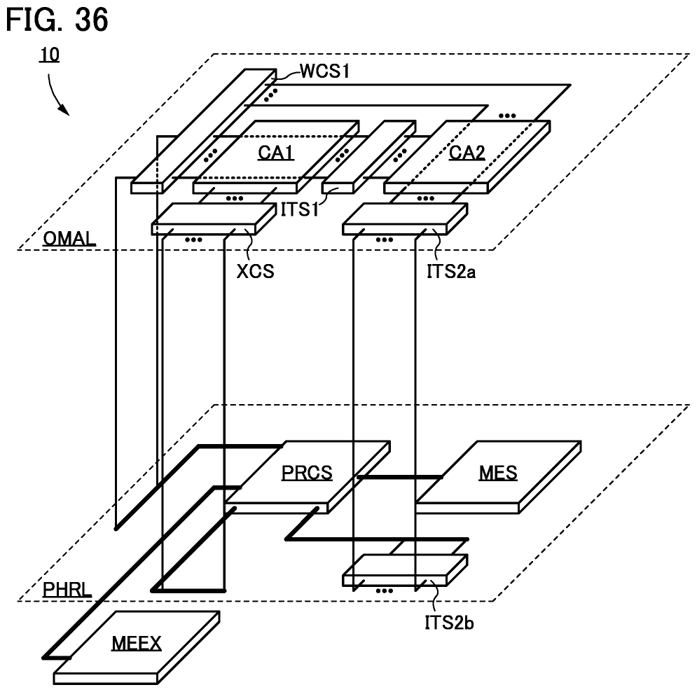

The configuration of one embodiment of the present invention is not limited to the configuration of the arithmetic circuit 10 shown in FIG. 35. For example, the circuit WCS2 may be omitted and the circuit WCS1 may be electrically connected to the cell array CA2 in the arithmetic layer OMAL as shown in FIG. 36. In that case, the circuit WCS1 supplies the first data not only to the cell array CA1 but also to the cell array CA2 in the arithmetic circuit 10 shown in FIG. 36. In the arithmetic circuit 10 having the configuration shown in FIG. 36, the number of circuits included in the arithmetic layer OMAL can be smaller, which will increase the yield of the arithmetic circuit 10 or reduce the power consumption, for example.

The configuration of one embodiment of the present invention is not limited to the configuration of the arithmetic circuit 10 shown in FIG. 35. For example, one or both of the processor PRCS and the memory device MES included in the circuit layer PHRL of the arithmetic circuit 10 shown in FIG. 35 may be provided outside the arithmetic circuit 10 (not shown).

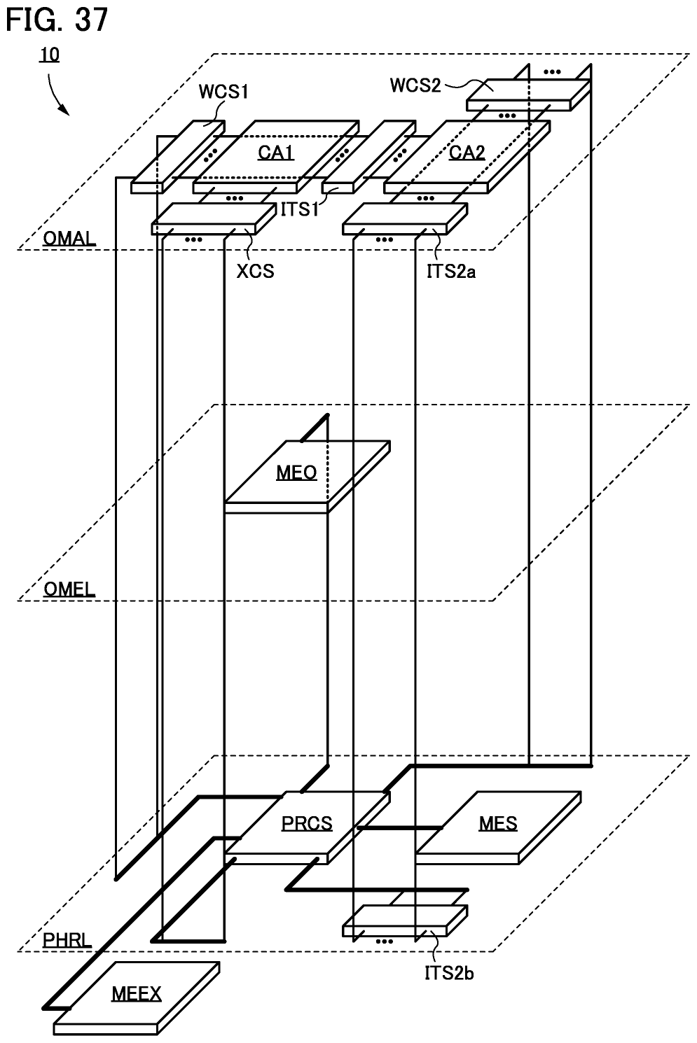

The configuration of one embodiment of the present invention is not limited to the configuration of the arithmetic circuit 10 shown in FIG. 34A. For example, as shown in FIG. 34B, a memory layer OMEL may be provided between the circuit layer PHRL and the arithmetic layer OMAL. FIG. 37 shows a specific circuit configuration example of the arithmetic circuit 10 shown in FIG. 34B. The arithmetic circuit 10 shown in FIG. 37 has the configuration of FIG. 35 to which the memory layer OMEL between the circuit layer PHRL and the arithmetic layer OMAL is added; the memory layer OMEL of the arithmetic circuit 10 in FIG. 37 includes a memory device MEO.

Like the arithmetic layer OMAL, the memory layer OMEL preferably includes an OS transistor. In other words, the memory device MEO of the memory layer OMEL can include an OS transistor. Since an OS transistor has an extremely low off-state current, using an OS transistor as a writing transistor allows written data to be stored for a long time, for example.

### Cross-Sectional Structure Example 1

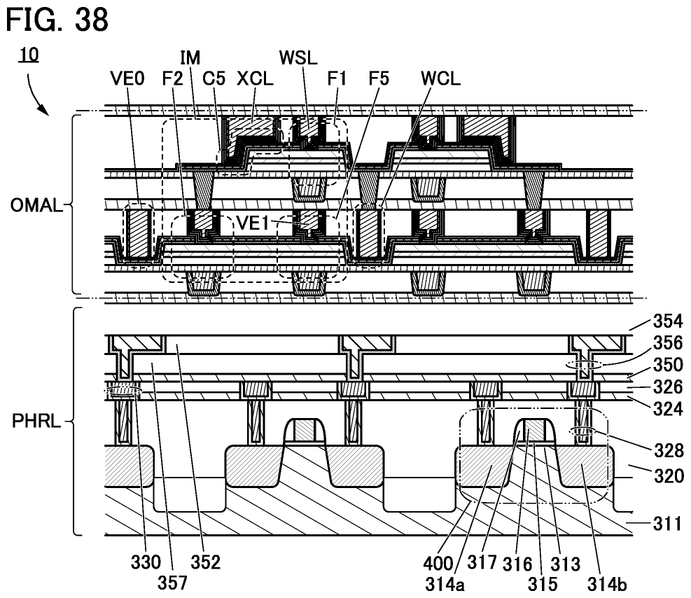

Next, a specific structure example of the arithmetic circuit 10 shown in FIG. 34A and FIG. 35 is described. FIG. 38 is a schematic cross-sectional view showing an example of the arithmetic circuit 10 shown in FIG. 34A and FIG. 35.

The schematic cross-sectional view in FIG. 38 shows the circuit layer PHRL and the arithmetic layer OMAL. Note that the arithmetic circuit 10 shown in FIG. 38 has a structure in which the arithmetic layer OMAL is directly formed on the circuit layer PHRL.

FIG. 38 shows a transistor 400 included in the circuit layer PHRL. The transistor 400 is provided on a substrate 311 and includes a conductor 316 functioning as a gate, an insulator 315 functioning as a gate insulator, an insulator 317, a semiconductor region 313 that includes part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

In the transistor 400 illustrated in FIG. 38, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. The transistor 400 is also referred to as a FIN transistor because it utilizes a protruding portion of the semiconductor substrate. An insulator functioning as a mask for forming the protruding portion may be provided in contact with the top surface of the protruding portion. Although the case where the protruding portion is formed by processing part of the semiconductor substrate is described here, a semiconductor film having a protruding shape may be formed by processing a silicon-on-insulator (SOI) substrate.

Note that the transistor 400 shown in FIG. 38 is just an example and is not limited to the structure shown therein; an appropriate transistor may be used in accordance with a circuit configuration or a driving method.

Wiring layers including an interlayer film, a wiring, and a plug may be provided between the structure bodies. A plurality of wiring layers can be provided in accordance with the design. Furthermore, in this specification and the like, a wiring and a plug electrically connected to the wiring may be a single component. That is, in some cases, part of a conductor functions as a wiring or part of a conductor functions as a plug.

For example, an insulator 320, an insulator 324, and an insulator 326 are stacked over the transistor 400 in this order as interlayer films. A conductor 328 or the like is embedded in the insulator 320. A conductor 330 or the like is embedded in the insulator 324 and the insulator 326. Note that the conductor 328 and the conductor 330 function as contact plugs or wirings.

The insulator functioning as an interlayer film may function as a planarization film that covers a roughness thereunder. For example, the top surface of the insulator 320 may be planarized by planarization treatment using a chemical mechanical polishing (CMP) method to improve planarity.

A wiring layer may be provided over the insulator 326 and the conductor 330. For example, in FIG. 38, an insulator 350, an insulator 357, an insulator 352, and an insulator 354 are stacked in this order over the insulator 326 and the conductor 330. A conductor 356 is formed in the insulator 350, the insulator 357, and the insulator 352. The conductor 356 functions as a contact plug or a wiring.

The insulator 354 is provided over the insulator 352 and the conductor 356. In the insulator 354, a contact plug or a wiring for electrical connection to an upper circuit (e.g., any of the circuits included in the arithmetic layer OMAL) may be embedded.

FIG. 38 shows the cell IM included in the arithmetic layer OMAL. Specifically, FIG. 38 shows the transistor F1, the transistor F2, the transistor F5, and the capacitor C5 included in the cell IM. The cell IM may be any of the cells IM[1,1] to IM[m,n] that are described in the above embodiment with reference to FIG. 8.

In the arithmetic layer OMAL of the arithmetic circuit 10 shown in FIG. 38, the transistor F1 and the capacitor C5 are positioned above the transistors F2 and F5.

In the arithmetic layer OMAL shown in FIG. 38, the transistors F2 and F5 are provided to share one island-shaped semiconductor layer. Specifically, a gate insulating film (sometimes referred to as a first gate insulating film) and a gate electrode (sometimes referred to as a first gate electrode) of the transistor F2 are formed in one of two regions of the one island-shaped semiconductor layer, and a gate insulating film and a gate electrode of the transistor F5 are formed in the other of the two regions of the one island-shaped semiconductor layer.

In the arithmetic layer OMAL shown in FIG. 38, each of the transistors F2 and F5 is a transistor that includes a back gate (sometimes referred to as a second gate electrode). Specifically, the back gate of the transistor F2 overlaps with the gate insulating film and the gate electrode thereof and is positioned in a region below the above-described one island-shaped semiconductor layer; the back gate of the transistor F5 overlaps with the gate insulating film and the gate electrode thereof and is positioned in a region below the above-described one island-shaped semiconductor layer. In each of the transistors F2 and F5, an insulating layer serving as a second gate insulating film is provided between the back gate and the semiconductor layer.

A conductor corresponding to a wiring VE0 is electrically connected to one of a source electrode and a drain electrode of the transistor F2. A conductor corresponding to the wiring WCL is electrically connected to one of a source electrode and a drain electrode of the transistor F5. The wiring VE0 and the wiring WCL extend in the channel width direction of the transistor F2 or F5, for example.

A conductor as the gate electrode of the transistor F5 extends in the channel width direction. This conductor corresponds to a wiring VE1.

An insulator serving as an interlayer film is formed between the transistor F1 and the transistors F2 and F5. The insulator includes an opening portion in each of a region overlapping with the gate electrode of the transistor F2 and a region overlapping with the wiring WCL, and conductors are embedded in the opening portions. One conductor is electrically connected to one of a source electrode and a drain electrode of the transistor F1, and the other conductor is electrically connected to the other of the source electrode and the drain electrode of the transistor F1.

As already described above, the transistor F1 is positioned above the transistors F2 and F5. A dielectric of the capacitor C5 is formed to cover an end portion of an island-shaped semiconductor layer of the transistor F1, and a conductor corresponding to the second terminal of the capacitor C5 is formed over the dielectric. The conductor corresponds to the wiring XCL.

In a region overlapping with the island-shaped semiconductor layer of the transistor F1, a gate insulating film and a gate electrode of the transistor F1 are formed. Specifically, a conductor as the gate electrode of the transistor F1 extends in the channel width direction. This conductor corresponds to the wiring WSL.

The transistor F1 is a transistor that includes a back gate like the transistor F2 and the transistor F5. Specifically, the back gate of the transistor F1 is positioned in a region overlapping with the gate insulating film and the gate electrode of the transistor F1 that are below the island-shaped semiconductor layer.

As described above, in each of the transistors F1, F2, and F5, the gate and the back gate are positioned to interpose a channel formation region of the semiconductor layer. The gate and the back gate are each formed using a conductor. The back gate can function in a manner similar to that of the gate. In addition, by changing the potential of the back gate, the threshold voltage of the transistor can be changed. The potential of the back gate may be the same as that of the gate or may be a ground potential or a freely selected potential.

Each of the gate and the back gate is formed using a conductor and thus has a function of preventing an electric field generated in the outside of the transistor from influencing the semiconductor layer in which the channel is formed (in particular, a function of preventing static electricity). That is, the variation in the electrical characteristics of the transistor due to the influence of an external electric field such as static electricity can be prevented. By providing the back gate, the amount of change in threshold voltage of the transistor due to the bias-temperature stress test (which is sometimes referred to as BT test) can be reduced.

For example, when including a back gate, the transistor F1 is less affected by an external electric field and can keep on being in an off state stably. As a result, data written to a first terminal of the capacitor C5 can be stably retained. Providing the back gate can make the operation of the cell IM stable and increase the reliability of the arithmetic layer OMAL that includes the cell IM.

For each of the semiconductor layers in which the channels of the transistors F1, F2, and F5 are formed, one or a combination of a single crystal semiconductor, a polycrystalline semiconductor, a microcrystalline semiconductor, an amorphous semiconductor, and the like can be used. As a semiconductor material, for example, silicon or germanium can be used as described in Embodiment 1. For another example, a compound semiconductor such as silicon germanium, silicon carbide, gallium arsenide, an oxide semiconductor, or a nitride semiconductor may be used.

Each of the transistors F1, F2, and F5 is preferably a transistor using an oxide semiconductor, which is one type of metal oxide, in its semiconductor layer where a channel is formed (also referred to as an OS transistor). An oxide semiconductor has a band gap of 2 eV or more and thus has an extremely low off-state current. Thus, power consumption of the cell IM can be reduced. Accordingly, power consumption of the arithmetic circuit 10 that includes the cell IM can be reduced.

In addition, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current of the OS transistor is less likely to decrease even in a high-temperature environment. Thus, the cell IM can operate stably and have high reliability even in a high-temperature environment.

### <<Constituent Material of Transistor>>

Next, constituent materials of the transistors F1, F2, and F5 are described.

### [Metal Oxide (Oxide Semiconductor)]

The channel formation region of each of the transistors F1, F2, and F5 preferably contains a metal oxide functioning as an oxide semiconductor. For example, the metal oxide to be the channel formation region has a band gap greater than or equal to 2 eV, preferably greater than or equal to 2.5 eV, further preferably greater than or equal to 3.0 eV.

Structures of metal oxides are classified into a single crystal structure and other structures (non-single-crystal structures). Examples of non-single-crystal structures include a c-axis aligned crystalline (CAAC) structure, a polycrystalline structure, a nanocrystalline (nc) structure, an amorphous-like (a-like) structure, and an amorphous structure. There is no particular limitation on the structure of the metal oxide of one embodiment of the present invention, and any of the above structures can be employed. Note that a crystalline metal oxide typified by a CAAC metal oxide and an nc metal oxide is preferably used to obtain a highly reliable semiconductor device.

The metal oxide preferably contains at least indium or zinc. In particular, the metal oxide preferably contains indium and zinc. In addition to them, the element M is preferably contained. As the element M, one or more selected from aluminum, gallium, silicon, yttrium, tin, copper, vanadium, boron, titanium, iron, nickel, germanium, zirconium, molybdenum, lanthanum, cerium, neodymium, hafnium, tantalum, tungsten, cobalt, magnesium, and antimony can be used. In particular, the element Mis preferably one or more of aluminum, gallium, yttrium, and tin. Furthermore, the element M preferably contains one or both of gallium and tin.

Specifically, for example, In—Ga—Zn oxide (indium-gallium-zinc oxide), Ga—Zn oxide, gallium oxide, or indium oxide can be used as the above metal oxide.

As the metal oxide, a metal oxide in which In:Ga:Zn=1:3:4 [atomic ratio], 1:3:2 [atomic ratio], 1:1:0.5 [atomic ratio], 1:1:1 [atomic ratio], 4:2:3 [atomic ratio], or 3:1:2 [atomic ratio] is used. A metal oxide in which In:Zn=4:1 [atomic ratio] may be used.

A sputtering method or an atomic layer deposition (ALD) method can be suitably used for forming a film of a metal oxide. A sputtering method enables formation of a metal oxide film having high crystallinity or high film density. An ALD method, in which one atomic layer can be deposited, enables formation of a metal oxide film having few defects such as pinholes, formation of a metal oxide film having high coverage, and formation of a metal oxide film at low temperatures, for example. After the formation of a metal oxide film, impurity removal treatment is preferably performed to remove an impurity (which is typically water, hydrogen, carbon, or nitrogen here) from the metal oxide film. Examples of the impurity removal treatment include plasma treatment, microwave treatment, and heat treatment.

### [Conductor]

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; an alloy containing a combination of two or more selected from the above metal elements; or the like. For the conductor, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, for the conductor, silicide (e.g., nickel silicide) or a semiconductor with high electrical conductivity typified by polycrystalline silicon containing an impurity element (e.g., phosphorus) may be used, for example.

A plurality of conductors formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

The conductor serving as the second gate electrode is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, a conductive material having a function of inhibiting diffusion of oxygen (e.g., oxygen atoms, oxygen molecules, or both) is preferably used. Specifically, examples of the conductive material having a function of inhibiting diffusion of oxygen include titanium, titanium nitride, tantalum, tantalum nitride, ruthenium, and ruthenium oxide.

Alternatively, a conductive material containing tungsten, copper, or aluminum as its main component is preferably used.

For the conductor functioning as the source electrode or the drain electrode, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; or an alloy containing a combination of two or more selected from the above metal elements. For the conductor, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

The conductor serving as the first gate electrode is preferably formed using the above-described conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, a conductive material having a function of inhibiting diffusion of oxygen (e.g., oxygen atoms, oxygen molecules, or both) is preferably used. Examples of the conductive material having a function of inhibiting diffusion of oxygen include tantalum, tantalum nitride, titanium, titanium nitride, ruthenium, and ruthenium oxide. When the conductive material containing oxygen is provided as the conductor, oxygen released from the conductive material is easily supplied to the channel formation region.

The conductor functioning as the first gate electrode is preferably formed using a conductive material containing tungsten, copper, or aluminum as its main component. The conductor also serves as a wiring and thus is preferably formed using a conductor having high conductivity. For example, a conductive material containing tungsten, copper, or aluminum as its main component can be used. Furthermore, the conductor may have a stacked-layer structure and may have a stacked-layer structure of titanium or titanium nitride and any of the above conductive materials, for example.

For example, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used for the conductor. For another example, indium gallium zinc oxide containing nitrogen may be used for the conductor. With the use of such a material, hydrogen contained in the metal oxide where the channel is formed can be captured in some cases. Alternatively, hydrogen entering from an external insulator or the like can be captured in some cases.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

The insulator that can be provided in the transistor preferably functions as a barrier insulating film that inhibits the entry of impurities such as water and hydrogen to the transistor F1, F2, or F5 from the substrate side. Accordingly, it is preferable to use, for the insulator, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, it is preferable to use an insulating material having a function of inhibiting diffusion of oxygen (e.g., an oxygen atom, an oxygen molecule, or both) (an insulating material through which the oxygen is less likely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specifically, as the insulator having a function of inhibiting the passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be used, for example. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

The second gate insulating film in contact with the metal oxide included in the channel formation region preferably releases oxygen by heating. In this specification and the like, oxygen that is released by heating is referred to as excess oxygen in some cases. For example, silicon oxide or silicon oxynitride can be used as appropriate for the second gate insulating film. When an insulator containing oxygen is provided in contact with the metal oxide, oxygen vacancies in the metal oxide can be reduced, leading to increased reliability of the transistor.

Specifically, an oxide material that releases part of oxygen by heating is preferably used for the insulator. An oxide that releases oxygen by heating is an oxide film in which the amount of released oxygen converted into oxygen atoms is greater than or equal to 1.0×10¹⁸ atoms/cm⁻³, preferably greater than or equal to 1.0×10¹⁹ atoms/cm⁻³, further preferably greater than or equal to 2.0×10¹⁹ atoms/cm⁻³ or greater than or equal to 3.0×10²⁰ atoms/cm⁻³ in thermal desorption spectrometry (TDS) analysis. Note that the temperature of the film surface in the TDS analysis is preferably within the range of 100° C. to 700° C. or 100° C. to 400° C.

As the insulator included in the transistor, an insulator containing an oxide of one or both of aluminum and hafnium, which is an insulating material, is preferably used. As examples of the insulator containing an oxide of one or both of aluminum and hafnium, aluminum oxide and hafnium oxide can be given. As another example, an oxide containing aluminum and hafnium (hafnium aluminate) can be given. In the case where the insulator is formed using such a material around the transistor, the insulator can function as a layer inhibiting oxygen release and the entry of impurities such as hydrogen into the metal oxide from the periphery of the transistor.

Alternatively, aluminum oxide, bismuth oxide, germanium oxide, niobium oxide, silicon oxide, titanium oxide, tungsten oxide, yttrium oxide, or zirconium oxide may be added to the insulator included in the transistor, for example. Alternatively, these insulators may be subjected to nitriding treatment. Silicon oxide, silicon oxynitride, or silicon nitride may be stacked over the above insulator.

The insulator included in the transistor may be a single layer or a stacked layer using an insulator containing a high-k material, such as aluminum oxide, hafnium oxide, tantalum oxide, zirconium oxide, lead zirconate titanate (PZT), strontium titanate (SrTiO₃), or (Ba,Sr)TiO₃ (BST).

The first gate insulating film is preferably provided in contact with the top surface of the metal oxide. For the insulating film, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. Silicon oxide and silicon oxynitride are particularly preferable in terms of high thermal stability.

### Cross-Sectional Structure Example 2

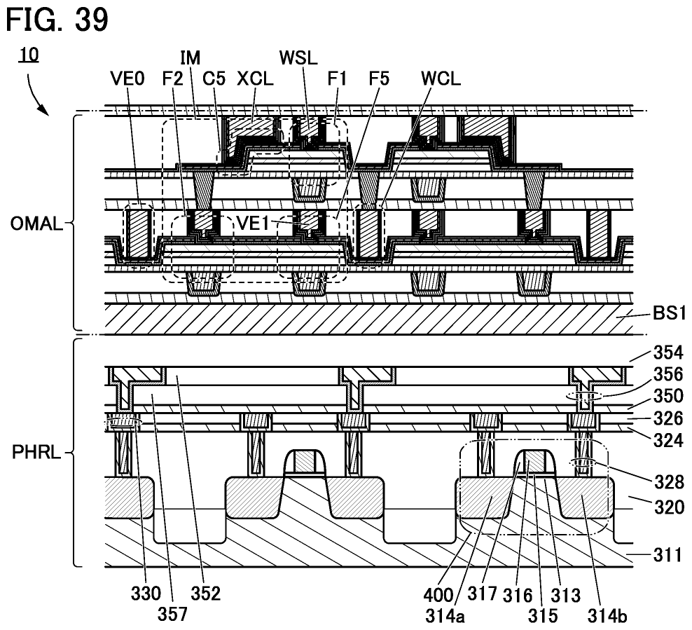

FIG. 39 is a schematic cross-sectional view, which differs from FIG. 38, showing an example of the arithmetic circuit 10 shown in FIG. 34A and FIG. 35.

The arithmetic circuit 10 in FIG. 39 differs from the arithmetic circuit 10 in FIG. 38 in that the arithmetic layer OMAL includes a substrate.

The arithmetic layer OMAL of the arithmetic circuit 10 in FIG. 39 includes a substrate BS1. The transistor F1, the transistor F2, the transistor F5, and the capacitor C5 are formed over the substrate BS1. The structure of the cell IM formed over the substrate BS1 is the same as that of the cell IM of the arithmetic circuit 10 in FIG. 38; however, the structure of the cell IM in FIG. 39 may be changed depending on circumstances.

As the substrate BS1, a substrate that can be applied to the substrate (e.g., the substrate 311) of the circuit layer PHRL can be used. For example, when a semiconductor substrate containing silicon as a material is used as the substrate BS1, the transistors F1, F2, and F5 can be Si transistors.

The substrate BS1 can be mounted over the substrate 311 by a flip-chip bonding method or a wire bonding method as described above. A bonding layer may be provided between the substrates to be bonded, and surface activated bonding and/or hydrophilic bonding may be used.

### Cross-Sectional Structure Example 3

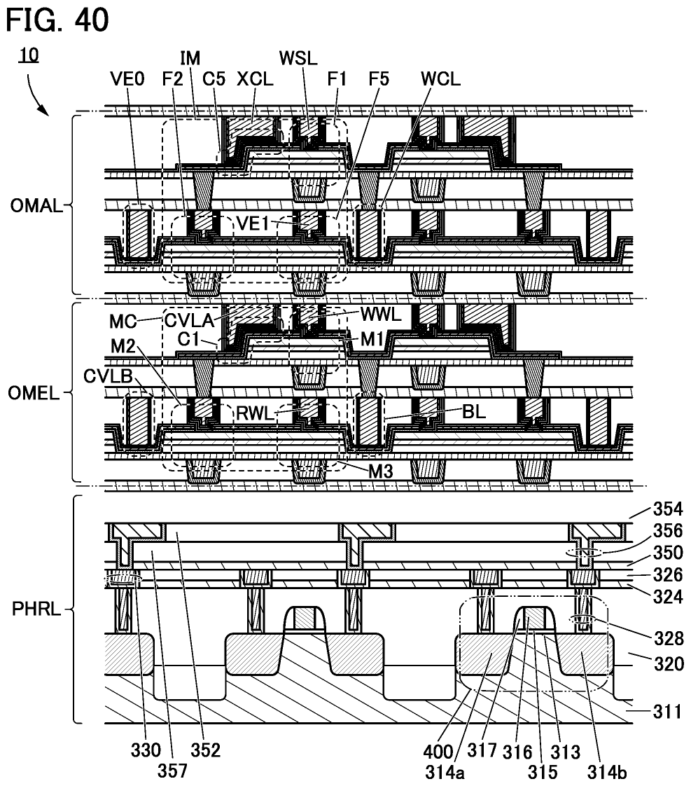

FIG. 40 is a schematic cross-sectional view showing an example of the arithmetic circuit 10 shown in FIG. 34B and FIG. 37.

The schematic cross-sectional view in FIG. 40 shows the circuit layer PHRL, the memory layer OMEL, and the arithmetic layer OMAL. Note that the arithmetic circuit 10 shown in FIG. 40 has a structure in which the memory layer OMEL is directly formed on the circuit layer PHRL and the arithmetic layer OMAL is directly formed on the memory layer OMEL

For the circuit layer PHRL shown in FIG. 40, the description of the circuit layer PHRL of the arithmetic circuit 10 shown in FIG. 38 can be referred to.

In the arithmetic circuit 10 shown in FIG. 40, the memory layer OMEL positioned above the circuit layer PHRL includes a memory cell MC. Specifically, FIG. shows a transistor M1, a transistor M2, a transistor M3, and a capacitor C1 included in the memory cell MC.

As shown in FIG. 40, the structure of the memory cell MC included in the memory layer OMEL can be the same as that of the cell IM included in the arithmetic layer OMAL. Thus, the above description of the cell IM included in the arithmetic layer OMAL is to be referred to for the structure of the memory cell MC included in the memory layer OMEL. The description of the cell IM included in the arithmetic layer OMAL can be read as the description of the memory cell MC included in the memory layer OMEL when the transistor F1 is replaced with the transistor M1, the transistor F2 is replaced with the transistor M2, the transistor F5 is replaced with the transistor M3, the capacitor C5 is replaced with the capacitor C1, the wiring WCL is replaced with a wiring BL, the wiring VE0 is replaced with a wiring CVLB, the wiring VE1 is replaced with a wiring RWL, the wiring XCL is replaced with a wiring CVLA, and the wiring WSL is replaced with a wiring WWL.

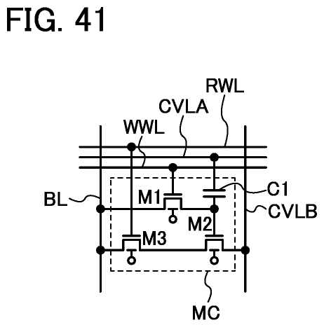

FIG. 41 shows an example circuit configuration usable for the memory cell MC shown in FIG. 40. In FIG. 41, the memory cell MC has a configuration of a three-transistor (3T) gain cell. Specifically, the memory cell MC in which the transistor M1 and the transistor M3 are OS transistors is sometimes referred to as a nonvolatile oxide semiconductor random access memory (NOSRAM (registered trademark)).

A first terminal of the transistor M1 is electrically connected to a gate of the transistor M2 and a first terminal of the capacitor C1. A second terminal of the transistor M1 is electrically connected to the wiring BL. A gate of the transistor M1 is electrically connected to the wiring WWL. A first terminal of the transistor M2 is electrically connected to a first terminal of the transistor M3, and a second terminal of the transistor M2 is electrically connected to the wiring CVLB. A second terminal of the transistor M3 is electrically connected to the wiring BL and a gate of the transistor M3 is electrically connected to the wiring RWL.

The wiring WWL functions as a write word line, for example. The wiring RWL functions as a read word line, for example. The wiring BL functions as a write bit line and a read bit line, for example.

The wiring CVLA has a function of supplying a constant potential, for example. The constant potential can be, for example, a high-level potential, a low-level potential, the ground potential, or a negative potential. Likewise, the wiring CVLB has a function of supplying any of the above constant potentials, for example. Note that a potential transmitted to the wiring CVLA and the wiring CVLB may be a variable potential (also referred to as a pulse voltage, a pulse signal, or the like), for example, instead of a constant potential.

The wiring CVLA and the wiring CVLB may supply the same potential. In the case where the wiring CVLA and the wiring CVLB supply the same potential, the wiring CVLA and the wiring CVLB may be electrically connected to each other (not shown).

In the case where one or more of the transistors M1 to M3 included in the memory cell MC in FIG. 40 are OS transistors, the memory cell MC can be referred to as an OS memory. The arithmetic circuit 10 that includes the memory cell can also be referred to as an OS memory.

As already described above, the OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current of the OS transistor is less likely to decrease even in a high-temperature environment. Thus, the OS memory can operate stably and have high reliability even in a high-temperature environment.

The structure of a semiconductor device of one embodiment of the present invention is not limited to the structures shown in FIGS. 34A and 34B, FIG. 35, FIG. 36, FIG. 37, FIG. 38, FIG. 39, and FIG. 40. Any of the structures shown in FIGS. 34A and 34B, FIG. 35, FIG. 37, FIG. 39, and FIG. 40 may be modified as appropriate to be used for the semiconductor device of one embodiment of the present invention.

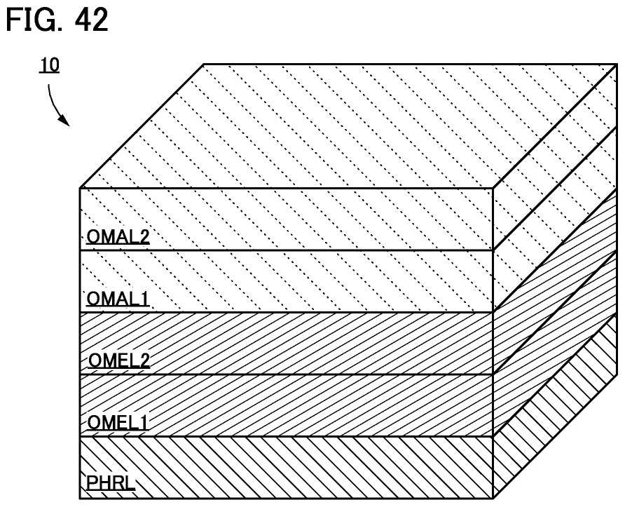

FIG. 42 shows a modification example of the arithmetic circuit 10 shown in FIG. 34B. The arithmetic circuit 10 shown in FIG. 42 differs from the arithmetic circuit 10 shown in FIG. 34B in that a memory layer OMEL1 and a memory layer OMEL2 are substituted for the memory layer OMEL and an arithmetic layer OMAL1 and an arithmetic layer OMAL2 are substituted for the arithmetic layer OMAL. In other words, the arithmetic circuit 10 shown in FIG. 42 includes the circuit layer PHRL, the memory layer OMEL1, the memory layer OMEL2, the arithmetic layer OMAL1, and the arithmetic layer OMAL2.

As described above, in the arithmetic circuit 10, the total number of the memory layer(s) OMEL and the arithmetic layer(s) OMAL provided over the circuit layer PHRL can be two or four. Note that the total number of the memory layers OMEL and the arithmetic layers OMAL provided over the circuit layer PHRL may be three or five or more.

### Cross-Sectional Structure Example 4

Here, another structure example of the transistors F1, F2, and F5 (the transistors M1 to M3) that are included in the arithmetic circuit 10 shown in FIG. 38 to FIG. 40 is described.

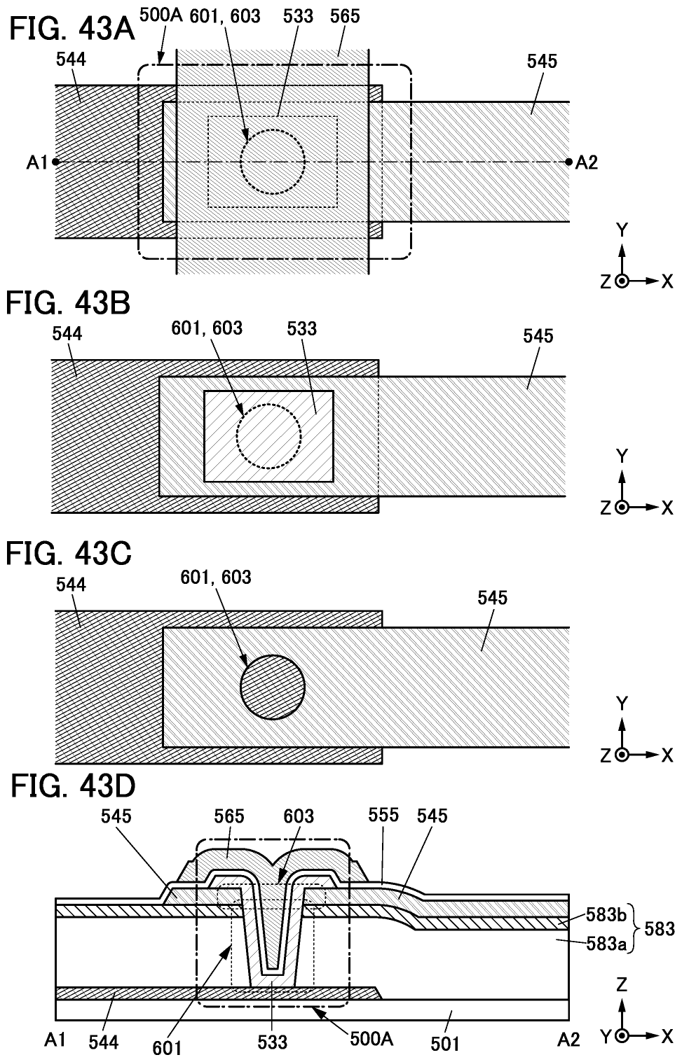

The plan view of FIG. 43A shows a structure example of a transistor 500A, which can substitute for the above-described transistors F1, F2, and F5 (transistors M1 to M3) of the arithmetic circuit 10, and the vicinity of the transistor 500A. FIG. 43D is a cross-sectional view taken along the dashed-dotted line A1-A2 in FIG. 43A. Note that in FIG. 43A, for example, some components of the transistor 500A such as an insulator are not illustrated. Also in the other plan views of the transistor, some components such as an insulator are not illustrated.

In the transistor 500A, the channel length direction is not substantially parallel to the substrate 311 but along the side surface of an opening provided in insulators.

The transistor 500A is provided over an insulator 501, for example. The transistor 500A includes conductors 544 and 545, a metal oxide 533, an insulator 555, and a conductor 565. In the example in FIG. 43A, the conductor 545 extends in the direction parallel to the conductor 544 and in the direction perpendicular to the conductor 565.

For the insulator 501, for example, the material that can be used for the insulator included in the above-described transistor F1, F2, or F5 can be used.

For the conductors 544 and 545, for example, the material that can be used for the conductor included in the above-described transistor F1, F2, or F5 can be used.

For the metal oxide 533, for example, the material that can be used for the metal oxide included in the transistor F1, F2, or F5 can be used.

In FIGS. 43A and 43D, the direction in which the conductor 545 extends is referred to as the X direction. The direction perpendicular to the X direction and parallel to the top surface of the insulator 501, for example, is referred to as the Y direction. The direction perpendicular the top surface of the insulator 501 is referred to as the Z direction. The definition of the X, Y, and Z directions applies in some drawings and does not apply in other drawings. The X, Y, and Z directions can be regarded as being perpendicular to one another. In the description of a plan view in this specification and the like, the X direction may be referred to as the right side or the left side and the Y direction may be referred to as the upper side or the lower side. Conversely, the right side may be referred to as the X direction, the left side may be referred to as the −X direction, the upper side may be referred to as the Y direction, and the lower side may be referred to as the −Y direction in some cases.

The conductor 544 serves as one of a source electrode and a drain electrode of the transistor 500A. The conductor 545 serves as the other of the source electrode and the drain electrode of the transistor 500A. The insulator 555 serves as a gate insulating layer of the transistor 500A. The conductor 565 serves as the gate electrode of the transistor 500A.

In the metal oxide 533, the whole region that is between the source electrode and the drain electrode and overlaps with the gate electrode with the gate insulating layer therebetween serves as a channel formation region. In the metal oxide 533, a region in contact with the source electrode serves as a source region and a region in contact with the drain electrode serves as a drain region.

The conductor 544 is provided over the insulator 501, an insulator 583 is provided over the insulator 501 and the conductor 544, and the conductor 545 is provided over the insulator 583. The insulator 583 can have a function of an interlayer insulating layer. The interlayer insulating layer here can be an interlayer film for separation of the source and drain electrodes in the transistor 500A. An insulator serving as an interlayer film may be provided above the transistor 500A in order that a circuit element or a wiring can be provided above the transistor 500A.

For the insulator 583, for example, the material that can be used for the insulator included in the transistor F1, F2, or F5 can be used.

Specifically, for example, an oxide or an oxynitride is preferably used for an insulator 583a. The insulator 583a is preferably formed using a film from which oxygen is released by heating. Silicon oxide or silicon oxynitride can be suitably used for the insulator 583a, for example. Oxygen released from the insulator 583a can be supplied to the metal oxide 533 from the insulator 583a. When oxygen is supplied from the insulator 583a to the metal oxide 533, in particular, the channel formation region of the metal oxide 533, oxygen vacancies in the metal oxide 533 and hydrogen that enters the oxygen vacancies can be reduced. Consequently, the transistor 500A can have favorable electrical characteristics and high reliability.

Specifically, silicon nitride, silicon nitride oxide, or aluminum oxide can be suitably used for an insulator 583b, for example. The insulator 583b preferably includes a region containing more nitrogen than the insulator 583a, for example. A material containing more nitrogen than the insulator 583a can be used for the insulator 583b, for example. A nitride or a nitride oxide is preferably used for the insulator 583b. Silicon nitride or silicon nitride oxide can be suitably used for the insulator 583b, for example. When silicon nitride or silicon nitride oxide is used for the insulator 583b, the insulator 583b can serve as a blocking layer that inhibits release of oxygen from the insulator 583a. When silicon nitride or silicon nitride oxide is used for the insulator 583b, the insulator 583b can serve as a blocking layer that inhibits diffusion of hydrogen into the metal oxide 533 through the insulator 583.

The insulator 583 includes an opening 601 reaching the conductor 544. The conductor 545 includes an opening 603 reaching the opening 601. Thus, the opening 603 includes a region overlapping with the opening 601.

FIG. 43A illustrates, as the components of the transistor 500A, the conductors 544 and 545, the metal oxide 533, the conductor 565, and the openings 601 and 603. The structure example in which the conductor 565 is excluded from the components illustrated in FIG. 43A is shown in FIG. 43B. In other words, FIG. 43B illustrates the conductors 544 and 545, the metal oxide 533, and the openings 601 and 603. The structure example in which the metal oxide 533 is excluded from the components illustrated in FIG. 43B is shown in FIG. 43C. In other words, FIG. 43C illustrates the conductors 544 and 545 and the openings 601 and 603.

As illustrated in FIGS. 43C and 43D, the conductor 545 includes the opening 603 in a region overlapping with the conductor 544. As illustrated in FIG. 43C, the conductor 545 can be formed to entirely surround the periphery of the opening 601 in a plan view. The conductor 545 is preferably absent in the opening 601. In other words, preferably, the conductor 545 is not in contact with the side surface of the insulator 583 on the opening 601 side.

FIGS. 43A to 43C show an example in which each of the openings 601 and 603 is circular in a plan view. High processing accuracy to form each of the openings 601 and 603 in a minute size is possible when the planar shapes of the openings 601 and 603 are each circular. Note that in this specification and the like, a circle is not limited to a perfect circle. For example, the planar shapes of the openings 601 and 603 may be elliptical, any shape including a curve, or polygonal.

In the example in FIG. 43D, the end portion of the conductor 545 on the opening 603 side is the same or substantially the same as the end portion of the insulator 583 on the opening 601 side. In other words, the planar shape of the opening 603 is the same or substantially the same as that of the opening 601. In this specification and the like, the end portion of the conductor 545 on the opening 603 side refers to the end portion of the bottom surface of the conductor 545 on the opening 603 side. The bottom surface of the conductor 545 refers to the surface on the insulator 583 side. The end portion of the insulator 583 on the opening 601 side refers to the end portion of the top surface of the insulator 583 on the opening 601 side. The top surface of the insulator 583 refers to the surface on the conductor 545 side. The planar shape of the opening 603 refers to that of the end portion of the bottom surface of the conductor 545 on the opening 603 side. The planar shape of the opening 601 refers to that of the end portion of the top surface of the insulator 583 on the opening 601 side.

In the case where end portions are the same or substantially the same, the end portions can also be said to be aligned or substantially aligned with each other. In the case where end portions are aligned or substantially aligned with each other and the case where planar shapes are the same or substantially the same, it can be said that outlines of stacked layers overlap with each other at least partly in a plan view. For example, the case of patterning an upper layer and a lower layer with the use of the same or partially the same mask patterns is included. The expression “end portions are substantially aligned with each other” or “planar shapes are substantially the same” also includes the case where the outlines do not completely overlap with each other; for instance, the end portion of the upper layer may be positioned inward or outward from the end portion of the lower layer.

The opening 601 can be formed with a resist mask used in the formation of the opening 603, for example. Specifically, after the conductor 544 is formed over the insulator 501, the insulator 583 over the insulator 501 and the conductor 544, a conductive film to be the conductor 545 over the insulator 583, and the resist mask over the conductive film are formed. Then, the opening 603 is formed in the conductive film with the use of the resist mask, and subsequently, the opening 601 is formed in the insulator 583 with the use of the resist mask, whereby the end portions of the openings 601 and 603 can be the same or substantially the same. With such a structure, the process can be simplified.

The metal oxide 533 is provided to include a region located inside the openings 601 and 603 to cover them. The metal oxide 533 has a shape along the top and side surfaces of the conductor 545, the side surface of the insulator 583, and the top surface of the conductor 544. The metal oxide 533 includes, for example, a region in contact with the top and side surfaces of the conductor 545, the side surface of the insulator 583, and the top surface of the conductor 544.

The metal oxide 533 preferably covers the end portion of the conductor 545 on the opening 603 side. For example, in FIG. 43D, the end portion of the metal oxide 533 is located over the conductor 545. The end portion of the metal oxide 533 can be said to be in contact with the top surface of the conductor 545.

Although the metal oxide 533 has a single-layer structure in FIG. 43D, for example, one embodiment of the present invention is not limited thereto. The metal oxide 533 may have a stacked-layer structure of two or more layers.

The insulator 555 serving as the gate insulating layer of the transistor 500A is provided to include regions positioned inside the openings 601 and 603 so as to cover the openings 601 and 603. The insulator 555 is provided over the metal oxide 533, the conductor 545, and the insulator 583. The insulator 555 can include a region in contact with the top and side surfaces of the metal oxide 533, the top and side surfaces of the conductor 545, and the top surface of the insulator 583. The insulator 555 has a shape along the top surface of the insulator 583, the top and side surfaces of the conductor 545, and the top and side surfaces of the metal oxide 533.

The conductor 565 serving as the gate electrode of the transistor 500A is provided over the insulator 555 and can include a region in contact with the top surface of the insulator 555. The conductor 565 includes a region overlapping with the metal oxide 533 with the insulator 555 provided therebetween. The conductor 565 has a shape along the top surface of the insulator 555.

For example, as illustrated in FIG. 43D, the conductor 565 includes a region overlapping with the metal oxide 533 with the insulator 555 provided therebetween in the openings 601 and 603. In the example in FIG. 43D, the conductor 565 includes a region overlapping with the conductors 544 and 545 with the insulator 555 and the metal oxide 533 provided therebetween. In the example in FIG. 43D, the conductor 565 includes a region overlapping with the conductors 544 and 545 with the insulator 555 therebetween but without the metal oxide 533 therebetween. The conductor 565 covers the entire metal oxide 533. With such a structure, a gate electric field can be applied to the entire metal oxide 533, which allows the transistor 500A to have better electrical characteristics, such as a higher on-state current.

The transistor 500A is a so-called top-gate transistor, in which the gate electrode is provided above the metal oxide 533. Furthermore, since the bottom surface of the metal oxide 533 includes regions in contact with the source electrode and the drain electrode, the transistor 500A can be referred to as a top-gate bottom-contact (TGBC) transistor.

The transistor 500A can be used as, for example, one or both of the transistor included in the cell IM and the transistor included in the circuit layer PHRL. The transistor 500A may be used as the transistor included in the memory layer OMEL.

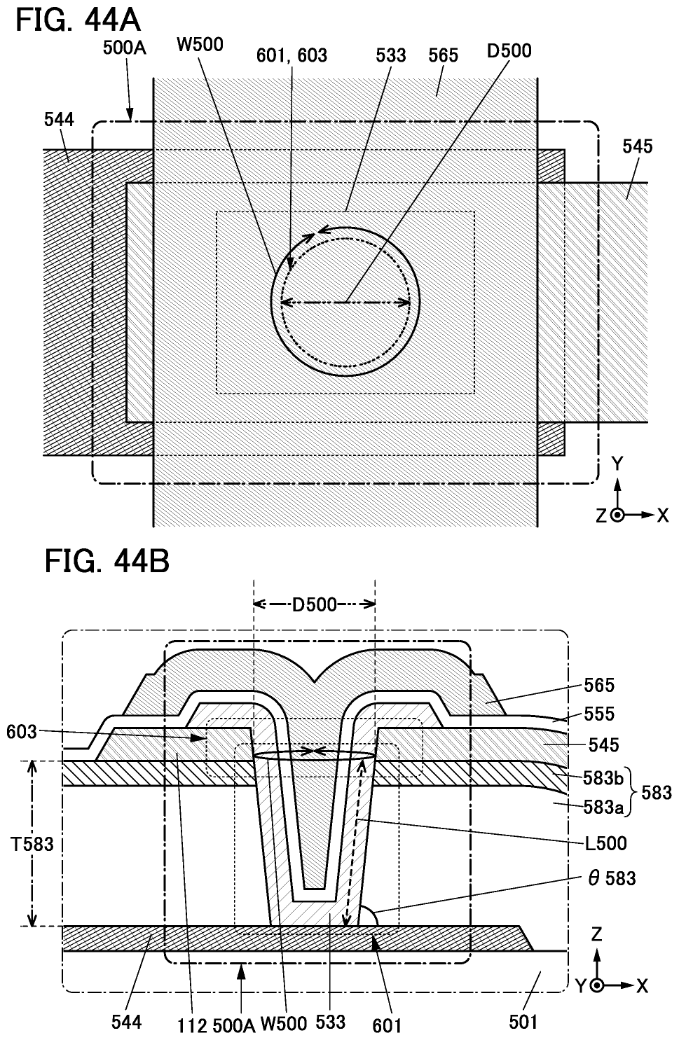

The channel length and channel width of the transistor 500A are described with reference to FIGS. 44A and 44B. FIG. 44A is an enlarged view of the plan view of FIG. 43A showing the structure example of the transistor 500A and the vicinity thereof. FIG. 44B is an enlarged view of the cross-sectional view of FIG. 43D showing the structure example of the transistor 500A and the vicinity thereof.

In the metal oxide 533, the region in contact with the conductor 544 serves as one of the source region and the drain region, the region in contact with the conductor 545 serves as the other of the source region and the drain region, and the region between the source region and the drain region serves as the channel formation region.

The channel length of the transistor 500A is a distance between the source region and the drain region. In FIG. 44B, a channel length L500 of the transistor 500A is indicated by a dashed double-headed arrow. In the cross section, the channel length L500 is a distance between an end portion of the region where the metal oxide 533 is in contact with the conductor 544 and an end portion of the region where the metal oxide 533 is in contact with the conductor 545.

The channel length L500 of the transistor 500A corresponds to the length of the side surface of the insulator 583 on the opening 601 side when seen from the XZ plane. That is, the channel length L500 depends on a thickness T583 of the insulator 583 and an angle θ583 formed between the side surface of the insulator 583 on the opening 601 side and the formation surface of the insulator 583 (the top surface of the conductor 544 here), and is not affected by the performance of a light-exposure apparatus used for manufacturing the transistor. Thus, the channel length L500 can be a smaller value than the resolution limit of the light-exposure apparatus and thus the transistor can be miniaturized. For example, the channel length L500 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. In FIG. 44B, the thickness T583 of the insulator 583 is denoted by a dashed-dotted double-headed arrow.

When the transistor 500A is used as the transistor included in the cell IM of the arithmetic circuit 10, the transistor included in the cell IM can be miniaturized, and the arithmetic circuit 10 can be miniaturized. The transistor 500A with a short channel length L500 can have a high on-state current. Thus, with the use of the transistor 500A as the transistor included in the arithmetic circuit 10, such as the transistor included in the cell IM of the arithmetic circuit 10, the cell IM of the arithmetic circuit 10 can be driven at high speed.

The channel length L500 can be changed by adjustment of the thickness T583 of the insulator 583 and the angle θ583.

The thickness T583 of the insulator 583 is preferably greater than or equal to 0.010 μm and less than 3.0 μm, further preferably greater than or equal to 0.050 μm and less than 3.0 μm, still further preferably greater than or equal to 0.10 μm and less than 3.0 μm, yet still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

The side surface of the insulator 583 on the opening 601 side preferably has a tapered shape. The angle θ583 formed by the side surface of the insulator 583 on the opening 601 side and the formation surface of the insulator 583 (the top surface of the conductor 544 here) is preferably less than 90°. By reducing the angle θ583, coverage with the layer (e.g., the metal oxide 533) over the insulator 583 can be improved. However, reducing the angle θ583 might reduce the contact area between the metal oxide 533 and the conductor 544 to increase the contact resistance between the metal oxide 533 and the conductor 544. The angle θ583 is preferably greater than or equal to 45° and less than 90°, further preferably greater than or equal to 50° and less than 90°, still further preferably greater than or equal to 55° and less than 90°, yet still further preferably greater than or equal to 60° and less than 90°, yet still further preferably greater than or equal to 60° and less than or equal to 85°, yet still further preferably greater than or equal to 65° and less than or equal to 85°, yet still further preferably greater than or equal to 65° and less than or equal to 80°, yet still further preferably greater than or equal to 70° and less than or equal to 80°. With the angle θ583 set in the above range, coverage with the layer (e.g., the metal oxide 533) over the conductor 544 and the insulator 583 can be improved, which can inhibit defects such as step disconnection or a void from being generated in the layer. In addition, the contact resistance between the metal oxide 533 and the conductor 544 can be reduced.

In this specification and the like, step disconnection refers to a phenomenon in which a layer, a film, or an electrode is split because of the shape of the formation surface (e.g., a step).

Although FIG. 44B illustrates a structure in which the side surface of the insulator 583 on the opening 601 side is linear in the cross section, for example, one embodiment of the present invention is not limited thereto. In the cross section, the side surface of the insulator 583 on the opening 601 side may be curved or include both a linear region and a curved region.

The channel width of the transistor 500A is the width of the source region or the drain region in a direction perpendicular to the channel length direction. In other words, the channel width is the width of the region where the metal oxide 533 is in contact with the conductor 544 or the width of the region where the metal oxide 533 is in contact with the conductor 545 in the direction perpendicular to the channel length direction. Here, the channel width of the transistor 500A is described as the width of the region where the metal oxide 533 is in contact with the conductor 545 in the direction perpendicular to the channel length direction. In FIGS. 44A and 44B, a channel width W500 of the transistor 500A is indicated by a solid double-headed arrow. The channel width W500 is the length of the end portion of the bottom surface of the conductor 545 on the opening 603 side in a plan view.

The channel width W500 depends on the planar shape of the opening 603. In FIGS. 44A and 44B, a width D500 of the opening 603 is denoted by a dashed double-dotted double-headed arrow. The width D500 is the shorter side of the smallest rectangle circumscribing the opening 603 in a plan view. When the opening 603 is formed by a photolithography method, the width D500 of the opening 603 is greater than or equal to the resolution limit of the light-exposure apparatus. For example, the width D500 is preferably greater than or equal to 0.20 μm and less than 5.0 μm, further preferably greater than or equal to 0.20 μm and less than 4.5 μm, still further preferably greater than or equal to 0.20 μm and less than 4.0 μm, yet still further preferably greater than or equal to 0.20 μm and less than 3.5 μm, yet still further preferably greater than or equal to 0.20 μm and less than 3.0 μm, yet still further preferably greater than or equal to 0.20 μm and less than 2.5 μm, yet still further preferably greater than or equal to 0.20 and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. Note that when the planar shape of the opening 603 is circular, the width D500 corresponds to the diameter of the opening 603, the channel width W500 can be equal to the length of the periphery of the opening 603 in a plan view and calculated to be “D500×π”.

Since the size of the transistor 500A is small, a display apparatus that includes the transistor 500A can achieve high resolution. Since the on-state current of the transistor 500A is high, a display apparatus that includes the transistor 500A can achieve high luminance. Since the operation speed of the transistor 500A is high, a display apparatus that includes the transistor 500A can achieve a high driving speed. Since the electrical characteristics of the transistor 500A are stable, a display apparatus that includes the transistor 500A can be highly reliable. Since the off-state current of the transistor 500A is low, a display apparatus that includes the transistor 500A can achieve low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 7

In this embodiment, a transistor whose channel formation region includes an oxide semiconductor (OS transistor) is described. Brief description is also made on comparison of an OS transistor with a transistor whose channel formation region includes silicon (also referred to as Si transistor).

### [Os Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In some cases, the OS transistor has a defect that is an oxygen vacancy in the oxide semiconductor into which hydrogen enters (hereinafter sometimes referred to as V_{O}H), which generates an electron serving as a carrier. When V_{O}H is formed in the channel formation region, the donor concentration in the channel formation region is increased in some cases. As the donor concentration in the channel formation region increases, the threshold voltage might vary. Accordingly, when the channel formation region in the oxide semiconductor includes oxygen vacancies, the transistor tends to have normally-on characteristics (a channel is generated even when no voltage is applied to a gate electrode and a current flows through the transistor). Therefore, the impurities, oxygen vacancies, and V_{O}H are preferably reduced as much as possible in the channel formation region of the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as I_{off}) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. Meanwhile, an OS transistor includes an oxide semiconductor that is a semiconductor material with a large band gap, and thus is less likely to suffer from the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometime also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length needs to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻ region and the source and drain regions become n⁺ regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has advantages over a Si transistor, such as a low off-state current and capability of having a short channel length.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

### Embodiment 8

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

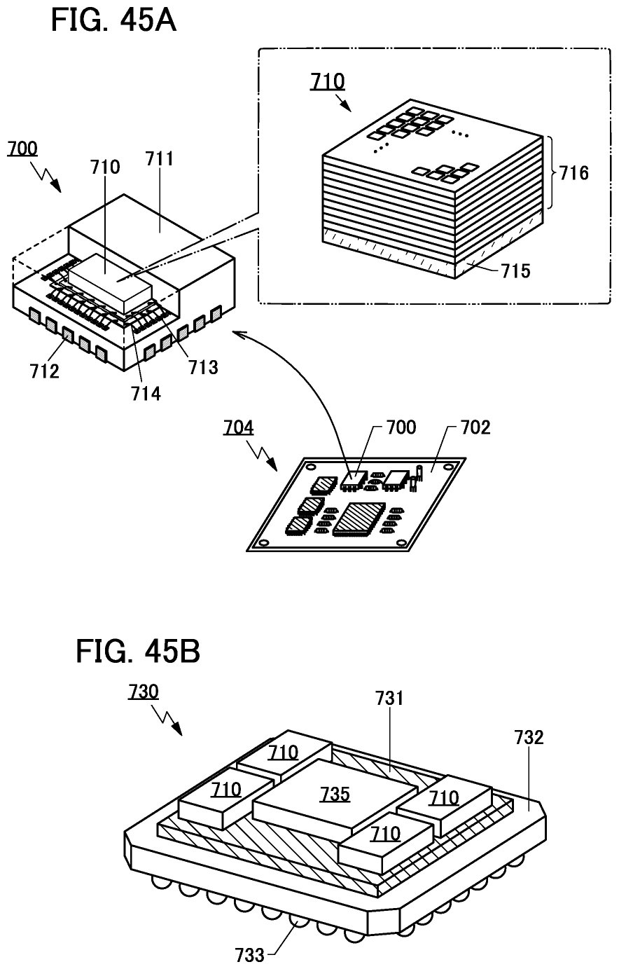

FIG. 45A is a perspective view of a substrate (a circuit board 704) on which an electronic component 700 is mounted. The electronic component 700 illustrated in FIG. 45A includes a semiconductor device 710 in a mold 711. Some components are omitted in FIG. 45A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase a memory bandwidth.

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the formation process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 45B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a central processing unit (CPU), a graphics processing unit (GPU), or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 45B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by any of various mounting methods other than BGA and PGA. Examples of a mounting method include a staggered pin grid array (SPGA), a land grid array (LGA), a quad flat package (QFP), a quad flat J-leaded package (QFJ), and a quad flat non-leaded package (QFN).

### [Electronic Device]

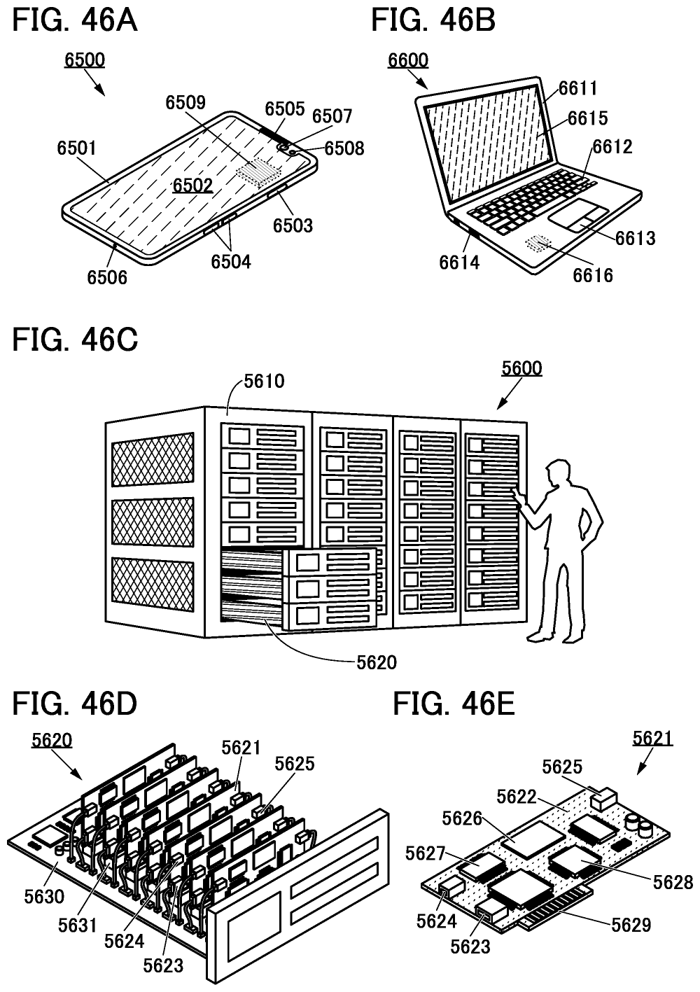

FIG. 46A is a perspective view of an electronic device 6500. The electronic device 6500 illustrated in FIG. 46A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are used as the control device 6509, for example. The semiconductor device of one embodiment of the present invention can be used for the display portion 6502, the control device 6509, and the like.

An electronic device 6600 illustrated in FIG. 46B is an information terminal that can be used as a notebook personal computer. The electronic device 6600 includes a housing 6611, a keyboard 6612, a pointing device 6613, an external connection port 6614, a display portion 6615, and a control device 6616. One or more selected from a CPU, a GPU, and a memory device are used as the control device 6616, for example. The semiconductor device of one embodiment of the present invention can be used for the display portion 6615, the control device 6616, and the like. Note that the semiconductor device of one embodiment of the present invention is preferably used for the control devices 6509 and 6616, in which case power consumption can be reduced.

### [Large Computer]

FIG. 46C is a perspective view of a large computer 5600. In the large computer 5600 illustrated in FIG. 46C, a plurality of rack mount computers 5620 are stored in a rack 5610. Note that the large computer 5600 may be referred to as a supercomputer.

The computer 5620 can have a structure in a perspective view of FIG. 46D, for example. In FIG. 46D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 46E is an example of a processing board provided with a CPU, a GPU, a memory device, and the like. The PC card 5621 includes a board 5622. The board 5622 includes the connection terminals 5623, 5624, and 5625, a semiconductor device 5626, a semiconductor device 5627, a semiconductor device 5628, and a connection terminal 5629. Although FIG. 46E also illustrates semiconductor devices other than the semiconductor devices 5626, 5627, and 5628, the following description of the semiconductor devices 5626, 5627, and 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can serve as, for example, an interface for performing power supply, signal input, or the like to the PC card 5621. For another example, they can serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI®.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used even in an environment where radiation can enter. For example, the OS transistor can be suitably used in outer space.

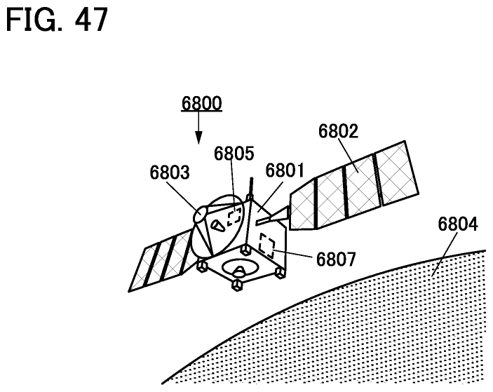

FIG. 47 illustrates an artificial satellite 6800 as an example of space equipment. The artificial satellite 6800 includes a body 6801, a solar panel 6802, an antenna 6803, a secondary battery 6805, and a control device 6807. FIG. 47 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 47, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a memory device are used as the control device 6807, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high temperature environment. Thus, the reliability of the data center can be increased.

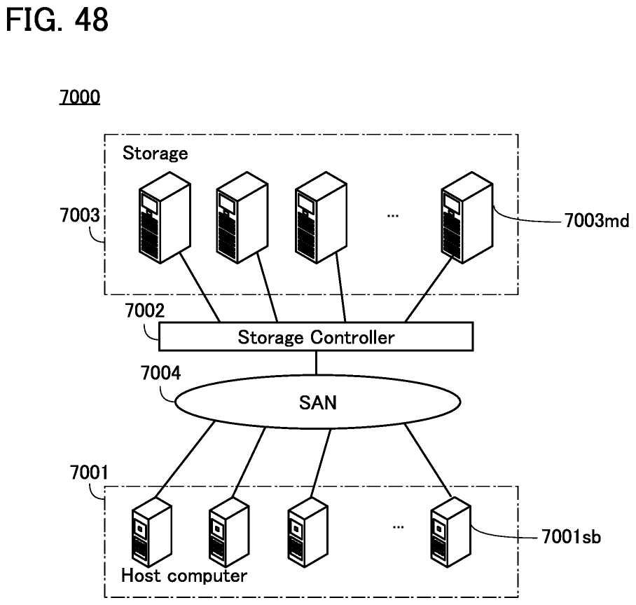

FIG. 48 illustrates a storage system that can be used in a data center. A storage system 7000 illustrated in FIG. 48 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with any of the other embodiments in this specification as appropriate. For example, the configurations, structures, methods, and the like described in this embodiment can be used in an appropriate combination with any of the configurations, structures, methods, and the like described in the other embodiments and the like.

This application is based on Japanese Patent Application Serial No. 2022-173321 filed with Japan Patent Office on Oct. 28, 2022, the entire contents of which are hereby incorporated by reference.

What is claimed is:

1. An operation method of a semiconductor device, the operation method comprising: an error obtaining step, a first correction step, a second correction step, a third correction step, and an inference step,
wherein the semiconductor device comprises a first cell array, a second cell array, a first circuit, a second circuit, a third circuit, a fourth circuit, and a fifth circuit,
wherein the first cell array comprises a first arithmetic cell and a first driving cell,
wherein the second cell array comprises a second arithmetic cell and a second driving cell,
wherein the error obtaining step comprises a first step and a second step,
wherein the first step comprises a first sub step, a second sub step, a third sub step, a fourth sub step, a fifth sub step, and a sixth sub step,
wherein the first substep comprises:
a step in which second reference data is written from the second circuit to the first driving cell;
a step in which a potential corresponding to the second reference data is input to the first arithmetic cell; and
a step in which first reference data is written from the first circuit to the first arithmetic cell included in a first region of the first cell array,
wherein the second substep comprises:
a step in which a result of a product-sum operation of the first reference data and the second reference data is input from the first cell array to the third circuit;
a step in which third reference data corresponding to the result of the product-sum operation of the first reference data and the second reference data is written from the third circuit to the second driving cell;
a step in which a potential corresponding to the third reference data is input to the second arithmetic cell; and
a step in which third standard data is written from the fourth circuit to the second arithmetic cell,
wherein the third sub step comprises:
a step in which second standard data is written from the second circuit to the first driving cell; and
a step in which first standard data is written from the first circuit to the first arithmetic cell included in the first region of the first cell array,
wherein the fourth sub step comprises:
a step in which a result of a product-sum operation of the first standard data and the second standard data is input from the first cell array to the third circuit;
a step in which fourth standard data corresponding to the result of the product-sum operation of the first standard data and the second standard data is written from the third circuit to the second driving cell;
a step in which a potential corresponding to the fourth standard data is input to the second arithmetic cell;
a step in which a result of a product-sum operation of the third standard data and the fourth standard data is input from the second cell array to the fifth circuit;
a step in which the fifth circuit outputs a first output value corresponding to the result of the product-sum operation of the third standard data and the fourth standard data; and
a step of obtaining a theoretical value that is the result of the product-sum operation of the first standard data and the second standard data,
wherein the fifth sub step comprises a step of updating the first standard data and the second standard data and a step of repetitively performing the third sub step and the fourth sub step,
wherein the sixth substep comprises a step of creating a first graph using a plurality of the theoretical values and a plurality of the first output values obtained in updates of the first standard data and the second standard data by the fourth sub step repetitively performed,
wherein the second step comprises:
a step of calculating, as a first error, the theoretical value such that the first output value is smallest and larger than 0 from the first graph; and
a step of calculating a second error that is a difference between a gradient in a range in which the first output value is larger than 0 in the first graph and a gradient in a range in which the first output value is larger than 0 in a standard graph,
wherein the first correction step comprises a step of obtaining correction data from the first error,
wherein the second correction step comprises a step of obtaining a first correction coefficient from the second error,
wherein the third correction step comprises a step of obtaining a second correction coefficient from the second error, and
wherein the inference step comprises a step in which data retained in the first cell array reflects the correction data and the first correction coefficient and data retained in the second cell array reflects the second correction coefficient.

2. The operation method of the semiconductor device, according to claim 1, further comprising a third step, a fourth step, a fifth step, and a sixth step,
wherein the third step comprises a step of proceeding to the fourth step when the first error is outside a first allowable range,
wherein the fourth step comprises a step of generating the correction data corresponding to the first error,
wherein the fifth step comprises a seventh sub step, an eighth sub step, a ninth sub step, and a tenth sub step,
wherein the seventh substep comprises:
a step in which the second standard data is written from the second circuit to the first driving cell;
a step in which the first standard data is written from the first circuit to the first arithmetic cell included in the first region of the first cell array; and
a step in which the correction data is written from the first circuit to the first arithmetic cell included in a second region of the first cell array,
wherein the eighth substep comprises:
a step in which a result of a product-sum operation of the second standard data and a sum of the first standard data and the correction data is input from the first cell array to the third circuit;
a step in which fifth standard data corresponding to the result of the product-sum operation of the second standard data and the sum of the first standard data and the correction data is written from the third circuit to the second driving cell;
a step in which a potential corresponding to the fifth standard data is input to the second arithmetic cell;
a step in which a result of a product-sum operation of the third standard data and the fifth standard data is input from the second cell array to the fifth circuit; and
a step in which the fifth circuit outputs a second output value corresponding to the result of the product-sum operation of the third standard data and the fifth standard data,
wherein the ninth sub step comprises a step of updating the first standard data and the second standard data and a step of repetitively performing the seventh sub step and the eighth sub step,
wherein the tenth sub step comprises a step of creating a second graph using a plurality of the second output values obtained in updates of the first standard data and the second standard data by the ninth sub step repetitively performed and the plurality of theoretical values,
wherein the sixth step comprises a step in which the theoretical value such that the second output value is smallest and larger than 0 is calculated from the second graph and the theoretical value is updated to the first error, and
wherein the third step is performed immediately after the sixth step.

3. The operation method of the semiconductor device, according to claim 2, further comprising a seventh step, an eighth step, a ninth step, and a tenth step,
wherein the third step comprises a step of proceeding to the seventh step when the first error is within the first allowable range or when the third step is repeated a first predetermined number of times,
wherein the seventh step comprises a step of proceeding to the eighth step when the second error is outside a second allowable range,
wherein the eighth step comprises an eleventh substep, a twelfth substep, and a thirteenth sub step,
wherein the eleventh sub step comprises:
a step in which the second reference data is written from the second circuit to the first driving cell;
a step in which a potential corresponding to the second reference data is input to the first arithmetic cell;
a step in which the first reference data is written from the first circuit to the first arithmetic cell included in the first region of the first cell array; and
a step in which the correction data is written from the first circuit to the first arithmetic cell included in the second region of the first cell array,
wherein the twelfth substep comprises:
a step in which a result of a product-sum operation of the second reference data and a sum of the first reference data and the correction data is input from the first cell array to the third circuit;
a step in which fourth reference data corresponding to the result of the product-sum operation of the second reference data and the sum of the first reference data and the correction data is written from the third circuit to the second driving cell;
a step in which a potential corresponding to the fourth reference data is input to the second arithmetic cell;
a step of generating the first correction coefficient corresponding to the second error; and
a step in which sixth standard data that is a product of the third standard data and the first correction coefficient is written from the fourth circuit to the second arithmetic cell,
wherein the thirteenth substep comprises:
a step in which the second standard data is written from the second circuit to the first driving cell;
a step in which the first standard data is written from the first circuit to the first arithmetic cell included in the first region of the first cell array; and
a step in which the correction data is written from the first circuit to the first arithmetic cell included in the second region of the first cell array,
wherein the ninth step comprises a fourteenth sub step, a fifteenth sub step, and a sixteenth sub step,
wherein the fourteenth sub step comprises:
a step in which the result of the product-sum operation of the second standard data and the sum of the first standard data and the correction data is input from the first cell array to the third circuit;
a step in which the fifth standard data corresponding to the result of the product-sum operation of the second standard data and the sum of the first standard data and the correction data is written from the third circuit to the second driving cell;
a step in which a potential corresponding to the fifth standard data is input to the second arithmetic cell;
a step in which a result of a product-sum operation of the sixth standard data and the fifth standard data is input from the second cell array to the fifth circuit; and
a step in which the fifth circuit outputs a third output value corresponding to the result of the product-sum operation of the sixth standard data and the fifth standard data,
wherein the fifteenth sub step comprises a step of updating the first standard data and the second standard data and a step of repetitively performing the thirteenth sub step and the fourteenth sub step,
wherein the sixteenth sub step comprises a step of creating a third graph using a plurality of the third output values obtained in updates of the first standard data and the second standard data by the fourteenth sub step repetitively performed and the plurality of theoretical values,
wherein the tenth step comprises a step of updating, to the second error, a difference between a gradient in a range in which the first output value is larger than 0 in the third graph and a gradient in the standard graph, and
wherein the seventh step is performed immediately after the tenth step.

4. The operation method of the semiconductor device, according to claim 3, further comprising an eleventh step, a twelfth step, a thirteenth step, and a fourteenth step,
wherein the seventh step comprises a step of proceeding to the eleventh step when the second error is within the second allowable range or when the seventh step is repeated a second predetermined number of times,
wherein the eleventh step comprises a step of proceeding to the twelfth step when the second error is outside the second allowable range,
wherein the twelfth step comprises a seventeenth substep, an eighteenth substep, and a nineteenth sub step,
wherein the seventeenth substep comprises:
a step in which the second reference data is written from the second circuit to the first driving cell;
a step in which a potential corresponding to the second reference data is input to the first arithmetic cell;
a step of generating the second correction coefficient corresponding to the second error; and
a step in which fifth reference data that is a product of the first reference data and the second correction coefficient is written from the first circuit to the first arithmetic cell,
wherein the eighteenth sub step comprises:
a step in which a result of a product-sum operation of the second reference data and a sum of the fifth reference data and the correction data is input from the first cell array to the third circuit;
a step in which sixth reference data corresponding to the result of the product-sum operation of the second reference data and the sum of the fifth reference data and the correction data is written from the third circuit to the second driving cell;
a step in which a potential corresponding to the sixth reference data is input to the second arithmetic cell; and
a step in which the sixth standard data is written from the fourth circuit to the second arithmetic cell,
wherein the nineteenth sub step comprises:
a step in which the second standard data is written from the second circuit to the first driving cell;
a step in which the first standard data is written from the first circuit to the first arithmetic cell included in the first region of the first cell array; and
a step in which the correction data is written from the first circuit to the first arithmetic cell included in the second region of the first cell array,
wherein the thirteenth step comprises a twentieth substep, a twenty-first substep, and a twenty-second substep,
wherein the twentieth sub step comprises:
a step in which the result of the product-sum operation of the second standard data and the sum of the first standard data and the correction data is input from the first cell array to the third circuit;
a step in which the fifth standard data corresponding to the result of the product-sum operation of the second standard data and the sum of the first standard data and the correction data is written from the third circuit to the second driving cell;
a step in which a potential corresponding to the fifth standard data is input to the second arithmetic cell and the second driving cell;
a step in which the result of the product-sum operation of the sixth standard data and the fifth standard data is input from the second cell array to the fifth circuit; and
a step in which the fifth circuit outputs a fourth output value corresponding to the result of the product-sum operation of the sixth standard data and the fifth standard data,
wherein the twenty-first substep comprises a step of updating the first standard data and the second standard data and a step of repetitively performing the nineteenth substep and the twentieth substep,
wherein the twenty-second sub step comprises a step of creating a fourth graph using a plurality of the fourth output values obtained in updates of the first standard data and the second standard data by the twentieth substep repetitively performed and the plurality of theoretical values,
wherein the fourteenth step comprises a step of updating, to the second error, a difference between a gradient in a range in which the fourth output value is larger than 0 in the fourth graph and a gradient in the standard graph, and
wherein the eleventh step is performed immediately after the fourteenth step.

5. The operation method of the semiconductor device, according to claim 4, further comprising a fifteenth step,
wherein the eleventh step comprises a step of proceeding to the fifteenth step when the second error is within the second allowable range or when the eleventh step is repeated a third predetermined number of times, and
wherein the fifteenth step comprises a step of proceeding to the third step when the first error is outside the first allowable range and the second error is outside the second allowable range.

6. The operation method of the semiconductor device, according to claim 5,
wherein the third circuit is electrically connected to the first arithmetic cell through a first wiring,
wherein the third circuit is electrically connected to the second driving cell and the second arithmetic cell through a second wiring,
wherein the third circuit is configured to perform an arithmetic operation of a first activation function using, as an input value, an amount of a first current flowing in the first wiring and to supply a result of the arithmetic operation of the first activation function as a current to the second wiring,
wherein the fifth circuit is electrically connected to the second arithmetic cell through a third wiring,
wherein the fifth circuit is electrically connected to a fourth wiring, and
wherein the fifth circuit is configured to perform an arithmetic operation of a second activation function using, as an input value, an amount of a third current flowing in the third wiring and to output a result of the arithmetic operation of the second activation function as digital data to the fourth wiring.

7. The operation method of the semiconductor device, according to claim 6,
wherein the first arithmetic cell comprises a first transistor, a second transistor, and a first capacitor,
wherein the second arithmetic cell comprises a third transistor, a fourth transistor, and a second capacitor,
wherein the first driving cell comprises a fifth transistor, a sixth transistor, and a third capacitor,
wherein the second driving cell comprises a seventh transistor, an eighth transistor, and a fourth capacitor,
wherein one of a source and a drain of the first transistor is electrically connected to a gate of the second transistor and a first terminal of the first capacitor,
wherein the other of the source and the drain of the first transistor is electrically connected to one of a source and a drain of the second transistor and the first wiring,
wherein one of a source and a drain of the third transistor is electrically connected to a gate of the fourth transistor and a first terminal of the second capacitor,
wherein the other of the source and the drain of the third transistor is electrically connected to one of a source and a drain of the fourth transistor and the third wiring,
wherein one of a source and a drain of the fifth transistor is electrically connected to a gate of the sixth transistor and a first terminal of the third capacitor,
wherein the other of the source and the drain of the fifth transistor is electrically connected to one of a source and a drain of the sixth transistor and a fifth wiring,
wherein one of a source and a drain of the seventh transistor is electrically connected to a gate of the eighth transistor and a first terminal of the fourth capacitor,
wherein the other of the source and the drain of the seventh transistor is electrically connected to one of a source and a drain of the eighth transistor and the second wiring,
wherein a second terminal of the first capacitor and a second terminal of the third capacitor are electrically connected to the fifth wiring,
wherein a second terminal of the second capacitor and a second terminal of the fourth capacitor are electrically connected to the second wiring,
wherein the first circuit is electrically connected to the first wiring,
wherein the second circuit is electrically connected to the fifth wiring, and
wherein the fourth circuit is electrically connected to the third wiring.

8. The operation method of the semiconductor device, according to claim 7,
wherein the first arithmetic cell comprises a ninth transistor,
wherein the second arithmetic cell comprises a tenth transistor,
wherein the first driving cell comprises an eleventh transistor,
wherein the second driving cell comprises a twelfth transistor,
wherein one of a source and a drain of the ninth transistor is directly and electrically connected to the other of the source and the drain of the first transistor and the first wiring,
wherein the other of the source and the drain of the ninth transistor is directly and electrically connected to the one of the source and the drain of the second transistor,
wherein one of a source and a drain of the tenth transistor is directly and electrically connected to the other of the source and the drain of the third transistor and the third wiring,
wherein the other of the source and the drain of the tenth transistor is directly and electrically connected to the one of the source and the drain of the fourth transistor,
wherein one of a source and a drain of the eleventh transistor is directly and electrically connected to the other of the source and the drain of the fifth transistor and the fifth wiring,
wherein the other of the source and the drain of the eleventh transistor is directly and electrically connected to the one of the source and the drain of the sixth transistor,
wherein one of a source and a drain of the twelfth transistor is directly and electrically connected to the other of the source and the drain of the seventh transistor and the second wiring, and
wherein the other of the source and the drain of the twelfth transistor is directly and electrically connected to the one of the source and the drain of the eighth transistor.

9. The operation method of the semiconductor device, according to claim 8,
wherein a channel formation region of each of the first to twelfth transistors comprises one or more of indium, zinc, and an element M, and
wherein the element M is one or more of aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.
